(19) United States
(12) Patent Application Publication
(10) Pub. No.: US 2026/0367179 A1
(43) Pub. Date: Nov. 19, 2026

(54) METHODS AND SYSTEMS TO DETECT CROSS-PORT FAULTS IN A FAULT MANAGED POWER (FMP) TRANSMISSION SYSTEM

(71) Applicant: VoltServer Inc., East Greenwich, RI (US)

(72) Inventors: Jonathan Casey, North Kingstown, RI (US); Charles Lutz, Providence, RI (US)

(21) Appl. No.: 19/677,766

(22) Filed: May 14, 2026

Related U.S. Application Data
(60) Provisional application No. 63/805,606, filed on May 14, 2025.

(51) Int. Cl. G01R 31/40

(52) U.S. Cl. CPC G01R 31/40

(57) ABSTRACT

In some aspects, this disclosure relates to methods and systems to detect cross-port faults in a fault managed power (FMP) transmission system, the method including: providing a first and second transmission line having a high potential conductor and a low potential conductor; connecting the first transmission line to a first transmitter and a first receiver; connecting the second transmission line to a second transmitter and second receiver; causing current to flow from a first and second power source to the first and second transmission line, respectively, during FMP power transfer intervals and nominally isolating the first and second power source from the first and second transmission line, respectively, during FMP isolation intervals; during isolation intervals, monitoring for electrical characteristics indicative of a first, second, third, or fourth fault current; in response to detection of a fault current, limiting the fault current.

### CROSS-REFERENCE TO RELATED APPLICATIONS

This application claims the benefit of priority to U.S. Provisional Application No. 63/805,606, filed on May 14, 2025, and entitled “Method and Apparatus for Periodic Capacitive Snubber Switching with Cross-Port Fault Detection,” which is incorporated by reference herein in its entirety.

### FIELD OF THE DISCLOSURE

This disclosure relates generally to power distribution system safety protection devices. In particular, this disclosure relates to methods and systems to detect cross-port faults in a fault managed power (FMP) transmission system.

### BACKGROUND

In any switching system, a common response observed immediately after a switch is operated is a portion of time where the signal oscillates, known as “ringing”. This ringing is due, at least in part, to the dynamic response of the system. In a communication or power transmission system, this switching is often done at one end of a transmission line. In this case, the ringing observed over time at a single point on the line is the result of traveling waves that oscillate between the source and load ends of the line. The magnitude and phase of these traveling waves can be altered at each end of the transmission line, where the quantification of these alterations is known as the “reflection coefficient”. A reflection coefficient with a magnitude of 1 will result in the reflected wave having the same magnitude as the incoming one, while a reflection coefficient of 0 will result in a complete lack of a reflected wave. This latter case with a reflection coefficient of 0 occurs when the impedance at that end of the transmission line is perfectly matched to the characteristic impedance of the transmission line. In this case, no further ringing is observed since there is no reflected traveling wave to continue the oscillations. In many power transmission systems, there can be a large mismatch between the transmission line impedance and the load since it is a primary interest of many power transmission systems to minimize the amount of power loss.

Another aspect of reflections is the constructive and destructive interference patterns. When the forward and backward traveling waves add in a constructive manner, this can create a localized higher voltage at any point along the transmission line. In some systems, such as fault managed power systems, consideration and control of peak voltages may be a crucial requirement to ensure safety.

In a fault managed power (FMP) system, also known as a pulse power, digital electricity (DE), or packet energy transfer (PET) system, one method of measuring the inline power loss involves estimating the voltage drop of the cable and multiplying by the current. To estimate the voltage drop of the cable, the voltage at each end of the cable is required. More precisely, this voltage at each end of the cable is represented by a value indicative of a transmitter voltage during the power transfer interval and a value indicative of the receiver input voltage during the power transfer interval, where this receiver input voltage will be the lowest receiver input voltage when a plurality of receivers is connected to the same transmission line. In U.S. Pat. No. 8,781,637 (Eaves '637) this is accomplished at the transmitter end by taking a measurement just before and just after opening the source disconnect switch. In practical implementations, this measurement after opening the switch to obtain a value indicative of the receiver input voltage is done in an alternative way to avoid the effects of ringing, such as delaying the measurement until ringing has subsided and extrapolating back to the moment the switch was opened to estimate what it would have been without ringing. These values indicative of transmitter voltage and receiver input voltage are combined with a value indicative of the transmitter current to determine the transmission line power loss. Regardless of these approaches, these still result in error when the load disconnect device is a diode. In these cases, the forward traveling wave of the oscillations forward conducts through the diode. After this forward conduction, the energy that conducted through the diode is unable to return to the line since the diode is subsequently reverse biased. This energy removal from the transmission line results in the transmission line settling to a lower voltage than the receiver voltage as it existed during the power transfer interval, which is the desired voltage value to obtain. This results in an overly conservative estimate of the inline power loss, and this can reduce the power and distance capability of the system where a limit must be applied to this power loss, such as 100 W.

Another challenge in fault managed power systems is detection of faults between the outputs of different transmitter outputs, particularly when those outputs exist on a common ground or isolation plane. This is known as a cross-port fault and is exemplified by connecting a fault resistance from the positive or negative output of one channel to the positive or negative output of another channel, which results in cross-channel currents that could reach dangerous levels. Detection of a cross-port fault condition requires additional signal processing for reliable operation.

Digital electric power, or digital electricity (DE), can be characterized as any power format where electrical power is distributed in discrete, controllable units of energy. Packet energy transfer (PET) is a new type of digital electric power protocol disclosed in U.S. Pat. Nos. 8,068,937, 8,781,637 (Eaves '637) and international patent application PCT/US2017/016870; and is a type of Fault Managed Power (FMP) introduced in UL 1400-1 as well as the 2025 National Fire Protection Agency (NFPA) 70—also known as the National Electrical Code (NEC)—Article 726 where FMP is a new classification of power known as Class 4.

The primary discerning factor in a digital power transmission system compared to traditional, analog power systems (i.e., “analog electricity” (AE) systems) is that the electrical energy is separated into discrete units; and individual units of energy can be associated with analog and/or digital information that can be used for the purposes of optimizing safety, efficiency, resiliency, control, or routing. Since the energy in a PET system is transferred as discrete quantities, or quanta, it can be referred to as “digital power” or “digital electricity”.

As described in Eaves '637, a source and a load are connected by power transmission lines. The source controller (i.e., transmitter controller) of Eaves '637 periodically isolates (disconnects) the power transmission lines from the power source and analyzes, at a minimum, the voltage characteristics present at the source controller terminals directly before and after the lines are isolated. The time interval when the power lines are isolated was referred to by Eaves '637 as the “sample period” (i.e., isolation interval), and the time period when the source is connected is referred to as the “transfer period” (i.e., power transfer interval). The rate of rise and decay of the voltage on the lines before, during and after the sample period reveals if a fault condition is present on the power transmission lines. Measurable faults include, but are not limited to, short circuit, high line resistance, or the presence of an individual who has improperly come in contact with the transmission lines.

Eaves '637 also describes digital information that may be sent between the source and load controllers over the power transmission lines to further enhance safety or provide general characteristics of the energy transfer, such as total energy or the voltage at the load controller terminals. One method for communications on the same digital power transmission lines as used for power was further described and refined in U.S. Pat. No. 9,184,795 (Eaves '795).

U.S. Pat. No. 9,853,689 (Eaves '689) describes the packaging of the source side components of Eaves '637, in various configurations, into a device referred to as a digital power transmitter.

U.S. Pat. No. 9,419,436 (Eaves '436) describes the packaging of various configurations of the load side components of Eaves '637 into a device referred to as a digital power receiver.

U.S. Pat. No. 11,892,494 (Mlyniec '494) describes methods for verifying that voltage measurements on the transmitter side of the system meet minimum requirements for integrity in an environment containing electrical noise and where certain transmission line properties are unknown. Mlyniec '494 also describes applying a known resistance to detect an excessively high cable capacitance, which can be used in combination with the crossline resistance fault detection of Eaves '637 to ensure that the system never fails to detect a crossline fault resistance.

U.S. Pat. No. 12,149,067 (Casey '067) builds off of this fault detection of Eaves '637 and Mlyniec '494 to describe how sets of parameters can be changed in an always-safe fashion. Casey '067 provides an enhanced explanation of the relationship in fault detection between measurements taken with and without a known bias such as a pulldown resistor.

Eaves in U.S. Pat. No. 11,499,997 (Eaves '997) addressed the validation of the receiver side voltage measurement by performing a calibration test during the sample period (i.e., isolation interval), rather than transfer period (i.e., power transfer interval), and using the calibration to validate the transmission line voltage measurements that are made during the transfer period. Eaves '997 relies on the principle that during the sample period, when all AC components have diminished as determined by the transmitter, despite the fact that the line voltage may still be decaying on a DC level from factors such as cross-line resistance or even a cross-line fault, the voltage at the transmitter terminals and the voltage at the receiver terminals must be equal, even when separated by a long distance. Any non-equality is indicative of hardware failure or miscalibration.

U.S. Pat. No. 12,566,220 (Eaves '220) continues with receiver side voltage measurement techniques for inline faults, expanding the methods for a novel approach for the receiver to detect the presence of an inline fault without the requirement for coordination with the transmitter by taking measurements at 2 sufficiently distinct current levels.

U.S. Pat. No. 10,714,930 (Weiss '930) describes the usage of carrier-wave detection to measure the impedance of a transmission line in a power-distribution system.

U.S. Pat. No. 11,831,144 (Eaves '144) describes adaptations made to the algorithm of Eaves '637 and others that can take advantage of optimizations possible when the load is a non-linear load such as an LED light string.

U.S. application Ser. No. 18/504,603 (Lutz '603), U.S. application Ser. No. 18/504,614 (Lutz '614) and U.S. application Ser. No. 18/504,620 (Lutz '620) share a largely common specification and disclose methods and apparatus for a hot-pluggable receiver, a transmitter that maintains safety even in the absence of a receiver, and further improvements on a multi-drop architecture in a digital electricity system, respectively.

U.S. application Ser. No. 19/306,479 (Weiss '479) introduces methods and apparatus for connecting a plurality of transmitters to a common bus to enable power sharing and redundancy.

### SUMMARY OF THE DISCLOSURE

In a system with undesired ringing present and where steady application of a matched impedance would inhibit proper operation of the system, disclosure herein is a method and apparatus to eliminate the critical impact of ringing without critically interfering with proper operation.

Furthermore, in fault managed power systems that use a diode at the receiver end of the transmission line, disclosed herein is a method and apparatus for accurately measuring the voltage drop of the cable by only taking measurements at one line end, such as the transmitter end.

In a fault managed power system that features unidirectional switching on at least one end of the cable, disclosed herein is a method for detecting cross-port faults. This disclosure also provides further enhancement to the method and apparatus for cross-port fault detection when a periodic impedance matching strategy is employed. Additional methods and apparatus are further disclosed to detect cross-port faults using switch voltage sensors regardless of whether unidirectional switching or bidirectional switching is implemented in the system devices.

Typically, in communications and power transmission systems, impedance matching is done to perfectly match the characteristic impedance of the transmission line without a preference for particular impedance characteristics that may result in an intentionally imperfect match. These systems also do not actively switch this impedance match and instead leave the impedance matched components connected to the circuit at all times. It is also more typical to match the impedance at the load end of the transmission line or at both ends of the transmission line.

For example, in cases where a line can be treated as lossless or in lossy lines where the Heaviside condition is met, the characteristic impedance of the transmission line only has a real component. In many common cable constructions, such as Cat5, this is approximately 100Ω. In fault managed power systems that seek to detect line-to-line faults on the order of 575Ω and greater, adding 100 Ωacross the line can greatly hinder the efficacy of measurements indicative of a fault. This is due to the difficulty of isolating the fault current through the 575Ω resistance from the current through the 100 Ω impedance matching resistance. Depending on the algorithm used, this can result in insufficient signal to measure a voltage indicative of the current due to rapid discharge of the energy storage elements required for a good measurement, or there can be poor relative signal resolution such as when subtracting the measured current through the 100Ω resistance from the total current when there is a higher impedance fault such as 50 kΩ.

Alternative methods for compensating for the error in the inline power loss measurement due to line reflection have been proposed in prior art, but these solutions require other analog or digital signal manipulations done at the receiver end or have other similar compromises.

An alternative method to simplify cross-port fault detection is through isolation of each transmitter output or a subset of transmitter outputs, but this additional isolation adds cost and reduces efficiency.

In a system where certain undesired switching effects are present and where steady application of a matched impedance would inhibit proper operation of the system, one or more aspects of this disclosure can be employed to eliminate the critical impact of ringing while still maintaining proper operation. In some cases, additional system improvements can be achieved through these methods and apparatus.

In one preferred embodiment of the present disclosure, the solution is to connect the snubber circuit to match or nearly match the transmission line impedance for a portion of time as required for one mode of fault detection, such as inline fault detection, and disconnect the matched impedance for a portion of time as required for another fault detection mode, such as cross-line fault detection. This would only be applicable in such a system where the system requires the matched impedance to be disconnected from the circuit for a portion of time and that portion of time is not the same as the portion of time required to eliminate the critical impact of ringing.

In another aspect of this disclosure, in a system with a unidirectional switching topology at least at the receiver end of the transmission line, a system can utilize a crossline snubber that features a relatively large capacitance in series with any other snubber components and minimal leakage around the capacitance. With said snubber capacitance properly sized, the crossline voltage just prior to removing the snubber from the circuit will be stored, and this can be used to recover a value indicative of the receiver voltage with a significantly improved accuracy. This estimate of the receiver voltage in combination with the voltage during the power transfer interval can be used to compute the inline voltage drop, where this inline voltage drop can then be combined with the current flowing from the transmitter to the receiver to provide an inline power loss with significantly increased accuracy.

In another aspect of this disclosure, in systems with a unidirectional switching topology at one or both ends of the transmission line, cross-port faults between the positive of one transmitter output port and the negative of another transmitter output port can be detected, where both transmitter ports are simultaneously in an isolation interval. This is accomplished by each transmitter channel independently looking for a large voltage drop across the transmission line conductors, indicative of the cross-port fault when both transmitters are in an isolation interval simultaneously. In this case, with this change in the voltage drop, at least one transmitter should settle at a voltage that is no greater than half of the voltage on the non-transmission-line side of the circuit plus any additional diode drops and tolerance. The voltage on the non-transmission-line side of the circuit can be estimated by the voltage during the power transfer interval.

This aspect can be adapted for compatibility with the usage of the snubber circuit. This may entail analyzing the cross-port fault effective circuit while the snubber circuit impedance is present and adjusting the algorithm parameters such as time or value limits. A simpler approach is to disconnect the snubber circuit at a delayed time during the isolation interval so that the normal cross-port fault behavior without the snubber can be observed, where the snubber circuit disconnect is delayed to permit the intended benefits of the snubber to still be attained. In said simpler approach, the ideal design will choose an optimum time to disconnect the snubber to most accentuate the lower settling voltage that is indicative of a cross-port fault.

In yet another aspect of this disclosure, line-to-earth faults or cross-port faults between the positive of one transmitter output port and the negative of another transmitter output port can be detected, where both transmitter ports are simultaneously in an isolation interval. This is accomplished by each transmitter channel independently looking for a switch voltage imbalance as the difference between a voltage across a high-side switch of a respective transmitter and a low-side switch of the same transmitter. When a line-to-earth fault or a cross-port fault is present, this switch voltage imbalance will be substantially different from zero, and the fault is registered upon detecting this substantial difference from zero. Similarly to other cross-port fault aspects, this can be adapted for compatibility with the usage of the snubber circuit in at least the same ways as above.

In some aspects, the techniques described herein relate to a method to detect cross-port faults in a fault managed power (FMP) transmission system, the method including: providing a first transmission line having a high potential conductor and a low potential conductor; connecting a first end of the first transmission line to an output port of a first transmitter, the first transmitter receiving power from a first power source; connecting a second end of the first transmission line to an input port of a first receiver; providing a second transmission line including a high potential conductor and a low potential conductor; connecting a first end of the second transmission line to an output port of a second transmitter, the second transmitter receiving power from a second power source; connecting a second end of the second transmission line to an input port of a second receiver; connecting with the first transmitter the first power source to the first transmission line via a first switch and a second switch causing current to flow from the first power source to the first transmission line during FMP power transfer intervals and at least partially nominally isolating the first power source from the first transmission line during FMP isolation intervals; connecting with the second transmitter the second power source to the second transmission line via a third switch and a fourth switch causing current to flow from the second power source to the second transmission line during FMP power transfer intervals and at least partially nominally isolating the second power source from the second transmission line during FMP isolation intervals; during isolation intervals, monitoring for either: an electrical characteristic indicative of a first fault current through a first unidirectional switching element in the first transmitter in a direction flowing from the output port of the first transmitter to the first source or for an electrical characteristic indicative of a second fault current through a second unidirectional switching element in the second transmitter in a direction flowing from the second source to the output port of the second transmitter indicating a cross-port fault between the lower potential conductor of the first transmission line and the higher potential conductor of the second transmission line; or an electrical characteristic indicative of a third fault current through a third unidirectional switching element in the first receiver in a direction flowing from the input port of the first receiver to a first bulk capacitor in the first receiver or for an electrical characteristic indicative of a fourth fault current through a fourth unidirectional switching element in the second receiver in a direction flowing from a second bulk capacitor in the second receiver to the input port of the second receiver indicating a cross-port fault between the lower potential conductor of the first transmission line and the higher potential conductor of the second transmission line; and in response to detecting an electrical characteristic indicative of one of the first fault current, the second fault current, the third fault current, or the fourth fault current limiting said detected first fault current, second fault current, third fault current, or fourth fault current within a predefined amount of time.

In some aspects, the techniques described herein relate to a method, wherein the electrical characteristic indicative of the first fault current, the second fault current, the third fault current, or the fourth fault current includes, respectively, detecting a change in voltage drop across the first transmitter output port, the second transmitter output port, the first receiver input port, or the second receiver input port.

In some aspects, the techniques described herein relate to a method, wherein the electrical characteristic indicative of the first fault current, the second fault current, the third fault current, or the fourth fault current includes detecting a faster time constant or increased non-linearity during a first time interval as compared to a time constant or non-linearity during a second time interval; wherein during the first time interval, the first unidirectional switch conducts the first fault current, or the second unidirectional switch conducts the second fault current, the third unidirectional switch conducts the third fault current, or the fourth unidirectional switch conducts the fourth fault current; and wherein during the second time interval, the first unidirectional switch does not conduct the first fault current, the second unidirectional switch does not conduct the second fault current, the third unidirectional switch does not conduct the third fault current, and the fourth unidirectional switch does not conduct the fourth fault current.

In some aspects, the techniques described herein relate to a method, wherein said non-linearity is determined using numerical analysis to produce an approximation in the form of a polynomial function, where the estimated accuracy of said polynomial function is based on the magnitude of the variance of the individual measurements from the approximation.

In some aspects, the techniques described herein relate to a method, wherein the non-linearity is determined by the estimated accuracy of said polynomial function not meeting a minimum accuracy requirement.

In some aspects, the techniques described herein relate to a method, further including providing the first unidirectional switch, the second unidirectional switch, the third unidirectional switch, or the fourth unidirectional switch with a transistor.

In some aspects, the techniques described herein relate to a method, further including providing the first unidirectional switch, the second unidirectional switch, the third unidirectional switch, or the fourth unidirectional switch with a diode.

In some aspects, the techniques described herein relate to a method, wherein the electrical characteristic indicative of the first fault current, the second fault current, the third fault current, or the fourth fault current includes detecting a value indicative of the energy transfer through the first unidirectional switch while it conducts the first fault current, the energy transfer through the second unidirectional switch while it conducts the second fault current, the energy transfer through the third unidirectional switch while it conducts the third fault current, or the energy transfer through the fourth unidirectional switch while it conducts the fourth fault current.

In some aspects, the techniques described herein relate to a method, further including one or both of providing the first transmitter or the first receiver with a first snubber circuit and periodically connecting the first snubber circuit across the first transmission line and periodically isolating the first snubber circuit from the first transmission line; and providing the second transmitter or the second receiver with a second snubber circuit and periodically connecting the second snubber circuit across the second transmission line and periodically isolating the second snubber circuit from the second transmission line.

In some aspects, the techniques described herein relate to a method, wherein the electrical characteristic indicative of the first fault current or the electrical characteristic indicative of the second fault current is measured while the first snubber is disconnected from the first transmission line and the second snubber is disconnected from the second transmission line.

In some aspects, the techniques described herein relate to a method, further including providing the first power source and the second power source as either a single power source or two different power sources.

In some aspects, the techniques described herein relate to a method, further including providing one or more of the first transmitter, the second transmitter, the first receiver, or the second receiver with one or more current sensors to measure, during an FMP power transfer interval, an imbalance current indicative of a current difference between either the first high potential conductor and the first low potential conductor or the second high potential conductor and the second low potential conductor.

In some aspects, the techniques described herein relate to a method, wherein the imbalance current being outside of a predefined range is indicative of a fault, wherein the fault is at least a line-to-line cross-port fault between the first transmission line and the second transmission line or a line-to-earth fault.

In some aspects, the techniques described herein relate to a system to detect cross-port faults between a first transmission line including a high potential conductor and a low potential conductor and a second transmission line including a high potential conductor and a low potential conductor, the system including: a first transmitter including an output port connected to the first transmission line, the first transmitter receiving power from a first power source, wherein the first transmitter includes a first switch and a second switch configured to connect the first power source to the first transmission line causing current to flow from the first power source to the first transmission line during power transfer intervals and wherein the first switch and the second switch are configured to disconnect the first power source from the first transmission line to at least partially nominally isolate the first power source from the first transmission line during isolation intervals; a first receiver including an input port connected to the first transmission line; a second transmitter including an output port connected to the second transmission line, the second transmitter receiving power from a second power source, wherein the second transmitter includes a third switch and a fourth switch configured to connect the second power source to the second transmission line causing current to flow from the second power source to the second transmission line during power transfer intervals and wherein the third switch and the fourth switch are configured to disconnect the second power source from the second transmission line to at least partially nominally isolate the second power source from the second transmission line during isolation intervals; a second receiver including an input port connected to the second transmission line; and a control circuit configured to either: monitor during isolation intervals for an electrical characteristic indicative of a first fault current through a first unidirectional switching element in the first transmitter in a direction flowing from the output port of the transmitter to the first source or for an electrical characteristic indicative of a second fault current through a second unidirectional switching element in the second transmitter in a direction flowing from the second source to the output port of the second transmitter indicating a cross-port fault between the lower potential conductor of the first transmission line and the higher potential conductor of the second transmission line, and in response to detecting an electrical characteristic indicative of either the first fault current or the second fault current, limiting said detected first fault current or said second fault current within a predefined amount of time; or monitor during isolation intervals for an electrical characteristic indicative of a third fault current through a third unidirectional switching element in the first receiver in a direction flowing from the input port of the first receiver to a first bulk capacitor in the first receiver or for an electrical characteristic indicative of a fourth fault current through a fourth unidirectional switching element in the second receiver in a direction flowing from a second bulk capacitor in the second receiver to the input port of the second receiver indicating a cross-port fault between the lower potential conductor of the first transmission line and the higher potential conductor of the second transmission line, and limiting said third fault current or said fourth fault current within a predefined amount of time in response to detecting an electrical characteristic of either the third fault current or the fourth fault current.

In some aspects, the techniques described herein relate to a system, wherein the control circuit is configured to detect a change in voltage drop across the first transmitter output port, the second transmitter output port, the first receiver input port, or the second receiver input port, as the electrical characteristic indicative of the first fault current, the second fault current, the third fault current, or the fourth fault current, respectively.

In some aspects, the techniques described herein relate to a system, wherein, in connection with monitoring for the electrical characteristic indicative of the first fault current, the second fault current, the third fault current, or the fourth fault current, the control circuit is configured to detect a faster time constant or increased non-linearity during a first time interval as compared to a time constant or non-linearity during a second time interval; wherein during the first time interval, the first unidirectional switch conducts the first fault current, or the second unidirectional switch conducts the second fault current, or the third unidirectional switch conducts the third fault current, or the fourth unidirectional switch conducts the fourth fault current; and wherein during the second time interval, the first unidirectional switch does not conduct the first fault current, the second unidirectional switch does not conduct the second fault current, the third unidirectional switch does not conduct the third fault current, and the fourth unidirectional switch does not conduct the fourth fault current.

In some aspects, the techniques described herein relate to a system, wherein the control circuit is configured to detect said non-linearity is using numerical analysis to produce an approximation in the form of a polynomial function, where the estimated accuracy of said polynomial function is based on the magnitude of the variance of the individual measurements from the approximation.

In some aspects, the techniques described herein relate to a system, wherein the control circuit is configured to detect detection is determined by the estimated accuracy of the polynomial function not meeting a minimum accuracy requirement.

In some aspects, the techniques described herein relate to a system, wherein the first unidirectional switch, the second unidirectional switch, the third unidirectional switch, or the fourth unidirectional switch includes a transistor.

In some aspects, the techniques described herein relate to a system, wherein the first unidirectional switch, the second unidirectional switch, the third unidirectional switch, or the fourth unidirectional switch includes a diode.

In some aspects, the techniques described herein relate to a system, wherein the electrical characteristic indicative of the first fault current, the second fault current, the third fault current, or the fourth fault current includes a value indicative of the energy transfer through the first unidirectional switch while it conducts the first fault current or the energy transfer through the second unidirectional switch while it conducts the second fault current.

In some aspects, the techniques described herein relate to a system, wherein the first transmitter or the first receiver includes a snubber circuit and wherein the control circuit is configured to periodically connect the first snubber circuit across the first transmission line and wherein the control circuit is configured to periodically isolate the first snubber circuit from the first transmission line; or wherein the second transmitter or the second receiver includes a snubber circuit and wherein the control circuit is configured to periodically connect the second snubber circuit across the second transmission line and wherein the control circuit is configured to periodically isolate the second snubber circuit from the second transmission line.

In some aspects, the techniques described herein relate to a system, wherein the electrical characteristic indicative of the first fault current or the electrical characteristic indicative of the second fault current is measured while the first snubber is disconnected from the first transmission line and the second snubber is disconnected from the second transmission line.

In some aspects, the techniques described herein relate to a system, wherein the first power source and the second power source are either a single power source or two different power sources.

In some aspects, the techniques described herein relate to a system, wherein the control circuit includes a first control circuit implemented in the first transmitter, the first receiver, or in part in both the first transmitter and the first receiver and a second control circuit implemented in the second transmitter, the second receiver, or in part in both the second transmitter and the second receiver.

In some aspects, the techniques described herein relate to a system, wherein the first transmitter, the second transmitter, the first receiver, or the second receiver further includes one or more current sensors to measure, during an FMP power transfer interval, an imbalance current indicative of a current difference between either the first high potential conductor and the first low potential conductor or the second high potential conductor and the second low potential conductor.

In some aspects, the techniques described herein relate to a system, wherein the imbalance current being outside of a predefined range is indicative of a fault, wherein the fault is at least a line-to-line cross-port fault between the first transmission line and the second transmission line or a line-to-earth fault.

In some aspects, the techniques described herein relate to a transmitter to detect at least cross-port faults in a fault managed power (FMP) transmission system, wherein the FMP transmission system further includes a first transmission line including at least a high potential conductor and a low potential conductor, the transmitter including: an input port including at least a high-side input terminal and a low-side input terminal, and configured to receive input power from an energy source, an output port including at least a high-side output terminal and a low-side output terminal, and configured to be connected to the first transmission line, a switching barrier including at least a high-side switch and a low-side switch configured to be closed to electrically connect the input port to the output port during a power transfer interval and to be opened to at least partially nominally isolate the input port from the output port during an isolation interval, one or more sensing circuits, the one or more sensing circuits including one or more of: an output voltage sensor configured to measure an output voltage indicative of a voltage of the high-side output terminal relative to the low-side output terminal; a high-side reverse current sensor configured to measure a high-side reverse current indicative of a current flowing from the high-side output terminal to the high-side input terminal; a low-side reverse current sensor configured to measure a low-side reverse current indicative of a current flowing from the low-side input terminal to the low-side output terminal; a high-side switch voltage sensor configured to measure a high-side switch voltage indicative of a voltage across the high-side switch as the high-side input terminal relative to the high-side output terminal; and a low-side switch voltage sensor configured to measure a low-side switch voltage indicative of a voltage across the low-side switch as the low-side output terminal voltage relative to the low-side input terminal, and a control circuit configured to: during the isolation interval, measure the output voltage, the high-side reverse current, the low-side reverse current, the high-side switch voltage, or the low-side switch voltage; determine that a fault is present when the output voltage is below a first threshold, when the high-side reverse current is above a second threshold, when the low-side reverse current is above the second threshold, when the high-side switch voltage is above a third threshold, or when the low-side switch voltage is above the third threshold; and upon determining that the fault is present, limiting the energy transfer from the input port to the output port to below an electrical constriction limit; wherein the fault includes a cross-port fault between the first transmission line and a second transmission line.

In some aspects, the techniques described herein relate to a transmitter, wherein the one or more sensing circuits includes the output voltage sensor.

In some aspects, the techniques described herein relate to a transmitter, wherein the control circuit is further configured to measure an initial output voltage during the power transfer interval, and wherein the first threshold is defined relative to the initial output voltage.

In some aspects, the techniques described herein relate to a transmitter, wherein the first threshold is defined as no less than half of the initial output voltage.

In some aspects, the techniques described herein relate to a transmitter, wherein the transmitter further includes an input voltage sensor configured to measure an input voltage indicative of the voltage of the high-side input terminal relative to the low-side input terminal, wherein the control circuit is further configured to measure the input voltage during the power transfer interval or the isolation interval, and wherein the first threshold is defined relative to the input voltage.

In some aspects, the techniques described herein relate to a transmitter, wherein the first threshold is defined as no less than half of the input voltage.

In some aspects, the techniques described herein relate to a transmitter, wherein the first threshold is predefined as no less than half of the maximum possible output voltage.

In some aspects, the techniques described herein relate to a transmitter, wherein the one or more sensing circuits includes one or more of the high-side reverse current sensor and the low-side reverse current sensor.

In some aspects, the techniques described herein relate to a transmitter, wherein the second threshold is a DC let-go limit or an AC let-go limit.

In some aspects, the techniques described herein relate to a transmitter, wherein the high-side reverse current sensor or the low-side reverse current sensor includes an opto-coupler circuit, wherein the sensing side of the opto-coupler circuit is connected in parallel with the high-side switch or low-side switch, and the output side of the opto-coupler circuit is connected to the control circuit.

In some aspects, the techniques described herein relate to a transmitter, wherein the control circuit is further configured to determine the output terminal to which the fault is connected, wherein the high-side reverse current being above the second threshold is indicative of the fault being connected to the low-side output terminal, and wherein the low-side reverse current being above the second threshold is indicative of the fault being connected to the high-side output terminal.

In some aspects, the techniques described herein relate to a transmitter, wherein the one or more sensing circuits includes one or more of the high-side switch voltage sensor and the low-side switch voltage sensor.

In some aspects, the techniques described herein relate to a transmitter, wherein the third threshold is defined relative to the low-side switch voltage when the third threshold is compared to the high-side switch voltage, or the third threshold is defined relative to the high-side switch voltage when the third threshold is compared to the low-side switch voltage.

In some aspects, the techniques described herein relate to a transmitter, wherein the fault further includes a line-to-earth fault.

In some aspects, the techniques described herein relate to a transmitter, wherein the transmitter further includes a line-to-earth sensing circuit, the line-to-earth sensing circuit including one or more of: a high-side input-to-earth voltage sensor configured to measure a high-side input-to-earth voltage indicative of the voltage of the high-side input terminal relative to an earth potential; a low-side earth-to-input voltage sensor configured to measure a low-side earth-to-input voltage indicative of the voltage of the earth potential relative to the low-side input terminal; a high-side output-to-earth voltage sensor configured to measure a high-side output-to-earth voltage indicative of the voltage of the high-side output terminal relative to the earth potential; and a low-side earth-to-output voltage sensor configured to measure a low-side earth-to-output voltage indicative of the voltage of the earth potential relative to the low-side output terminal.

In some aspects, the techniques described herein relate to a transmitter, wherein the control circuit is further configured to measure the high-side input-to-earth voltage, the low-side earth-to-input voltage, the high-side output-to-earth voltage, or the low-side earth-to-output voltage during the power transfer interval or the isolation interval.

In some aspects, the techniques described herein relate to a transmitter, wherein the control circuit is further configured to distinguish between a cross-port fault and a line-to-earth fault; wherein the high-side input-to-earth voltage being above a fourth threshold, the low-side earth-to-input voltage being above the fourth threshold, the high-side output-to-earth voltage being above the fourth threshold, or the low-side earth-to-output voltage being above the fourth threshold distinguishes the fault as a line-to-earth fault.

In some aspects, the techniques described herein relate to a transmitter, wherein the fourth threshold is defined as relative to the output voltage.

In some aspects, the techniques described herein relate to a transmitter, wherein the transmitter further includes an input voltage sensor configured to measure an input voltage indicative of the voltage of the high-side input terminal relative to the low-side input terminal, wherein the control circuit is further configured to measure the input voltage during the power transfer interval or the isolation interval, and wherein the fourth threshold is defined relative to the input voltage.

In some aspects, the techniques described herein relate to a transmitter, wherein the fourth threshold is defined as relative to the low-side earth-to-input when the fourth threshold is compared to the high-side input-to-earth voltage; the fourth threshold is defined as relative to the high-side input-to-earth when the fourth threshold is compared to the low-side earth-to-input voltage; the fourth threshold is defined as relative to the low-side earth-to-output when the fourth threshold is compared to the high-side output-to-earth voltage; or the fourth threshold is defined as relative to the high-side output-to-earth voltage when the fourth threshold is compared to the low-side earth-to-output voltage.

In some aspects, the techniques described herein relate to a transmitter, wherein the fault further includes a failed switch fault; wherein the control circuit is further configured to obtain a second high-side switch voltage or a second low-side switch voltage while limiting the energy transfer from the input port to the output port to below an electrical constriction limit; wherein the control circuit is further configured to distinguish between a cross-port fault and a failed switch fault; and wherein the second high-side switch voltage being above a fifth threshold or the second low-side switch voltage being above the fifth threshold distinguishes the fault as a failed switch fault.

In some aspects, the techniques described herein relate to a transmitter, wherein the fifth threshold is defined relative to the second low-side switch voltage when the fifth threshold is compared to the second high-side switch voltage, or the fifth threshold is defined relative to the second high-side switch voltage when the fifth threshold is compared to the second low-side switch voltage.

In some aspects, the techniques described herein relate to a transmitter, wherein the control circuit is further configured to determine the output terminal to which the fault is connected, wherein the high-side switch voltage being above the third threshold is indicative of the fault being connected to the high-side output terminal, and wherein the low-side switch voltage being above the third threshold is indicative of the fault being connected to the low-side output terminal.

In some aspects, the techniques described herein relate to a transmitter, wherein the control circuit is further configured to determine the output terminal to which the fault is connected, wherein the high-side input-to-earth voltage or the high-side output-to-earth voltage being above the fourth threshold is indicative of the fault being connected to the low-side output terminal, and wherein the low-side earth-to-input voltage or the low-side earth-to-output voltage being above the fourth threshold is indicative of the fault being connected to the high-side output terminal.

In some aspects, the techniques described herein relate to a transmitter, wherein the control circuit is further configured to determine whether the high-side switch or the low-side switch is failed, wherein the high-side switch voltage being above the third threshold or the second high-side switch voltage being above the fifth threshold is indicative of the fault being a failed low-side switch, and wherein the low-side switch voltage being above the third threshold or the second low-side switch voltage being above the fifth threshold is indicative of the fault being a failed high-side switch.

In some aspects, the techniques described herein relate to a transmitter, wherein the electrical constriction limit includes one or more of a value indicative of a DC let-go limit, a value indicative of an AC let-go limit, or a value indicative of a power limit.

In some aspects, the techniques described herein relate to a transmitter, wherein the high-side switch or the low-side switch includes a plurality of switches.

In some aspects, the techniques described herein relate to a transmitter, wherein the high-side switch or the low-side switch includes a transistor.

In some aspects, the techniques described herein relate to a transmitter, wherein the transmitter further includes a snubber circuit that is periodically connected between the high-side output terminal and the low-side output terminal, and periodically isolated from the high-side output terminal or the low-side output terminal.

In some aspects, the techniques described herein relate to a transmitter, wherein the control circuit measures the output voltage, the high-side reverse current, the low-side reverse current, the high-side switch voltage, or the low-side switch voltage while the snubber circuit is isolated from the high-side output terminal or the low-side output terminal.

In some aspects, the techniques described herein relate to a transmitter, wherein the one or more sensing circuits further include a residual output current sensor configured to measure a residual output current indicative of the difference in current flowing out of the high-side output terminal towards the first transmission line and current flowing into the low-side output terminal from the transmission line.

In some aspects, the techniques described herein relate to a transmitter, wherein the control circuit is further configured to measure the residual output current during the power transfer interval.

In some aspects, the techniques described herein relate to a transmitter, wherein the control circuit is further configured to determine that the fault is present when the residual output current is outside of an predefined range.

In some aspects, the techniques described herein relate to a transmitter, wherein the residual output current sensor includes high-side output current sensor and a low-side output current sensor.

In some aspects, the techniques described herein relate to a transmitter, wherein the residual output current sensor includes a flux sensor configured to measure the difference between the current flowing out of the high-side output terminal and into the low-side output terminal.

In some aspects, the techniques described herein relate to a transmitter, wherein the energy source is a DC power format.

In some aspects, the techniques described herein relate to a transmitter, wherein the switching barrier further includes a current injection circuit configured to allow a limited energy transfer from the input port to the output port for at least a portion of the isolation interval.

In some aspects, the techniques described herein relate to a transmitter, wherein the one or more sensing circuits further include an output current imbalance sensor configured to measure an output current imbalance indicative of a difference in current sent and returned through each output terminal.

In some aspects, the techniques described herein relate to a transmitter, wherein the control circuit is further configured to measure the output current imbalance during the power transfer interval, and determine that a fault is present when the output current imbalance is outside of a predefined range.

In some aspects, the techniques described herein relate to a receiver to detect at least cross-port faults in a fault managed power (FMP) transmission system, wherein the FMP transmission system further includes a first transmission line including at least a high potential conductor and a low potential conductor, the receiver including: an input port including at least a high-side input terminal and a low-side input terminal, and configured to be connected to the first transmission line, an output port including at least a high-side output terminal and a low-side output terminal, and configured to supply power to a load, a switching barrier including at least a high-side switch and a low-side switch configured to be closed to electrically connect the input port to the output port during a power transfer interval and to be opened to at least partially nominally isolate the input port from the output port during an isolation interval, one or more sensing circuits, the one or more sensing circuits including one or more of: an input voltage sensor configured to measure an input voltage indicative of a voltage of the high-side input terminal relative to the low-side input terminal; a high-side leakage current sensor configured to measure a high-side leakage current indicative of a current flowing from the high-side input terminal to the high-side output terminal; a low-side leakage current sensor configured to measure a low-side leakage current indicative of a current flowing from the low-side output terminal to the low-side input terminal; a high-side switch voltage sensor configured to measure a high-side switch voltage indicative of a voltage across the high-side switch as the high-side output terminal relative to the high-side input terminal; and a low-side switch voltage sensor configured to measure a low-side switch voltage indicative of a voltage across the low-side switch as the low-side input terminal voltage relative to the low-side output terminal; and a control circuit configured to: during the isolation interval, measure the input voltage, the high-side leakage current, the low-side leakage current, the high-side switch voltage, or the low-side switch voltage; determine that a fault is present when the input voltage is below a first threshold, when the high-side leakage current is above a second threshold, when the low-side leakage current is above the second threshold, when the high-side switch voltage is above a third threshold, or when the low-side switch voltage is above the third threshold; and upon determining that the fault is present, activating a disconnect mechanism; wherein the fault includes a cross-port fault between the first transmission line and a second transmission line.

In some aspects, the techniques described herein relate to a receiver, wherein the one or more sensing circuits includes the input voltage sensor.

In some aspects, the techniques described herein relate to a receiver, wherein the control circuit is further configured to measure an initial input voltage during the power transfer interval, and wherein the first threshold is defined relative to the initial input voltage.

In some aspects, the techniques described herein relate to a receiver, wherein the first threshold is defined as no less than half of the initial input voltage.

In some aspects, the techniques described herein relate to a receiver, wherein the receiver further includes an output voltage sensor configured to measure an output voltage indicative of the voltage of the high-side output terminal relative to the low-side output terminal, wherein the control circuit is further configured to measure the output voltage during the power transfer interval or the isolation interval, and wherein the first threshold is defined relative to the output voltage.

In some aspects, the techniques described herein relate to a receiver, wherein the first threshold is defined as no less than half of the output voltage.

In some aspects, the techniques described herein relate to a receiver, wherein the first threshold is predefined as no less than half of the maximum possible input voltage.

In some aspects, the techniques described herein relate to a receiver, wherein the one or more sensing circuits includes one or more of the high-side leakage current sensor and the low-side leakage current sensor.

In some aspects, the techniques described herein relate to a receiver, wherein the second threshold is a DC let-go limit or an AC let-go limit.

In some aspects, the techniques described herein relate to a receiver, wherein the high-side leakage current sensor or the low-side leakage current sensor includes an opto-coupler circuit, wherein the sensing side of the opto-coupler circuit is connected in parallel with the high-side switch or low-side switch, and the output side of the opto-coupler circuit is connected to the control circuit.

In some aspects, the techniques described herein relate to a receiver, wherein the control circuit is further configured to determine the input terminal to which the fault is connected, wherein the high-side leakage current being above the second threshold is indicative of the fault being connected to the low-side input terminal, and wherein the low-side leakage current being above the second threshold is indicative of the fault being connected to the high-side input terminal.

In some aspects, the techniques described herein relate to a receiver, wherein the one or more sensing circuits includes one or more of the high-side switch voltage sensor and the low-side switch voltage sensor.

In some aspects, the techniques described herein relate to a receiver, wherein the third threshold is defined relative to the low-side switch voltage when the third threshold is compared to the high-side switch voltage, or the third threshold is defined relative to the high-side switch voltage when the third threshold is compared to the low-side switch voltage.

In some aspects, the techniques described herein relate to a receiver, wherein the fault further includes a line-to-earth fault.

In some aspects, the techniques described herein relate to a receiver, wherein the receiver further includes a line-to-earth sensing circuit, the line-to-earth sensing circuit including one or more of: a high-side input-to-earth voltage sensor configured to measure a high-side input-to-earth voltage indicative of the voltage of the high-side input terminal relative to an earth potential; a low-side earth-to-input voltage sensor configured to measure a low-side earth-to-input voltage indicative of the voltage of the earth potential relative to the low-side input terminal; a high-side output-to-earth voltage sensor configured to measure a high-side output-to-earth voltage indicative of the voltage of the high-side output terminal relative to the earth potential; and a low-side earth-to-output voltage sensor configured to measure a low-side earth-to-output voltage indicative of the voltage of the earth potential relative to the low-side output terminal.

In some aspects, the techniques described herein relate to a receiver, wherein the control circuit is further configured to measure the high-side input-to-earth voltage, the low-side earth-to-input voltage, the high-side output-to-earth voltage, or the low-side earth-to-output voltage during the power transfer interval or the isolation interval.

In some aspects, the techniques described herein relate to a receiver, wherein the control circuit is further configured to distinguish between a cross-port fault and a line-to-earth fault; wherein the high-side input-to-earth voltage being above a fourth threshold, the low-side earth-to-input voltage being above the fourth threshold, the high-side output-to-earth voltage being above the fourth threshold, or the low-side earth-to-output voltage being above the fourth threshold distinguishes the fault as a line-to-earth fault.

In some aspects, the techniques described herein relate to a receiver, wherein the fourth threshold is defined as relative to the output voltage.

In some aspects, the techniques described herein relate to a receiver, wherein the transmitter further includes an input voltage sensor configured to measure an input voltage indicative of the voltage of the high-side input terminal relative to the low-side input terminal, wherein the control circuit is further configured to measure the input voltage during the power transfer interval or the isolation interval, and wherein the fourth threshold is defined relative to the input voltage.

In some aspects, the techniques described herein relate to a receiver, wherein the fourth threshold is defined as relative to the low-side earth-to-input when the fourth threshold is compared to the high-side input-to-earth voltage; the fourth threshold is defined as relative to the high-side input-to-earth when the fourth threshold is compared to the low-side earth-to-input voltage; the fourth threshold is defined as relative to the low-side earth-to-output when the fourth threshold is compared to the high-side output-to-earth voltage; or the fourth threshold is defined as relative to the high-side output-to-earth voltage when the fourth threshold is compared to the low-side earth-to-output voltage.

In some aspects, the techniques described herein relate to a receiver, wherein the fault further includes a failed switch fault; wherein the control circuit is further configured to obtain a second high-side switch voltage or a second low-side switch voltage while the disconnect mechanism is activated; and wherein the control circuit is further configured to distinguish between a cross-port fault and a failed switch fault; and wherein the second high-side switch voltage being above a fifth threshold or the second low-side switch voltage being above the fifth threshold distinguishes the fault as a failed switch fault.

In some aspects, the techniques described herein relate to a receiver, wherein the fifth threshold is defined relative to the second low-side switch voltage when the fifth threshold is compared to the second high-side switch voltage, or the fifth threshold is defined relative to the second high-side switch voltage when the fifth threshold is compared to the second low-side switch voltage.

In some aspects, the techniques described herein relate to a receiver, wherein the control circuit is further configured to determine the input terminal to which the fault is connected, wherein the high-side switch voltage being above the third threshold is indicative of the fault being connected to the high-side input terminal, and wherein the low-side switch voltage being above the third threshold is indicative of the fault being connected to the low-side input terminal.

In some aspects, the techniques described herein relate to a receiver, wherein the control circuit is further configured to determine the input terminal to which the fault is connected, wherein the high-side input-to-earth voltage or the high-side output-to-earth voltage being above the fourth threshold is indicative of the fault being connected to the low-side input terminal, and wherein the low-side earth-to-input voltage or the low-side earth-to-output voltage being above the fourth threshold is indicative of the fault being connected to the high-side input terminal.

In some aspects, the techniques described herein relate to a receiver, wherein the control circuit is further configured to determine whether the high-side switch or the low-side switch is failed, wherein the high-side switch voltage being above the third threshold or the second high-side switch voltage being above the fifth threshold is indicative of the fault being a failed low-side switch, and wherein the low-side switch voltage being above the third threshold or the second low-side switch voltage being above the fifth threshold is indicative of the fault being a failed high-side switch.

In some aspects, the techniques described herein relate to a receiver, wherein the electrical constriction limit includes one or more of a value indicative of a DC let-go limit, a value indicative of an AC let-go limit, or a value indicative of a power limit.

In some aspects, the techniques described herein relate to a receiver, wherein the high-side switch or the low-side switch includes a plurality of switches.

In some aspects, the techniques described herein relate to a receiver, wherein the high-side switch or the low-side switch includes a transistor or a diode.

In some aspects, the techniques described herein relate to a receiver, wherein the receiver further includes a snubber circuit that is periodically connected between the high-side input terminal and the low-side input terminal, and periodically isolated from the high-side input terminal or the low-side input terminal.

In some aspects, the techniques described herein relate to a receiver, wherein the control circuit measures the input voltage, the high-side leakage current, the low-side leakage current, the high-side switch voltage, or the low-side switch voltage while the snubber circuit is isolated from the high-side input terminal or the low-side input terminal.

In some aspects, the techniques described herein relate to a receiver, wherein the one or more sensing circuits further include a residual input current sensor configured to measure a residual input current indicative of the difference in current flowing into the high-side input terminal from the first transmission line and current flowing out of the low-side input terminal towards the transmission line.

In some aspects, the techniques described herein relate to a receiver, wherein the control circuit is further configured to measure the residual input current during the power transfer interval.

In some aspects, the techniques described herein relate to a receiver, wherein the control circuit is further configured to determine that the fault is present when the residual input current is outside of an predefined range.

In some aspects, the techniques described herein relate to a receiver, wherein the residual input current sensor includes high-side input current sensor and a low-side input current sensor.

In some aspects, the techniques described herein relate to a receiver, wherein the residual input current sensor includes a flux sensor configured to measure the difference between the current flowing into the high-side input terminal and out of the low-side input terminal.

In some aspects, the techniques described herein relate to a receiver, wherein the electricity format of the first transmission line is a DC power format or a pulsed DC power format.

In some aspects, the techniques described herein relate to a receiver, wherein the one or more sensing circuits further include an input current imbalance sensor configured to measure an input current imbalance indicative of a difference in current sent and returned through each input terminal.

In some aspects, the techniques described herein relate to a receiver, wherein the control circuit is further configured to measure the input current imbalance during the power transfer interval, and determine that a fault is present when the input current imbalance is outside of a predefined range.

In some aspects, the techniques described herein relate to a receiver, wherein the disconnect mechanism clamps the input port to limit the available fault energy.

In some aspects, the techniques described herein relate to a receiver, wherein the disconnect mechanism transmits a signal to the transmitter to limit the transmitter output to below an electrical constriction limit.

In some aspects, the techniques described herein relate to a receiver, wherein the signal is a crossline fault applied by the receiver across the input port, wherein the crossline fault is within the fault detection range of the transmitter.

In some aspects, the techniques described herein relate to a receiver, wherein the receiver further includes an inline communications circuit, and wherein the inline communications circuit transmits the signal to the transmitter.

In some aspects, the techniques described herein relate to a receiver, wherein the receiver further includes an external communications circuit including an optical fiber or communications conductors distinct from the high potential conductor and the low potential conductor, wherein the external communications circuit transmits the signal to the transmitter.

In some aspects, the techniques described herein relate to a receiver wherein the output port includes a load switch to selectively connect the load to and disconnect the load from the output port.

In some aspects, the techniques described herein relate to a method to detect cross-port faults in a fault managed power (FMP) transmission system including: a first transmission line including a high potential conductor and a low potential conductor configured to be connected to a first power distribution device, a second transmission line including a high potential conductor and a low potential conductor configured to be connected to a second power distribution device, a first fault monitoring device configured to be connected to the first transmission line or the first power distribution device, and a second fault monitoring device configured to be connected to the second transmission line or the second power distribution device; wherein the first power distribution device connects a first voltage maintaining element to the first transmission line via a first switch and a second switch during power transfer intervals and at least partially nominally isolates the first voltage maintaining element from the first transmission line during isolation intervals and the second power distribution device connects the first voltage maintaining element or a second voltage maintaining element to the second transmission line via a third switch and a fourth switch during power transfer intervals and nominally isolates the first voltage maintaining element or the second voltage maintaining element from the second transmission line during isolation intervals, the method including: during a time period when an isolation interval of the first power distribution device and an isolation interval of the second power distribution device are overlapping, an overlapping isolation Interval, monitoring by a first fault monitoring device and a second fault monitoring device for: a first electrical characteristic indicative of a first fault current through the second switch in a direction flowing from the first transmission line to the first voltage maintaining element; or a second electrical characteristic indicative of a second fault current through the third switch in a direction flowing from the first voltage maintaining element or the second voltage maintaining element to the second transmission line; wherein the first fault current or the second fault current are indicative of a cross-port fault between the low potential conductor of the first transmission line and the high potential conductor of the second transmission line; and in response to detecting the first electrical characteristic is outside of a first predefined range or the second electrical characteristic outside of a second predefined range, limiting the first fault current or the second fault current within a predefined amount of time.

In some aspects, the techniques described herein relate to a method, wherein the first electrical characteristic includes a crossline voltage indicative of a voltage across the first transmission line or the second electrical characteristic includes a crossline voltage indicative of a voltage across the second transmission line.

In some aspects, the techniques described herein relate to a method, wherein the first predefined range is defined relative to a first maintained voltage indicative of a voltage across the first voltage maintaining element or the second predefined range is defined relative to the first maintained voltage or a second maintained voltage indicative of a voltage across the second voltage maintaining element.

In some aspects, the techniques described herein relate to a method, wherein the first predefined range is defined as a range from negative to positive of half of the first maintained voltage, or the second predefined range is defined as a range from negative to positive of the first maintained voltage or from negative to positive of the second maintained voltage.

In some aspects, the techniques described herein relate to a method, wherein the first electrical characteristic includes a leakage current indicative of a current through the first switch or the second electrical characteristic includes a leakage current indicative of a current through the second switch.

In some aspects, the techniques described herein relate to a method, wherein the first predefined range or the second predefined range includes a range no more than a let-go limit, wherein the let-go limit includes a DC let-go limit or an AC let-go limit.

In some aspects, the techniques described herein relate to a method, wherein the first electrical characteristic includes an imbalance voltage indicative of a difference in voltage across the first switch and voltage across the second switch, or the second electrical characteristic includes an imbalance voltage indicative of a difference in voltage across the third switch and voltage across the fourth switch.

In some aspects, the techniques described herein relate to a method, wherein the first electrical characteristic includes a faster time constant or increased non-linearity during a first time interval as compared to a time constant or non-linearity during a second time interval; wherein during the first time interval, the first switch conducts the first fault current; wherein, during the second time interval, the first switch does not conduct the first fault current; wherein the first time interval and the second time interval are a subset of the overlapping isolation interval.

In some aspects, the techniques described herein relate to a method, wherein said non-linearity is determined using numerical analysis to produce an approximation in the form of a polynomial function, where the estimated accuracy of said polynomial function is based on the magnitude of the variance of the individual measurements from the approximation.

In some aspects, the techniques described herein relate to a method, wherein the detection is determined by the estimated accuracy of the polynomial function not meeting a minimum accuracy requirement.

In some aspects, the techniques described herein relate to a method, wherein the first switch, the second switch, the third switch, or the fourth switch includes a transistor.

In some aspects, the techniques described herein relate to a method, wherein the first switch, the second switch, the third switch, or the fourth switch includes a diode.

In some aspects, the techniques described herein relate to a method, wherein a first one or more snubber circuits are connected to the first transmission line, the first switch, or the second switch during a first snubber time interval; or a second one or more snubber circuits are connected to the second transmission line, the third switch, or the fourth switch during a second snubber time interval; and wherein the first snubber time interval or the second snubber time interval at least partially overlap with the overlapping isolation interval.

In some aspects, the techniques described herein relate to a method, wherein the first electrical characteristic indicative or the second electrical characteristic is monitored at a time distinct from the first snubber time interval and the second snubber time interval.

In some aspects, the techniques described herein relate to a method, wherein, during an at least partially concurrent power transfer interval of a power transfer interval of the first power distribution device and a power transfer interval of the second power distribution device, the first fault monitoring device is further configured to monitor a first residual current as a current difference indicative of a difference between a current through the first switch in a direction from the first voltage maintaining element to the first transmission line and a current through the second switch from the first transmission line to the first voltage maintaining element; or the second fault monitoring device is further configured to monitor a second residual current as a current difference indicative of a difference in current between a current through the third switch in a direction from the first voltage maintaining element or the second voltage maintaining element to the second transmission line and a current through the fourth switch in a direction from the second transmission line to the first voltage maintaining element of the second voltage maintaining element.

In some aspects, the techniques described herein relate to a method, wherein, in response to detecting the first residual current being outside of a third predefined range or the second residual current being outside of a fourth predefined range, limiting the first residual current or the second residual current within a predefined amount of time.

In some aspects, the techniques described herein relate to a method, wherein the third predefined range or the fourth predefined range includes a range from negative to positive of a let-go limit, wherein the let-go limit includes a DC let-go limit or an AC let-go limit.

In some aspects, the techniques described herein relate to a system to detect cross-port faults, including: a first transmission line including a first high potential conductor and a first low potential conductor; a second transmission line including a second high potential conductor and a second low potential conductor; a first voltage maintaining element; a second voltage maintaining element; a first power distribution device configured to be connected to the first transmission line and the first voltage maintaining element, wherein the first power distribution device includes a first switch and a second switch configured to connect the first voltage maintaining element to the first transmission line during power transfer intervals and to at least partially nominally isolate the first voltage maintaining element from the first transmission line during isolation intervals; a second power distribution device configured to be connected to the second transmission line and the second voltage maintaining element, wherein the second power distribution device includes a third switch and a fourth switch configured to connect the second voltage maintaining element to the second transmission line during power transfer intervals and to at least partially nominally isolate the second voltage maintaining element from the second transmission line during isolation intervals; a first fault monitoring device configured to be connected to the first transmission line or the first power distribution device, wherein the first fault monitoring device includes a first monitoring circuit; and a second fault monitoring device configured to be connected to the second transmission line or the second power distribution device, wherein the second fault monitoring device includes a second monitoring circuit; wherein the first monitoring circuit is configured to: measure a first electrical characteristic indicative of a first fault current through the second switch in a direction flowing from the first transmission line to the first voltage maintaining element; determine that a cross-port fault is present when the first electrical characteristic is outside of a first predefined range; and upon determining that the cross-port fault is present, activate a first disconnect mechanism; and wherein the second monitoring circuit is configured to: measure a second electrical characteristic indicative of a second fault current through the third switch in a direction flowing from the second voltage maintaining element to the second transmission line; determine that the cross-port fault is present when the second electrical characteristic is outside of a second predefined range; and upon determining that the cross-port fault is present, activate a second disconnect mechanism; and wherein the first fault current or the second fault current are indicative of the cross-port fault between the low potential conductor of the first transmission line and the high potential conductor of the second transmission line.

In some aspects, the techniques described herein relate to a system, wherein the first electrical characteristic includes a crossline voltage indicative of a voltage across the first transmission line or the second electrical characteristic includes a crossline voltage indicative of a voltage across the second transmission line.

In some aspects, the techniques described herein relate to a system, wherein the first predefined range is defined relative to a first maintained voltage indicative of a voltage across the first voltage maintaining element or the second predefined range is defined relative to the first maintained voltage or a second maintained voltage indicative of a voltage across the second voltage maintaining element.

In some aspects, the techniques described herein relate to a system, wherein the first predefined range is defined as a range from negative to positive 18, wherein the first electrical characteristic includes a leakage current indicative of a current through the first switch or the second electrical characteristic includes a leakage current indicative of a current through the second switch.

In some aspects, the techniques described herein relate to a method, wherein the first predefined range or the second predefined range includes a range no more than a let-go limit, wherein the let-go limit includes a DC let-go limit or an AC let-go limit.

In some aspects, the techniques described herein relate to a system, wherein the first electrical characteristic includes an imbalance voltage indicative of a difference in voltage across the first switch and voltage across the second switch, or the second electrical characteristic includes an imbalance voltage indicative of a difference in voltage across the third switch and voltage across the fourth switch.

In some aspects, the techniques described herein relate to a system, wherein the first electrical characteristic includes a faster time constant or increased non-linearity during a first time interval as compared to a time constant or non-linearity during a second time interval; wherein during the first time interval, the first switch conducts the first fault current; wherein, during the second time interval, the first switch does not conduct the first fault current; wherein the first time interval and the second time interval are a subset of the overlapping isolation interval.

In some aspects, the techniques described herein relate to a system, wherein said non-linearity is determined using numerical analysis to produce an approximation in the form of a polynomial function, where the estimated accuracy of said polynomial function is based on the magnitude of the variance of the individual measurements from the approximation.

In some aspects, the techniques described herein relate to a system, wherein the detection is determined by the estimated accuracy of the polynomial function not meeting a minimum accuracy requirement.

In some aspects, the techniques described herein relate to a system, wherein the first switch, the second switch, the third switch, or the fourth switch includes a transistor.

In some aspects, the techniques described herein relate to a system, wherein the first switch, the second switch, the third switch, or the fourth switch includes a diode.

In some aspects, the techniques described herein relate to a system, wherein a first one or more snubber circuits are connected to the first transmission line, the first switch, or the second switch during a first snubber time interval; or a second one or more snubber circuits are connected to the second transmission line, the third switch, or the fourth switch during a second snubber time interval; and wherein the first snubber time interval or the second snubber time interval at least partially overlap with the overlapping isolation interval.

In some aspects, the techniques described herein relate to a system, wherein the first electrical characteristic indicative or the second electrical characteristic is monitored at a time distinct from the first snubber time interval and the second snubber time interval.

In some aspects, the techniques described herein relate to a system, wherein, during an at least partially concurrent power transfer interval of a power transfer interval of the first power distribution device and a power transfer interval of the second power distribution device, the first fault monitoring device is further configured to monitor a first residual current as a current difference indicative of a difference between a current through the first switch in a direction from the first voltage maintaining element to the first transmission line and a current through the second switch from the first transmission line to the first voltage maintaining element; or the second fault monitoring device is further configured to monitor a second residual current as a current difference indicative of a difference in current between a current through the third switch in a direction from the first voltage maintaining element or the second voltage maintaining element to the second transmission line and a current through the fourth switch in a direction from the second transmission line to the first voltage maintaining element of the second voltage maintaining element.

In some aspects, the techniques described herein relate to a system, wherein, in response to detecting the first residual current being outside of a third predefined range or the second residual current being outside of a fourth predefined range, limiting the first residual current or the second residual current within a predefined amount of time.

In some aspects, the techniques described herein relate to a system, wherein the third predefined range or the fourth predefined range includes a range from negative to positive of a let-go limit, wherein the let-go limit includes a DC let-go limit or an AC let-go limit.

In some aspects, the techniques described herein relate to a method to detect cross-port faults or line-to-earth faults in a fault managed power (FMP) transmission system including a first transmission line including a high potential conductor and a low potential conductor configured to be connected to a transmission line port of a transmitter or a receiver; wherein the transmitter or the receiver further includes a non-transmission line port and a switching barrier connected between the transmission line port and the non-transmission line port; wherein the switching barrier includes a high-side switch and a low-side switch; wherein the high-side switch and the low-side switch are configured to be closed to electrically connect the transmission line port to the non-transmission line port during a power transfer interval and to at least partially nominally isolate the transmission line port from the non-transmission line port during an isolation interval; the method including: during the isolation interval, determining an electrical characteristic indicative of a fault current through the high-side switch or the low-side switch that does not return through the low-side switch or the high-side switch, respectively, wherein the electrical characteristic includes at least one of: a transmission line voltage indicative of a voltage of the high potential conductor relative to the low potential conductor at the transmission line port; a high-side leakage current indicative of a current flowing through the high-side switch from the transmission line port to the non-transmission line port; a low-side leakage current indicative of a current flowing through the low-side switch from the non-transmission line port to the transmission line port; a high-side switch voltage indicative of a voltage across the high-side switch as the non-transmission line port relative to the transmission line port; and a low-side switch voltage indicative of a voltage across the low-side switch as the transmission line port relative to the non-transmission line port; determining that a fault is present when the transmission line voltage is below a first threshold, when the high-side leakage current is above a second threshold, when the low-side leakage current is above the second threshold, when the high-side switch voltage is above a third threshold, or when the low-side switch voltage is above the third threshold; and upon determining that the fault is present, activating a disconnect mechanism to limit the current flow through the fault; wherein the high-side leakage current is not combined with the low-side leakage current to include the electrical characteristic; and wherein the fault includes a line-to-earth fault, or a cross-port fault between a first fault conductor of the first transmission line and a second fault conductor of a second transmission line; wherein the first fault conductor includes the high potential conductor or the low potential conductor; and wherein the first fault conductor is a distinct potential from the second fault conductor.

In some aspects, the techniques described herein relate to a method, wherein the electrical characteristic includes the transmission line voltage.

In some aspects, the techniques described herein relate to a method, wherein the step of determining an electrical characteristic indicative of a fault current further includes measuring or calculating an initial transmission line voltage indicative of a voltage of the high potential conductor relative to the low potential conductor at the transmission line port during the power transfer interval.

In some aspects, the techniques described herein relate to a method, wherein the first threshold is defined as no less than half of the initial transmission line voltage.

In some aspects, the techniques described herein relate to a method, wherein the method further includes measuring or calculating a non-transmission line voltage indicative of a voltage of the across the non-transmission line port from the high-side relative to the low-side.

In some aspects, the techniques described herein relate to a method, wherein the first threshold is defined as no less than half of the non-transmission line voltage.

In some aspects, the techniques described herein relate to a method, wherein the first threshold is predefined as no less than half of the maximum possible transmission line voltage.

In some aspects, the techniques described herein relate to a method, wherein the electrical characteristic includes one or more of the high-side leakage current or the low-side leakage current.

In some aspects, the techniques described herein relate to a method, wherein the second threshold is at least at most a DC let-go limit or an AC let-go limit.

In some aspects, the techniques described herein relate to a method, wherein the method further includes determining whether the first fault conductor is the high potential conductor or the low potential conductor, wherein the high-side leakage current being above the second threshold is indicative of the first fault conductor being the low potential conductor, and wherein the low-side leakage current being above the second threshold is indicative of the first fault conductor being the high potential conductor.

In some aspects, the techniques described herein relate to a method, wherein the electrical characteristic includes one or more of the high-side switch voltage and the low-side switch voltage.

In some aspects, the techniques described herein relate to a method, wherein the third threshold is defined relative to the low-side switch voltage when the third threshold is compared to the high-side switch voltage, or the third threshold is defined relative to the high-side switch voltage when the third threshold is compared to the low-side switch voltage.

In some aspects, the techniques described herein relate to a method, wherein the electrical characteristic further includes one or more of: a high-side transmission-line-to-earth voltage indicative of a voltage of the high potential conductor relative to an earth potential, a low-side earth-to-transmission-line voltage indicative of a voltage of the earth potential relative to the low potential conductor, a high-side non-transmission-line-to-earth voltage indicative of a voltage of the high-side non-transmission line port relative to the earth potential, and a low-side earth-to-non-transmission-line voltage indicative of a voltage of the earth potential relative to the low-side non-transmission line port.

In some aspects, the techniques described herein relate to a method, the method further includes distinguishing whether the fault is a line-to-earth fault or a cross-port fault; wherein the high-side transmission-line-to-earth voltage being above a fourth threshold, the low-side earth-to-transmission-line voltage being above the fourth threshold, the high-side non-transmission-line-to-earth voltage being above the fourth threshold, or the low-side earth-to-non-transmission-line voltage being above the fourth threshold distinguishes the fault as a line-to-earth fault.

In some aspects, the techniques described herein relate to a method, wherein the fourth threshold is defined relative to the transmission line voltage.

In some aspects, the techniques described herein relate to a method, wherein the method further includes measuring or calculating a non-transmission line voltage indicative of a voltage of the across the non-transmission line port from the high-side relative to the low-side; and wherein the fourth threshold is defined relative to the non-transmission line voltage.

In some aspects, the techniques described herein relate to a method, wherein the fourth threshold is defined relative to the low-side earth-to-transmission-line voltage when the fourth threshold is compared to the high-side transmission-line-to-earth voltage; the fourth threshold is defined relative to the high-side transmission-line-to-earth voltage when the fourth threshold is compared to the low-side earth-to-transmission-line voltage; the fourth threshold is defined relative to the low-side earth-to-non-transmission-line voltage when the fourth threshold is compared to the high-side non-transmission-line-to-earth voltage; or the fourth threshold is defined relative to the high-side non-transmission-line-to-earth voltage when the fourth threshold is compared to the low-side earth-to-non-transmission-line voltage.

In some aspects, the techniques described herein relate to a method, wherein the fault further includes a failed switch fault; wherein the method further includes measuring or calculating a second high-side switch voltage or a second low-side switch voltage while the disconnect mechanism is activated; wherein the method is further configured to distinguish between a cross-port fault and a failed switch fault; and wherein the second high-side switch voltage being above a fifth threshold or the second low-side switch voltage being above the fifth threshold distinguishes the fault as a failed switch fault.

In some aspects, the techniques described herein relate to a method, wherein the fifth threshold is defined relative to the second low-side switch voltage when the fifth threshold is compared to the second high-side switch voltage, or the fifth threshold is defined relative to the second high-side switch voltage when the fifth threshold is compared to the second low-side switch voltage.

In some aspects, the techniques described herein relate to a method, wherein the method further includes determining whether the high-side switch or the low-side switch is failed, wherein the high-side switch voltage being above the third threshold or the second high-side switch voltage being above the fifth threshold is indicative of the fault being a failed low-side switch; and wherein the low-side switch voltage being above the third threshold or the second low-side switch voltage being above the fifth threshold is indicative of the fault being a failed high-side switch.

In some aspects, the techniques described herein relate to a method, wherein limiting the current flow through the fault includes limiting the current through the high-side switch or the low-side switch to below an electrical constriction limit.

In some aspects, the techniques described herein relate to a method, wherein the electrical constriction limit is a DC let-go limit or an AC let-go limit.

In some aspects, the techniques described herein relate to a method, wherein the method includes using the disconnect mechanism to clamp the transmission line port to limit the available fault energy to a safe level.

In some aspects, the techniques described herein relate to a method, wherein the method includes using the disconnect mechanism to transmit a signal to a supplying transmitter connected to the first transmission line or the second transmission line to limit the output of the supplying transmitter to below an electrical constriction limit.

In some aspects, the techniques described herein relate to a method, wherein the high-side switch or the low-side switch includes a transistor.

In some aspects, the techniques described herein relate to a method, wherein the high-side switch or the low-side switch includes a diode.

In some aspects, the techniques described herein relate to a method, further including providing a first one or more snubber circuits are connected to the first transmission line, the high-side switch, or the low-side switch during a first snubber time interval; or a second one or more snubber circuits are connected to the second transmission line, or a switch connected to the second transmission line during a second snubber time interval; and wherein the first snubber time interval or the second snubber time interval at least partially overlap the isolation interval.

In some aspects, the techniques described herein relate to a method, wherein the electrical characteristic is measured or calculated at a time distinct from the first snubber time interval and the second snubber time interval.

In some aspects, the techniques described herein relate to a method, the method further including, during a power transfer interval, measuring or calculating a residual current as a current difference indicative of a difference between a current through the high-side switch in a direction from the non-transmission line port to the transmission line port and a current through the low-side switch in a direction from the transmission line port to the non-transmission line port.

In some aspects, the techniques described herein relate to a method, the method further including determining that the fault is present when the residual current is outside of a predefined range.

In some aspects, the techniques described herein relate to a method, wherein the predefined range includes a range from negative to positive of a let-go limit, wherein the let-go limit includes a DC let-go limit or an AC let-go limit.

In some aspects, the techniques described herein relate to a system to detect cross-port faults or line-to-earth faults, including: a transmitter or a receiver, the transmitter or the receiver including a transmission line port, a non-transmission line port, and a switch barrier configured to be connected between the transmission line port and the non-transmission line port; wherein the switching barrier includes a high-side switch and a low-side switch, wherein the high-side switch and the low-side switch are configured to be closed to electrically connect the transmission line port to the non-transmission line port during a power transfer interval during a power transfer interval and to at least partially nominally isolate the transmission line port from the non-transmission line port during an isolation interval; a first transmission line including a high potential conductor and a low potential conductor configured to be connected to the transmission line port; one or more sensing circuits, the one or more sensing circuits including one or more of: a transmission line voltage sensor configured to measure a transmission line voltage indicative of a voltage of the high potential conductor relative to the low potential conductor at the transmission line port; a high-side leakage current sensor configured to measure a high-side leakage current indicative of a current flowing through the high-side switch from the transmission line port to the non-transmission line port; a low-side leakage current sensor configured to measure a low-side leakage current indicative of a current flowing through the low-side switch from the non-transmission line port to the transmission line port; a high-side switch voltage sensor configured to measure a high-side switch voltage indicative of a voltage across the high-side switch as the non-transmission line port relative to the transmission line port; and a low-side switch voltage sensor configured to measure a low-side switch voltage indicative of a voltage across the low-side switch as the transmission line port relative to the non-transmission line port; and a control circuit configured to: during the isolation interval, measure the transmission line voltage, the high-side leakage current, the low-side leakage current, the high-side switch voltage, or the low-side switch voltage; determine that a fault is present when the transmission line voltage is below a first threshold, when the high-side leakage current is above a second threshold, when the low-side leakage current is above the second threshold, when the high-side switch voltage is above a third threshold, or when the low-side switch voltage is above the third threshold; and upon determining that the fault is present, activating a disconnect mechanism to limit the current flow through the fault; wherein the high-side leakage current is not combined with the low-side leakage current when compared to the third threshold; wherein the fault includes a line-to-earth fault, or a cross-port fault between a first fault conductor of the first transmission line and a second fault conductor of a second transmission line; wherein the first fault conductor includes the high potential conductor or the low potential conductor; and wherein the first fault conductor is a distinct potential from the second fault conductor.

In some aspects, the techniques described herein relate to a system, wherein the electrical characteristic includes the transmission line voltage.

In some aspects, the techniques described herein relate to a system, wherein the step of determining an electrical characteristic indicative of a fault current further includes measuring or calculating an initial transmission line voltage indicative of a voltage of the high potential conductor relative to the low potential conductor at the transmission line port during the power transfer interval.

In some aspects, the techniques described herein relate to a system, wherein the first threshold is defined as no less than half of the initial transmission line voltage.

In some aspects, the techniques described herein relate to a system, wherein the method further includes measuring or calculating a non-transmission line voltage indicative of a voltage of the across the non-transmission line port from the high-side relative to the low-side.

In some aspects, the techniques described herein relate to a system, wherein the first threshold is defined as no less than half of the non-transmission line voltage.

In some aspects, the techniques described herein relate to a system, wherein the first threshold is predefined as no less than half of the maximum possible transmission line voltage.

In some aspects, the techniques described herein relate to a system, wherein the electrical characteristic includes one or more of the high-side leakage current or the low-side leakage current.

In some aspects, the techniques described herein relate to a system, wherein the second threshold is at least at most a DC let-go limit or an AC let-go limit.

In some aspects, the techniques described herein relate to a system, wherein the method further includes determining whether the first fault conductor is the high potential conductor or the low potential conductor, wherein the high-side leakage current being above the second threshold is indicative of the first fault conductor being the low potential conductor, and wherein the low-side leakage current being above the second threshold is indicative of the first fault conductor being the high potential conductor.

In some aspects, the techniques described herein relate to a system, wherein the electrical characteristic includes one or more of the high-side switch voltage and the low-side switch voltage.

In some aspects, the techniques described herein relate to a system, wherein the third threshold is defined relative to the low-side switch voltage when the third threshold is compared to the high-side switch voltage, or the third threshold is defined relative to the high-side switch voltage when the third threshold is compared to the low-side switch voltage.

In some aspects, the techniques described herein relate to a system, wherein the electrical characteristic further includes one or more of: a high-side transmission-line-to-earth voltage indicative of a voltage of the high potential conductor relative to an earth potential, a low-side earth-to-transmission-line voltage indicative of a voltage of the earth potential relative to the low potential conductor, a high-side non-transmission-line-to-earth voltage indicative of a voltage of the high-side non-transmission line port relative to the earth potential, and a low-side earth-to-non-transmission-line voltage indicative of a voltage of the earth potential relative to the low-side non-transmission line port.

In some aspects, the techniques described herein relate to a system, the method further includes distinguishing whether the fault is a line-to-earth fault or a cross-port fault; wherein the high-side transmission-line-to-earth voltage being above a fourth threshold, the low-side earth-to-transmission-line voltage being above the fourth threshold, the high-side non-transmission-line-to-earth voltage being above the fourth threshold, or the low-side earth-to-non-transmission-line voltage being above the fourth threshold distinguishes the fault as a line-to-earth fault.

In some aspects, the techniques described herein relate to a system, wherein the fourth threshold is defined relative to the transmission line voltage.

In some aspects, the techniques described herein relate to a system, wherein the method further includes measuring or calculating a non-transmission line voltage indicative of a voltage of the across the non-transmission line port from the high-side relative to the low-side; and wherein the fourth threshold is defined relative to the non-transmission line voltage.

In some aspects, the techniques described herein relate to a system, wherein the fourth threshold is defined relative to the low-side earth-to-transmission-line voltage when the fourth threshold is compared to the high-side transmission-line-to-earth voltage; the fourth threshold is defined relative to the high-side transmission-line-to-earth voltage when the fourth threshold is compared to the low-side earth-to-transmission-line voltage; the fourth threshold is defined relative to the low-side earth-to-non-transmission-line voltage when the fourth threshold is compared to the high-side non-transmission-line-to-earth voltage; or the fourth threshold is defined relative to the high-side non-transmission-line-to-earth voltage when the fourth threshold is compared to the low-side earth-to-non-transmission-line voltage.

In some aspects, the techniques described herein relate to a system, wherein the fault further includes a failed switch fault; wherein the method further includes measuring or calculating a second high-side switch voltage or a second low-side switch voltage while the disconnect mechanism is activated; wherein the method is further configured to distinguish between a cross-port fault and a failed switch fault; and wherein the second high-side switch voltage being above a fifth threshold or the second low-side switch voltage being above the fifth threshold distinguishes the fault as a failed switch fault.

In some aspects, the techniques described herein relate to a system, wherein the fifth threshold is defined relative to the second low-side switch voltage when the fifth threshold is compared to the second high-side switch voltage, or the fifth threshold is defined relative to the second high-side switch voltage when the fifth threshold is compared to the second low-side switch voltage.

In some aspects, the techniques described herein relate to a system, wherein the method further includes determining whether the high-side switch or the low-side switch is failed, wherein the high-side switch voltage being above the third threshold or the second high-side switch voltage being above the fifth threshold is indicative of the fault being a failed low-side switch; and wherein the low-side switch voltage being above the third threshold or the second low-side switch voltage being above the fifth threshold is indicative of the fault being a failed high-side switch.

In some aspects, the techniques described herein relate to a system, wherein limiting the current flow through the fault includes limiting the current through the high-side switch or the low-side switch to below an electrical constriction limit.

In some aspects, the techniques described herein relate to a system, wherein the electrical constriction limit is a DC let-go limit or an AC let-go limit.

In some aspects, the techniques described herein relate to a system, wherein the method includes using the disconnect mechanism to clamp the transmission line port to limit the available fault energy to a safe level.

In some aspects, the techniques described herein relate to a system, wherein the method includes using the disconnect mechanism to transmit a signal to a supplying transmitter connected to the first transmission line or the second transmission line to limit the output of the supplying transmitter to below an electrical constriction limit.

In some aspects, the techniques described herein relate to a system wherein the high-side switch or the low-side switch includes a transistor.

In some aspects, the techniques described herein relate to a system, wherein the high-side switch or the low-side switch includes a diode.

In some aspects, the techniques described herein relate to a system, further including providing a first one or more snubber circuits are connected to the first transmission line, the high-side switch, or the low-side switch during a first snubber time interval; or a second one or more snubber circuits are connected to the second transmission line, or a switch connected to the second transmission line during a second snubber time interval; and wherein the first snubber time interval or the second snubber time interval at least partially overlap the isolation interval.

In some aspects, the techniques described herein relate to a system, wherein the electrical characteristic is measured or calculated at a time distinct from the first snubber time interval and the second snubber time interval.

In some aspects, the techniques described herein relate to a system, the method further including, during a power transfer interval, measuring or calculating a residual current as a current difference indicative of a difference between a current through the high-side switch in a direction from the non-transmission line port to the transmission line port and a current through the low-side switch in a direction from the transmission line port to the non-transmission line port.

In some aspects, the techniques described herein relate to a system, the method further including determining that the fault is present when the residual current is outside of a predefined range.

In some aspects, the techniques described herein relate to a system, wherein the predefined range includes a range from negative to positive of a let-go limit, wherein the let-go limit includes a DC let-go limit or an AC let-go limit.

### BRIEF DESCRIPTION OF THE DRAWINGS

FIG. 1 is a high-level block diagram of a generic communication or power distribution system, including a digital electricity system.

FIG. 2 is a detailed circuit of a digital electricity transmitter.

FIG. 3 is a detailed circuit of a digital electricity receiver.

FIG. 4 shows a generic power system with a snubber circuit at the receiver-end to facilitate a more accurate cable voltage drop measurement at the transmitter.

FIG. 5 shows a digital electricity system with a snubber at the transmitter-end to facilitate a more accurate cable voltage drop measurement at the transmitter.

FIG. 6 is a circuit diagram of a generic power system including crossline snubber circuits present in the transmitters and receivers and with a cross-port fault introduced.

FIG. 7 is a circuit diagram of one typical digital electricity system including a transmitter with cross-port fault detection and a snubber; and with a unidirectional-switching receiver; where a cross-port fault is introduced.

FIG. 8 is a circuit diagram of another typical digital electricity system including a transmitter with cross-port fault detection and a snubber; and with a unidirectional-switching receiver; wherein the transmitters feature bidirectional switches and individual voltage sensors for unidirectional elements; where a cross-port fault is introduced.

FIG. 9 is a circuit diagram of another possible digital electricity system including a receiver with cross-port fault detection and a snubber, where the transmitter and receiver both feature bidirectional switches, and where a cross-port fault is introduced.

FIG. 10 shows several simple variations of snubber circuit impedance networks and switch configurations, including active control.

FIG. 11 describes the phenomenon of a cross-port positive-negative resistive fault as seen by the transmitter, including the currents and voltages involved.

FIG. 12 describes the phenomenon of a cross-port positive-negative human-body model fault as seen by the transmitter, including the currents and voltages involved.

FIG. 13 describes the phenomenon of a cross-port positive-negative resistive fault as seen by a single receiver, including the currents and voltages involved.

FIG. 14 describes the phenomenon of a cross-port positive-negative resistive fault as seen by 2 separate receivers, including the currents and voltages involved, where coupling occurs at the receiver outputs (e.g., the loads).

FIG. 15 shows examples of decay waveforms seen as the transmitter output voltage, including resistive and capacitive faults, where each isolation interval may alternate usage of a known bias, or where each isolation interval may feature a multitude of states in a single isolation interval including with bias, without bias, and with inline communications.

FIG. 16 shows examples of transmitter output voltage in a digital electricity system where ringing is typically present, where this is shown with and without the snubber connected.

FIG. 17 shows the circuit and waveforms for a digital electricity system including unidirectional switches and a snubber in the transmitter, where the waveforms show the behavior with and without power delivered to the load with significant distance between the transmitter and receiver.

FIG. 18 shows the waveforms of a cross-port positive-negative fault between 2 channels with simultaneous isolation intervals when no snubber is used with varying amounts (not depicted) of load, distance, fault resistance, and crossline capacitance.

FIG. 19 shows the circuit and waveforms of a cross-port positive-negative fault between 2 channels with simultaneous isolation intervals when a snubber is used.

FIG. 20A shows the timing diagram of periodic snubber usage in a generic power or communications system.

FIG. 20B shows the timing diagram of periodic snubber usage in a typical digital electricity system.

FIG. 21 shows the common transmission line circuit model as well as a variation that facilitates observations of voltage drop on the positive and negative sides of the circuit and allows better observations of the dynamic effects of dielectric dipole behavior.

FIG. 22A includes several system architectural arrangements of transmitters and receivers in power and communication systems including digital electricity systems.

FIG. 22B includes further system architectural arrangements of transmitters and receivers in power and communication systems including digital electricity systems.

FIG. 23 shows voltage waveforms of load inrush with significant distance between the transmitter and the receiver, where this effect is shown with and without usage of a snubber.

FIG. 24 shows a circuit and waveforms for energy injection by the transmitter or receiver to compensate for error in the cable voltage drop to allow a more accurate measurement, including detection of multiple or changing time constants.

FIG. 25 shows waveforms for an alternative cross-port fault detection algorithm accomplished through staggering or dithering of channels.

FIG. 26 shows a circuit and waveforms for cross-port faults when the fault is positive-positive as well as when the fault is negative-negative between the 2 ports with simultaneous isolation intervals.

FIG. 27 shows snubber circuits connected line-to-earth.

FIG. 28 shows a circuit and waveforms for cross-port fault detection based on current imbalance between positive and negative rails, which can be done while using bidirectional switches.

FIG. 29 is an example system diagram of bidirectional transfer (i.e., transmitter to receiver transfer and receiver to transmitter transfer on the same conductor pair), including a battery and load that could be grouped together inside of an electric vehicle (EV).

FIG. 30 shows ringing waveforms observed in a digital electricity system during the isolation interval with bidirectional and with unidirectional switches in the receiver front-end, including a highlight of the unidirectional switching phenomenon of the forward-traveling wave energy loss through receiver's unidirectional switch's diode (or the equivalent unidirectional switch's diode at the transmitter).

FIG. 31 is a collection of switching circuit alternatives for cross-port fault detection with bidirectional switches, where all circuits are shown for the transmitter positive position only.

FIG. 32 shows the phenomenon of a cross-port positive-negative resistive fault between the input receiver port and the output transmitter port of a repeater, wherein the current path that charges at least one of the transmission lines during the power transfer interval is not part of the fault current path during the isolation interval.

FIG. 33A shows the phenomenon of a cross-port positive-negative resistive fault between an input receiver port and an output transmitter port of a power network switch or router, wherein the transmitters that connect to the input receiver ports are not shown but may be connected to the same isolated voltage source or different isolated voltage sources. This shows the state during the power transfer interval.

FIG. 33B shows the same phenomenon as FIG. 33A, but shows the state during the isolation interval instead of the power transfer interval.

FIG. 34 shows the cross-port positive-negative fault phenomenon for 2 transmitters in an isolation interval, wherein each transmitter has its own voltage supply circuit, and wherein the degree of isolation between the 2 voltage supply circuits is represented by a voltage and impedance between each voltage supply circuit's negative rail and a voltage and impedance between each voltage supply circuit's common ground.

FIG. 35 shows a configuration with 2 repeaters connected in series, wherein a cross-port fault is introduced from the negative input of the first repeater to the positive output of the second repeater, and wherein the receiver portion of each repeater includes diodes as AE/DE switching barrier switches.

FIG. 36 shows a configuration with 3 repeaters connected in series, wherein a cross-port fault is introduced from the negative input of the first repeater to the positive output of the third repeater, and wherein the receiver portion of each repeater includes MOSFETs as AE/DE switching barrier switches that are each synchronously switched with the transmitter connected to its input.

FIG. 37 describes the phenomenon of a cross-port positive-negative resistive fault as seen by the transmitter, including the currents and voltages involved, wherein the second transmitter keeps its positive switch in a closed position resulting in the fault current not conducting through the non-fault-side switch of the second transmitter.

FIG. 38 describes the phenomenon of a cross-port positive-negative resistive fault as seen by the transmitter, including the currents and voltages involved, wherein the second transmitter keeps its negative switch in a closed position resulting in the fault current not conducting through the unidirectional element (not depicted).

FIG. 39A shows a cross-port fault embodiment applied to a pair of AC systems represented as H-bridge inverters, wherein the fault characteristics are detected during the positive portion of the AC cycle.

FIG. 39B shows the same system as FIG. 39A, but wherein the fault characteristics are detected during the negative portion of the AC cycle, and wherein the direction of the fault current through the fault resistance is the opposite as compared to FIG. 39A.

FIG. 40A is an individual switch failure detection circuit for bidirectional switches comprising unidirectional switches using a passive bias circuit.

FIG. 40B is another individual switch failure detection circuit for bidirectional switches comprising unidirectional switches using a semi-passive circuit.

FIG. 40C is an individual switch failure detection circuit for bidirectional switches comprising unidirectional switches using an active reverse bias circuit.

FIG. 40D is another individual switch failure detection circuit for bidirectional switches comprising unidirectional switches using a passive bias circuit and an active reverse bias circuit.

### DETAILED DESCRIPTION

The foregoing and other features and advantages of various aspects in this disclosure will be apparent from the following, more-particular description of various concepts and specific embodiments within the broader bounds of this disclosure. Various aspects of the subject matter introduced above and discussed in greater detail below may be implemented in any of numerous ways, as the subject matter is not limited to any particular manner of implementation. Examples of specific implementations and applications are provided primarily for illustrative purposes.

Unless otherwise defined, used or characterized herein, terms that are used herein (including technical and scientific terms) are to be interpreted as having a meaning that is consistent with their accepted meaning in the context of the relevant art and are not to be interpreted in an idealized or overly formal sense unless expressly so defined herein.

The terminology used herein is for the purpose of describing particular embodiments and is not intended to be limiting of exemplary embodiments. As used herein, singular forms, such as “a” and “an,” are intended to include the plural forms as well, unless the context indicates otherwise. Additionally, the terms, “includes,” “including,” “comprises” and “comprising,” specify the presence of the stated elements or steps but do not preclude the presence or addition of one or more other elements or steps.

The methods described in this specification include a novel method to ensure the accurate detection of what was described in Eaves '637 as an “inline” fault. The electrical industry often uses the term “resistive fault” interchangeably with “inline” fault. Inline faults are defined as a fault where excessive power losses are experienced in the transmission lines between the source and load devices. For example, a loose termination can result in a high connection resistance. The high resistance can result in heating that can in-turn result in fire. Inline faults are one of the primary causes of electrical fires in the power distribution industry.

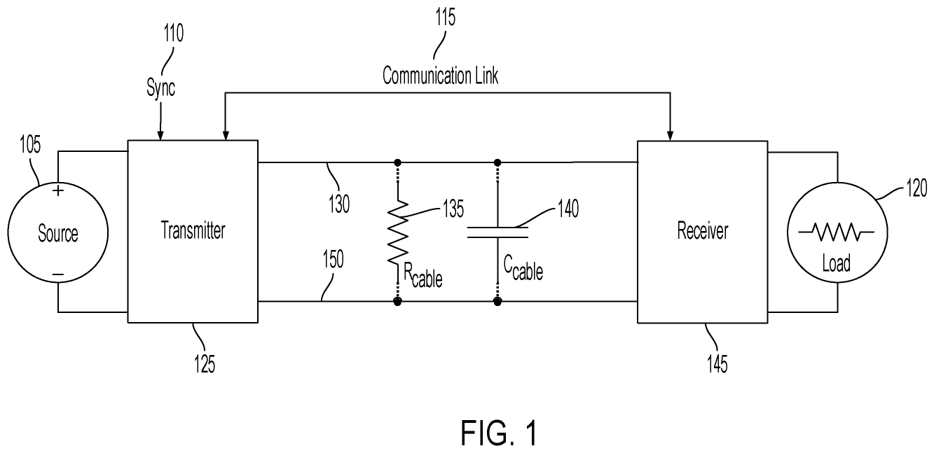

A simplified diagram of general power transmission system including at least a digital-power system, as originally described in Eaves '637 and further expanded upon in Mlyniec '494 and Casey '067, is shown in FIG. 1. The system performs the PET protocol when the power transmission lines 130 and 150 are periodically isolated from source 105 and load 120 via action of transmitter 125 and receiver 145. During this period of isolation, referred to as the isolation interval, the transmitter 125 performs measurements to verify the integrity of the transmission line to determine if energy transfer to the receiver should resume. As discussed in Eaves '637, the rate of decay of the energy stored on the transmission lines can be observed and indicates whether there is a crossline fault present on the transmission lines.

The digital-power system in FIG. 1 shows additional elements that may be implemented as described in prior art. A synchronization signal 110 may be implemented to synchronize a plurality of transmitters as described by Mlyniec '494. An optional external communication link 115 can be used to exchange information between the transmitter and receiver as described in Eaves '637 and other prior art. In other embodiments, this external communication link may be replaced with an in-band communication link over the same transmission line conductors 130 and 150 that are used for power transfer as described in Eaves '795.

The inherent line-to-line impedance of the transmission line is represented with resistance (R_{cable}) 135 and capacitor (C_{cable}) 140. From the perspective of the transmitter 125, this line-to-line, or crossline, impedance also includes the crossline impedance of the transmitter and receiver circuitry, referred to as the effective crossline impedance.

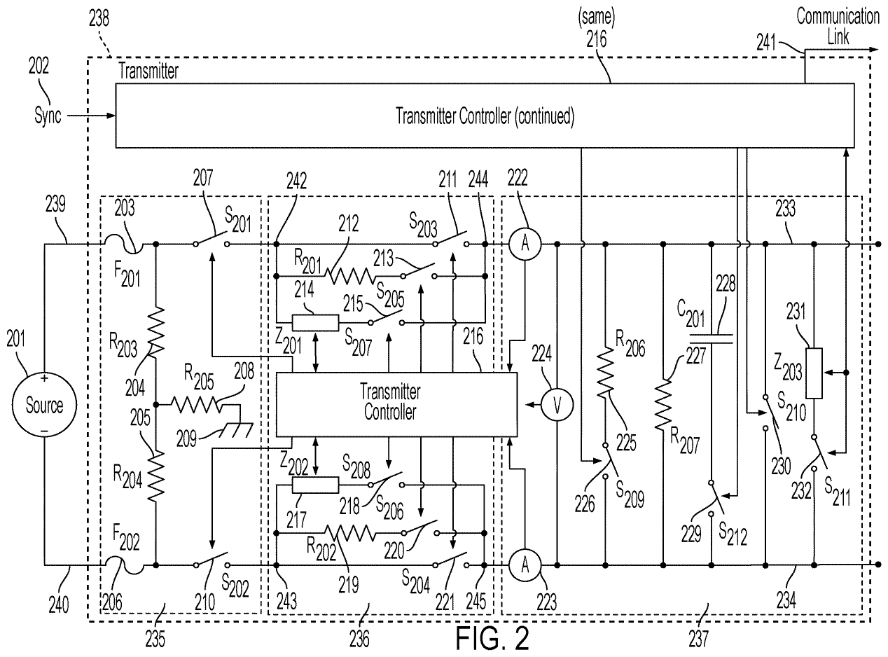

FIG. 2 shows a primary embodiment of the circuit of a DE transmitter. The transmitter accepts input power from Source 201 at positive and negative input terminals 239 and 240, respectively. Each input terminal is fused by fuse F₂₀₁ (203) and F₂₀₂ (206), respectively. After the fuses, a high-impedance center-tie current-limiting earth ground balance circuit is connected comprising resistors R₂₀₃ (204) and R₂₀₄ (205) to form a center point between the positive and negative fused DC bus and resistor R₂₀₅ (208) providing a current-limited path between the center point and the earth ground connection 209. The positive and negative fused DC bus continues to secondary protection switches S₂₀₁ (207) and S₂₁₀ (210). After the secondary protection switches, the positive and negative DC bus continues to the main switching section. On the positive side, this main switching section comprises the parallel combination of main primary switch S₂₀₃ (211), soft-start resistor R₂₀₁ (212) in series with soft-start switch S₂₀₅ (213), and snubber impedance Z₂₀₁ (214) in series with snubber switch S₂₀₇ (215). This is mirrored on the negative side by main primary switch S₂₀₄ (221), soft-start resistor R₂₀₂ (219), soft-start switch S₂₀₆ (220), snubber impedance Z₂₀₂ (217), and snubber switch S₂₀₈ (218), respectively. While the soft-start and snubber elements are described by these descriptive names, they can be used for other purposes, such as communications, or can be combined or omitted in accordance with design goals.

Continuing with FIG. 2, after the main switching section is a positive and a negative current sensor 222 and 223, respectively. There is also a crossline output voltage sensor 224 sensing the voltage across the positive and negative output bus connected to the output terminals 233 and 234 that are configured to connect to a transmission line that connects to a DE receiver. Pulldown resistor R₂₀₆ (225) and pulldown switch S₂₀₉ (226) are also connected across the output bus, as is bleed resistor R₂₀₇ (227). Output capacitor C201 (228) can be connected across the output bus or isolated from the output bus via output capacitor switch S₂₁₂ (229). A simplified shunt switch S₂₁₀ (230) for crowbar usage is also connected across the output bus. Finally, snubber impedance Z₂₀₃ (231) and snubber switch S₂₁₁ (232) are connected across the output bus.

The transmitter further comprises a transmitter controller 216, which connects to each of the switches (207, 210, 211, 213, 215, 218, 220, 221, 226, 229, 230, 232) as well as to each sensor (222, 223, 224) and to snubber impedances that may comprise a control circuit (214, 217, 231). The transmitter controller 216 is configured to connect to a sync signal 202 to receive or drive a synchronization signal to coordinate with other devices. The transmitter controller 216 is further configured to connect to a communication link 241, which is depicted as an external communication link in FIG. 2 but may be an inline communication link connected to the output terminals 233 and 234.

The elements 203, 204, 205, 206, 207, 208, and 210 can be grouped into a transmitter AE-side circuit 235. The elements 222, 223, 224, 225, 226, 227, 228, 229, 230, 231, and 232 can be grouped into a transmitter DE-side circuit 237. The elements 211, 212, 213, 214, 215, 217, 218, 219, 220, and 221 can be grouped into a transmitter AE/DE switching barrier circuit 236 that separates the transmitter AE-side circuit 235 from the transmitter DE-side circuit 237. The transmitter controller 216 may be connected to each of these grouped circuits 235, 236, and 237; or may be sub-divided into a plurality of transmitter controllers that connect to a subset of grouped circuits 235, 236, or 237. The interface between the AE-side circuit 235 and the AE/DE switching barrier 236 is defined by the input link interface comprising input link terminals 242 and 243; while the interface between the DE-side circuit 237 and the AE/DE switching barrier 236 is defined by the output link interface comprising output link terminals 244 and 245. The collection of the AE-side circuit 235, DE-side circuit 237, AE/DE switching barrier 236, and transmitter controller 216 comprise a full transmitter 238; wherein a transmitter may refer to the full transmitter 238 or to a subset of the full transmitter 238 (e.g., only 237, or only 236 and 237, etc.) based on context. In a DC-based system or for half of the phase of an AC-based system, elements 203, 207, 211, 212, 213, 214, 215, 233, 239, 242, and 244 are considered high-side elements while elements 206, 210, 217, 218, 219, 220, 221, 223, 234, 240, 243, and 245 are considered low-side elements.

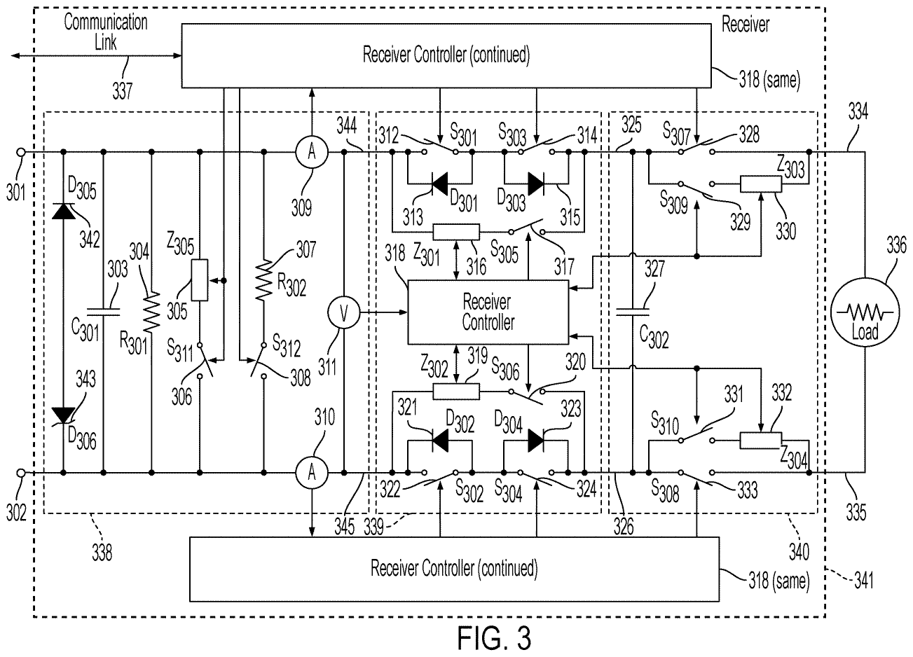

FIG. 3 shows a primary embodiment of the circuit of a DE receiver. The DE receiver receives input power at positive and negative input terminals 301 and 302 that are configured to connect to a transmission line that connects to a DE transmitter. The DE input bus formed electrically by the input terminals 301 and 302 has input capacitor C₃₀₁ (303) connected across it. Resistor R₃₀₁ (304) is also connected across the DE input bus. The series combination of diode D₃₀₅ (342) and Zener diode D₃₀₆ (343) is also connected across the DE input bus for purposes such as reverse connect detection, wherein Zener diode 343 can be omitted and replaced with a short to still provide reverse connect detection. The series combination of snubber impedance Z₃₀₅ (305) and snubber switch S₃₁₁ (306) connects across this same DE input bus. Finally, the series combination of pulldown resistance R₃₀₂ (307) and pulldown switch S₃₁₂ (308) connects across the DE input bus. Current sensors 309 and 310 are present on the positive and negative side, respectively, in series with the corresponding side of the DE input bus. Voltage sensor 311 is configured to measure a value indicative of the voltage across the DE input bus, depicted in FIG. 3 wherein a negligible voltage change is present across the current sensors 309 and 310.

Continuing with FIG. 3, after the DE input bus, a main switching section of the DE receiver is present. On the positive side, this comprises back-to-back main switches S₃₀₁ (312) and S₃₀₃ (314), each with an associated diode D₃₀₁ (313) and D₃₀₃ (315) in parallel, respectively. In parallel around the set of back-to-back main switches is the series combination of snubber impedance Z₃₀₁ (316) and snubber switch S₃₀₅ (317). This circuitry is mirrored on the negative side as main switches S₃₀₄ (324) and S₃₀₂ (322), diodes D₃₀₄ (323) and D₃₀₂ (321), snubber impedance Z₃₀₂ (319), and snubber switch S₃₀₆ (320), respectively.

After the main switching section, DC link bus comprising a positive side 325 and negative side 326 is connected. DC link cap C₃₀₂ (327) is connected across the DC link bus. The DC link bus connects to an output stage, which on the positive side comprises main load switch S₃₀₇ (328) in parallel with the series combination of snubber/soft-start switch S₃₀₉ (329) and snubber/soft-start impedance Z₃₀₃ (330); wherein this is mirrored on the negative side as main load switch S₃₀₈ (333), snubber/soft-start switch S₃₁₀ (331), and snubber/soft-start impedance Z₃₀₄ (332), respectively. The output of this output stage circuit is connected to positive and negative output terminals 334 and 335, respectively, which are configured to be connected to load 336.

The receiver further comprises a receiver controller 318, which connects to each of the switches (306, 308, 312, 314, 317, 320, 322, 324, 328, 329, 331, 333), as well as to each sensor (309, 310, 311) and to snubber/soft-start impedances that may comprise a control circuit (305, 316, 319, 330, 332). The receiver controller 318 is configured to connect to a communication link 337, which is depicted as an external communication link in FIG. 3 but may be an inline communication link connected to the input terminals 301 and 302.

The elements 303, 304, 305, 306, 307, 308, 309, 310, 311, 342 and 343 can be grouped into a receiver DE-side circuit 338. The elements 327, 328, 329, 330, 331, 332, and 333 can be grouped into a receiver AE-side circuit 340. The elements 312, 313, 314, 315, 316, 317, 319, 320, 321, 322, 323, and 324 can be grouped into a receiver AE/DE switching barrier circuit 339 that separates the receiver DE-side circuit 338 from the receiver AE-side circuit 340. The receiver controller 318 may be connected to each of these grouped circuits 338, 339, and 340; or may be sub-divided into a plurality of receiver controllers that connect to a subset of grouped circuits 338, 339, or 340. The interface between the DE-side circuit 338 and the AE/DE switching barrier 339 is defined by the input link interface comprising input link terminals 344 and 345; while the interface between the AE-side circuit 340 and the AE/DE switching barrier 339 is defined by the output link interface comprising output link terminals 325 and 326. The collection of the DE-side circuit 338, AE-side circuit 340, AE/DE switching barrier 339, and receiver controller 318 comprise a full receiver 341; wherein a receiver may refer to the full receiver 341 or to a subset of the full receiver 341 (e.g., only 338, or only 338 and 339, etc.) based on context. In a DC-based system or for half of the phase of an AC-based system, elements 301, 309, 312, 313, 314, 315, 316, 317, 325, 328, 329, 330, 334, and 344 are considered high-side elements while elements 302, 310, 319, 320, 321, 322, 323, 324, 326, 331, 332, 333, 335, and 345 are considered low-side elements.

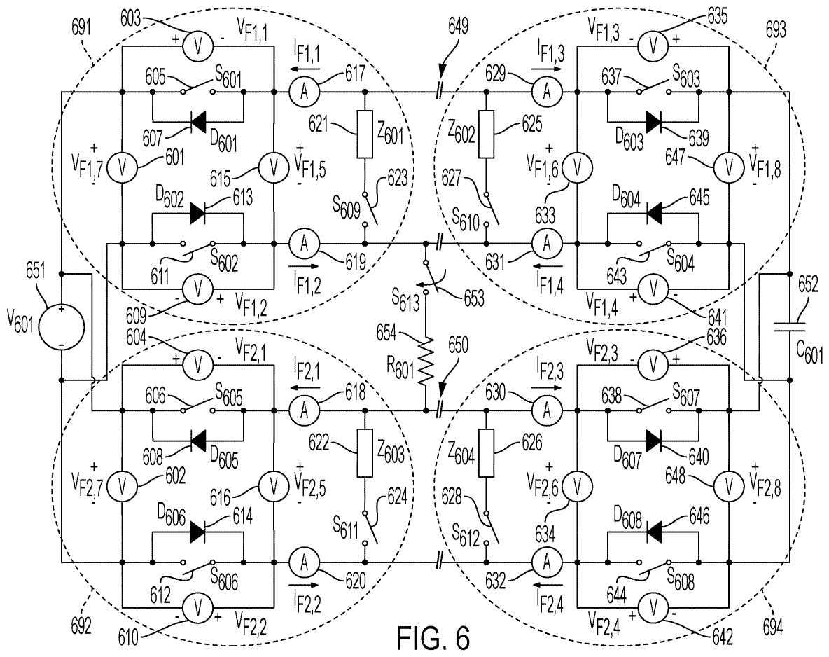

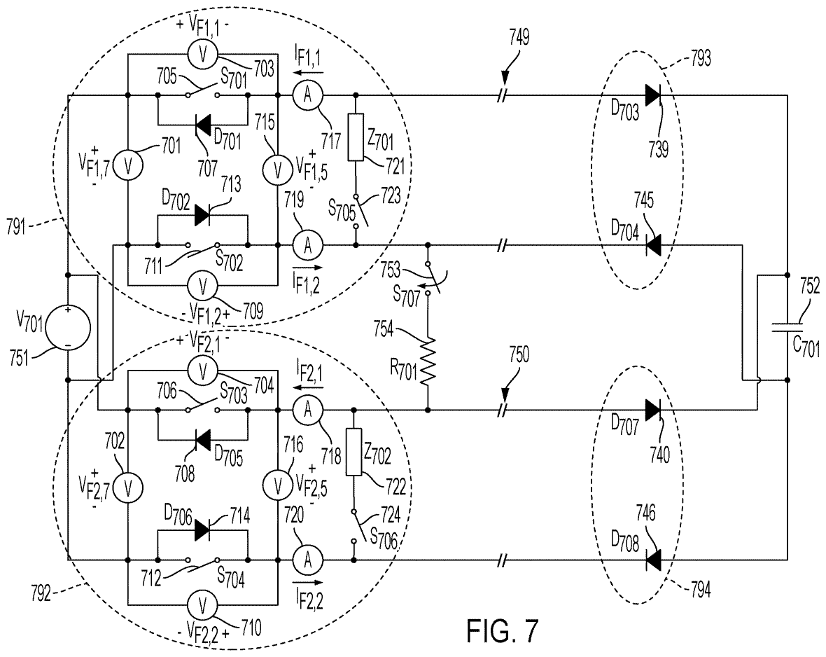

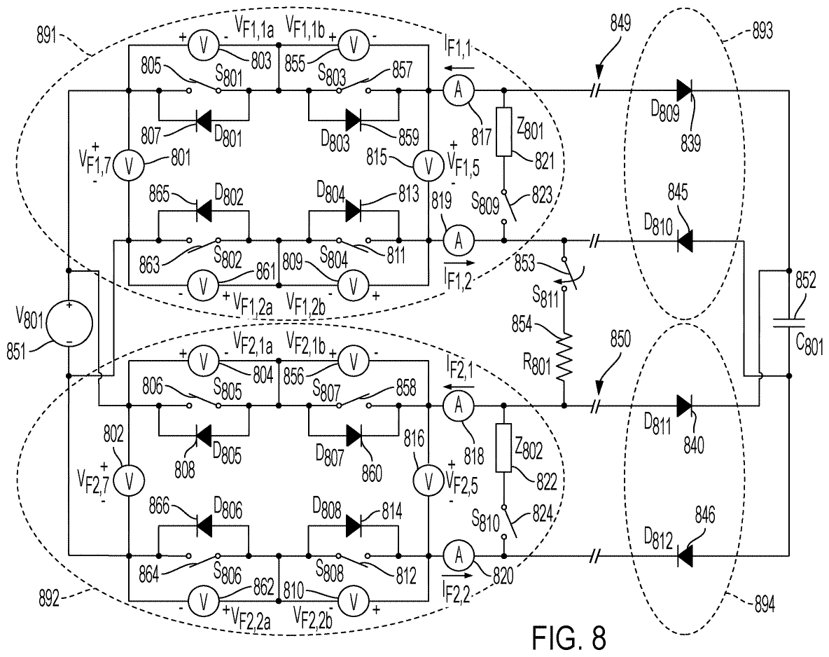

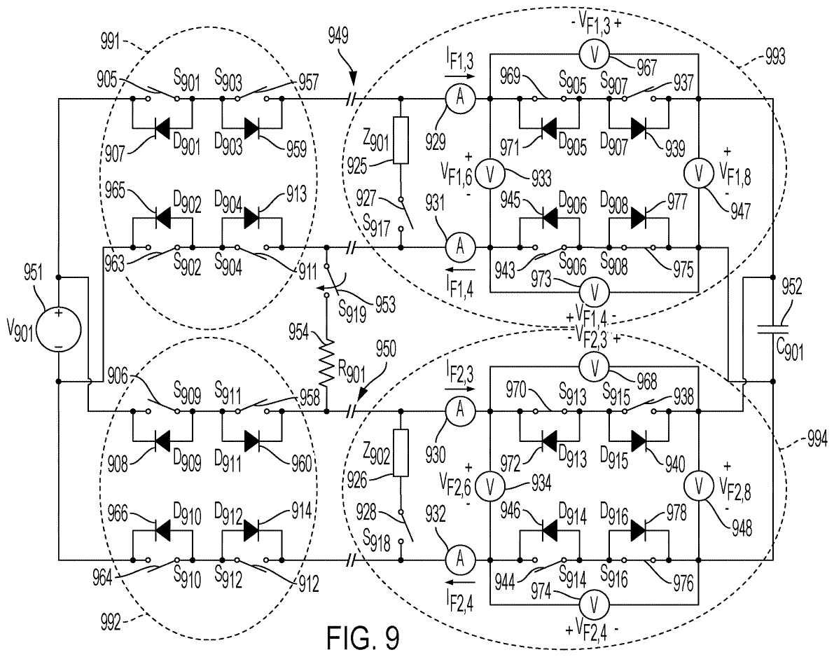

FIG. 6, FIG. 7, FIG. 8, and FIG. 9 show various switch, sensor, and snubber circuit arrangements for periodic snubbing applications, cross-port fault detection, and other methods described herein. These varied embodiments show how different factors are impacted by arrangement of different sections of the circuit. It is understood that these are not exhaustive, and that other combinations of arrangements can be realized based on the teachings disclosed herein. At a high-level, as will be later formally defined, each drawing represents 2 channels; wherein the upper half is a first channel comprising a first transmitter in the upper left quadrant and a first receiver in the upper right quadrant; and the lower half is a second channel comprising a second transmitter in the lower left quadrant and a second receiver in the lower right quadrant. To aid in seeing how each of these embodiments align with each other, callouts for equivalent components between FIG. 6, FIG. 7, FIG. 8, and FIG. 9 retain the same last 2 digits. For example, switch 612 in FIG. 6 is equivalent to switch 812 in FIG. 8, as both callouts end in the last 2 digits being “12”.

Starting with FIG. 6, this shows a fairly comprehensive embodiment of circuit components, wherein each switch is implemented as a unidirectional switch. Both the first channel and the second channel are powered by source 651 connected to the first transmitter 691 and the second transmitter 692. The first transmitter includes a switching barrier comprising switches 605 and 611 with associated respective diodes 607 and 613. Around switch 605 and 611 are switch voltage sensors 603 and 609, respectively. The first transmitter further comprises an input voltage sensor 601 and output voltage sensor 615 along with output current sensors 617 and 619. Finally, the first transmitter further includes an output snubber circuit comprising snubber switch 623 and snubber impedance 621. These components 601, 603, 605, 607, 609, 611, 613, 615, 617, 619, 621, and 623 comprise the first transmitter 691. The respective components 602, 604, 606, 608, 610, 612, 614, 616, 618, 620, 622, and 624 comprise the second transmitter 692.

The first receiver includes a switching barrier comprising switches 637 and 643 with associated respective diodes 639 and 645, which each have a switch voltage sensor 635 and 641 in parallel, respectively. The first receiver further comprises an input voltage sensor 633, an output voltage sensor 647, and input current sensors 629 and 631. Finally, the first receiver further includes an input snubber circuit comprising snubber switch 627 and snubber impedance 625. The components 625, 627, 629, 631, 633, 635, 637, 639, 641, 643, 645, and 647 comprise the first receiver 693. The respective components 626, 628, 630, 632, 634, 636, 638, 640, 642, 644, 646, and 648 comprise the second receiver 694. The first and second receiver are further connected to a shared receiver link capacitance 652, which is typically part of a receiver in many embodiments, but is shown as a distinct component for ease of illustration and to represent that the relevant current path may be provided external to the receiver such as through load connections.

In addition to the first transmitter, second transmitter, first receiver, and second receiver, a first abbreviation mark 649 and a second abbreviation mark 650 for the first channel and the second channel, respectively, represent a variable length of cable. These abbreviation marks also serve to further demark between the transmitter and the receiver for each channel. Finally, the cross-port fault is shown as comprising fault switch 653 and fault resistance 654. This cross-port fault is connected towards the transmitter-end of the system between the positive output of the second transmitter to the negative output of the first transmitter.

As will be referenced in embodiments herein, when all transmitter and receiver switches are open during concurrent isolation intervals and a cross-port fault is present (i.e., the cross-port fault switch 653 is closed), the effects of the cross-port fault can be measured in a number of ways by a transmitter or a receiver using various voltage or current sensors; and this may take into account the snubber circuit effects if used.

FIG. 7 shows a variation of the circuit in FIG. 6, wherein the first and second transmitter now embody a typical digital electricity transmitter while the first and second receiver embody a typical digital electricity receiver; wherein each of these digital electricity transmitters and digital electricity receivers are presented as simplified circuits to show the relevant effects for cross-port fault detection in a digital electricity system.

The first and second transmitters are unchanged from FIG. 6, so FIG. 6 elements 625, 627, 629, 631, 633, 635, 637, 639, 641, 643, 645, and 647 correspond respectively to equivalent FIG. 7 elements 725, 727, 729, 731, 733, 735, 737, 739, 741, 743, 745, and 747 to comprise the first transmitter 791; and these then correspond to respective components 726, 728, 730, 732, 734, 736, 738, 740, 742, 744, 746, and 748 to comprise the second transmitter 792. The first receiver 793, however, for the purposes of the cross-port algorithm, is simplified to comprise only diodes 739 and 745, which form the AE/DE switching barrier. These elements 739 and 745 of the first receiver correspond respectively to 740 and 746 to comprise the second receiver 794. Finally, the source 651, shared receiver link capacitance 652, cross-port fault switch 653, and cross-port fault resistance 654 correspond respectively to the same elements in FIG. 7 as 751, 752, 753, and 754. As with FIG. 6, this circuit presented in FIG. 7 will be referenced in embodiments herein to describe multiple methods of detecting cross-port faults during concurrent isolation intervals using various voltage and current sensors, possibly in conjunction with the usage of the snubber circuits.

FIG. 8 is a variation of FIG. 7, but features bidirectional switches used for the transmitters, wherein each bidirectional switch comprises back-to-back unidirectional switches. In addition to the first transmitter 891 comprising elements 825, 827, 829, 831, 833, 835, 837, 839, 841, 843, 845, and 847 that correspond respectively to elements 725, 727, 729, 731, 733, 735, 737, 739, 741, 743, 745, and 747; the first transmitter 891 further comprises additional switches 857 and 863 with respective diodes 859 and 865 along with respective switch voltage sensors 855 and 861. The cumulative first transmitter elements 825, 827, 829, 831, 833, 835, 837, 839, 841, 843, 845, 847, 855, 857, 859, 861, 863, and 865 correspond respectively to elements 826, 828, 830, 832, 834, 836, 838, 840, 842, 844, 846, 848, 856, 858, 860, 862, 864, and 866 to comprise the second transmitter 892.

Note that each bidirectional switch arranges its composite unidirectional switches in a common anode configuration with respect to the diodes. This would correspond to using n-channel MOSFETs as the unidirectional switch, wherein this common anode configuration would be called a common source configuration with respect to the MOSFETs. Other configurations, such as common cathode or common drain, are possible; though one advantage of a common source configuration is that a single isolated gate voltage supply can be generated for both MOSFETs of a single bidirectional switch since the single isolated gate voltage supply can be referenced to the same, singular node (i.e., the common source node).

Continuing with the circuit of FIG. 8, the first and second receivers are unchanged from FIG. 7, so elements 739 and 745 correspond respectively to 839 and 845 to comprise the first receiver 893; and elements 740 and 746 correspond respectively to 840 and 846 to comprise the second receiver 894. Finally, the source 751, shared receiver link capacitance 752, cross-port fault switch 753, and cross-port fault resistance 754 correspond respectively to the same elements in FIG. 8 as 851, 852, 853, and 854. As with FIG. 6 and FIG. 7, this circuit presented in FIG. 8 will be referenced in embodiments herein to describe multiple methods of detecting cross-port faults during concurrent isolation intervals using various voltage and current sensors, possibly in conjunction with the usage of the snubber circuits; with the emphasis with respect to this circuit being the bidirectional switch configuration of the transmitters.

FIG. 9 provides yet another circuit variation, adapting elements largely from FIG. 6 and FIG. 8, and focusing on a bidirectional switch configuration used for the receivers as well as a single switch voltage sensor used around a bidirectional switch. The first and second transmitters retain the bidirectional switch configuration; but the voltage sensors, current sensors, and output snubber circuits have been omitted for simplicity. Therefore, the first transmitter 991 has been reduced to comprise elements 905, 907, 911, 913, 957, 959, 963, and 965 that correspond respectively to elements 805, 807, 811, 813, 857, 859, 863, and 865; and these then correspond respectively to elements 906, 908, 912, 914, 958, 960, 964, and 966 to comprise the second transmitter 992.

The first receiver 993 retains comprising elements 925, 927, 929, 931, 933, 937, 939, 943, 945, and 947 that correspond respectively to elements 625, 627, 629, 631, 633, 637, 639, 643, 645, and 647. The first receiver 993 further comprises additional switches 957 and 963 with respective diodes 959 and 965. Each switch voltage sensor 967 and 973, however, measures across the entirety of its respective bidirectional switch rather than across each unidirectional switch comprising a bidirectional switch. The cumulative first receiver elements 925, 927, 929, 931, 933, 937, 939, 943, 945, 947, 957, 959, 963, 965, 967, and 973 correspond respectively to elements 926, 928, 930, 932, 934, 938, 940, 944, 946, 948, 958, 960, 964, 966, 968, and 974 to comprise the second receiver 994. Note that some switches (969, 970, 975, 976) are depicted in a closed position in FIG. 9. This depiction is used to also show how a bidirectional switch comprising unidirectional switches can be configured to operate equivalent to a unidirectional switch configuration shown in FIG. 6; though in some embodiments, these switches are still switched depending on the details of that embodiment.

Finishing the introduction of FIG. 9, the source 951, shared receiver link capacitance 952, cross-port fault switch 953, and cross-port fault resistance 954 correspond respectively to the same elements in FIG. 8 as 851, 852, 853, and 854. As with FIG. 6, FIG. 7, and FIG. 8, this circuit presented in FIG. 9 will be referenced in embodiments herein to describe multiple methods of detecting cross-port faults during concurrent isolation intervals using various voltage and current sensors, possibly in conjunction with the usage of the snubber circuits; with the emphasis with respect to this circuit being the receiver-side detection and the bidirectional switch configuration with a single switch voltage sensor for each bidirectional switch of the receivers.

To understand the underlying electrical properties for at least the snubber aspects of this disclosure, it is well known that transmission lines can be represented by an impedance, known as its characteristic impedance. For a lossy transmission line, this characteristic impedance, Z₀, is commonly defined in terms of the resistance per unit length, R′, the inductance per unit length, L′, the conductance per unit length, G′, the capacitance per unit length, C′, and the angular frequency, ω, as well as the imaginary number, j, using the equation:

$${Z}_{0} = \sqrt{\frac{{R}^{′} + jwL ′}{{G}^{′} + jwC ′}}$$

This characteristic impedance can be used in combination with the load impedance, Z_{L}, to calculate the reflection coefficient at the load, I′_{L}:

$${Γ}_{L} = \frac{{Z}_{L} - {Z}_{0}}{{Z}_{L} + {Z}_{0}}$$

These impedances and the reflection coefficient itself can be complex numbers. In some applications, the phase of this complex reflection coefficient may not be important and it is the magnitude that is the primary interest, where that magnitude can be calculated as the square root of the product of the reflection coefficient by its complex conjugate.

Similarly, the reflection coefficient at the source or generator side of the circuit, I′_{g}, can be calculated using the source impedance, Z_{g}:

$${Γ}_{g} = \frac{{Z}_{g} - {Z}_{0}}{{Z}_{g} + {Z}_{0}}$$

This load impedance and source impedance used in the reflection coefficient calculation can be referred to generically as the “line-end impedance” or “termination impedance”.

When active or passive switching is employed at a given end of the transmission line, the line-end impedance may exclude impedances on the non-transmission-line side of the switch if the switch effectively provides isolation. For example, opening MOSFET switches will result in only circuit elements on the transmission-line side of the switches to factor into the source impedance, typically transitioning from a low impedance to a high impedance from the perspective of the transmission line. Similarly, reverse biasing diodes will result in only circuit elements on the transmission-line side of the diodes to factor into the load impedance. In these scenarios, this isolation can greatly increase the simplicity and the control over the impedance matching. For example, at the receiver end, while the isolation via active or passive switching is in effect, the impedance of the external load connected to its output does not factor into the impedance matching, thereby eliminating the need to account for an external load that may have a dynamic or unexpected impedance that is beyond the receiver's control, nor does it require system designers to specify restrictions on those external loads for this purpose.

A perfectly matched impedance results in a reflection coefficient of 0. This occurs when the line-end impedance is exactly the same as the characteristic impedance. A perfect match may not be required for most applications, and line-end impedance values close to the characteristic impedance may be sufficient. Therefore, a reflection coefficient near 0 may be sufficient for many applications provided that the resulting measurements and limit evaluations have enough tolerance that the minimized effects from a non-zero reflection coefficient do not alter the determinations in any meaningful way, such as producing too many false positives or false negatives.

For example, for a transmission line featuring a complex impedance, it is often observed that the real part is a much greater portion of the reflection coefficient's magnitude than the imaginary part at lower frequencies. In this case, the snubber can be designed with a primary focus on matching the real part precisely while matching the imaginary portion can have more flexibility, allowing the design to incorporate other considerations.

In the case of a characteristic impedance that does not have an imaginary part, there may be motivation to intentionally avoid a perfect match. A transmission line can achieve a characteristic impedance with a negligible imaginary part by a variety of means, often negating the relevance of frequency through various methods, such as being designed and operated within a region where the lossless transmission line assumptions are valid, or by fine tuning the impedance through techniques such as the Heaviside condition (i.e., R′/L′=G′/C′). A typical characteristic impedance with no imaginary part for cables such as Cat6 cables is 100Ω. For this characteristic impedance, a perfectly matched line-end impedance is also 100Ω. In a power transmission system, particularly at higher voltages, a 100Ω resistance placed across the positive and negative terminals may constitute excessive power loss and impair proper functioning of the system. One way to solve this would be to add a small capacitance in series with the 100Ω matched impedance. This creates only a small, negligible deviation from 0 for the reflection coefficient, but prevents steady power draw by the matched impedance network. To achieve this, any capacitance value will be sufficient, with the exact capacitance value desired deferred to system design constraints, such as minimizing the reflection coefficient. This works most effectively in a DC power system, but even an AC system would have an efficiency improvement compared to not using the capacitor. Another solution here would be to switch the 100 Ω into the circuit only for the time window when ringing is expected. This may result in a more challenging design if time constraints are critical, and it may still impact other aspects of the system functionality in adverse ways.

Among the motivations to intentionally deviate from a perfectly matched impedance is to improve receiver voltage sensing accuracy by the transmitter in a system utilizing unidirectional switching at the receiver. By including an effective series capacitance in the snubber circuit, the energy from the snubber circuit can be used to replenish any excess non-snubber crossline capacitance energy lost through forward conduction of the receiver diode. This allows the transmitter to then sense its own output voltage when this energy replenishment has effectively finished, and to conclude that this is an estimate of the receiver input voltage during the power transfer interval. This is because receivers typically contain a large capacitance on the DC link side of the receiver's disconnect switch that effectively stores the voltage that existed on the receiver side of the transmission line just before the conclusion of the last power transfer interval. In the case of a plurality of receivers connected to the same transmission line, this estimate of the receiver input voltage will be a value indicative of the lowest receiver input voltage. When the snubber current diminishes, it means that the snubber voltage has reached the point where it is nearly equal to the voltage of the receiver capacitors and hence it is nearly equal to the receiver side voltage just before the end of the last power transfer interval.

The design of this snubber requires balance of time constants. In its simplest typical form, this is a series resistor, R, and capacitor, C, that is switched across the line. This has an impedance, Z, of:

$$Z = R + \frac{1}{jwC} = R - j \frac{1}{wC}$$

The time constant of the snubber resistor and capacitor should be slow enough to resist the excess capacitor energy drainage that occurs during the initial forward moving wave along the transmission line from the transmitter to the receiver. The time constant balance between the snubber components and the other cross-line components should be such that all capacitances can reach nearly the same voltage with minimal current flowing through the snubber resistor within the required amount of time for the system to take a measurement based on the system's timing constraints, such as the maximum allowable duration of the isolation interval.

The design of this snubber must also consider the energy balance. The energy storage of the snubber must be large enough relative to the energy loss of the other crossline capacitance such that the snubber can restore the energy to the crossline capacitance up to the receiver DC link voltage. This energy storage capability is related to the capacitance values and the voltages involved.

This snubber circuit will add in parallel with any existing line-end impedance present. A complete solution must include this in the circuit analysis for proper evaluation.

Regarding cross-port faults, the observable phenomenon is as follows. In an example system, 2 transmitters are synchronized to be in an isolation interval simultaneously and feature a unidirectional switch on the positive and negative sides of the circuit such that current can flow in the direction of the transmission line positive to the source side positive while the switches are open. During the power transfer interval, each transmitter will have any capacitance across its output terminals charged to that voltage at the transmitter end. When a cross-port fault is present and both transmitters enter the isolation interval, the cross-port effectively stacks the capacitors in a series arrangement from the perspective of the source side of the switches, thereby effectively adding their total voltage. With this total voltage being larger than the sum of the source side voltage and the effective diode voltage drops of the unidirectional switches that are open, this excess voltage is shunted from the crossline capacitances through the unidirectional switches and into the source side of the circuit. Once the sum of the voltage of the crossline capacitances is less than the sum of the source side voltage and the diode voltage drops, the diodes become reverse biased and this current conduction path ceases. At this point, while the balance of current between the 2 crossline capacitances may be unequal due to differing amounts of capacitance, differing leakage currents, and other differing circuit parameters, at least one must be no more than half of the sum of the supply voltage and the diode voltage drops. This provides a means for the transmitter to set an appropriate limit to detect this.

The above example describes a situation with a small RC time constant formed by the crossline impedances and the fault impedance. In cases with large RC time constants, it is possible that the transfer of energy from the transmission line side of the circuit to the source side of the circuit is still ongoing when the circuit makes its determination of whether there is a cross-port fault present using the settled voltage. In this case, the transmitter can perform analysis to determine an unexpected waveform due to the complexity or increased non-linearity of the waveform's profile. In one such method, the linear regression technique taught in Mlyniec '494 could be used to assess a significant deviation from a linear waveform and determine that a fault may be present when a value indicative of deviation from linearity exceeds a limit.

In cases with further larger RC time constants, said complexity or increased non-linearity may not be appreciable, such as when there is much more line-to-line capacitance or the line-to-line fault is a much higher resistance. In these cases where the fault current is still large enough to require detection, there is still an alteration to the effective time constant compared to the time constant that would exist without a fault present, wherein this time constant will be faster while the fault current is conducting compared to when the fault current is not conducting. This can be factored into consideration when designing fault limits and can utilize the same methods of Eaves '637 that are used to detect line-to-line faults from the positive of a port to the negative of the same port.

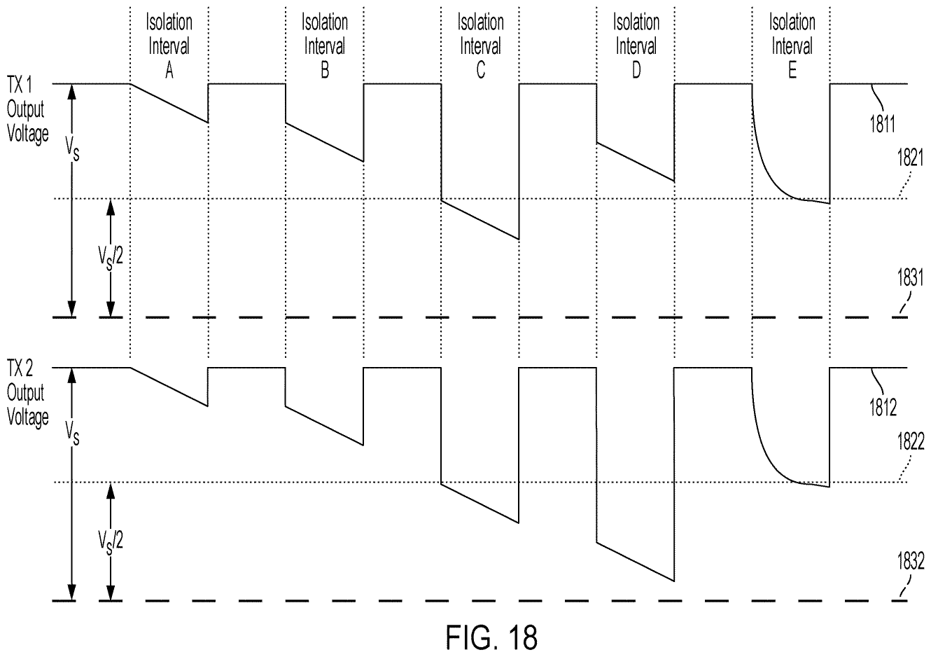

These concepts of the effect of crossline capacitance on cross-port faults are shown in FIG. 18, which shows some of the possible transmitter output voltages that can be observed with different cross-port fault scenarios between a first transmitter and a second transmitter, wherein each transmitter is configured with unidirectional switches. The transmitter output voltage for the first transmitter is shown as waveform 1811 relative to the 0V reference line 1831. The transmitter output voltage for the second transmitter is shown as line 1812 relative to the 0V reference line 1832. For each of these plots, a reference line is provided at half of the supply voltage (i.e., Vₛ/2)—line 1821 for the first transmitter and line 1822 for the second transmitter. For the various scenarios, each one described for a distinct isolation interval, the circuit configuration may be varied as will be described for each.

Starting with isolation interval A, this shows a non-faulted state with either no significant load or no significant cable length. Here, the RC decay occurs on each transmitter output voltage waveform 1811 and 1812, and the waveforms stay well above the half-supply voltage level. For isolation interval B, the circuit has been configured with a significant load with significant cable length, and there is still no cross-port fault present. When isolation interval B begins, a large initial voltage drop is observed on transmitter output voltage waveforms 1811 and 1812; but again, this stays above the half-supply voltage level, and the RC decay occurs normally after the initial voltage drop.

In isolation interval C, the cross-port fault has been introduced, and the crossline capacitance connected to the output of the first transmitter is approximately equal to the crossline capacitance connected to the output of the second transmitter. When the isolation interval begins, a large initial voltage drop is observed again, but this time the half-supply voltage level is reached. Since the crossline capacitances are equal for each transmitter, both transmitters reach their respective half-supply line 1821 and 1822. Therefore, using the methods disclosed herein, both transmitters would detect a cross-port fault. In this case, this would be the observation regardless of whether the waveforms would have appeared as isolation interval A (i.e., no significant load or not significant cable length) or isolation interval B (i.e., significant load and significant cable length) without the cross-port fault present since this effect dominates the initial voltage drop magnitude. Note that, under extreme load level or extreme cable lengths, the large initial voltage drop of isolation interval C can be reached without a cross-port fault present; but in these cases, it is likely not desirable to operate the system at such an extreme level, and if such extreme operation is required, other methods for cross-port fault detection disclosed herein must be used.

Continuing to isolation interval D, this also introduces the cross-port fault, but now the crossline capacitance of the first transmitter is greater than the crossline capacitance of the second transmitter. When the isolation interval begins, each transmitter observes a large initial voltage drop. In this case, though, the initial voltage drop for the second transmitter in waveform 1812 is larger than that for the first transmitter in waveform 1811. The sum of the initial voltage drops will equal the supply voltage (i.e., the average of the initial voltage drops approximately equals half the supply voltage); but in this case, only the second transmitter will detect the cross-port fault using the methods disclosed herein.

Finally, in isolation interval E, the crossline capacitances for the first transmitter and the second transmitter are again equal, and there is no significant load or no significant cable length, but the cross-port fault resistance is a higher resistance value. When the isolation interval begins, instead of a sudden initial voltage drop, a gradual drop to the half-supply line is observed on each waveform 1811 and 1812. Once the half-supply line is reached, the cross-port fault is no longer conducting significant current, and the RC decay occurs as if there were no cross-port fault for the remainder of the isolation interval. Note that in this case, each transmitter can detect the cross-port fault if the initial voltage drop is assessed using data later in the isolation interval (e.g., the middle of the isolation interval). Another useful characteristic is that, as shown in the figure, there is an increased nonlinearity during the gradual transition to the half-supply voltage. This is typically not a simple RC exponential decay (e.g., V₀e^{-t}/_{RC}), but rather is a more complex equation with multiple time constants; and this nonlinearity can be detected using methods disclosed herein to detect the cross-port fault by each transmitter. Finally, even if an approximation of a rate of decay is measured or calculated, this may be significant enough to register a fault using the methods of Eaves '637 and others.

With a snubber in the circuit, this cross-port fault detection may not work as intended. For example, if the snubber circuit has a large capacitive effect, this may prevent both the timely capacitance drainage as well as prevent the presentation of higher complexity or non-linear waveforms due to the fault. This same methodology of looking for a lower settling voltage can still be done, but instead of looking for this settling voltage at a time delay relative to the start of the isolation interval, this should instead look for this settling voltage at a time delay relative to the disconnection of the snubber circuit during the isolation interval. Once the snubber circuit is disconnected, the effective circuit remaining behaves as previously described, and the same lower settling voltage examination method along with the same unexpected waveform evaluation method or effective time constant alteration can be employed.

In a primary embodiment of periodic snubber matching, a snubber circuit is designed for one line end with an impedance that results in a reflection coefficient that is sufficiently reduced within an acceptable tolerance for a particular effective characteristic impedance during a critical time. This snubber circuit is connected to the circuit during an interval of time where the undesired oscillations may occur. Most commonly, this would be when a switch is connected or disconnected within the system. This snubber circuit would then be disconnected from the circuit during a second critical interval where the snubber circuit would prevent proper operation of the system. Outside of these two critical intervals, the snubber circuit can remain either connected or disconnected depending on other system design parameters. For example, having the snubber remained connected during any remaining time intervals could keep snubber circuit energy charged as desired. In another example, connecting the snubber during certain intervals of time may result in an increased adverse EMC impact or increased power dissipation that, while not a critical failure, may be made more efficient by leaving the snubber disconnected and instead connecting the snubber again at a later time.

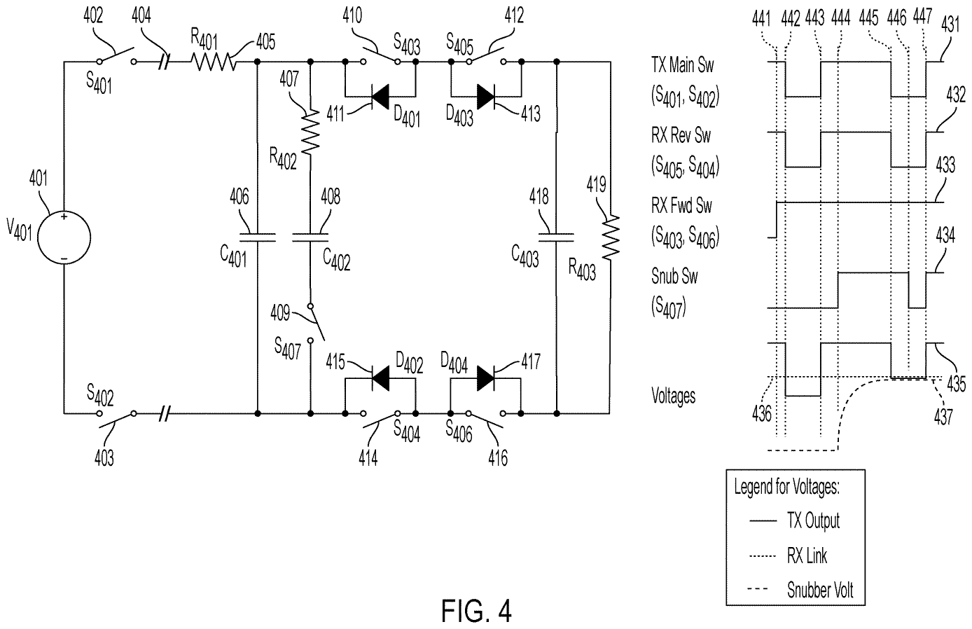

A version of this embodiment of a snubber circuit implemented at the receiver end of a generic power system is shown in FIG. 4. Power is provided by source 401, and the transmitter is represented by switches 402 and 403. The variable length of cable between the transmitter and receiver is depicted by abbreviation mark 404 on the positive and negative conductors. The effective bulk series resistance 405 and effective bulk crossline capacitance 406 represent the simplified values between the transmitter and the receiver contributed by at least the cable and any components on that side of the circuit for the transmitter or receiver. A receiver-side snubber circuit comprises the series combination of resistance 407, capacitance 408, and switch 409. The receiver switching circuit comprises forward-blocking switches 410 and 416 with associated respective diodes 411 and 417; as well as reverse-blocking switches 412 and 414 with associated respective diodes 413 and 415. The effective circuit after the receiver switches is represented by capacitance 418 and resistance 419; wherein the capacitance is typically embodied as a receiver link capacitance, an external load capacitance, or both; and the resistance is typically embodied by an external load.

FIG. 4 further shows a timing diagram of the controls and certain crossline voltages over time. For each switch, a high signal corresponds to the switch being closed and a low signal corresponds to the switch being open (i.e., non-conducting); and this convention is maintained throughout all drawings and descriptions herein. Waveform 431 shows the control of the transmitter switches 402 and 403. Waveform 432 shows the control of the reverse-blocking receiver switches 412 and 414 while waveform 433 shows the control of the forward-blocking receiver switches 410 and 416. Waveform 434 is the control of the snubber switch 409. Finally, the crossline voltage waveforms are plotted together on the same scale, with waveform 435 being the crossline voltage at the transmitter output (i.e., immediately to the right of 402 and 403), waveform 436 being the crossline voltage at the receiver output or across its link capacitance (i.e., across capacitance 418), and waveform 437 shows the voltage across snubber capacitance 408.

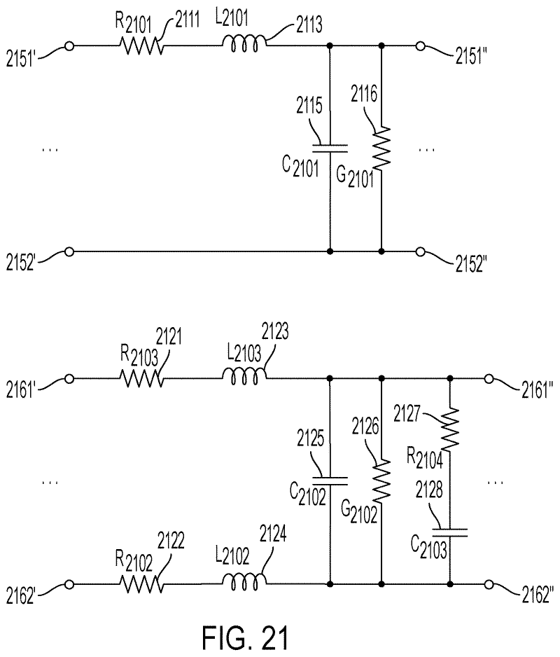

At time 441, the receiver forward-blocking switches are closed and remain closed for illustrating the relevant circuit behavior. Due to the voltage drop across the series resistance of the cable, the transmitter output voltage in waveform 435 is higher than the receiver link voltage in waveform 436. Since the snubber switch is open and has been open for a long duration (for illustrative purposes), the voltage across the snubber capacitance is approximately 0V as seen in waveform 437. At time 442, the transmitter switches as well as the receiver reverse-blocking switches open at approximately the same time. The receiver link voltage in waveform 436 remains nearly constant when sized large enough to continue providing power to resistance 419 with minimal voltage decay, but the transmitter output voltage in waveform 435 overshoots the receiver link voltage due to the oscillations (not shown) triggered by switching as well as the cable impedance (including the inductance, not shown but depicted in FIG. 21), settling at a lower voltage than the receiver link voltage. At time 443, the transmitter switches and receiver reverse-blocking switches return to a closed state.

At time 444, the snubber switch is closed to allow the snubber capacitance to begin charging as seen in waveform 437. By the time the transmitter switches and receiver reverse-blocking switches are opened at time 445, the snubber capacitance is charged to approximately the same voltage as the receiver link capacitance. While oscillations may still occur similar to the ones at time 442, the energy transferred from crossline capacitance 406 to receiver link capacitance 418 is restored to crossline capacitance 406 by snubber capacitance 408. With the snubber capacitance properly sized, negligible voltage decay from the snubber capacitance will be observed, allowing all 3 capacitances (406, 408, 418) to equalize to approximately the same voltage minus any relevant diode voltage drops. At time 446, the snubber switch can be opened while the three voltages in waveforms 435, 436, and 437 remain nearly unchanged by this switch operation. With the snubber switch open, any operations that must be done while the transmitter switches and receiver reverse-blocking switches are opened but without the snubber circuit connected can be performed between time 446 and time 447. At time 447, the transmitter switches and receiver reverse-blocking switches are again closed. Typically, as shown, the snubber switch is also closed at time 447 to allow the snubber capacitance to re-charge as needed.

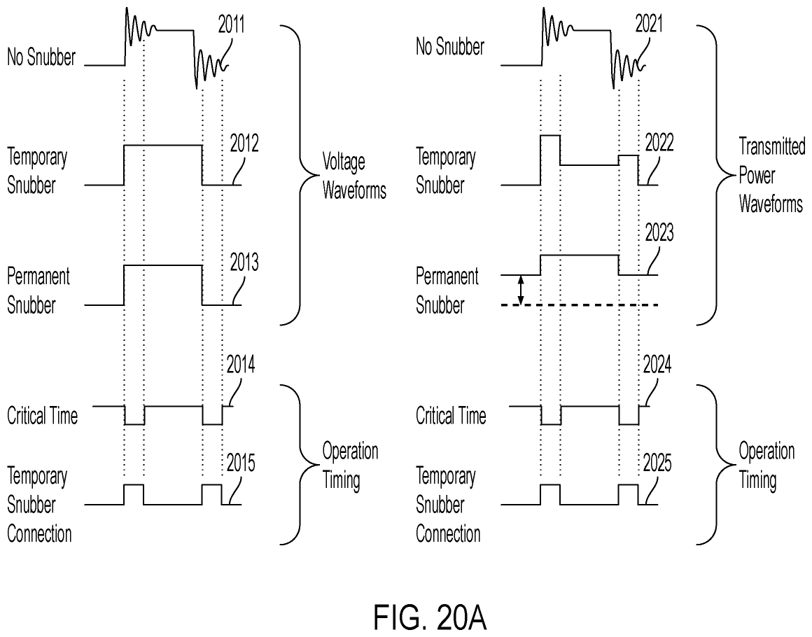

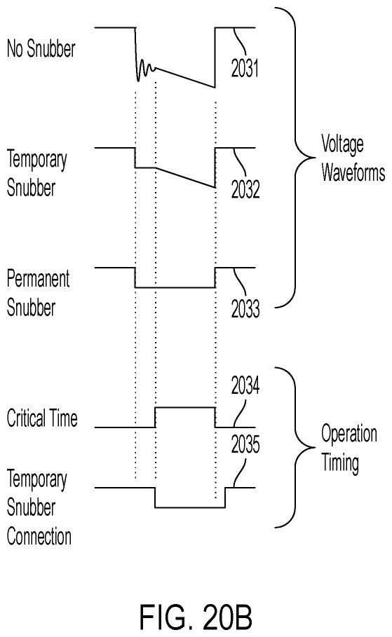

A simplified demonstration of the appeal and usage of a periodic snubber in a generic power or communications system is shown in FIG. 20A. To demonstrate, the system is assumed to be a DC system, and the snubber circuit comprises a crossline resistance when connected. In this figure, 3 cases are presented as transmitter output waveforms: a waveform without any snubber usage, a waveform with a temporary or periodic snubber usage, and a waveform with permanent snubber usage (i.e., snubber is connected at all times). Towards the bottom are timing waveforms: one to show the critical time when the system uses the signal (e.g., reads the state to determine a transmitted bit), and one to show when the temporary or periodic snubber is connected. All of these waveforms are shown for both the transmitter output voltage on the left and the transmitter output power on the right, with the timing waveforms identical between for the voltage waveform set and the power waveform set.

Examining the voltage waveforms first, the benefit of the snubber circuit is clearly visible. The no snubber voltage waveform 2011 shows excessive ringing after each state transition, which could interfere with operation during the critical time intervals indicated by waveform 2014. Both the temporary snubber voltage waveform 2012 and the permanent snubber voltage waveform 2015 show the same resulting voltage waveform that eliminates the ringing seen in 2011 despite the temporary snubber only connected for a limited amount of time as shown in waveform 2015.

The advantage of the temporary snubber usage, though, is apparent in this case when examining the power that is transmitted. Again, the critical time intervals indicated by waveform 2024 and the timing of the temporary snubber connection in waveform 2025 are identical to waveforms 2014 and 2015, respectively. With no snubber used, the transmitted power waveform 2021 is similar to the associated voltage waveform 2011 albeit scaled by the current. With the snubber, however, the power waveforms are much different. With a permanently connected snubber, the transmitted power waveform 2023 shows a significant increase in transmitted power throughout the duration of the entire waveform, as the snubber circuit itself is constantly dissipating power by being connected at all times. This is contrasted against the temporary snubber transmitted power waveform 2022, which only has an increase in power dissipation when the snubber is connected per the timing of waveform 2025. Hence, a significant benefit in the form of power savings and efficiency is realized by using a temporary snubber over a permanent snubber configuration while still retaining the benefits of using a snubber compared to not using any snubber.

In another embodiment, a snubber circuit can be used across a transmitter output in a digital electricity system. The snubber circuit impedance is designed based on the effective circuit impedance during the isolation interval, where this snubber circuit impedance will result in a reflection coefficient that is sufficiently reduced within an acceptable tolerance for the characteristic impedance of the transmission line during that time. The snubber circuit is connected during the power transfer interval. For a first critical time interval at the start of the isolation interval, the snubber circuit remains connected to the transmitter output. This first critical time interval may be prior to performing at least some measurements or calculations for an assessment of safe operation of the transmission system. After this first critical time interval, the snubber circuit is disconnected and the transmitter remains in the isolation interval for a second critical time interval. This second critical time interval allows the transmitter to perform actions to ensure safe operation of the transmission line, such as taking measurements and evaluating said measurements against design limits. After this second critical time interval, the snubber circuit is reconnected to the transmitter circuit again. It is not critical whether this reconnection happens prior to the start of the next power transfer interval or after the start of the next power transfer interval.

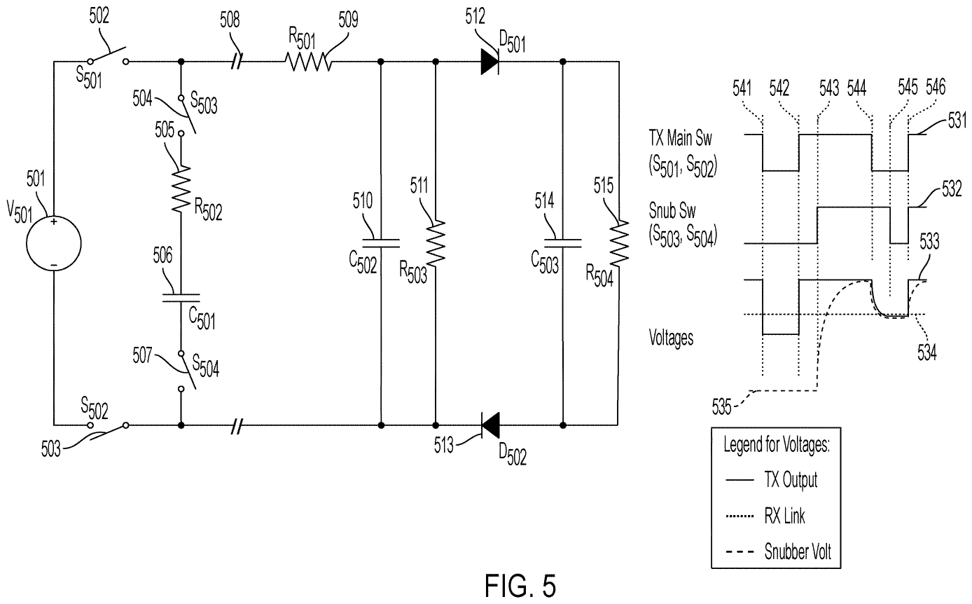

FIG. 5 shows such an embodiment of a snubber circuit implemented at the transmitter end of a digital electricity system. Contrasting to FIG. 4, not only does this exhibit the behavior with common digital electricity system embodiments, but it also highlights at least some differences between a snubber circuit at the transmitter end compared to one at the receiver end. Similar to FIG. 4, power is provided by source 501, and the transmitter is represented by switches 502 and 503. The transmitter further comprises the transmitter-side snubber circuit, which comprises the series combination of snubber switches 504 and 507, snubber resistance 505, and snubber capacitance 506; wherein each snubber switch may be a unidirectional switch blocking current in a distinct direction. The variable length of the cable between the transmitter and receiver is depicted by abbreviation mark 504 on the positive and negative conductors. The effective bulk series resistance 509 and effective bulk crossline capacitance 510 represent the simplified values between the transmitter and the receiver contributed by at least the cable and any components on that side of the circuit for the transmitter or receiver. A further effective bulk crossline resistance 511 represents an analogous simplified value. The receiver switching circuit comprises reverse-blocking diodes 512 and 513. The effective circuit after the receiver switches is represented again by capacitance 514 and resistance 515; wherein the capacitance is typically embodied as a receiver link capacitance, an external load capacitance, or both; and the resistance is typically embodied by an external load.

The timing diagram of the controls and crossline voltages over time are also shown in FIG. 5. Waveform 531 shows the control of the transmitter switches 502 and 503. Receiver switch control is not depicted as these are not directly controlled but rather indirectly controlled (e.g., by transmitter switch operation resulting in forward-biasing or reverse-biasing the receiver switch diodes). Waveform 532 is the control of the snubber switches 504 and 507. Finally, the crossline voltage waveforms are plotted together on the same scale, with waveform 533 being the crossline voltage at the transmitter output (i.e., immediately to the right of 502 and 503), waveform 534 being the crossline voltage at the receiver output or across its link capacitance (i.e., across capacitance 514), and waveform 535 shows the voltage across snubber capacitance 506.

At time 541, the transmitter switches are opened. The receiver link voltage in waveform 534 remains nearly constant when sized large enough to continue providing power to resistance 515 with minimal voltage decay, but the transmitter output voltage in waveform 533 overshoots the receiver link voltage due to the oscillations (not shown) triggered by switching as well as the cable impedance (including the inductance, not shown but depicted in FIG. 21), settling at a lower voltage than the receiver link voltage. Since the snubber switch is open and has been open for a long duration (for illustrative purposes), the voltage across the snubber capacitance is approximately 0V as seen in waveform 535. At time 542, the transmitter switches return to a closed state.

At time 543, the snubber switches are closed to allow the snubber capacitance to begin charging as seen in waveform 535. By the time the transmitter switches are opened at time 544, the snubber capacitance is charged to approximately the same voltage as the source. Again, while some oscillations may occur, the energy transferred from crossline capacitance 510 to receiver link capacitance 514 is restored to crossline capacitance 510 by snubber capacitance 506. In this case, with the snubber capacitance properly sized, and in combination with the forward conducting properties of receiver diode switches 512 and 513, all 3 capacitances (506, 510, 514) will equalize at approximately the same voltage less any relevant diode voltage drops. This is also depicted as a gradual process as shown on waveforms 533 and 534 between time 544 and time 545. At time 545, the snubber switch is opened while the three voltages in waveforms 533, 534, and 535 remain nearly unchanged by this switch operation. With the snubber switch opened, any operations that must be done during an isolation interval but without the snubber circuit connected can be performed between times 545 and 546. At time 546, the transmitter switches are closed, and typically the snubber switch is also closed as shown to allow the snubber capacitance to re-charge as needed.

Another simplified demonstration of the appeal and usage of a periodic snubber is shown for a digital electricity system in FIG. 20B. In this case, only voltage waveforms are shown with the timing waveforms, as the power waveforms are not needed to show the primary benefits.

As can be seen by looking at the ringing portion of the no snubber voltage waveform 2031, using a snubber—whether it is the temporary or periodic snubber in voltage waveform 2032 or the permanent snubber in voltage waveform 2033—mitigates the effects of the ringing as well as the excessive initial voltage drop at the start of an isolation interval as explained in this disclosure. During the critical time indicated by waveform 2034, however, the permanent snubber does not permit any appreciable RC decay that is used for safety measurements or inline communications. The temporary snubber, on the other hand, does permit this RC decay to occur unaltered during the critical time interval since the snubber is disconnected for at least this critical time interval as shown in the temporary snubber connection timing waveform 2035. As an example, the temporary snubber is shown to be reconnected at a time slightly later than the end of the critical time interval as well as slightly later after the end of the isolation interval, showing that it is not essential that the snubber be reconnected exactly at the end of a critical time interval.

In a primary embodiment of a largely capacitive snubber, a snubber circuit is used in a system that features unidirectional switching at the receiver end of the transmission line. The snubber is designed with a relatively large series capacitance such that it can provide energy lost from the other capacitances in parallel with the transmission line during the transient event. Ideally, this snubber is also designed with sufficient impedance matching to critically negate undesired oscillations. When a switch is opened to disconnect the source from the load, the snubber is connected to transfer energy from the snubber's large capacitance to the transmission line and other parallel capacitances, where these capacitances will all settle at nearly the same voltage, where that voltage is nearly the same as or substantially equal to the voltage across the link capacitance of the receiver. Ideally, the snubber circuit remains connected until this equalization has been achieved. This voltage at which the transmission line settles can be measured to provide a value indicative of voltage drop of the transmission line that was present when the source-to-load switches were all closed.

In another embodiment, a largely capacitive snubber circuit can be used across a transmitter output in a digital electricity system. The receiver uses diodes as the unidirectional switches. The snubber is connected to the transmitter output during the power transfer interval to charge the snubber capacitance. When the source disconnect switches are opened, the snubber begins the energy transfer. When the change in voltage over time is sufficiently small, the voltage present across the transmitter output terminals is indicative of the input voltage of the receiver during the power transfer interval, which can be used to calculate a value indicative of the voltage drop of the cable.

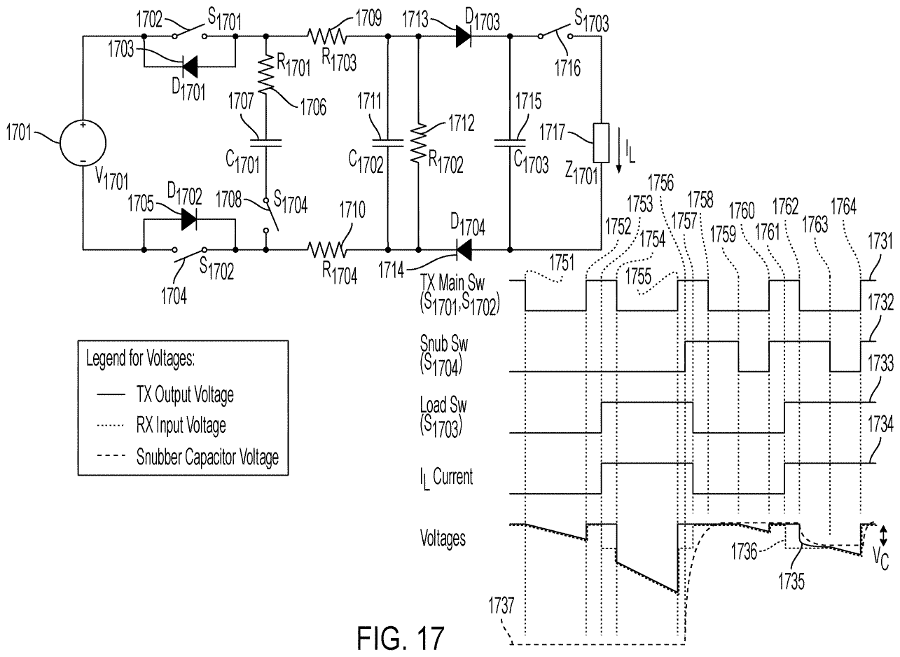

FIG. 17 shows a timing diagram and waveforms for such an embodiment of a periodic capacitive snubber used for at least the reason of improving the inline voltage drop measurement by the transmitter. A simplified, representative circuit is shown to be used in conjunction with the timing diagram and waveforms. Source 1701 provides power to the transmitter input; wherein the transmitter comprises main switches 1702 and 1704 with respective associated diodes 1703 and 1705, and an output snubber circuit; wherein the output snubber circuit comprises a series combination of a snubber resistance 1706, a snubber capacitance 1707, and a snubber switch 1708. The effective impedance between the transmitter and the receiver is represented by series resistances 1709 and 1710, effective crossline capacitance 1711, and effective crossline resistance 1712. The receiver comprises diodes 1713 and 1714 as the AE/DE switching barrier along with link capacitance 1715 and output switch 1716 as the output control and conditioning circuit. The output of the receiver is configured to be connected to load impedance 1717.

Waveform 1731 shows the open/close operation of the transmitter main switches 1702 and 1704. Waveform 1732 shows the open/close operation of the snubber switch 1708. Waveform 1733 shows the open/close operation of the receiver output and load switch 1716. The load current, I_{L}, is shown in waveform 1734 and is the current through load impedance 1717 as shown. The transmitter output voltage is shown in waveform 1735 and is measured across the output snubber circuit. The receiver input voltage is shown in waveform 1736 and is measured across the effective crossline resistance 1712. Finally, the snubber capacitance voltage is shown in waveform 1737 and is measured across the snubber capacitance 1707. Note that the timing diagram and waveforms, as with other figures in this disclosure, are shown with a compressed power transfer interval duration in order to show prominent effects more clearly.

Prior to time 1751, the circuit is in a first power transfer interval with no snubber and no load connected. At time 1751, the transmitter main switches are opened to initiate an isolation interval. The transmitter output and receiver input voltage waveforms decay based on the RC decay of capacitance 1711 and resistance 1712 until the isolation interval is ended and a second power transfer interval commences at time 1752 when the transmitter main switches are closed. At time 1753, the receiver output and load switch is closed, resulting in an increase in the load current and a decrease in the receiver input voltage due to the voltage drop of the series resistances 1709 and 1710.

At time 1754, a second isolation interval is started by the transmitter main switches opening. This results in a sudden drop in the transmitter output voltage as well as the receiver input voltage below the level of the receiver input voltage during the prior power transfer interval. After this sudden initial drop, the transmitter output voltage and receiver input voltage continue to decay until the end of the second isolation interval is reached at time 1755 when the transmitter main switches are closed to start a third power transfer interval. At time 1756, the snubber switch is closed to allow the snubber capacitance to charge. At time 1757, the receiver output and load switch is opened in order to show as an example the behavior when no load is present initially with the snubber circuit in use.

At time 1758, a third isolation interval is started by the transmitter main switches opening. With no load current present, there is no sudden initial voltage drop, but there is also no significant RC decay either since the snubber circuit holds up the crossline voltage by designing the snubber capacitance 1707 to be substantially larger than crossline capacitance 1711. When the snubber switch is opened at time 1759, the RC decay of crossline capacitance 1711 and crossline resistance 1712 can proceed unaltered until the end of the isolation interval at time 1760 when the transmitter main switches are closed to begin a fourth power transfer interval. The snubber switch is also closed at this time to permit the snubber capacitance to charge or discharge as needed. At time 1761, the receiver output and load switch is closed to increase the load current and reduce the receiver input voltage once again.

At time 1762, a fourth isolation interval is started by the transmitter main switches opening. This initiates a gradual reduction of the snubber capacitance voltage as it transfers its energy to the crossline capacitance 1711, with any excess energy transferred to the receiver link capacitance when said excess energy would result in a receiver input voltage in excess of the receiver link voltage across receiver link capacitance 1715 plus the forward voltage drop of diodes 1713 and 1714. As this transfer gradually occurs, there is some temporary mismatch between the transmitter output voltage, receiver input voltage, and the snubber capacitance voltage due to the current flow and resulting voltage drop across resistances 1706, 1709, and 1710.

At time 1763, the snubber switch is opened. Since the voltages had equalized by this time and there was negligible current flow between the transmitter and the receiver, no significant sudden voltage changes occur when the snubber switch is opened. The difference in transmitter output voltage between time 1762 and 1763 provides the cable voltage drop, V_{C}, which the transmitter can use to estimate the receiver input voltage or the inline power loss using methods described by Eaves '637. Starting at time 1763, the RC decay of crossline capacitance 1711 and crossline resistance 1712 can again proceed unaltered until the end of the isolation interval at time 1764 when the transmitter main switches are closed to begin a next isolation interval. The snubber switch is again closed, and as shown, it takes some time for the snubber capacitance to gradually recharge through the snubber resistance 1706.

In a primary embodiment of cross-port fault detection, the same method is implemented on each of 2 source devices on the same isolation plane, where said source devices execute the same method independently without measurement data from the other source device. While both source devices open their unidirectional switches to isolate the sources from the transmission lines in one direction, the source devices monitor for a significantly lower output voltage, where the unidirectional switches still permit current flow in the reverse direction, such as through a diode; wherein this reverse direction is reversed with respect to the normal or forward direction of current flow between the source side and the transmission line when the unidirectional switches are closed. If the significantly lower output voltage for either source device reaches a level that is at most half of the source voltage plus any expected diode voltage drops, that source device can conclude that a fault may be present and will not turn its switches back on.

In another embodiment, cross-port fault detection can be implemented in a digital electricity system. With 2 transmitters connected to the same isolation plane, each transmitter periodically isolates the source from its transmission line by opening its disconnect switches in a unidirectional fashion, where current flow opposite the direction during the power transfer interval is permitted through a device such as a diode. During the transmitter's isolation interval, the transmitter monitors the voltage across its output terminals. If the transmitter detects said output voltage to reach a level that is at most half of its supply voltage plus any expected diode drops, the transmitter can conclude that a fault may be present and may not turn its source disconnect switches back on to start the next power transfer interval. The transmitter may further examine characteristics of the waveform during the isolation interval to determine that the output voltage is still being altered by the presence of a cross-port fault through the fault's continued current conduction, where said characteristics may include higher complexity or increased non-linear indicators beyond the simple RC time constant typically observed. Finally, the transmitter can rely on the fault detection methods used for line-to-line faults on a singular port (i.e., from the positive of a port to the negative of the same port) provided that the effectively faster time constant present in this case has been factored into the fault limit sensitivity.

In a primary embodiment of enhancing cross-port fault detection with the use of a snubber, where the source device has a snubber circuit configured to be connected for a portion of the time when its unidirectional switches are open, the source devices utilize the same methods for cross-port fault detection that are used without a snubber, with the only change required being a modification to the timing. Instead of beginning to look for a significantly lower voltage after the source opens its unidirectional switches, the source will look for this voltage after disconnecting the snubber circuit while said unidirectional switches are open.

In another embodiment, cross-port fault detection in a digital electricity system can be similarly adapted to be compatible with the use of a snubber. Each transmitter starts its isolation interval with its snubber circuit already connected. After a delay to negate undesired oscillations, the snubber circuit is disconnected from the circuit. The transmitter then utilizes the same method of cross-port fault detection that is used without a snubber present, with the only modification required that the examination of a cross-port fault indication begins after the snubber circuit is removed rather than at the beginning of the isolation interval.

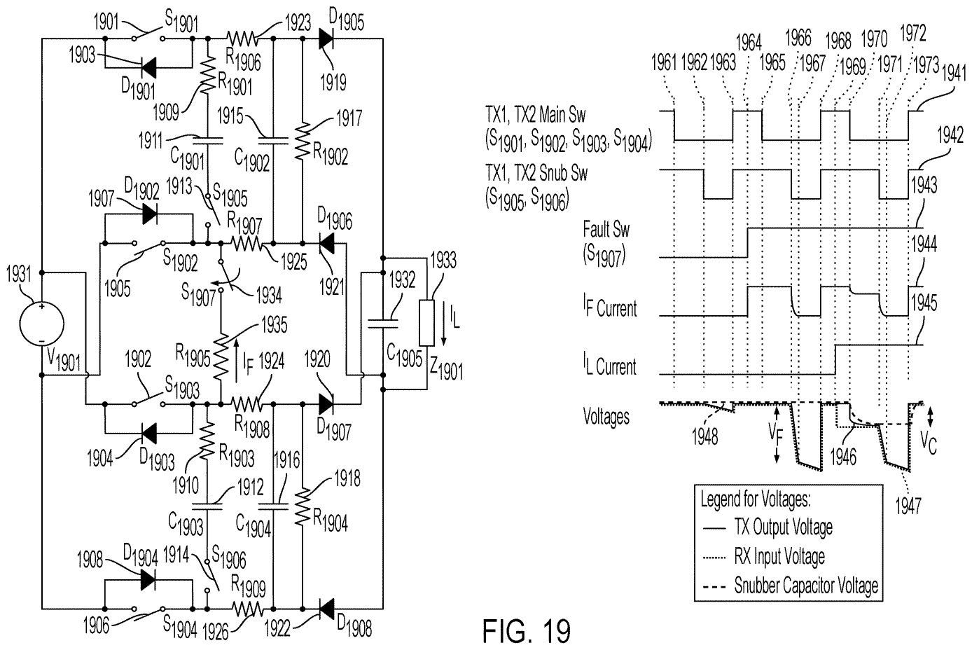

FIG. 19 shows the timing and specifics with respect to inline cable voltage drop measurements and cross-port fault detection in conjunction with periodic snubber usage in the context of a representative circuit. The circuit shows a first channel in the top half and a second channel in the bottom half. The first channel comprises a first transmitter, series resistances 1923 and 1925 (e.g., cable series resistance), a first crossline capacitance 1915, a first crossline resistance 1917, and a first receiver; wherein the first transmitter comprises switches 1901 and 1905 with respective associated diodes 1903 and 1907 along with a first snubber circuit that comprises snubber resistance 1909, snubber capacitance 1911, and snubber switch 1913; and wherein the first receiver comprises diodes 1919 and 1921. These elements 1901, 1903, 1905, 1907, 1909, 1911, 1913, 1915, 1917, 1919, 1921, 1923, and 1925 correspond respectively to elements 1902, 1904, 1906, 1908, 1910, 1912, 1914, 1916, 1918, 1920, 1922, 1924, and 1926 that comprise the second channel; wherein the second transmitter comprises 1902, 1904, 1906, 1908, and a second snubber circuit; wherein the second snubber circuit comprises 1910, 1912, and 1914; and wherein the second receiver comprises 1920 and 1922. Each transmitter input is connected to source 1931, and each receiver output is connected to a common receiver link capacitance 1932 and a dynamic load impedance 1933 (the receiver output switch is omitted for simplicity). Finally, the cross-port fault circuit is connected between the positive of the second transmitter output and the negative of the first transmitter output, and the cross-port fault circuit comprises fault switch 1934 and fault resistance 1935. For simplicity of the behavior shown in the waveforms, the respective elements between the first channel and the second channel are equal in magnitude (e.g., crossline capacitance 1915 is the same amount of capacitance as crossline capacitance 1916).

Waveform 1941 is the control signal for the open/close state of the transmitter main switches 1901, 1905, 1902, and 1908 for both the first and second transmitter. Waveform 1942 is the control signal for the open/close state of the snubber switches 1913 and 1914 for both the first and second transmitter. Waveform 1943 is the control signal for the open/close state of the fault switch 1943. The fault current, I_{F}, is shown in waveform 1944. The load current, I_{L}, is shown in waveform 1945, which also effectively serves as the control signal of the dynamic load impedance 1933 since this is depicted as a load that can alter its current draw at any time. Finally, the transmitter output voltage waveform 1946, receiver input voltage waveform 1947, and snubber capacitance voltage waveform 1948 are shown on the same plot. Since components are equal between the first and second channel, these voltage waveforms are the same for both the first and second channels. Therefore, the transmitter output voltage is both the voltage across the first snubber circuit and the voltage across the second snubber circuit; the receiver input voltage is both the voltage across the crossline resistance 1917 and the voltage across the crossline resistance 1918; and the snubber capacitance voltage is both the voltage across snubber capacitance 1911 and the voltage across snubber capacitance 1912.

Prior to time 1961, both transmitters are in a power transfer interval with each snubber switch closed, no fault present, and no load current. At time 1961, a first isolation interval is initiated by opening all transmitter main switches. The snubber circuits are still connected until time 1962, so there is negligible decay observed and all voltages stay approximately the same until that time. At time 1962, the snubber circuits are disconnected, and approximately equal RC decay is observed for both the transmitter output voltage and the receiver input voltage while the snubber capacitance voltage remains unchanged. At time 1963, the isolation interval is terminated by the closing of all transmitter main switches, which begins the second power transfer interval. Also, at approximately the same time as time 1963, the snubber circuits are reconnected.

At time 1964, during the second power transfer interval, the fault is connected to the circuit, which results in an increase in the fault current, I_{F}, shown in waveform 1944. At time 1965, the second isolation interval is initiated by the opening of all transmitter main switches. Again, with the snubber circuits still connected until time 1966, negligible voltage changes are observed until that time 1966. When the snubber circuits are disconnected at time 1966, a rapid voltage drop is observed in the transmitter output voltage and the receiver input voltage, which remain approximately equal to each other. Also, during this time between time 1966 and time 1967, a decay in the fault current is observed until it reaches approximately 0 A at time 1967 (the equivalent nonlinear decay is not shown in the voltage waveforms). This voltage drop observed in the transmitter output voltage between time 1966 and 1967 is the initial voltage drop that would be used for fault voltage (V_{F}) determination, and by time 1967, this initial voltage drop reaches approximately half the source voltage of source 1931, thereby allowing each transmitter to determine the presence of a cross-port fault. Typically, the transmitters would register a fault and discontinue high power transmission upon detecting this; but for the purposes of illustrating the circuit mechanics, this is omitted here.

The RC decay continues as if no fault were present between time 1967 and 1968. At time 1968, all transmitter main switches are closed to end the isolation interval and begin the third power transfer interval. During this third power transfer interval, at time 1969, the dynamic load impedance 1933 begins drawing a significant load. This results in a disparity between the transmitter output voltage and the receiver input voltage due to the inline cable voltage drop; and the snubber capacitance remains at approximately the same voltage as the transmitter output voltage since the snubber circuit is connected at the transmitter end.

At time 1970, all transmitter main switches are opened to initiate a third isolation interval. With the snubber circuits still connected, the transmitter output voltage drops and slowly equalizes at the receiver input voltage, with the snubber capacitance voltage also gradually approaching this receiver input voltage as well, wherein the receiver input voltage remains approximately unchanged as it is held up by the voltage across the common receiver link capacitance 1932 (voltage waveform for this capacitance not shown, but is nearly equal to the receiver input voltage at the most recent point during a power transfer interval). Since the transmitter output voltages are reduced, the voltage across the fault resistance 1935 is also reduced and therefore the fault current, I_{F}, is reduced but non-zero between time 1970 and 1971.

At time 1971, just as the voltages are equalized, a measurement of the transmitter output voltage can be taken. The voltage difference between the transmitter output voltage at time 1970 and at time 1971 is indicative of the inline cable voltage drop, thereby enabling each transmitter to measure and calculate this voltage drop along with measuring and calculating the receiver input voltage using only measurements taken at the transmitter output. With this measurement completed, the snubber circuits are disconnected at time 1971. The circuit then exhibits a second large voltage drop until time 1972. This additional voltage drop is due to the cross-port fault, and once the fault current, I_{F}, reaches approximately OA and the transmitter output voltage along with the receiver input voltage reach at most approximately half the supply voltage, the cross-port fault no longer contributes to the circuit behavior for this isolation interval, relegating the remainder of the isolation interval to unaltered RC decay until time 1973. The total voltage drop from time 1970 until 1972 is used to compare against the limit for a cross-port fault per embodiments disclosed herein; and in this case, each transmitter would register a fault, followed by typically desisting from high power transfer (not shown in these illustrative waveforms).

In a primary embodiment of cross-port fault detection, the same method is implemented on each of 2 source devices on the same isolation plane, where said source devices execute the same method independently without measurement data from the other source device. While both source devices open their switches to isolate the sources from the transmission lines, the source devices monitor for a significant switch voltage imbalance between the voltages across each switch of the source device. If the significant switch voltage imbalance for either source device reaches a threshold, that source device can conclude that a fault may be present and will not turn its switches back on. This can similarly be implemented for line-to-earth fault detection with one or more source devices present.

In another embodiment, cross-port fault detection can be implemented in a digital electricity system. With 2 transmitters connected to the same isolation plane, each transmitter periodically isolates the source from its transmission line by opening its disconnect switches. During the transmitter's isolation interval, the transmitter monitors the voltage across its switches, wherein the difference in voltage across its switches comprises a switch voltage imbalance. If the transmitter detects said switch voltage imbalance to reach a threshold, the transmitter can conclude that a fault may be present and may not turn its source disconnect switches back on to start the next power transfer interval. This can similarly be implemented for line-to-earth fault detection with one or more transmitters present.

In a primary embodiment of enhancing cross-port fault detection or line-to-earth fault detection with the use of a snubber, where the source device has a snubber circuit configured to be connected for a portion of the time when its unidirectional switches are open, the source devices utilize the same methods for cross-port fault detection that are used without a snubber, with the only change required being a modification to the timing. Instead of beginning to look for a significant switch voltage imbalance after the source opens its switches, the source will look for this switch voltage imbalance after disconnecting the snubber circuit while said switches are open.

In another embodiment, cross-port fault detection or line-to-earth fault detection in a digital electricity system can be similarly adapted to be compatible with the use of a snubber. Each transmitter starts its isolation interval with its snubber circuit already connected. After a delay to negate undesired oscillations, the snubber circuit is disconnected from the circuit. The transmitter then utilizes the same method of cross-port fault detection or line-to-earth fault detection that is used without a snubber present, with the only modification required that the examination of a cross-port fault indication or a line-to-earth fault indication begins after the snubber circuit is removed rather than at the beginning of the isolation interval.

### SUMMARY, RAMIFICATIONS AND SCOPE

Periodic connection of the snubber should be designed for optimal operation of the system. One consideration of this optimal operation is the identification of a first critical time interval where connecting the snubber is overall beneficial, and the identification of a second critical time interval where the snubber must be disconnected. In most common applications, the snubber being connected is overall beneficial at transition points in time, such as when another switch in the system is opened or closed, or some other operational change in the system occurs. These transition points may include switches in a primary high-power path being opened or closed; applying or removing known impedances for safety measurement, safety system self-validation, or communication; edges in PWM signals for power or communications, which may be superimposed in some embodiments; transitioning to a lower or higher level based on a Zener regulator circuit or other regulator circuit; or any number similar transition points. In general, the snubber can be used to settle and smooth voltage or current for more accurate sensing, whether the desired signal to retain is AC or DC. Snubber circuit usage can be coordinated or independent of transmitter and receiver switching. A snubber circuit in a receiver may be synchronized with the transition of its own switches, or it may be coordinated with the anticipated or detected transition of a connected transmitter's switches. This applies similarly in a vice versa fashion with respect to the transmitter and receiver (i.e., the transmitter is coordinated with the anticipated or detected transition of a connected receiver's switches), or a combination of such operations could be employed. Outside of the second critical time interval, there may be other times where it is preferred but not required to disconnect the snubber from the circuit for optimal system operation. Time intervals where keeping the snubber connected will increase power dissipation without the snubber providing significant benefit, such as high-power transfer in power transmission systems or the power transfer interval in DE systems after the transition from the isolation interval, are among the other times where disconnecting the snubber can be done for optimal system operation.

In embodiments where blocking DC is a significant interest, the snubber impedance network can be adapted to include this ability despite the possibility that it results in an imperfect impedance match with a non-zero reflection coefficient. The simplest way to accomplish this is with a capacitance in series with the rest of the snubber impedance network. Any non-zero capacitance will accomplish this goal, allowing the value of the capacitance to be chosen based on other design parameters using techniques known to those skilled in the art, such as by targeting a minimal reflection coefficient or a particular frequency response. This series capacitance does not need to strictly exclude any parallel impedance provided that the leakage resulting from other parallel components is acceptable. For example, a high value resistance could be added in parallel with the capacitance to provide a discharge path if disconnected for an extended time interval, such as when a transmitter is powered down or removed from operation, while the resistance itself does not conduct enough current during operation to cause interference.

In general, components can be added that either align with or deviate from contributing to a perfectly matched impedance for a reflection coefficient of zero. In one example, a characteristic impedance of a+jb, where b is a positive number, could use a series combination of a resistance and an inductance for a snubber impedance to achieve a perfect match with the correct values. Despite this, a capacitance could be added if needed for other purposes, such as for DC blocking or inline voltage measurement, and the impedance values of the snubber can be adjusted to achieve a reflection coefficient of zero or nearly zero. In another example, a characteristic impedance of a−jb, where b is a positive number, could use a series combination of a resistance and a capacitance for a snubber impedance to achieve a perfect match with the correct values. Despite this, inductance and other components can be added to address other design requirements, such as other transient suppression, other smoothing of the waveform, improving EMC impact, or otherwise improving particular frequency responses for a particular dynamic response as desired. These components can be included in the snubber impedance calculation and values can be chosen to meet design goals while still achieving a reflection coefficient of zero or nearly zero. These techniques can be mixed as is known to one skilled in the art.

Another motivation for purposefully deviating from a perfectly matched impedance is component selection and other practical component rating factors. While more specific values are possible at lower tolerances, these often increase the cost and may not be necessary. Other ratings, such as voltage, current, and power ratings of components along with physical size are among the practical ratings and factors to consider. For example, an ideal snubber circuit impedance may result in an extremely high-power dissipation, which may generate too much heat or result in a component that is physically too large. In this case, alternative component values may significantly improve those aspects of the design while still achieving an effective reflection coefficient that is acceptably low. In cases where the power on snubber components is significantly large for only a short duration, components with either single or continuous pulse ratings may provide an optimal specification. Further practical design considerations may also apply based on common design principles known to one skilled in the art.

Yet another motivation for purposefully deviating from a perfectly matched impedance can manifest in scenarios where the snubber circuit can also be used for other purposes. In one example, in some systems, it may be possible to use the snubber circuit for ringing mitigation as well as for applying a known impedance or bias if the ideal impedances for each of those circuits are close enough. This could be used in a variety of systems, including digital electricity systems, that feature slope limiting control or measurement of current or voltage, or any other systems that can utilize a known impedance being applied to validate proper operation. In a similar fashion, it may be possible in some scenarios for the snubber circuit to also be used to quickly discharge stored energy to reach a desired level of current or voltage within a required interval of time or to achieve a desired effective time constant. This can be particularly useful in systems that require voltage or current to be sufficiently low by a particular time or are predicated on a particular system time constant. In another example, in systems that feature frequency modulation (FM) or phase modulation (PM) for communications and switch in different impedance networks to change the response in order to send information, the snubber may be able to be used as one of those different impedance networks. In such systems, the snubber could alternatively be used at the end of a transmission at a particular frequency or phase in order to eliminate reflections significantly faster, allowing for the next bit of information to be sent sooner and therefore enabling an overall higher bandwidth. In another example, in systems that use a phase detector to use a phase deviation as a fault indication, the snubber circuit could be re-used in multiple ways, such as altering the characteristics to improve the signal measurement over a given frequency range, or by applying a known impedance so the phase detector can periodically validate its own proper operation. In such a system, the snubber impedance may instead be altered to avoid significant contributions to alterations at a given frequency or subset of frequencies. In a more general example, taking measurements with and without the snubber impedance applied may aid in measuring and calculating transmission line characteristics using techniques known to one skilled in the art. In another general example, the snubber circuit may be aligned with filter design that is used for smoothing, allowing the critical function of said filter to be attained without necessarily incurring the efficiency loss from its continued presence in the circuit. All of these cases may be limited in their probability of resulting in a successful design, and one skilled in the art will be able to assess the trade-offs for acceptable error in the performance of the respective algorithms.

Unless lossless transmission line assumptions are valid or other techniques such as compensation using the Heaviside condition are applied, the characteristic impedance is frequency dependent. Similarly, the snubber circuit may have frequency dependent elements. As a result, the reflection coefficient itself can be frequency dependent. This must be considered using knowledge known to those skilled in the art. For example, a primary frequency can often be observed for the oscillations as the traveling waves reach each end of the cable based on the propagation delay, which is also frequency dependent due to the effect of dispersion. This primary frequency may be an optimal frequency to ensure is targeted by the snubber circuit's effect on the reflection coefficient. Other frequencies of interest may be considered. In an AC system, this frequency may be the fundamental frequencies of the AC transmission itself, but may include other related frequencies, such as harmonics, carrier frequencies, sideband frequencies, and others known to one skilled in the art. In general, any frequencies of interest should be evaluated to determine the optimal snubber circuit impedance.

Propagation delay relative to the switching frequency or signal frequency may also be an important factor in deciding whether this is important. In some cases, a small propagation delay relative to the period of the relevant transmission frequency may not need a snubber, as the oscillations may occur so quickly that no adverse effects are observed in interpreting the signal at a receiver. Alternatively, signals with a short pulse width on a longer transmission line may not need to consider effects such as interference patterns from reflections depending on the system design and switching duty cycle.

In general, a perfectly matched impedance for a reflection coefficient equal to 0 may be unrealistic in practice, as tolerance of components and variations in transmission line characteristics that are within an acceptable range can make it a mathematical impossibility with a static snubber impedance. These tolerances should be considered in the design of the snubber circuit to ensure adequate performance over the range of possible values within the tolerance window.

The primary embodiments describe the snubber usage after opening a switch, but the same techniques can be applied to the closing of a switch. In a digital electricity system, this would be equivalent to the snubber negating oscillations when entering the power transfer interval, whereas the primary embodiments describe negating oscillations when entering the isolation interval. Since different impedances need to be considered, this can result in additional challenges. For example, in a digital electricity system, during the power transfer interval, the source impedance and the load impedance may need to be included in the evaluation of the reflection coefficient at each line end, and these may increase the difficulty of impedance matching by being dynamic values, being values unknown at design time, or presenting a strong effect that makes it difficult to achieve all system and snubber design goals.

While using passive components provides a straight-forward way to calculate the reflection coefficient, the effective snubber circuit impedance does not need to be determined only by passive components. Active control elements can be utilized using techniques known to one skilled in the art. An active control system can use a variety of open-loop and closed-loop feedback techniques to cancel the undesired oscillations while still permitting the achievement of other system design goals. An active snubber control, since at least parts of the snubber circuit are not discrete in some regards, is one way to compensate for system tolerances and possibly overcome these to attain a reflection coefficient of zero or nearly zero. Any combination of passive and active circuitry can be used to comprise the snubber circuit. These passive components can also include stub tuners and any other impedance matching techniques for transmission lines that are known to one skilled in the art.

While many embodiments describe a snubber circuit connected across the transmission line, similar effects can be attained by placing the snubber in other relevant locations known to one skilled in the art. A common snubber location is in parallel with switching elements, such as the source disconnect switches. In this configuration, the reflection coefficient can be calculated using known circuit analysis techniques and the snubber circuit impedance can be designed to meet system design goals.

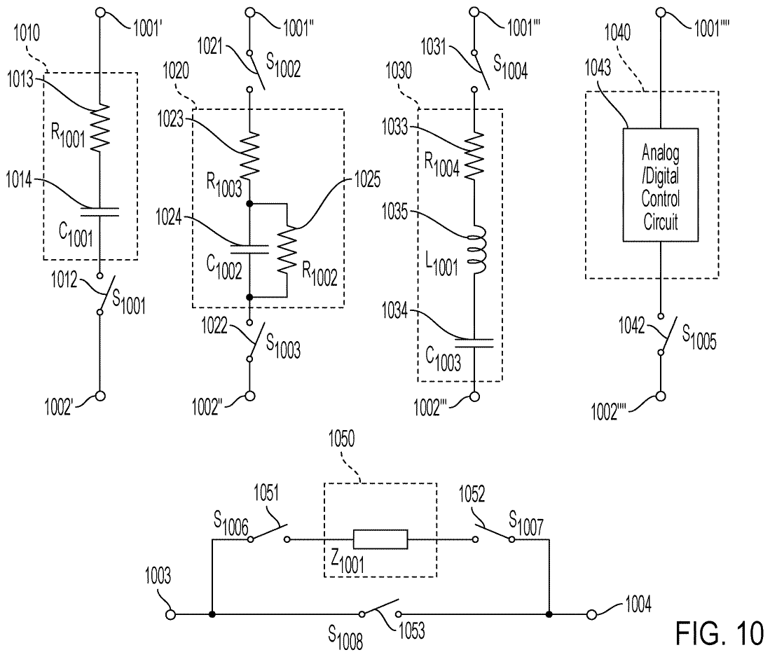

These recently described aspects are exhibited in FIG. 10, which shows some common possibilities for snubber impedance and snubber circuit arrangements to utilize the methods disclosed herein. With terminals 1001 and 1002 typically connected crossline as shown in many circuits in other figures, a first arrangement is shown with snubber switch 1012 configured to connect or disconnect snubber impedance 1010, which comprises a series combination of resistance 1013 and capacitance 1014.

In a second arrangement, snubber switch 1022 is complemented by a second snubber switch 1021, wherein this may be desirable when unidirectional switches are used but bidirectional blocking is required and an isolated gate voltage supply (e.g., for a MOSFET) is already present at each of the terminals 1001 and 1002 for other purposes such as controller other switches outside of this snubber circuit. The snubber impedance 1020 comprises resistance 1023 and capacitance 1024 similar to the first arrangement, but the capacitance 1024 has an additional resistance 1025 in parallel. This parallel resistance 1025 can be used to ensure capacitance 1024 is discharged when the snubber impedance is disconnected for an extended duration of time.

A third arrangement is shown with a single snubber switch 1031 to emphasize that the placement of the single snubber switch is flexible. The snubber impedance 1030 comprises the series combination of resistance 1033 and capacitance 1034 as well as inductance 1035. The introduction of this inductance allows fine tuning of the impedance based on available components values as well as adjust the frequency response for EMC particularly with respect to adjusting the current spike at the moment that the snubber is connected. While not shown, a flyback diode as is often used in the art could also be used in parallel with at least the inductance to protect against voltage spikes when the snubber switch is opened.

A fourth arrangement shows a single snubber switch 1042 again. The snubber impedance 1040 comprises an analog and/or digital control circuit 1043. This analog/digital control circuit represents a generalized embodiment wherein any active or passive control circuit known in the art with respect to snubbing can be used with the methods and apparatus in this disclosure provided that the control circuit design accounts for the fact that snubber switch 1042 may abruptly connect or disconnect the snubber impedance 1040 depending on the requirements of the system operation in accordance with periodic snubber embodiments.

Finally, another embodiment is shown to clarify that, while most snubber circuit embodiments disclosed herein focus on crossline snubber circuits, a snubber circuit can alternatively be used in parallel with a switch. With switch 1053 connected between terminals 1003 and 1004, a snubber circuit can be placed in parallel comprising snubber switches 1051 and 1052 along with snubber impedance 1050. Any of the snubber impedances 1010, 1020, 1030, and 1040 can be used as snubber impedance 1050. The switch 1053 typically corresponds to a main switch, such as switch 211; and to be effective when switch 221 is opened at the same time as switch 211, a second snubber circuit would also be needed for switch 221. The snubber circuit is not restricted to only being placed in parallel with main switches and can be placed in parallel with any other switches that would benefit from control of significant changes in voltage or current when opening or closing. It is also understood that a plurality of snubber circuits may be present for a given switch to cover different conditions or to have a first snubber circuit for opening a switch and a second snubber circuit for closing a switch.

In all cases, there is no restriction to only a single snubber circuit. Any number of snubber circuits can be used in any combination to meet any of the various design goals. For example, multiple snubbers can be used to target different frequencies to ensure all critical frequency content is negated. One snubber circuit may target AC content while another targets DC content (e.g., achieving equalization with the receiver DC voltage). In another example, different snubber circuits can be used for the power transfer interval and the isolation interval. Snubber circuits can be placed in multiple locations, and a plurality of snubber circuits can be connected or disconnected at any given time provided that the total effective impedances at those times meet design goals. In another example, a passive snubber circuit can be used as the primary snubber circuit or a fallback snubber circuit while an active snubber circuit is attempted to be used when certain operating conditions are met that could make it beneficial. In another example, periodically switched snubber circuits can be combined with permanently connected snubber circuits to achieve all design goals. In further examples, redundancy can be used to detect or handle internal failures. Circuits can be implemented at both line ends to increase the efficacy of the impedance matching and attain a negligible ringing amplitude through the compounding effect of the reflection coefficient at each end being nearly zero. Snubber circuits can be installed at any number of points along the transmission line so long as they provide impedance matching to produce a zero or nearly-zero reflection coefficient at least at the points on the transmission line where measurements will be made that benefit from the snubber circuits, though this may not be ideal if the benefits do not outweigh the challenge of coordinating the switching of said snubber circuits, and may include additional complexity in calculating an ideal snubber impedance due to consideration of the transmitted and reflected waves in each direction at the location of the snubber circuits.

Additional benefits can be observed or targeted by the snubber circuit. A common existing benefit of snubber circuits is an improvement in EMC performance, which can be applicable with proper design. When using anomaly detection methods taught in Mlyniec '494 among others in the art, the snubber circuit can improve the efficacy of these methods. Mlyniec '494 teaches taking a measurement of an electrical characteristic of the transmission line during a time interval such as the isolation interval and evaluating the measurement using a numerical analysis to produce an approximation of the measurement in the form of a polynomial function, wherein an accuracy of said polynomial function is based on a magnitude of a variance of the measurement from the approximation of the measurement, and wherein power transmission over the transmission line is interrupted if the magnitude of the variance of the measurement from the approximation does not meet a minimum accuracy requirement. The negation of oscillations can decrease the probability of false positives in anomaly detection. This can also improve methods of Eaves '637 that utilized a delay to minimize improper evaluations due to signal disturbances, as this delay can be reduced, allowing for higher duty cycles, increased efficiency, increased frequency of safety checks, faster MOSFET switching times, increased time allotted for inline communications, and any other changes that are possible with a reduction in the minimum amount of time required in the isolation interval for safety evaluation.

In a digital electricity system, after the snubber circuit is disconnected during the isolation interval, the remaining time in the isolation interval can be used for any number of digital electricity methods. These methods include but are not limited to in any valid combination: the method of Eaves '637 to use voltage measurements over time to detect a cross-line resistive fault; the method of Mlyniec '494 to detect a cross-line capacitance by applying a known bias; the method of Eaves '795 for inline communication; the method of Weiss to use carrier wave change fault impedance detection; the method of Casey '067 to simultaneously evaluate the cross-line resistance and cross-line capacitance using a single known bias. As with Mlyniec '494 and Casey '067, evaluations with and without a known bias applied can be done either in the same isolation interval or in separate isolation intervals.

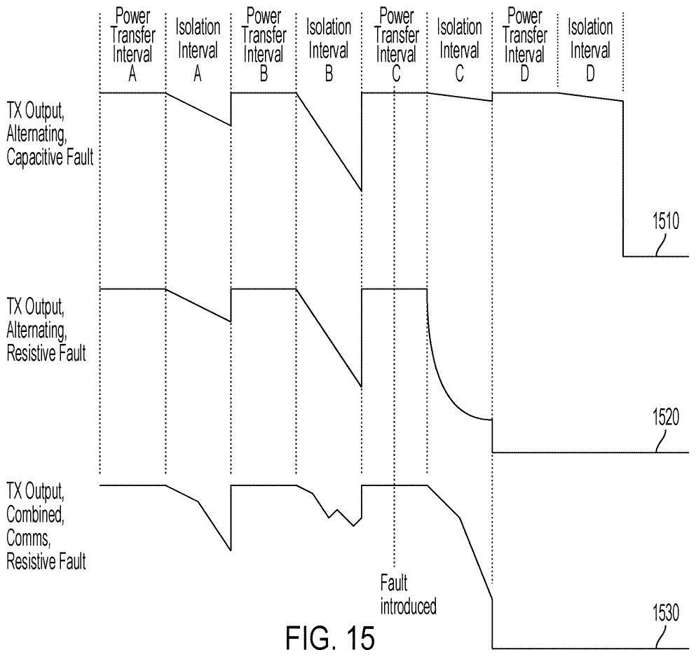

FIG. 15 shows some of these common configurations and fault conditions for operating a DE transmitter. For each waveform plot, the transmitter alternates between power transfer intervals and isolation intervals as described herein and in prior art (e.g., Eaves '637). Starting with the middle plot 1520, this shows the output voltage of a transmitter wherein the transmitter performs different actions in alternative isolation intervals, wherein these alternating actions are connecting a known crossline resistance in isolation interval B and keeping the known crossline resistance disconnected in isolation intervals A and C. When a crossline resistance fault is introduced mid-way through power transfer interval C, the effect is observed during isolation interval C. The transmitter detects the fault using methods disclosed herein or in prior art and enters a safe state after registering the fault.

Plot 1510 shows the transmitter configured to operate in the same fashion as the transmitter shown in plot 1520. This time, mid-way through power transfer interval C, a high crossline capacitance fault is introduced. This is observed by the transmitter in isolation interval C, but the transmitter does not check for this type of fault condition during isolation interval C. The transmitter continues to see the effect of this fault during isolation interval D and detects the fault using methods disclosed herein or in prior art, which triggers the transmitter to enter a safe state after registering the fault.

Plot 1530 shows an alternative operation of a transmitter. Instead of performing different actions in alternating isolation intervals, the transmitter is configured to perform all actions in each isolation interval. A first portion of the isolation interval keeps the known pulldown resistance disconnected while a second portion of the isolation interval has the pulldown resistance connected. A third portion of the isolation interval, seen most clearly in isolation interval B, is reserved for any inline communications. When a fault is introduced midway through power transfer interval C, the transmitter detects this fault during isolation interval C using methods disclosed herein or in prior art, which triggers the transmitter to enter a safe state after registering the fault. In plot 1530, this is shown with a crossline resistance fault; but the behavior would be the same in this case if the fault were a high crossline capacitance fault (i.e., the fault would be detected during isolation interval C).

When operating a source disconnect switch while the snubber is connected, some oscillations may still be observed. In particular, it can be common to see a large initial transient. This can occur despite having a perfectly matched impedance. For example, with a perfectly matched snubber impedance circuit connected across the transmitter output terminals, a large initial downward transient can be observed across the transmitter output terminals as the forward traveling wave moves towards the receiver line end before returning back to the transmitter where it is negated. This initial transient and other smaller oscillations do not necessarily preclude proper operation of the snubber circuit for the desired results. In the event that this cannot be tolerated, such as due to significant EMC impact that results in critically poor EMC performance, other transient suppression techniques or other mitigation techniques can also be applied.

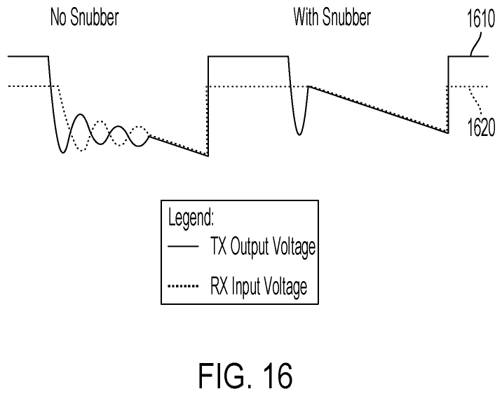

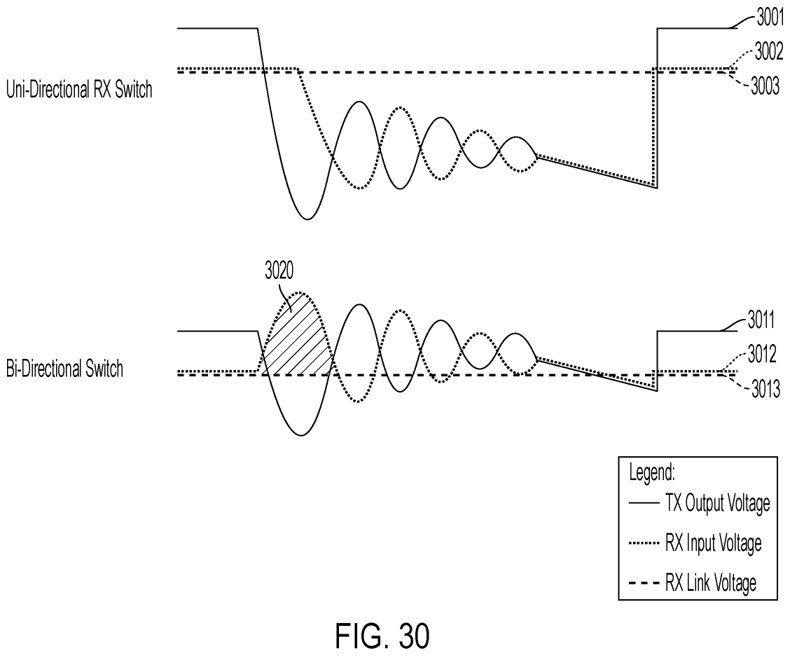

FIG. 16 shows the conceptual benefit of an ideal periodic snubber usage in a digital electricity system with respect to this source disconnect switch operation. Waveform 1610 represents the output voltage of a transmitter over time while waveform 1620 represents the input voltage of a receiver over the same time interval. At the beginning of the waveforms during the power transfer interval, a voltage difference between the waveforms reflects the lower voltage of the receiver relative to the transmitter due to the inline voltage drop of the cable. In the first isolation interval labeled “No Snubber”, oscillations occur due to the forward and backward wave propagation along the cable. These oscillations diminish in magnitude until the dominant voltage change apparent is the one due to the RC decay of the effective crossline capacitance and crossline resistance. One key feature to note is that the oscillations occur at a lower voltage than both the transmitter output voltage and the receiver input voltage during the power transfer interval, which is a phenomenon that will be explained further subsequently with respect to FIG. 30.

Continuing with FIG. 16, after a second power transfer interval, a second isolation interval is shown, labeled as “With Snubber”. During an initial portion of this isolation interval, a snubber circuit is connected to mitigate the oscillations as well as preserve the start of the RC decay portion at a voltage approximately equal to the receiver input voltage during the power transfer interval. Once these oscillations have been mitigated and the initial voltage set, the snubber circuit is disconnected to permit the RC decay to continue unaltered by the snubber circuit. This allows the RC decay to be used for safety measurements as described in Eaves '637 and others while improving the accuracy of the transmitter acquiring a measurement during the isolation interval indicative of what the receiver input voltage was during the prior power transfer interval. The details and timing of this snubber circuit will be explained further in other figures.

In many embodiments, a matched impedance for a snubber circuit typically refers to a reflectionless match where the transmission line characteristic impedance is the same as the line-end impedance for a perfect match. In power transmission, it is common to target a conjugate match, which targets a perfect phase alignment to maximize real power transfer for a perfect match. The type of match to target depends on the system design goals. When both types of matching are desirable, a trade-off may be required to improve one type of match at an acceptable expense of another. Any number of techniques can be used for computation of a target snubber impedance, including the Smith Chart, computer aided design tools, numerical computation, simulation, and prototyping.

In AC applications, some further considerations specific to AC may be factored into the snubber impedance and impedance matching. In addition to calculating the magnitude of the reflection, the phase angle of the reflection coefficient may also be calculated. In some applications, it may be preferred to maintain at least a moderate amount of reflection magnitude at a given frequency and simultaneously maintain a nearly zero reflection phase angle. This may be a preferred trade-off for systems that critically utilize phase information, such as phase modulation communication or systems that detect human body and other faults based on a deviation measured by a phase detector exceeding a threshold.

For periodically interrupted AC systems, a periodically connected snubber could still be used at the transition points as the transmission is interrupted or as the transmission is resumed. This could be done whether the periodically interrupted AC system only interrupts near the zero crossings of the AC waveform or enforces a “blanking time” around the zero-crossing, or if the interruptions are done throughout the AC cycle. Many devices experience adverse effects when a portion of the AC cycle is suddenly “chopped”, such as the buzzing heard by incandescent bulbs with simple triac dimmer switches that only conduct during certain phases of each AC cycle. Said snubber usage to smooth these edges can improve EMC and reduce total harmonic distortion (THD) while also providing a signal without significant ringing much sooner, allowing for faster and more accurate sensing during the interruption time interval (i.e., isolation interval). These can also improve the efficacy of load-end smoothing filters that attempt to minimize the impact of these interruptions to the load by limiting the frequency spectra that said smoothing filters must target, possibility further optimizing the size, cost, and efficiency of the filter components.

Snubber circuits may be parallel circuits that are open circuited to effectively disconnect or may be series circuits that are short circuited to effectively disconnect (e.g., the circuit in FIG. 10 between terminals 1003 and 1004 is placed in series with a disconnect switch such as switch 211 of FIG. 2, with switch 1053 now acting to short or bypass the snubber circuit when it is not desired to be in use, possible with switches 1051 and 1052 omitted and replaced with shorts as well). This may change the components required, failure modes and effects analysis (FMEA), functional safety assessment, and system efficiencies. For example, it may not be desirable to use a series snubber if it would increase losses in a DC system. In another example, an AC system may prefer a series snubber circuit if it improves component selection and the change in efficiency is acceptable. Whether the system is AC or DC, the frequencies under consideration may be important factors in this design aspect.

Thus, in general, a snubber circuit as disclosed herein is connected to at least a transmission line terminal or an effectively equivalent location (i.e., effectively equivalent circuit operation with respect to the methods disclosed herein), wherein the snubber circuit may more specifically be connected across a transmission line, in series with a switch between a transmission line port and non-transmission line port, or in parallel with said switch. Note that, in the case of a snubber circuit in series with a switch, the operation for how a snubber impedance is effectively switched into and out of a circuit is opposite of that a snubber circuit across a transmission line or in parallel with a switch. To simplify the description for snubber operation in order to generalize, in most contexts, a snubber impedance electrically connected to a terminal or other electrical location signifies that the snubber impedance is effectively in the circuit—not isolated, and not bypassed (i.e., not shorted out); and a snubber impedance electrically disconnected to a terminal or other electrical location signifies that the snubber impedance is effectively out of the circuit-isolated or bypassed (i.e., shorted out). In practice, this means that for most snubber circuits that are across a transmission line or in parallel with a switch, the snubber circuit will be configured with a snubber switch and a snubber impedance in series, and therefore closing the snubber switch electrically connects the snubber impedance to the respective transmission line terminals or switch terminals, and opening the snubber switch electrically disconnects the snubber impedance to the respective transmission line terminals or switch terminals. This also means that for most snubber circuits that are in series with a switch, the snubber circuit will be configured with a snubber switch and a snubber impedance in parallel, and therefore opening the snubber switch electrically connects the snubber impedance to the switch and another terminal, and closing the snubber switch electrically disconnects the snubber impedance from the switch and the other terminal. While technically the snubber impedance may still be connected to one or more terminals while it is “electrically disconnected” as described here (e.g., with a snubber circuit in series with a switch, the snubber impedance may also be connected to the switch; e.g., with a snubber circuit across a transmission line, the snubber impedance may still be connected to one terminal while the snubber switch is open), it is understood that there is no effective difference to the circuit behavior in this state whether the snubber impedance exists or not. For example, with a snubber impedance bypassed with a short, the snubber impedance could be fully removed from the circuit with no effective change to the circuit behavior. Similarly, with a snubber impedance isolated from one of the terminals by a series snubber switch, the snubber impedance could be fully removed from the circuit with no effective change to the circuit behavior. These terms “electrically connected” and “electrically disconnected” can be viewed analogous to functional terms such as “enabled” and “disabled”, respectively, or “effective” and “ineffective”, respectively.

Said snubber circuit usage can be applied in a multitude of different circuit locations. Another typical location, particularly in a digital electricity system, is between line and earth. Switching transients can cause oscillations observable as a voltage from a positive voltage reference to earth as well as from earth to a negative voltage reference. The positive voltage reference, for example, could be the positive lead of the source, the output of the transmitter, the input of the receiver, the positive link voltage of the receiver, or any other similar location. The negative voltage reference could be in similar locations on the negative side of the circuit.

Switching transients can also result in common mode voltage oscillations, which may be undesirable due to EMC impact and possible incorrect behavior of the system. Snubbers for earth ground would typically be applied symmetrically to each positive and negative line with respect to earth, but it is not necessarily a requirement. Calculation of a snubber circuit for earth is more involved but can be derived using common knowledge by one skilled in the art; or the snubber circuit can be tuned through other means such as computer aided design or empirical prototype testing.

The snubber circuit can be used in combination with or in place of other methods of ringing mitigation. For example, analog filtering can be applied to the original signal itself, such as at the transmitter output. This may allow some frequency content to be filtered out effectively while the snubber can be periodically connected to address other frequency ranges or phenomena where an analog filter may be impractical or non-optimal. In another example, analog or digital filtering could be applied to the output of a voltage or current sensor to further filter undesirable signals and noise without any significant loading effects on the original signal. In this case, the snubber could also be used to at least partially mitigate the effects of ringing so that the combination with the sensor output filtering results in improved overall filtering efficacy.

Benefits of the periodic snubber circuit usage can be applied to communication protocols, including inline communications described by Eaves '795. With oscillations significantly attenuated, a cleaner edge for synchronization can be observed between communication devices, allowing faster and more reliable communication. This could be used in combination with techniques to intentionally enact a voltage drop at the start of the isolation interval that is large enough for an edge trigger to allow devices to trigger on the start of the isolation interval rather than relying on triggering on the rising edge at the end of the isolation interval, which requires devices to account for the time duration of the power transfer interval in order to communicate during the next isolation interval. The snubber circuit could also be used at the transition point for each individual bit if significant oscillations are observed to improve signal integrity and possibly enable higher bandwidth communications.

An additional application that can be realized through the snubber circuit usage is in detecting incorrect or unexpected system configurations. For example, if an invalid or unsupported cable is used in an installation, or if the cable is installed improperly or damaged, the snubber may not perform to the efficacy expected. A significant deviation from the snubber's performance could be indicative of such an invalid configuration and the system can set limits on such indications. When said limit is exceeded, the system could either notify the user that there may be a potential problem and continue to function in a degraded or best-effort manner; or it may cease operation and remain in an isolated safe state, whether this is due to expected unreliability and repeated faults, or the system cannot guarantee sufficient performance of its safety algorithms. Similarly, the snubber could be used in conjunction with the receiver to ensure a valid receiver is connected and the receiver provides an indication that it has a reasonable probability that it is operating satisfactorily in some critical regard. This can function as a so-called “signature”, thereby acting as an essential element in a singular or complementary method for the transmitter to audit connected devices to ensure only supported devices are connected to avoid potentially unsafe conditions.

The timing of the snubber's connection relative to the switch opening to disconnect the source from the load can be selected as desired. The snubber can be connected prior to opening the switch to disconnect the source from the load, where this may be desirable for embodiments that use snubber impedance matching for that transition. The snubber could also be connected at a later time while the source-to-load disconnect switch has already been open for an interval of time. In this latter case, the functionality is still maintained; as upon snubber connection, reflections will be matched when the waves reach the snubber, and the energy transfer will commence and will settle at nearly the same voltage to allow inline voltage drop evaluation; provided that the snubber, transmission line, and receiver link capacitances are all appropriately sized to account for this.

In some cases, trade-offs may be required between timing, accuracy, and robustness. In ideal cases, the snubber remains in the circuit until the snubber capacitance voltage, transmission line and other parallel capacitances, and the receiver link capacitance all settle at nearly the same voltage after adjusting for any diode drops. This may not be practical in all cases, nor is it always possible to know when the time of complete settlement has been reached. Once a significant portion of the equalization has taken place, the snubber can be disconnected from the circuit. This may result in a small overshoot that then results in a small amount of error, but still a significant improvement over non-usage of the snubber. This error can be compensated through a number of ways, such as padding the measurements or limits in a conservative direction, averaging the measurements before and after disconnecting the snubber to get a closer estimate, or including any other reasonable compensation factor. This overshoot is at least partially the result of the additional ringing that occurs due to the impedance change while substantial current is flowing during equalization. When the interval immediately following the snubber disconnection is subject to the anomaly detection methods of Mlyniec '494, this ringing could trigger a fault due to said methods. This is a further consideration that can be addressed by an earlier disconnection of the snubber circuit to allow a time interval between the snubber disconnection and the start of the data used with anomaly detection methods, wherein this must strike a balance between avoiding these faults during known, temporary ringing intervals and the error introduced from less equalization. Adaptive methods can be employed to adjust for this delay in equalization. The connection of the snubber could be delayed, or it can be temporarily removed and re-added to adjust the timing of the equalization process, which is more effective when done based on previous data to use techniques such as Kalman filters to home in on an appropriate value. Expanding on a detail of this, while the snubber circuit is typically connected at the very start of an isolation interval, it is still feasible for the connection of the snubber circuit to be connected for an initial portion of the isolation interval wherein this initial portion is not completely aligned with the start of the isolation interval and is instead delayed from the start of the isolation interval. Active circuitry in the snubber circuit could be used to bleed the snubber capacitance more aggressively either while it is connected or during one or more of the disconnected time intervals in order to achieve a balance by the expected point in time.

When using the snubber circuit for improved inline voltage drop evaluation, the equalization of the snubber capacitance, crossline and transmission line capacitances, and the receiver link capacitance is a crucial step to incorporate properly. This equalization can be estimated based on the rate of change of the signal. As the voltage equalization point is reached, the rate of change will become smaller and smaller until the change in voltage for an interval of time approaches zero. While reaching zero exactly in an ideal system takes an infinite amount of time, a limit can be set on this change in voltage or rate of change where it is practically negligible. For example, after 5 time constants, a signal will be 99.3% settled, meaning that an initial voltage difference of 100V will be 0.7V after a duration of 5 time constants. Ensuring that this reasonable equalization level is reached within an allowable interval of time is a consideration in the system design and impedance selection. The time constants formed between the various capacitances, resistances, and other circuit components involved determine this timing. Achieving this reasonable time interval for equalization is another case where intentionally using an imperfect match for the snubber impedance with respect to the reflection coefficient may be an acceptable trade-off. While mathematical derivation of these time constants is possible, the complexity of the resulting equations may make it more efficient to design using computer-aided design tools, numerical computation, simulation, or prototyping.

Expanding on ringing when disconnecting a snubber circuit, when using a capacitive snubber for improved inline voltage accuracy, it is possible that the voltage difference in combination with the resistance and capacitance in the circuit does not allow full equalization within the allotted amount of time. In such a case, there will likely be a smaller additional amount of ringing observed when the snubber is removed. One method to handle this is to use other methods for handling ringing, such as filtering or abstaining from usage of data from that time interval until the ringing is or expected to be substantially subsided. In another method, a combination of goals can be met by first using a snubber resistance that is smaller than the one preferred for impedance matching to allow the snubber capacitance voltage to equalize with the receiver link capacitance voltage quickly, then switch to a second snubber resistance that is the one preferred for impedance matching to negate any ringing present. This adds complexity and cost, and it will increase peak currents observed, but it will produce the least amount of error and minimize ringing with the highest efficacy.

Another method to address this case is to use a smaller snubber capacitance. This may increase the error of the inline voltage measurement slightly, particularly where the line-to-line capacitance is larger, but this slight increase in error may be tolerable and preferred to the error observed when there is secondary ringing after the snubber is disconnected. This change in capacitance must also be balanced with how much it affects the resulting reflection coefficient to ensure the impedance matching is still sufficient to use the methods disclosed herein. In general, the snubber capacitance sizing must balance the impact to the reflection coefficient with accuracy of the inline voltage measurement, where this inline voltage measurement accuracy is largely governed by the energy transfer between the relevant system capacitances. In particular, the voltage of the stored energy in a capacitor and the capacitance value of a capacitor must be considered for at least the snubber capacitance, the effective bulk capacitance across the transmission line, and the bulk link capacitance in the receiver. These voltage and capacitance values, in combination with relevant resistances and diodes that have a non-negligible contribution to the effective circuit configuration and time constants, can be evaluated to select an optimal snubber capacitance value to provide the highest accuracy over the key ranges of system configurations. Such evaluation and analysis are typically mathematically intensive and may be best to evaluate using simulations, computer aided design tools, numerical computation, simulation, and prototyping; but closed-form solutions may still be feasible.

Another benefit of the large capacitive snubber is seen when starting a load connected to the receiver output. Some loads exhibit an “inrush” effect, where the load temporarily pulls more power as it starts up in order to charge its energy storing elements, among other reasons. This can increase the magnitude of the energy loss from the transmission line during the isolation interval due to switching transient effects in unidirectional switching systems. This can have wide-ranging effects, from adverse EMC performance to increased difficulty in executing safety algorithms without falsely concluding a fault exists. Through this properly designed snubber circuit, this increased energy loss is mitigated, thereby not impacting those factors any more than would be expected without those energy loss effects.

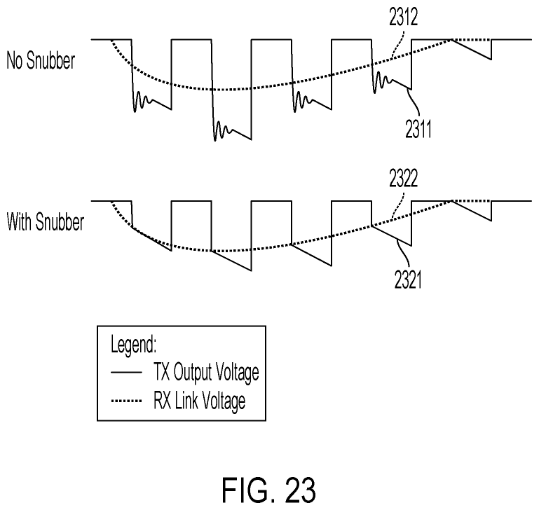

FIG. 23 emphasizes this particular benefit realized through the usage of the periodic snubber usage while a receiver soft-starts a load when there is significant cable length between the transmitter and the receiver. A set of waveforms is shown for each of 2 cases: one with no snubber usage and one with snubber usage. Each set of waveforms shows the transmitter output voltage as well as the receiver link voltage. During soft-start of a load with significant inrush requirements when there is significant cable length between the transmitter and the receiver, a temporary sagging of the receiver link voltage is observed as energy from the receiver link capacitance is used to soft-start the load at a higher rate than what the transmitter can replenish given the cable length. One remedy for this is an alternative design of the soft-start apparatus and method, such as a much larger receiver link capacitance or a control circuit that manages the energy transfer and the receiver link voltage level; but these are known in the art, and these will increase cost, complexity, or size.

Without snubber usage, the transmitter output voltage waveform 2311 shows excessive overshoot in each isolation interval due to the increased current during the immediately prior power transfer interval, wherein this overshoot is apparent by observing the transmitter output voltage overshooting far below the receiver link voltage in waveform 2312. This also correlates with an increase in the magnitude and duration of ringing that occurs at the start of each isolation interval. Both the increase in the initial voltage drop and the increase of the ringing can result in false positives with respect to fault detection, as the a large initial voltage drop may be interpreted as a cross-port fault based on methods disclosed herein, and an increase of the ringing may exceed the limits of anomaly detection disclosed in Mlyniec '494. In some cases, the system may be able to tolerate targeted time-limited exceptions such as allowing a large initial voltage drop when ringing is also detected for a limited number of isolation intervals since this is more likely to be due to a soft-start event than a cross-port fault (since the cross-port fault will not exhibit such ringing); but this is highly dependent on functional safety analysis and is not preferred.

A preferred solution is to use the snubber to mitigate the effects of the large initial drop as well as the ringing. By connecting the snubber for at least an initial portion of the isolation interval in accordance with the apparatus and methods disclosed herein, the transmitter output voltage in waveform 2321 is observed to have an initial voltage drop that reaches and stops at approximately the voltage of the receiver link voltage at that time as shown in waveform 2322. Once the snubber is disconnected in the isolation interval, the RC decay is allowed to occur, allowing other methods to be implemented during the remainder of the isolation interval such as performing safety measurements or exchanging inline communications data.

The voltages during the isolation interval after the disconnection of the snubber circuit will generally be higher than if the snubber were not used and the energy loss occurred. Since RC decay is a ratiometric or geometric effect, the magnitude of the voltage difference over a fixed duration of time will be greater when started at a higher voltage, resulting in improved voltage sampling resolution.

A significant improvement of voltages during the isolation interval can be appreciated with respect to dielectric absorption. This dielectric absorption is represented in a modified transmission line model. FIG. 21 shows simplified transmission line models that are applicable to any application that features any non-trivial length of cable between a transmitter and a receiver (or any 2 devices in general). These modeled components capture the intrinsic properties of the transmission line that are essential to explain effects such as inline cable voltage drop, propagation delay, ringing, and additional effective crossline capacitance during isolation intervals among other effects. For these models, a section of the transmission line is shown comprising the components presented in the figure. Mathematically, the section is meant to represent an infinitesimal length of the transmission line, wherein the transmission line comprises an infinite number of said sections.

The top half of FIG. 21 shows a first common transmission line model known in the art. A first conductor of the transmission line is represented by terminals 2151 while a second conductor of the transmission is represented by terminals 2152; wherein 2151′ and 2152′ represent an input-side of the transmission line, respectively, and 2151″ and 2152″ represent an output-side of the transmission line, respectively; wherein the input-side and output-side are arbitrary assignments. In this model, the total effective series resistance for both conductors between the input-side and output-side is represented by series resistance 2111. The total effective inductance for both conductors for this section of the transmission line is represented by inductance 2113. This inductance is often defined primarily by the mutual inductance between the first and second conductors; but the self-inductance of each conductor can also be factored into this inductance. The total effective capacitance representing the capacitive coupling between the conductors for this section is represented by capacitance 2115. Finally, the total effective crossline conductance capturing leakage currents between the conductors is represented by shunt conductance 2116.

This first transmission line model can be expanded and adapted to show behavior of interest, with one such expanded second model shown in the bottom half of FIG. 21. Here, the first conductor 2161 and second conductor 2162 correspond respectively to the first conductor 2151 and second conductor 2152 in the first model. To capture the behavior that inline cable voltage drop occurs on each conductor rather than only one of them, the series resistance 2111 is split evenly into 2 series resistance—a series resistance 2121 and 2122 for the first and second conductors, respectively. Similarly, the inductance 2113 is split evenly into 2 inductances—inductance 2123 and inductance 2124 for the first and second conductors, respectively. Capacitance 2125 and shunt conductance 2126 are identical to 2115 and 2116 of the first model, respectively. An additional crossline circuit comprising the series combination of a resistance 2127 and capacitance 2128 is included in the second model. This crossline circuit allows some behavior effected by dielectric absorption to be observed with greater accuracy.

While this second model does add the improvements described above, many variations can be added, such as additional RC branches for improved modeling of dielectric absorption modeling. Skin effect, proximity effect, and others can also be modeled if required for accurate system analysis. For the purposes of the methods and apparatus disclosed herein, these models are sufficient to explain the effects observed and addressed.

Returning to the effects of dielectric absorption, when a sudden, large initial drop occurs, the effects of dielectric absorption are more prominent. These effects can alter the rate of decay by effectively slowing down the overall observed rate for an interval of time or may even result in the decay initially exhibiting a rising characteristic before the dielectric absorption effect has diminished and the expected downward rate of decay is observable. By the snubber mitigating these large initial drops, the difference between the cross-line capacitance and effective capacitive effect of the dielectric absorption with respect to their effective energy storage and potential is minimized (i.e., the magnitude of the electric field is not reduced as much, thereby maintaining the orientation of more polarized particles in the dielectric and therefore minimizing how much charge the dielectric can release), making the effects of dielectric absorption negligible. This can be used in combination or in place of other techniques for mitigating dielectric absorption effects; such as time delays or padding limits on the rate of decay, on the calculated impedances, or on any similar limit.

With this improved accuracy, an accurate calculation of the series resistance of the cable can be performed using the inline voltage drop and the current through Ohm's Law. This can be used in combination with TDR and other methods to determine the length of the cable to provide an estimate of the cable gauge. This can be compared against an expected cable gauge to warn of a potential discrepancy, as a fault or an incorrect cable installation may explain such a discrepancy. The resistance can also be used in combination with other measurements, such as TDR measurements, to calculate other cable characteristics, such as the capacitance and inductance that comprise the characteristic impedance. Many of these methods are taught in Eaves '220.

While a common embodiment is to implement the snubber and inline power measurement at the transmitter, this is not the only possibility. The snubber may instead be located at the receiver. This may result in a slight increase in error since the receiver snubber will be at a lower voltage. If the transmitter is performing the measurements, there would need to be coordination between the transmitter and receiver in the form of either a predetermined synchronization or a dynamically controlled algorithm. These factors may be acceptable trade-offs if there are other design reasons that make a receiver-side snubber beneficial, such as using the snubber for other signaling or system identification so the transmitter knows a receiver is connected via the “signature” of the snubber circuit operation.

Performing the inline power measurement at the receiver can similarly utilize a snubber circuit either on the local side (i.e., receiver side) or remote side (i.e., transmitter side) with similar stipulations. Regardless of the snubber location, additional alterations to the algorithm are required. Crucially, while the receiver can easily obtain the current and the receiver-side line-to-line voltage, the receiver must either obtain a measurement of the line-to-line voltage at the transmitter end or obtain current and receiver line-to-line voltage measurements at 2 different current levels. Many applicable methods are disclosed by Eaves '220. In one embodiment, the receiver can open its disconnect switch between the front-end and the DC link in order to obtain a measurement of the transmitter voltage when there is negligible current flow between the transmitter and the receiver while the transmitter disconnect switch remains closed. The receiver could also do this by opening its disconnect switch between the DC link and the load and waiting for the DC link capacitance to be fully charged, but many loads will not function properly with such an interruption.

Expanding on an aspect to explain improvements to inline cable voltage drop measurement, FIG. 30 explains the phenomenon of the cable voltage oscillations during the isolation interval occurring at a voltage lower than the transmitter output voltage and the receiver input voltage. FIG. 30 shows 2 cases: a first case of operation with unidirectional switches used and operated within at least the receiver, and a second case of operation with bidirectional switches used and operated within the transmitter and the receiver. Each case shows 3 waveforms over the same time interval: the transmitter output voltage (3001 for the first case, 3011 for the second case), the receiver input voltage (3002 for the first case, 3012 for the second case), and the receiver link voltage (3003 for the first case, 3013 for the second case).

Starting with the first case, it is observed that immediately at the start of the isolation interval, the transmitter output voltage 3001 drops while the receiver input voltage 3002 remains approximately unchanged for a duration of time while the first cycle of the forward propagating wave travels from the transmitter to the receiver. Eventually, as the reverse propagation wave begins, the receiver input voltage begins to drop as the transmitter output voltage begins to rise. In this case, though, neither the transmitter output voltage nor the receiver input voltage ever rises to the level of the receiver link voltage 3003. This is because some of the energy is transferred through the unidirectional switch of the receiver from the capacitance on the receiver input side to the capacitance on the receiver link side during the first cycle of the forward propagating wave; and this energy cannot return during the reverse propagating wave cycles since the unidirectional nature of the switch blocks this direction of current flow.

When bidirectional switches are used as shown for the second case, this energy transfer during the first half cycle is blocked. At the start of the isolation interval, the transmitter output voltage 3011 initially falls as before, but less steeply and less significantly. The receiver input voltage 3012, however, initially rises, and it initiates a wave propagating from the receiver to the transmitter immediately. These oscillations continue back and forth until sufficiently dampened by the cable impedances and other circuit impedances present, and with significant loses, the transmitter output voltage and the receiver voltage will settle at a voltage close to the receiver link voltage 3013, albeit possibly a little higher due to the distributed energy that was stored along the cable at linearly diminishing voltages during the power transfer interval. The shaded region 3020 is the area between the receiver input voltage and the receiver link voltage for the first half cycle of the oscillations; and this approximately correlates with the energy that is transferred from the receiver input side to the receiver link side during the first cycle of the forward propagating wave in the first case of unidirectional receiver switching.

Other methods to compensate for lost energy can be accomplished without relying on snubber capacitive energy. This can be a preferred method if a large snubber capacitance is prohibitive for other reasons, such as not being able to sufficiently match the impedance to minimize the attain a reflection coefficient of nearly 0. One such alternative method utilizes energy transfer from the source or load side of the circuit to the transmission line side of the circuit. These methods can be used in combination with a snubber circuit, such as allowing a snubber circuit to negate oscillations and then performing the compensation energy transfer. It is possible for the snubber and the compensation energy injection to occur simultaneously, but this may make snubber circuit design difficult, particularly if the motivation for compensation energy injection was due to the desired snubber impedance being already prohibitively difficult.

One embodiment of this alternative method can be done at the receiver. With a sufficiently sized link capacitance in the receiver, while the transmission line is in an isolated state such as an isolation interval, the receiver can allow current flow from its link capacitance back to the transmission line by closing its unidirectional switch. When the link capacitance is much larger than the combination of the transmission line capacitance and other capacitance in parallel with the transmission line, such as by an order or magnitude; and the expected voltage difference is within an acceptable range; the energy lost from the transmission line due to the forward conduction of the receiver's unidirectional switch can be returned without an excessive reduction of the link capacitor's voltage level. Once the voltage levels between all said capacitances are approximately equal, the receiver's switch can be returned to a unidirectional or fully disconnected state. The equalization of the voltage of the capacitances can be determined by various means, such as measuring the voltage levels or by measuring the current flow between them. An advantage of this method is that the transmission line voltage will not settle at a voltage higher than the receiver's input voltage, ensuring a conservative calculation of the inline voltage drop will follow. Another advantage of this method is that the energy lost from the transmission line was primarily transferred to the link capacitance, which means that the return of this energy through this method further reduces the error in the inline voltage drop calculation without requiring further margin due to this method.

Another embodiment of this alternative method can be done at the transmitter. While closing the transmitter's disconnect switch to produce a low impedance path from the source to the transmission line will likely result in the same energy loss effect to occur again, the transmitter can instead use a higher impedance or current-controlled energy injection path to minimize this effect. An advantage to the higher impedance is that it can facilitate methods to determine when the energy restoration has completed. When this energy restoration process commences, all of the energy goes into the capacitance on the transmission line side of the circuit. Once the transmission line voltage reaches the same level of the receiver link capacitor voltage plus any diode drops, the energy injected by the transmitter will flow into both the transmission line side capacitance as well as the receiver link capacitance and possibly the load. This will result in a discontinuity in the voltage charge rate of the transmission line side capacitance. This can be detected by the transmitter using any number of methods, such as a non-zero value for the second time derivative of its output voltage measurements, a zero-crossing for the first time derivative or second time derivative of its output voltage measurements, or a jump discontinuity in any order of time derivative of its output voltage measurements. Once detected, the transmitter must cease this energy transfer, at which point the transmitter can proceed with its measurements and safety evaluation using existing methods.

Energy injection by the transmitter has some additional considerations. Since the transmitter's detection of the voltage equalization lags behind the actual equalization, the resulting inline voltage drop calculation will tend to produce a smaller value than the actual, which is an error away from conservativism. The transmitter will need to compensate for this, either by using other methods to fine tune the inline voltage drop measurement, or by applying a corrective factor to account for the margin of error. Different methods of energy transfer may present different challenges. For example, using a simple resistor to limit the current can have difficulty in striking a balance between charge time and the maximum voltage attainable due to voltage divider effects. A preferred embodiment will use a constant current injection circuit to avoid this issue. This has the advantage of raising the voltage of a capacitance by a linear amount or nearly linear amount with respect to time provided that the capacitive current draw is significantly larger than any other resistive leakage current, thereby simplifying evaluation. The transmitter may be able to use other methods, such as PWM, but these may have significant difficulty in avoiding the reproduction of the energy loss effect as well as determining the point at which the voltage equalization has been reached. The transmitter must also provide logic for evaluations where the voltage equalization point is never observed or not clearly determined. In these cases, alternative methods of inline voltage drop measurement may be employed, or the transmitter can use the original inline voltage drop calculation without the usage of this energy injection as a conservative estimate. This will be an accurate measurement of the inline voltage drop in cases where there is little energy loss from the transmission line through unidirectional current conduction at the receiver, such as when the load does not draw significant power, when the transmission line is very lossy, or the transmission line is short.

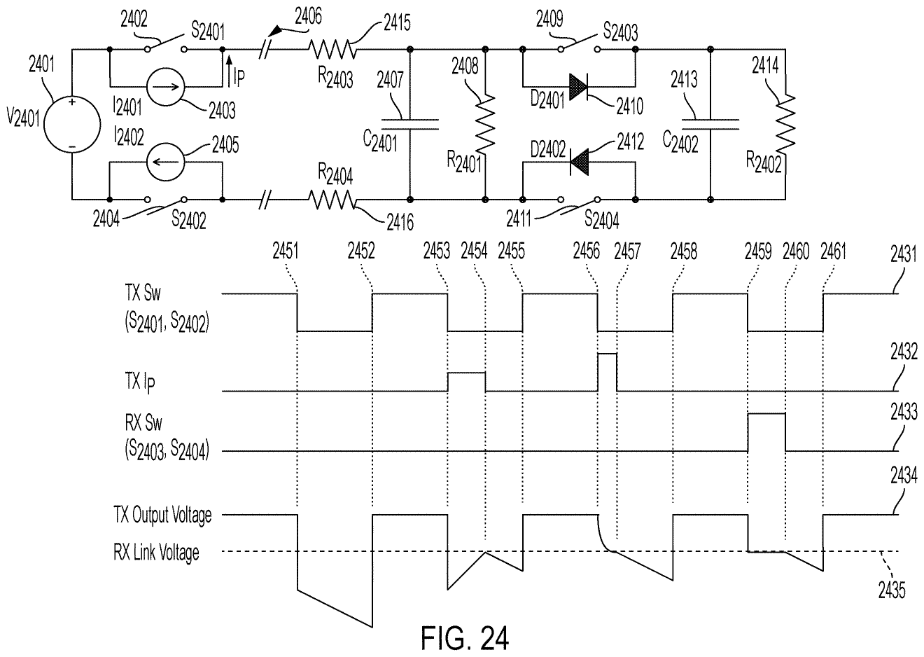

FIG. 24 demonstrates these alternative methods of energy loss compensation on the DE-side of the circuit. A representative circuit is shown, with a transmitter comprising switches 2402 and 2404 with variable current sources 2403 and 2405 in parallel, respectively. Source 2401 is connected to the transmitter input to provide power. The transmitter output is connected to abbreviation mark 2406 shown on the positive and the negative sides of the transmission line, which is used to represent the variable length of cable as well as demark between the transmitter and receiver ends of the circuit. Series resistance 2415 and 2416 are used to represent the bulk series resistance of the cable while crossline capacitance 2407 and crossline resistance 2408 represent the effective bulk crossline impedances on the DE-side of the circuit. The receiver comprises switches 2409 and 2411 with associated respective diodes 2410 and 2412; and the receiver further comprises link capacitance 2413. Finally, the receiver is configured to be connected to load resistance 2414.

Waveforms and timing diagrams associated with this representative circuit are also shown in FIG. 24. Waveform 2431 shows the control of the transmitter switches. Waveform 2432 shows the current sourced through the positive current source 2403 with the current oriented as shown in the circuit diagram. Control of the receiver switches is shown in waveform 2433. Finally, plotted together, the transmitter output voltage is shown in waveform 2434 while the receiver link voltage is shown in waveform 2435.

Prior to time 2451, with the transmitter switches closed during a first power transfer interval, power is drawn by the load and an inline cable voltage drop is present, which is reflected by the receiver link voltage being lower than the transmitter output voltage. At time 2451, the transmitter opens its switches to initiate a first isolation interval. Since no compensation methods are used during this first isolation interval, a large overshot initial voltage drop is observed (ringing and the inductance also associated with this are not shown for simplicity). The RC decay occurs until time 2452, at which point the transmitter closes its switches to end the isolation interval and begin the second power transfer interval.

At time 2453, the transmitter opens its main switches to initiate a second isolation interval. This time, the transmitter also sources a constant current through both current sources, with this current shown in waveform 2432. Since this current is of a low magnitude relative to the amount required to compensate immediately for the initial voltage drop, the initial voltage drop still occurs, but the current source gradually raises the transmitter output voltage. When the transmitter output voltage reaches approximately the receiver link voltage, a discontinuity is observed by the transmitter as the transmitter output voltage will no longer rise significantly above the receiver link voltage. The transmitter can quickly detect this, obtain a measurement indicative of the receiver input voltage, and desist sourcing current through its current sources at time 2454. From this time 2454, the remainder of the isolation interval permits the unaltered RC decay by the crossline impedances until the end of the isolation interval at time 2455. At that time 2455, the transmitter closes its switches and beings a third power transfer interval.

At time 2456, the transmitter opens its main switches to initiate a third isolation interval. The current sources are activated again with a non-zero current, but a larger magnitude current is sourced. In this case, the magnitude is sufficient to slow the initial voltage drop, so a gradual decay towards the receiver link voltage is observed on the transmitter output voltage. When the transmitter output voltage reaches approximately the receiver link voltage at time 2457, given the constant current sourced between time 2456 and 2457, an abrupt discontinuity is observed as the decay of the transmitter output voltage suddenly converts to a nearly horizontal line. The transmitter can again detect this discontinuity, obtain a measurement indicative of the receiver input voltage, and stop sourcing current for the remainder of the isolation interval to permit unaltered RC decay until time 2458. At that time 2458, the transmitter closes its main switches to begin a fourth power transfer interval.

At time 2459, the transmitter opens its switches to initiate a fourth isolation interval. For this fourth isolation interval, instead of the transmitter providing a current source, the receiver instead closes its switches to allow bidirectional current flow between the receiver link capacitance 2413 and the crossline capacitance 2407. This allows the crossline capacitance to settled at the same voltage as the receiver link capacitance. Once this equalization is completed or after a predetermined amount of time, the receiver switches are open at time 2460 to allow the unaltered RC decay of the crossline impedances until the end of the isolation interval at time 2461. At time 2461, the transmitter closes its main switches to begin a fifth power transfer interval.

With regard to the receiver switches being closed at time 2459, some nuance is not shown in the diagram for simplicity. Typically, the receiver switches would be closed prior to the opening of the transmitter switches to minimize the risk of a gap where both the transmitter switches and the receiver switches are open. Also, depending on the current levels and the resulting power dissipation, it may be preferrable to keep the receiver switches also closed for the duration of each power transfer interval to minimize the power dissipation. Finally, while the transmitter output voltage is shown as a flat line between time 2459 and time 2460, there may still be oscillations due to the reflection coefficient formed by the receiver link capacitance and the load resistance; so this may still prefer to be complemented with the usage of a snubber circuit designed with these additional impedances in mind.

One additional advantage of using the snubber circuit to improve the inline voltage measurement accuracy is that there may be more flexibility and acceptability with respect to the switching speed of the snubber's connect and disconnect switches. One factor in determining the magnitude of the excessive line-to-line voltage drop associated with the inline voltage measurement error is the dI/dt or rate of change in current through the transmission line. Reducing this dI/dt reduces the magnitude of the ringing oscillations, and thereby reduces the magnitude of the excessive voltage drop and the error it introduces. While this dI/dt reduction by opening a switch at a slower speed can be applied to the main switches, those switches are likely under more stress due to being in the main power path, and such an approach could result in an unacceptable increase in failures or decrease in efficiency. Slowing the snubber disconnect switch instead could achieve similar improvements to the effective dI/dt while not worsening the failure rate or efficiency when compared to the same approach being done with the main FETs. The snubber switch may further have the advantage of the current already being lower as the snubber capacitor discharges, making a lower dI/dt easier to achieve. Other methods of dI/dt control can similarly be used, whether through the usage of passive analog circuits or active control circuits.

In the most general sense, the periodically connected snubber circuit is applicable not just to a transmitter or receiver switch opening or closing, but generally to any source or impedance change that produces a change in the oscillations or reflections on the transmission line. This includes any form of a step response, but also more gradual changes that produce a dV/dt or dI/dt event. Source changes include voltage or current magnitude changes, voltage or current phase changes, the addition or removal of a constant voltage source or a constant current source, changes from a constant voltage source to a constant current source, changes from a constant current source to a constant voltage source, other effective behavior such as a constant voltage source connected to a current limiting circuit where the current limit is reached or a constant current sink connected to a voltage limiting circuit where the voltage limit is reached, and any other similar combinations; where said changes can be effected by operating a switch, changing a switching frequency, changing analog or digital control parameters, or allowing predefined circuit behavior (e.g., allowing a current limiting circuit to reach its limit). Impedance changes can be effected by similar operations.

Continuing with this generalization, in other words, a periodically connected snubber can be connected in any scenario where a permanently connected snubber would have a beneficial effect for at least some duration of time, with the key distinction being that a permanently connected snubber would substantially interfere with critical function of the system at a later time interval whereas a periodically connected snubber would be disconnected during said later time interval.

It is understood that the periodically connected snubber can also be used without any other switching elements. For example, a system transmitting a high frequency AC signal on a transmission line may periodically connect one or more snubber circuits without any other source or impedance changes if such an operation provides value, such as some form of signaling or allowing different measurements to be taken.

On the topic of cross-port fault detection, many alternative methods of cross-port fault detection exist, but many are strongly dependent on the details of the ports involved in the fault and the type of fault. For example, a cross-port positive-to-negative fault between a transmitter in its power transfer interval and a transmitter in its isolation interval may behave differently and be detected by methods already taught by Eaves '637 and Mlyniec '494. In another example, a cross-port fault that is positive-to-positive or negative-to-negative may not require any action if the fault current is sufficiently low due to the voltage difference between those ports being sufficiently low. The type of fault can require different detection methods. For example, a purely resistive fault may require the same or different detection method as compared to a human-body model fault, which itself may require the same or different detection method as compared to a human-body model with additional series resistance that simulates additional partial insulation effects from clothing and other scenarios. Similarly, the magnitude of the fault may also require different detection methods.

As introduced herein previously, a uniquely challenging scenario is a cross-port positive-to-negative fault between 2 transmitters that are both in an isolation interval at the same time and are connected to the same isolation plane. One alternative method to solve this fault detection problem is through prevention by instead isolating these transmitters. This introduces a high impedance in the current path for the fault, thereby significantly limiting the fault current capacity. Depending on the power level and other system design parameters, this can either be an acceptable solution or it can be cost prohibitive.

Another simple solution is for all transmitter channels to only switch one side of their circuit, such as only positive-side switches while leaving negative-side switches closed. This single-side switching (i.e., unbalanced switching) technique is effective at mitigating positive-to-negative cross-port faults, as these are now an equivalent circuit representation as a crossline fault, thereby allowing existing methods of crossline fault detection to work without modification. One major trade-off with this solution is that the benefits of switching both sides (i.e., dual-side switching, or balanced switching) are lost, which may include EMC benefits, reliability and performance improvements, other algorithms that depend on such balanced switching, and others. Some hybrid solutions may exist to retain some of the benefits of dual-side switching while utilizing single-side switching for this aspect, such as only temporarily enacting single-side switching at a particular time. Using dual-side switching while interrupting the main high-power current flow can continue to exhibit EMC improvements, with all transmitters closing only one side of their switches (e.g., the negative-side switches) at approximately the same time after a delay while still in the isolation interval. It is relative to this delayed time that cross-port faults can be checked using the same methods as crossline fault detection. The transmitters could alternate between which side is closed and which is opened during single-side switching operation, and this may facilitate other benefits, such as detecting failed switches on a single side when a change in output voltage is not observed while the switches are open. A variation of this can be realized by using dual-side switching, but using a common link to connect one side for an interval of time to achieve an effect similar to single-side switching. Since this common link is not connected to the main power path on the AE-side (e.g., to the source for a transmitter), this limits the current paths to provide some EMC benefits over single-side switching, though some of the downsides of single-side switching are still present, such as introducing additional leakage paths.

Another alternative solution involves dithering and staggering techniques. By changing the phase alignment of the isolation interval of one transmitter relative to another, a fault that may be cross-port positive-to-negative between 2 transmitters both in their isolation interval at the same time will later be transitioned to a different scenario where 1 transmitter is in its isolation interval and the other is in its power transfer interval. A critical consideration with this method is the fault detection time, as it may take a plurality of isolation intervals to detect a fault. For significantly high fault currents, this may require alternative methods for at least these higher fault current scenarios depending on the duration of the fault current during the power transfer interval.

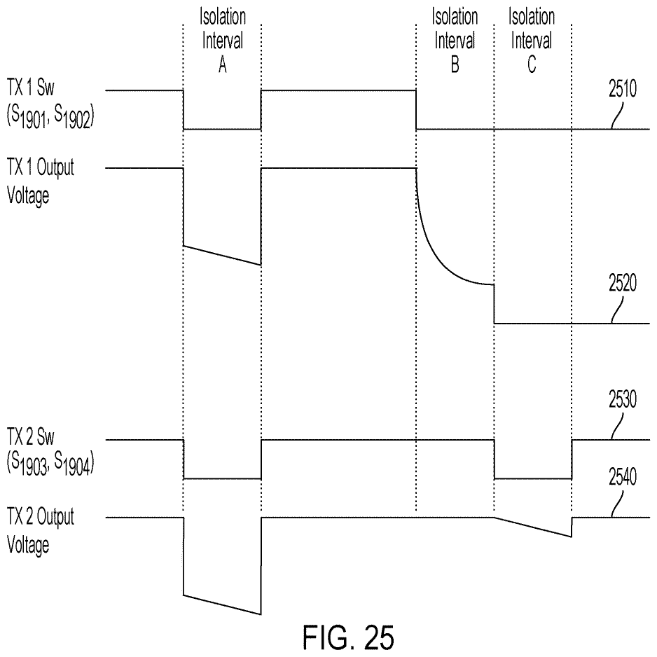

FIG. 25 shows example waveforms of this alternative cross-port fault method that relies on staggering or dithering transmitter channel phase synchronization. Explained in the context of the circuit presented in FIG. 19, the operation of main switches 1901 and 1905 for the first transmitter is shown in waveform 2510 while the operation of main switches 1902 and 1906 for the second transmitter is shown in waveform 2530. The first transmitter output voltage is plotted in waveform 2520 while the second transmitter output voltage is plotted in waveform 2540.

During isolation interval A, with a cross-port fault present, both transmitters begin this example phase-aligned wherein both transmitters are concurrently in an isolation interval during isolation interval A. As can be seen in waveforms 2520 and 2540, a large initial voltage drop is observed that is indicative of a cross-port fault as described in embodiments disclosed herein. Provided that the shock magnitude-duration curve will not be exceeded, each transmitter closes its main switches at the end of isolation interval A to begin a second power transfer interval despite detecting the characteristics of a cross-port fault.

During this second power transfer interval, due to the detection of the cross-port fault characteristics, the second transmitter extends its power transfer interval or the first transmitter shortens its power transfer interval. When isolation interval B commences, only the first transmitter is in an isolation interval during this time, as the second transmitter remains in its second power transfer interval. Since the circuit behavior is now different given the different configuration of main switches closed an open, the first transmitter is able to detect the cross-port fault using the methods disclosed herein or disclosed in prior art such as Eaves '637, register a fault, and discontinue high power transfer instead of beginning a third power transfer interval. The second transmitter, when it reaches its second isolation interval as isolation interval C, the cross-port fault characteristics are no longer present since the other channel connected to the fault—the first transmitter—is in a high-impedance or isolated state and does not enable significant fault current. Therefore, the second transmitter can continue to a third power transfer interval as no fault is detected nor is any fault required to be detected at this point.

In more general terms, a method to detect a positive-to-negative cross-port fault between two devices during their isolation intervals, wherein each device is connected to a distinct transmission line, is commonly predicated on the energy transfer through the unidirectional switch elements of said devices. As such, any means of measuring, detecting, or quantifying this energy transfer can be implemented using methods and apparatus known in the art.

Based on the phenomenon where the current flows through the unidirectional switches in the reverse direction, one alternative method for detecting cross-port faults is to look for this reverse leakage current. This can be examined on a particular transmitter or receiver and compared to a limit for each individual sensor, such as a reverse current through the transmitter positive switch, or it can be compared to a limit based on the difference between the reverse current through the positive and negative switches for a device. This differential current approach has the advantage of being distinguishable from scenarios where there is normally some current flow allowed through said switches in a balanced fashion for a particular transmission line, such as the energy transfer from the transmission line to the receiver link capacitance through the receiver's series diodes during the transient when the transmission line power transfer is stopped. In these scenarios, the current through the positive switch is expected to be about the same as the current through the negative switch on the same port to complete the current loop; whereas in the event of a cross-port fault, the current through the positive switch is expected to be about the same as the current through the negative switch on a different port to complete the current loop. This method may be well suited to detect higher fault current scenarios and may be complementary to other methods, such as dithering or staggering methods that may require faster detection of significant fault currents. One advantage of looking for this reverse leakage current is that the current sensor sensitivity can be scaled down to look for these small currents in the reverse direction so long as larger currents are still permitted in the forward direction, thereby significantly improving the signal to noise ratio for the reverse current sensing. In the event that both the transmitter and receiver exhibit unidirectional switching characteristics, it is essential to consider that the fault current could be split between these devices, such as by reducing the limit by a factor of the maximum number of unidirectional devices that could be connected or by other similar means.

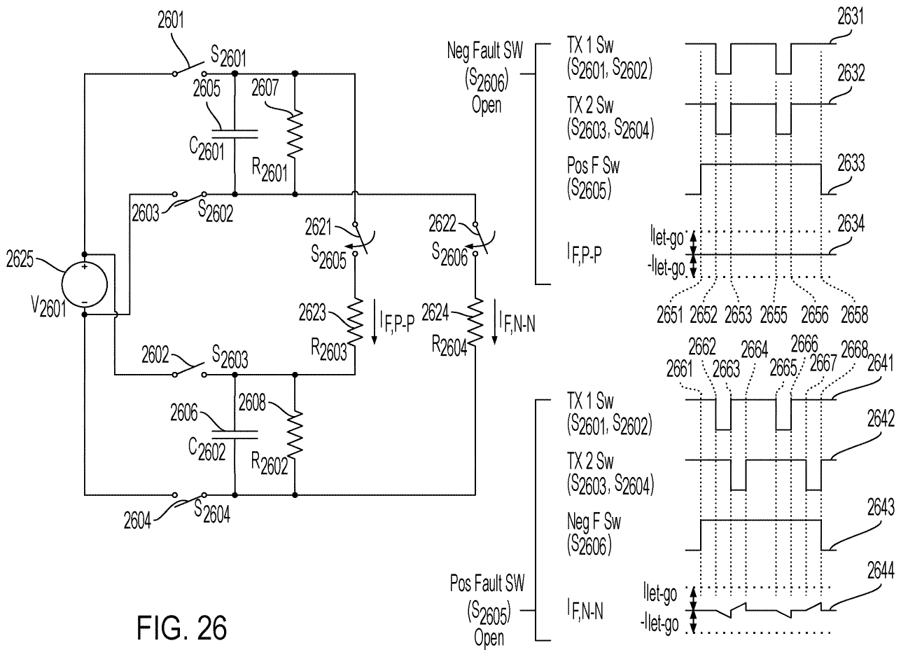

FIG. 26 shows the behavior when cross-port faults are connected either negative-to-negative or positive-to-positive between 2 transmitter outputs. A representative circuit is shown with a first channel in the top half and a second channel in the bottom half. The first channel comprises a first transmitter, a crossline capacitance 2605, and a crossline resistance 2607; wherein the first transmitter comprises switches 2601 and 2603. The second channel comprises a second transmitter, a crossline capacitance 2606, and a crossline resistance 2608; wherein the second transmitter comprises switches 2602 and 2604. The circuit further includes source 2625 connected to the input of each transmitter. 2 distinct cross-port fault circuits are provided: a positive cross-port fault circuit comprising fault switch 2621 and fault resistance 2623, and a negative cross-port fault circuit comprising fault switch 2622 and fault resistance 2624.

For the timing diagrams and waveforms, 2 distinct sets of waveforms are provided to show similarities and differences between different aspects. The upper set of waveforms shows a positive-to-positive cross-port fault and also shows concurrent isolation intervals for each transmitter channel. The lower set of waveforms shows a negative-to-negative cross-port fault and also shows misaligned or non-overlapping isolation intervals between the transmitter channels. For each set of waveforms, the first transmitter switch control is shown (waveform 2631 for the upper set, waveform 2641 for the lower set); the second transmitter switch control is shown (waveform 2632 for the upper set, waveform 2642 for the lower set); the appropriate fault switch control is also shown (waveform 2633 for switch 2621 for the upper set, waveform 2643 for switch 2622 for the lower set); and the appropriate fault current is shown (waveform 2634 for I_{F,P-P} for the upper set, waveform 2644 for I_{F,N-N} for the lower set).

Starting with the upper set of waveforms, the negative fault switch 2622 is kept open throughout. Prior to time 2651, since the positive fault switch is also open, there is no fault current as expected. At time 2651, the positive fault switch is closed, but the fault current remains approximately OA since both ends of the fault resistance 2623 are at approximately the same potential. When a first isolation interval commences at time 2652 with the opening of the switches for both the first and the second transmitter, there is still no appreciable fault current. This is dependent on the relative magnitude of crossline impedances among other factors between the first and second channels; but when corresponding components are matched between the first and second channels, both ends of the fault resistance remain at approximately the same potential, so there is again negligible fault current and the fault current therefore remains well below the let-go limit that would require fault detection. This lack of fault current continues throughout the other power transfer intervals initiated at times 2653 and 2656 as well as the isolation interval initiated at time 2655. When the cross-port fault current is disconnected at time 2658 for this example, there is still no change in the fault current observed.

Turning to the lower set of waveforms, the positive fault switch 2621 is kept open throughout. Similar to the upper set of waveforms, prior to time 2661, there is no fault current since the negative fault switch is open, and at time 2662 when the negative fault switch is closed, there is still no fault current due to both ends of the fault resistance 2624 being at approximately the same potential. At time 2662, the first transmitter opens its switches to commence a first isolation interval, but the second transmitter remains in a power transfer interval. Since the first transmitter output is permitted to decay while the second transmitter output remains at approximately the source voltage, there may be a potential difference across the fault resistance 2624. This fault current is still limited since it must complete a current loop, such as through an intrinsic body diode or a capacitive coupling (not depicted) across open transmitter switches when the transmitter switches are embodied as a MOSFET, for example. This limited current as well as limited potential difference across the fault resistance results in a small fault current as shown in waveform 2644, wherein this remains below the let-go limit and does not require fault detection.

At time 2663, the first isolation interval is terminated by the first transmitter closing its main switches. Also at time 2663, a second isolation interval is initiated by the second transmitter opening its switches, wherein only the second channel is in an isolation interval since the first transmitter is in a power transfer interval. This again results in a potential difference across the fault resistance, and this potential difference as well as the fault current magnitude follows the changing magnitude of the decaying nature of the second transmitter output voltage until time 2664. Note that the polarity of the fault current changes depending on which transmitter is in an isolation interval and which transmitter is in a power transfer interval. This behavior continues for the other power transfer intervals starting at times 2666 and 2668 and other isolation intervals starting at times 2665 and 2667, wherein there is no significant change in the behavior when there is a time interval between the end of an isolation interval for the first transmitter and the start of an isolation interval for the second transmitter.

While this shows a positive-to-positive fault with concurrent isolation intervals and a negative-to-negative fault with non-overlapping isolation intervals, the primary differences shown in fault current between waveforms 2634 and 2644 are due to the phase alignment of the isolation intervals between the 2 transmitter channels rather than which fault switch was closed. In other words, if the upper waveform set were repeated with the positive fault switch 2621 open and the negative fault switch 2622 instead operated at times 2651 and 2658, the fault current for the negative fault resistance 2624 would have a waveform identical to 2634; and this would apply in vice versa fashion to the lower waveform set being repeated with negative fault switch 2622 being open and the positive fault switch 2621 being operating instead.

Similar methods of detecting such imbalances can be used equivocally. A voltage sensor around the switches (e.g., drain-to-source of a MOSFET) can detect an imbalance between the positive and negative switches for a device and can detect that one is approximately at the forward voltage of the switch to suggest that it may be forward conducting, where forward conducting in this context of a unidirectional switch for the transmitter is considered reverse leakage current. Similarly, in a system utilizing a center-tied earth ground balance, the difference between the positive-to-earth and the earth-to-negative voltages can similarly provide an indication of an imbalance caused by a cross-port fault. This earth ground imbalance would also occur when an earth-to-line fault is present, which is also a desirable fault to detect and does not necessarily need to be separated from the cross-port fault indication. Such methods can be adapted for implementation at the receiver end with consideration of the orientation of the unidirectional switch and the leakage current. In the case of a receiver in a fault managed power system featuring a unidirectional switch at the receiver, said unidirectional switch would have its forward conduction oriented such that the cathode of the positive rail switch is connected to the link-side of its circuit. With this orientation, the leakage current and normal current are the same direction; but during an isolation interval, it is expected that this switch is normally reverse biased when there is no fault present. Hence, during the isolation interval, this forward conduction can be considered a leakage current, where said leakage current may be unintentional when a fault is present.

Generalizing this switch voltage sensor embodiment, a difference between the measurements from each switch voltage sensor exceeding a threshold is indicative of a fault. Nominally, in a balanced system without a fault present, the voltage across each switch should be approximately equal, with this being most relevant during an isolation interval when a larger voltage drop across each switch is expected.

When a cross-port fault is present between two transmission lines such as from the negative conductor of a first transmission line to the positive conductor of a second transmission line, during an isolation interval, this has an effect similar to a pullup on the first transmission line while the second transmission line experiences a pulldown effect. Another way to view this effect is that, during an isolation interval, the common mode voltage shifts upward on the first transmission with respect to the AE-side of the circuit (and with respect to the second transmission line) while the common mode voltage shifts downward on the second transmission line with respect to the AE-side of the circuit (and with respect to the first transmission line). In one embodiment, this common mode voltage shift can be measured directly using any methods known in the art, such as measuring a common mode voltage difference from a center-point across a transmission line to a center-point across the AE-side of the circuit and registering a fault if the common mode voltage difference exceeds a positive threshold or drops below a negative threshold, wherein this is performed for each transmission line. Other ways to measure or represent the common mode voltage can be applied, such as measuring a center-point relative to a different node, using a ratio of positive-to-center and center-to-negative voltages, and so on.

Another effective method for measuring this voltage indicative of a cross-port fault is by measuring the voltage across each switch of a device to detect a switch voltage sensor imbalance. As mentioned, without a fault present, the voltage across each switch is approximately equal. When a cross-port fault is present between a first transmission line and a second transmission line, during an isolation interval, the voltage across each switch of a first device that is connected to the first transmission line will deviate. This is true for the voltage across each switch of a second device that is connected to the second transmission line, albeit the deviation will be in the opposite direction (e.g., if the first device sees a larger voltage drop across its positive switch compared to its negative switch, then the second device sees a larger voltage drop across its negative switch compared to its positive switch). This deviation can be represented mathematically as the difference between the voltage measurement from each switch voltage sensor of the device.

In a preferred embodiment, a transmitter or receiver nominally isolates a transmission line on a DE-side of a circuit from an AE-side of the circuit via a first unidirectional switch on the positive-side of the circuit and a second unidirectional switch on the negative-side of the circuit. The transmitter or receiver further includes a first switch voltage sensor connected across the first unidirectional switch and a second switch voltage sensor connected across the second unidirectional switch. During an isolation interval, the transmitter or receiver measures a first switch voltage via the first switch voltage sensor and a second switch voltage via the second switch voltage sensor. The transmitter or receiver then calculates a switch voltage difference as the difference between the first switch voltage sensor and the second switch voltage sensor, and if the switch voltage difference is above a positive threshold or the switch voltage difference is below a negative threshold, a fault is registered.

While this primary embodiment is described using unidirectional switches, the same method can be performed with bidirectional switches as well. In this embodiment, the switch voltage sensor measures around the entirety of the bidirectional switch. For example, wherein a bidirectional switch comprises a first unidirectional switch (e.g., MOSFET) and a second unidirectional switch, the switch voltage sensor is connected from the AE-side of the first unidirectional switch to the DE-side of the second unidirectional switch, which corresponds to the AE-side of the bidirectional switch to the DE-side of the bidirectional switch, respectively. Alternatively, a switch voltage sensor can be placed around each unidirectional switch and the combination of these switch voltage sensors can be used since they can calculate the equivalent of the voltage across the bidirectional switch.

Regarding the timing and limits for cross-port fault detection, an important factor to consider is the capacitance and resulting time constants of the system when a cross-port fault is present. Because of the line-to-line capacitance present on both the DE-side and AE-side of the circuit along with any effective capacitance across each switch (e.g., the output capacitance or drain-to-source capacitance of a MOSFET), the voltages intended to be measured when a cross-port fault is present do not change instantaneously due to these system capacitances. To account for this, a preferred embodiment measures the voltage via the switch voltage sensors at approximately the end of the isolation interval, as the voltage changes will have had the most time to be realized and any voltage difference present will be maximized. The limit to use as the threshold (positive or negative) against which the voltage difference is compared should be defined by at least the factors of the fault resistance values that must be detected within a required amount of time by this check, the worst-case time constants formed by the range of system capacitances, and the time duration between the start of the isolation interval and when the switch voltage sensor measurements are taken. These factors can further include other elements such as other nominal crossline impedances that impact the time constants formed, though this may make the analysis much more involved and an impact analysis may be warranted to determine if other factors are necessary to include.

One additional benefit realized by using switch voltage sensors for cross-port fault detection is that additional diagnostic information to aid troubleshooting is acquired; specifically, the lines involved in the cross-port fault can be identified. In other methods that only examine the initial voltage drop, the ports involved in the cross-port fault are identified, but the measurements do not indicate which line of each port is connected to the cross-port fault. With the switch voltage sensor method of cross-port fault detection, the specific line for each port connected to the cross-port fault is identified. For a given port or channel, for a switch voltage sensor imbalance indicative of a larger voltage drop on a first switch compared to a second switch, this is indicative of the first switch being connected to the line to which the cross-port fault is connected for that port. This can similarly be applied to common mode voltage methods by evaluating the direction of the common mode shift for a given port or channel. For example, when a port sees its common mode voltage shift such that its center point on the DE-side is shifted upwards relative to the AE-side of the circuit during an isolation interval, this is indicative of a cross-port fault connected to the negative side of that port (for a DC-based system). This fault location identification greatly improves troubleshooting in the event of a cross-port fault, which is a significant benefit given the increased complexity of troubleshooting a cross-port fault due to the increased number of possibilities without this information.

Enhancements and variations to these embodiments of cross-port fault detection via switch voltage sensor imbalance exist. Wherein the switch voltage sensors provide an excessive leakage path or present an undesirable impedance to the circuit during certain time intervals, the switch voltage sensor circuit can further comprise a switch that can connect the switch voltage sensor prior to taking a measurement and disconnect the switch voltage sensor when a measurement is not being taken. More specifically, it may be preferred to leave the switch voltage sensors disconnected for the beginning of an isolation interval so that the switch voltage sensors do not alter the characteristics of the crossline decay used for safety measurements to detect crossline faults nor require the switch voltage sensor impedances to be factored into the crossline fault detection thresholds. In this case, the switch voltage sensors can still be connected towards the end of the isolation interval after the safety measurements for crossline fault detection have been taken. It may also be preferred to leave the switch voltage sensors disconnected when a device is in a non-conducting or limited state, such as after detecting a fault, to further improve the isolation between the AE-side and DE-side of the circuit, with the switch voltage sensors only being switched in during this time interval if a measurement from the switch voltage sensors is desired as part of the methods disclosed herein.

With a bidirectional switch configuration, other variations for cross-port fault detection are possible by sensing in a different location or by altering the bidirectional switch arrangement. One such variation using MOSFETs is arranging the bidirectional switches on the positive side with a common-source arrangement and the bidirectional switches on the negative side with a common-drain arrangement. By then sensing the voltage at the positive common-source node with respect to the negative common-drain node, a cross-port fault can be detected by the presence of a large initial voltage drop as described in the methods disclosed herein. While a common-drain arrangement for a MOSFET is unusual, this nevertheless shows the existence of other arrangement and sensor locations to implement the same methods disclosed herein, and these are considered equivalent embodiments given that the fault characteristics and effective circuit presentation from the perspective of the fault is equivalent.

Similar to these methods of using switch voltage sensors to detect cross-port faults, the switch voltage sensors can also be used for line-to-earth fault detection. Many FMP systems provide a current-limited center-tie to earth ground as shown in FIG. 2; however, for reasons such as EMC and stability, many power supplies used as sources also include an effective capacitance between each line and earth ground, commonly referred to as Class-Y capacitors or Y-capacitance (e.g., capacitors 3409 and 3411). This means that line-to-earth faults are not current-limited with respect to the discharge of the Y-capacitance since a line-to-earth fault is effectively applied directly in parallel with one of these Y-capacitors. When this Y-capacitance is too large, the time constant for the Y-capacitance to discharge to a safe level through the line-to-earth fault may be too slow and may exceed a magnitude-duration shock curve limit or any other chosen safety limit.

In a preferred embodiment, any Y-capacitors are designed such that the effective capacitance is small enough to allow any line-to-earth fault to remain below a magnitude-duration shock limit or any other chosen safety limit given the range of line-to-earth fault resistances that pose a potential safety hazard as well as the range of other circuit impedances that impact the time constant based on circuit analysis. For UL 1400-1, this range of fault resistance ranges from 500Ω up to a resistance guaranteed to be below the appropriate let-go limit based on the maximum line-to-earth touch voltage. Based on this, it is preferred to enforce that the line-to-earth voltage reminds approximately balanced (e.g., for a DC-based 2-line system, each line-to-earth voltage should be approximately half of the line-to-line voltage) within a tolerance to avoid needing to consider the full line-to-line voltage as a possible worst-case line-to-earth touch voltage if an existing imbalance exists prior to a person touching line-to-earth.

In some cases, limiting the sizing of the Y-capacitance is not a feasible solution due to other system design parameters or is not considered sufficiently robust. In these cases, a method to detect the line-to-earth fault condition in a required amount of time is needed, with the system subsequently limiting the system to an electrical construction limit as disclosed herein. This is not necessarily required for all fault resistances, but rather for at least a portion of the fault resistance range that requires fault detection and response faster than those provided by passive methods (e.g., allowing Y-capacitance to discharge and current-limiting circuit to sufficiently limit fault current) due to an excessively slow effective time constant.

In a first embodiment of active earth ground fault detection, a voltage indicative of the line-to-earth fault on the AE-side of the circuit or the DE-side of the circuit can be measured, and when this voltage exceeds a threshold, a line-to-earth fault is registered. While this method is straight-forward, it is not preferred in all cases. In most cases, all devices on the same isolation plane will see the same line-to-earth imbalance when all devices are in a power transfer interval, so it is indeterminate which device has the line-to-earth fault on its DE-side of the circuit, resulting in all devices on that isolation plane registering the fault. This is not a significant issue if each device is isolated, but when many devices share an isolation plane, this can be an unacceptably large impact. A second issue is that the change in voltage that must be detected in a short amount of time is typically very small, especially as Y-capacitance is increased, making this prone to false positives or risks missing required fault detection scenarios.

In a second embodiment, a first line-to-earth voltage sensor connected on the DE-side of the circuit measures a first line-to-earth voltage during an isolation interval, and if the first line-to-earth voltage is outside of an acceptable range, a fault is registered. An embodiment of said first line-to-earth voltage sensor would be configured to measure the voltage between nodes 233 and 209 or between nodes 209 and 234. Since the line-to-line voltage during an isolation interval is often changing, this is further enhanced when at least a second voltage sensor is used to account for this, wherein the second voltage sensor can be a line-to-line voltage sensor on the DE-side of the circuit, or a second line-to-earth voltage sensor on the DE-side of the circuit that measures a line distinct from the line measured by the first line-to-earth voltage sensor (e.g., measures across 233 and 209 if the first line-to-earth voltage sensor measures across 209 and 234). It is understood that, in a 2-line system, the chosen voltage sensor used for the second voltage sensor can be used with the first line-to-earth voltage sensor to calculate what would be measured by the unchosen voltage sensor from the options for the second voltage sensor. For example, with a positive-to-earth voltage sensor as the first voltage sensor and a positive-to-negative voltage sensor as the second voltage sensor, these two voltage sensors can be used to effectively calculate what the earth-to-negative voltage sensor would measure if the earth-to-negative voltage sensor had been implemented.

With this second voltage sensor acquiring a second voltage (whether this is a first line-to-line voltage or a second line-to-earth voltage), an earth voltage imbalance can be compared to an acceptable range, and when the earth voltage imbalance is outside of the acceptable range, a fault is registered. This earth voltage imbalance is effectively indicative of a common mode voltage shift, and the earth voltage imbalance can be defined in a number of ways, including but not limited to a difference between the first line-to-earth voltage the second line-to-earth voltage, a ratio of the first line-to-earth voltage to the second line-to-earth voltage, a difference between the first line-to-earth voltage and half of the line-to-line voltage, or a ratio of the first line-to-earth voltage to half of the line-to-line voltage. This earth voltage imbalance is typically most accentuated towards the end of the isolation interval, which is the recommended time at which to take the voltage measurements. It is also preferred to sample the voltage from each voltage sensor at approximately the same time to reduce the magnitude of error. Similar to other methods described herein and in prior art such as Mlyniec '494, it may be preferable to measure a plurality of voltages with each voltage sensor to provide robustness and resilience against disturbances.

In a third embodiment, the switch voltage sensors are used to detect the line-to-earth imbalance during an isolation interval. The method and apparatus for this method are identical to that for cross-port fault detection using the switch voltage sensors, and similarly applies to both unidirectional and bidirectional switches. The primary differences between the implementation for cross-port fault detection versus line-to-earth fault detection are the required response time and thresholds (positive or negative). Since each type of fault (i.e., cross-port fault or line-to-earth fault) has a different effective circuit when a fault is present, and since each type of fault has different shock detection requirements (e.g., cross-port faults use a more permissive heart-current factor of 0.4 compared to the heart-current factor of 1 for line-to-earth faults in UL 1400-1), the design requirements to define the thresholds and the response time must consider each type of fault and use the worst-case threshold and response time combinations to ensure all required faults are always detected; wherein these threshold and response time combinations can be determined through circuit analysis and mathematical means known in the art.

As mentioned previously, the AE-side Y-capacitance sizing can impact the fault behavior, and this, in turn, affects the magnitude of the voltages measured by the voltage switch sensors. As the Y-capacitance voltage balance transitions towards a new voltage balance as dictated by the voltage divider formed by the line-to-earth fault resistance and the other relevant resistances in the circuit such as the current-limited center-tied earth circuit, there is a lesser voltage magnitude observed by the switch voltage sensors. This lesser magnitude can make it difficult to set an appropriate limit to detect the line-to-earth fault without resulting in being overly sensitive that results in false positives due to other small circuit oscillations or error, among other causes. In these cases, however, there may be additional mitigation; and in some cases, no response may be required at all.

Beginning with the case of not requiring any response, when either the current through the fault (i.e., fault current) or the voltage across the fault (i.e., fault voltage) is below a let-go limit as defined by an appropriate specification (e.g., UL 1400-1), no response is required provided that it remains below this level for a minimum amount of time (e.g., 3 seconds per UL 1400-1) if the fault current and fault voltage previously exceeded the let-go limit for at least some amount of time. In order for this to be completely true, the fault current must also not exceed the magnitude-duration shock limit as defined by an appropriate specification (e.g., UL 1400-1) prior to the fault current or fault voltage reaching below a let-go limit. These specifications, in combination with the worst-case circuit analysis and the range of fault resistances that must be detected, provide the bounds by which the thresholds and response time for line-to-earth fault detection via the switch voltage sensor imbalance can be derived using circuit analysis and mathematical means known in the art.

Continuing to the additional mitigation methods, a recommended circuit to include in the design of the system is an Earth Voltage Monitor (EVM) circuit. This circuit, which monitors the line-to-earth voltage on the AE-side of the circuit, sets bounds for at least the maximum line-to-earth voltage that is permitted without registering a fault. In a preferred embodiment, this EVM circuit further sets bounds for the minimum line-to-earth voltage as well. This mitigation method and apparatus can be implemented as an EVM circuit for each line to earth, or it can allow composite approaches, such as one EVM circuit and a line-to-line voltage monitor on the same AE-side of the circuit, where the bounds defined by each of these circuits effectively creates at least a maximum and typically also a minimum for each line-to-earth voltage.

With this EVM, the maximum fault voltage for a line-to-earth fault is limited, which limits the maximum line-to-earth fault resistance that must be detected based on the minimum let-go current limit at the maximum fault voltage. With a minimum fault voltage also enforced by the EVM, this provides further constraints that allow less restrictive thresholds and response times for the switch voltage sensor imbalance to be derived.

With unidirectional switches, an additional design constraint that can be altered is the sizing of the Y-capacitance. While a minimum amount of Y-capacitance may be required for other design requirements such as power supply stability, filtering, and EMC; in many designs, adding more Y-capacitance is permissible. Since the size of the Y-capacitance is a key element in deriving the thresholds and response times, this can provide additional control. More Y-capacitance will keep more fault resistances easier to detect with a higher switch voltage sensor imbalance magnitude, but will slow how quickly the fault current and fault voltage can decay below a let-go limit or outside of an EVM threshold. This trade-off may provide a better balance and more margin in staying below the magnitude-duration shock limit as can be determined through analysis.

An additional detail in incorporating EVM circuit operation is that the EVM circuit does not determine to which channel the line-to-earth fault is connected. As a result, in a simplest embodiment, an EVM circuit registering a fault will result in faulting out all channels connected to that same isolation plane. This can be a significant impact since this can result in an outage that is much larger than the single channel to which the fault is connected. An alternative to this action is for the EVM circuit to work in tandem with the switch voltage sensors of the channels. One embodiment of this is a controller incorporating the measurement data (i.e., line-to-earth voltage, switch voltage) or the conclusion of the individual methods (i.e., EVM circuit outside of acceptable range, switch voltage above or below a threshold) to identify the most likely channel to which the line-to-earth fault is connected and faulting out that channel before other action is taken. This requires enough response time available such that, if that is not the correct channel, there is still enough time to turn off another channel that meets these criteria or to fault out all channels within the required amount of time. An ideal embodiment of this method is performed by each channel, taking in only the line-to-earth voltage from the EVM circuit or the conclusion of the EVM circuit method so that each channel can make its own decision. A preferred enhancement is that the EVM circuit define 2 acceptable ranges-a first, narrower range to detect a line-to-earth fault is present but no action is required yet (e.g., to permit each channel to evaluate and potentially take action); and a second, wider range to detect a line-to-earth fault is present and immediate action is required.

With bidirectional switches, the Y-capacitance does not have as much of an impact, normally making line-to-earth faults easier to detect reliably in most cases. An additional factor becomes significant, however, in this case when multiple transmitter outputs are each connected to a distinct receiver front-end wherein each receiver front-end connects to the same output and conditioning circuit. This enacts a coupling through the receiver since the coupling is no longer dominated via current paths through the common AE-side of the transmitter's outputs. In this case, for each transmitter in an isolation interval concurrently, each of these transmitter outputs observes a switch voltage sensor imbalance.

Many methods to mitigate this effect can be used. In a first solution, when a switch voltage sensor imbalance is observed, each transmitter can attempt to alter or stagger the timing of their respective isolation interval. This may not be feasible in all cases due to required response times, and it can be prone to additional collisions. These collisions can be minimized via randomization, or they can be minimized and possibly eliminated by staggering based on the magnitude of the switch voltage sensor imbalance observed since this magnitude will be maximized for the transmitter to which the line-to-earth fault is connected. This introduces a second solution, wherein the fault response time can be distinct for different thresholds. In most cases, this will enforce that the transmitter to which the fault is connected will fault out sooner since the other transmitters will allow more time before faulting out; and after the transmitter connected to the fault registers the fault (e.g., responds by opening its main switches), the remaining transmitters will stop observing the switch voltage sensor imbalance. This plurality of threshold and response time combinations can be the same ones already derived for line-to-earth fault detection as described previously without this consideration; or additional threshold and response time combinations can be defined based on this receiver coupling effect to reduce the probability of false positives.

Similar to cross-port faults, the usage of switch voltage sensors for line-to-earth faults enables a benefit in the form of additional diagnostic information to aid in troubleshooting; specifically, identifying the line channel and the line involved in the line-to-earth fault. In many other embodiments such as relying solely on an EVM circuit to fault out all channels connected to an isolation plane when a line-to-earth fault is detected, it is not determined which channel is connected to the fault, and this faulting out of all channels can be excessively disruptive. A post-fault algorithm can be implemented to identify the channel connected to the fault after faulting all channels out, such as by turning channels back on one at a time and looking for a line-to-earth fault using the methods disclosed herein, but this does not prevent the original large outage, and such a post-fault algorithm can be time consuming.

With switch voltage sensors, the channel to which the fault is connected can be identified since it will be the only one with the measurable characteristics indicative of a fault (e.g., a large switch voltage sensor imbalance), or it will be the channel with the most prominent characteristics indicative of a fault (e.g., the largest magnitude switch voltage sensor imbalance). In addition to identifying the channel connected to the fault, the individual line of the channel connected to the fault can be identified based on the polarity of the switch voltage sensor imbalance. For example, in a DC-based system, a switch voltage sensor imbalance measured as a larger magnitude switch voltage across a positive switch relative to a smaller magnitude switch voltage across a negative switch is indicative of a line-to-earth fault present from the positive side to earth.

As mentioned, these switch voltage sensors can be used for many other purposes. One such purpose is detection of switch failures, particularly switches failing short since a switch failing open does not result in a potentially hazardous condition.

Without said switch voltage sensors, switch failures must be detected by other means. This includes methods such as seeing a negligible difference in voltage between the end of the power transfer interval and the end of the isolation interval (or similar values indicative thereof) and seeing excessive output voltage or output current during operational states wherein the transmitter should be in an isolated or current-limited state. A switch test routine can be executed before the transmitter begins any low or high power transmission by closing a first switch on one side (e.g., the negative side switch) and looking for an excessive output voltage or an excessive output current through a second switch on the other side (or an excessive output current through the first switch since this should not conduct current either). In an ideal embodiment of this, both the output voltage and the output current are measured while the first switch is closed; as this, in combination with the voltage on the AE-side of the transmitter, provides a means to calculate a value indicative of the effective resistance of the second switch that is nominally open; wherein a fault can be registered if this effective resistance is too low. Alternatively, a target resistance threshold can be used to determine the thresholds for the output voltage and output current, wherein exceeding a threshold for the output voltage or exceeding a threshold for the output current results in registering a fault. This switch test routine can be executed with or without the output of the transmitter shorted or maintained with a low impedance across its output as is done in at least one embodiment of mitigating a fault after detection.

With these switch voltage sensors, switch failures can be detected by monitoring the voltage measured across each switch. Similar to cross-port fault behavior described herein, with a switch failed short, that failed short switch will show little or negligible voltage drop across it while any substantial voltage drop that does exist will be present a switch distinct from the failed short switch. One difference between a switch failure and a cross-port fault is that the switch failure behavior is not dependent on the time constant for the equalization circuit present with a cross-port fault (unless the switch failure is present at the same time as a cross-port fault), wherein the switch failure behavior features a time constant that is predominantly defined by the crossline characteristics of the transmission line to which the failed switch is connected. Another difference is that the cross-port fault current substantially stops conducting when the equalization point is reached and further voltage changes are reduced, while the failed switch behavior is such that the voltage drop across the non-failed switch will continue to rise so long as the crossline voltage of the transmission line to which the failed switch and non-failed switch are connected continues to decay. Yet another difference is that a switch conducting a cross-port fault current through a unidirectional element such as a diode will feature a forward voltage drop while a failed switch will not present such a forward voltage drop when fully failed. A partially failed switch that is not fully equivalent to a short circuit may have a larger voltage drop; but typically this progresses into a short circuit, especially with voltage across the switch or current flowing through the switch.

The thresholds for failed switch detection can be implemented in a number of ways, most of which are similar to cross-port fault detection threshold implementation. In a first method, the difference between switch voltage sensors is compared to a predetermined threshold, and a failed switch fault is determined when the predetermined threshold is exceeded. In this comparison, the absolute value of the difference can be used, or a lower and upper threshold can be used to account for the fact that the difference will have an opposing polarity depending on which switch is failed and which sensor is subtracted from which. In a second method, each switch voltage sensor measurement can be compared to a first predetermined threshold and a second predetermined threshold. With the switch voltage sensors oriented to measure a positive voltage polarity, if the measurement for a first switch is below the first threshold and the measurement for a second switch is above the second threshold, this is indicative of a failed switch (i.e., the first switch) and a fault is registered. This second method is tailored more specifically to the characteristics of a failed switch wherein the failed switch will have low voltage across it. Hence, the first predetermined threshold should be set to the maximum voltage expected when a switch is failed and must be detected, while the second predetermined threshold is set to the minimum voltage level expected to be reached given at least the first predetermined threshold and the voltages of the AE-side and DE-side of the circuit.

When performed during an isolation interval, the second predetermined threshold can further consider the nominal minimum amount of decay observed across the transmission line to which the switches are connected. A combination of the first and second method can also be used, such as using the first method to determine a fault is present and augmenting this with at least a comparison of the first predetermined threshold of the second method to determine if this is more likely to be a failed switch or a cross-port fault. When used during a different state of operation, such as when the system is nominally off or isolated and the switches are tested for failures prior to beginning low or high power transfer, the first method and second method are still applicable, though different thresholds may be chosen to account for different circuit conditions at the time. For example, at start-up, it is not expected that the transmission line will have any substantial charge and should therefore have a crossline voltage of approximately 0V. This can make detection easier since, with an AE-side voltage of 400V and a first switch that is failed short and a second switch that is not failed, there should be approximately 0V across the first switch and approximately 400V across the second switch per Kirchoff's Voltage Law (KVL).

As shown in FIG. 7, this can be done for unidirectional switch configurations, wherein this is shown at the transmitter. As shown in FIG. 9, this can be done for bidirectional or back-to-back switch configurations, and it can be done for receivers in addition to being done for transmitters. With a single voltage sensor around the pair of switches (e.g., 967) as shown in FIG. 9, this may only detect when both switches are failed short (e.g., 969 and 937), or this may detect when one switch is failed short (e.g., 937) but this may not detect when the other switch is failed short (e.g., 969) depending on the orientation; but in these cases where the failure is not detected, a safety issue is not present and this only results in operation in a degraded state such as reduced EMC robustness.

To detect single switch failures reliably with a bidirectional switch configuration wherein each bidirectional switch comprises at least 2 unidirectional switches connected “back-to-back”, additional operations are performed to accentuate the fault characteristics. This back-to-back arrangement will be described in this context for n-channel MOSFETS, which means that this back-to-back arrangement can be common source (i.e., body diode anodes connected together) or common drain (i.e., body diode cathodes connected together). In all of these embodiments, the detection method remains the same wherein a fault is registered when a voltage across a unidirectional switch is approximately 0 or not substantially large as described previously; as these embodiments describe the different circuit apparatus and methods of operating said circuit apparatus to enable said detection method.

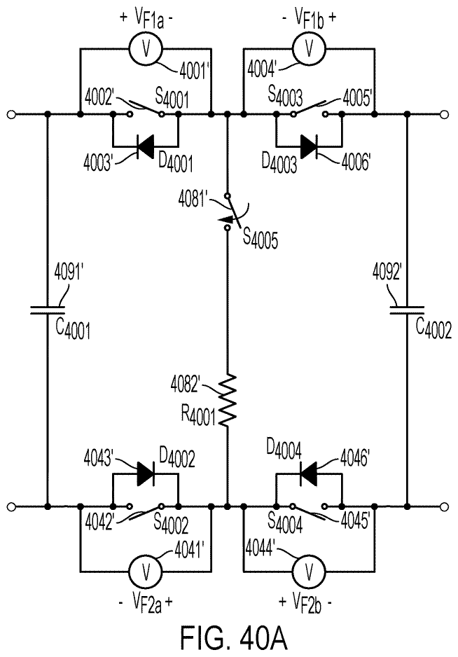

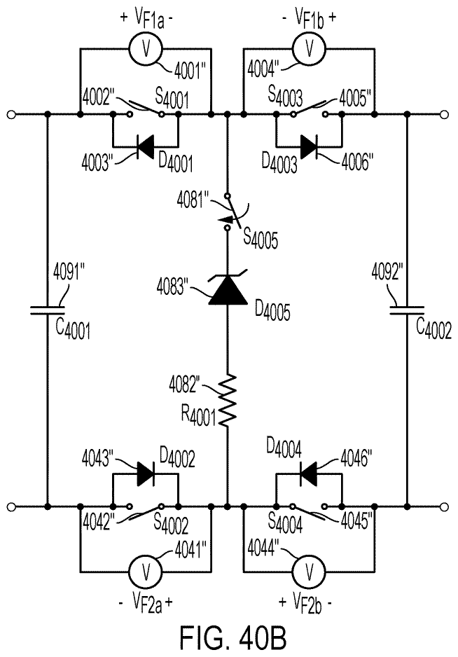

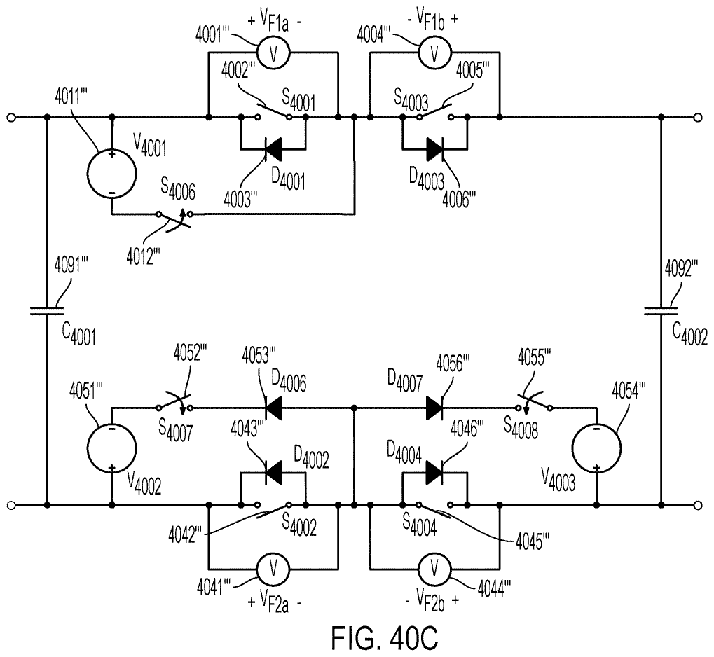

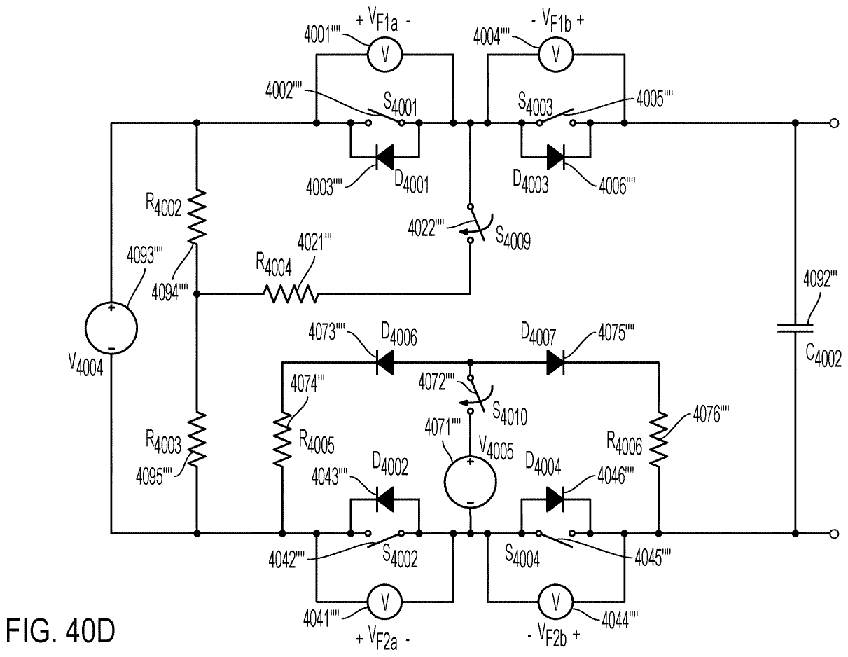

These various embodiments and aspects are shown in FIG. 40A, FIG. 40B, FIG. 40C, and FIG. 40D; wherein callouts for substantially equivalent components use the same number; and each callout is appended with a single prime symbol, double prime symbol, triple prime symbol, or quadruple prime symbol, respectively, to indicate the specific figure to which it belongs when necessary to distinguish. In all figures, a first bidirectional switch comprises unidirectional switches typically on a higher potential side, wherein the unidirectional switches comprise switches 4002 and 4005 with associated respective diodes 4003 and 4006 and with respective switch voltage sensors 4001 and 4004 measuring the voltage across each respective switch. This is similarly repeated for a second bidirectional switch that comprises unidirectional switches typically on a lower potential side, wherein the unidirectional switches comprise switches 4042 and 4045 with associated respective diodes 4043 and 4046 and with respective switch voltage sensors 4041 and 4044 measuring the voltage across each respective switch. Note that the orientation of diodes 4043 and 4046 along with the polarity of switch voltage sensors 4041 and 4044 are reversed in FIG. 40A and FIG. 40B relative to FIG. 40C and FIG. 40D. As with other figures, any effective capacitance in parallel with a switch (e.g., drain-to-source capacitance of a MOSFET) is not depicted for simplicity but may contribute to the circuit dynamic response. As will be explained in more detail, these embodiments are largely classified as either active or passive depending upon whether an active source (voltage or current) is part of the circuit or not, respectively.

In a first embodiment of single unidirectional switch failure detection with bidirectional switches comprised of at least 2 unidirectional switches, in at least a DC system comprising a positive side (i.e., a higher potential side) and a negative side (i.e., a lower potential side), the AE/DE switching barrier circuit is arranged with the positive side bidirectional switch as common source and the negative side bidirectional switch as common drain as shown in FIG. 40A. The circuit further comprises a passive bias circuit comprising a series combination of a bias switch 4081 and a bias resistance 4082 connected between the positive side common source and the negative side common drain. Completing the representative circuit are crossline capacitances 4091 and 4092. During an isolation interval, the bias switch 4081 is closed in an attempt to reverse bias each body diode (or equivalent unidirectional switch element) of each unidirectional switch comprising the bidirectional switches. By measuring the voltage around each unidirectional switch, any voltage that is approximately 0V or not substantially positive is indicative of the respective unidirectional switch being failed short.

In this passive bias circuit, while the bias resistance 4082 could be omitted and replaced with a short (i.e., a small resistance), proper selection of the bias resistance value will protect the switches from excessive currents while still allowing the change in voltage to be measurable within an allotted amount of time.

Since closing and opening the bias switch 4081 can alter the decay characteristics on the DE-side of the circuit that are used for other fault detection methods such as those described by Eaves '637, this alteration must be taken into consideration. One way to account for this alteration is to factor the magnitude of the effect into the other fault detection methods such as by changing the limits used to detect faults using those methods. In many cases, however, the effect will not be a simple one, so this method may be best when analysis shows the effects to be minimal. Another way to account for this alteration is to use time multiplexing methods to only close the bias switch for a time interval distinct from other time intervals used for other safety methods. This can be as simple as reserving a small amount of time at the end of an isolation interval for closing the bias switch and taking voltage measurements for this switch failure detection method. A relationship between the time allotted for the switch failure detection method and the time constants involved in the circuit over the range of supported operation can be analyzed to determine the design parameters such as the duration of the time interval to allot to the switch failure detection method and the magnitude of the bias resistance.

Other variations of this switch failure detection method and apparatus exist. The passive bias circuit can further comprise a Zener diode 4083 added in series with the bias resistance 4082 and bias switch 4081 to only clamp the positive side common source to the negative side common drain down to a threshold voltage as shown in FIG. 40B, thereby reducing how much energy must be replenished after opening the shunt switch and starting the next power transfer interval. In another variation, a controller (e.g., transmitter controller) can be configured to operate the bias switch 4081′ to mimic this Zener diode effect wherein the bias switch 4081′ is opened once a threshold voltage is reached or when the voltage measurement for each unidirectional switch of the bidirectional switches is confirmed to be substantial enough to affirm that no unidirectional switch is failed. In this variation, the passive bias circuit may further comprise a bias voltage sensor to measure a voltage indicative of the voltage across the bias resistance 4082′, wherein the bias switch 4081′ is opened when the voltage is below a threshold voltage. In yet another variation, instead of a bias switch and a bias resistance connected from positive side common source to negative side common drain as described, a first passive bias circuit comprising a series combination of a first bias switch 4022 and a first bias resistance 4021 can be connected between the positive side common source and a center-tie node, and a second passive bias circuit (not depicted) comprising a second series combination of a second bias switch and a second bias resistance can be connected between the center-tie node and the negative side common drain; wherein the center-tie node may be defined as the common node connected to resistors 4094 and 4095 to split voltage supply 4093. This may only be applicable if the voltages across the unidirectional switches are not expected to exceed half of the voltage on the AE-side; and this may be most applicable to low-impedance paths for the center-tie node, such as with a split-rail design; but this nevertheless shows that equivalent arrangements are possible using the elements of the method and apparatus disclosed herein.

Continuing with these concepts, in another embodiment that allows the negative side bidirectional switch to use a common source arrangement, during part of an isolation interval, the common source of each bidirectional switch (i.e., positive side and negative side) can be driven with a negative voltage relative to the drain of at least one of the unidirectional switches for a respective bidirectional switch. This effectively forces each unidirectional element to be reverse biased, wherein a lack of a measurable reverse bias voltage is indicative of a failed switch.

Many variable embodiments of this circuit exist. In a first embodiment, an active reverse bias circuit comprising a series combination of a reverse bias voltage source and a reverse bias switch is connected across the drain and source of a unidirectional switch element of a bidirectional switch such that the reverse bias voltage is oriented with the positive terminal towards the drain. This is shown on the higher potential side in FIG. 40C with reverse bias voltage source 4011 and reverse bias switch 4012. This works most effectively when a large reverse bias voltage is used to ensure both unidirectional switches of a bidirectional switch will be nominally reverse biased; or when the worst-case configuration is identified based upon which unidirectional switch comprising a bidirectional switch will have the lower drain voltage, and connecting the reverse bias circuit across said unidirectional switch. This may be further enhanced by the reverse bias voltage being varied during operation, such as a controller (e.g., transmitter controller) sensing a voltage indicative of the voltage of the drains of a bidirectional switch and adjusting the magnitude of the reverse bias voltage to ensure it is large enough or reducing it from an excessively high magnitude; and this may eliminate the need for an explicit reverse bias switch (e.g., 4012), replacing said reverse bias switch with a short, especially if the reverse bias supply is inherently current-limited as a self-protection feature so long as the activation of this current-limiting effect can be detected or is indicated.

In a variation of this embodiment, an active reverse bias circuit can be connected across each unidirectional switch comprising a bidirectional switch. Since this will result in contention between the reverse bias voltage supplies as well as provide an unintended circuit path between the AE-side and the DE-side of the circuit, in a preferred embodiment of this variation, the reverse bias circuit further comprises a reverse bias diode in series with the other active reverse bias circuit elements, wherein the orientation of the reverse bias diode is the same as the orientation of the unidirectional switch. This is shown in FIG. 40C as reverse bias voltage supplies 4051 and 4054 with respective reverse bias switches 4052 and 4055 along with respective series reverse bias diodes 4053 and 4056. This ensures that the common source uses the lower of the possible voltages provided by the active reverse bias circuits for a bidirectional switch. An advantage is that, since the worst-case is always captured, a small reverse bias voltage can be used that allows a measurable voltage with respect to sensing accuracy, diode forward voltage drop, and circuit response time.

In a preferred embodiment of the active reverse bias circuit, the active reverse bias circuit is reconfigured to comprise a series combination of a reverse bias voltage supply and a reverse bias switch. In this embodiment, the active reverse bias circuit further comprises a reverse bias diode for each unidirectional switch comprising the bidirectional switch. The reverse bias voltage is oriented with the positive terminal towards the anodes of the reverse bias diodes, with the cathode of each reverse bias diode connected to the drain of a respective unidirectional switch comprising the bidirectional switch. This consolidates the previous variation requiring a reverse bias voltage supply for each drain to only requiring a single reverse voltage supply while still retaining the advantage of using a smaller reverse bias voltage. This is shown in FIG. 40D as reverse bias voltage supply 4071 and reverse bias switch 4072 that then splits to diodes 4073 and 4075 in series with respective resistances 4074 and 4076.

While the reverse bias switch is described as being in series with the reverse bias voltage supply, this may alternatively be configured instead as a reverse bias switch in series with each reverse bias diode. Without a reverse bias switch for each reverse bias diode, the design will need to consider that, during a power transfer interval, the reverse bias diodes may conduct substantial power depending on the voltage drop across the respective unidirectional switch. Alternatively, in some embodiments, reverse bias switch 4072″″ can be omitted and replaced with a short since nominally the reverse bias supply 4071″″ should not conduct significant current nor contribute to any significant alteration of measurements taken for other purposes such as executing the safety algorithm of Eaves '637 and others disclosed herein.

While these single unidirectional switch failure detection methods for bidirectional switches are typically used as described, many of the embodiments can be mixed with elements of another embodiment. For example, as shown in FIG. 40D, the positive side bidirectional switch may use an embodiment of a passive bias circuit that pulls the common source to a lower voltage node such as a center-tie since this is readily available; but the negative side may use an active reverse bias circuit to allow the bidirectional switch to still be used in a common source arrangement.

Switch failure can also be detected with a small leakage current or larger conducting through the switch when nominally in a non-conducting or isolated state. The current sensor (e.g., 717; e.g., 3147) to sense this current is typically designed with a small sensing range in order to maximize the signal to noise ratio. When sensing small currents, consideration is required for details such as a MOSFET switch containing an intrinsic drain-to-source capacitance that will conduct some current in normal operation for a duration of time. Such a current from an intrinsic capacitance requires this to be factored into the limit or to measure for a current indicative of a failed switch when current through the intrinsic capacitance is sufficiently reduced, among other solutions.

When a failed switch is detected by any means, it is preferred to take additional action to create a safer condition. A first action that can be performed is to desist from further attempts to start-up until the device is serviced. This state can be stored in non-volatile memory so that the desisting from further attempts to start-up persists through power cycling of the device. It may be advantageous to confirm the failed switch with a plurality of tests prior to taking this action to avoid possible false positives. Other actions include clamping the output of the device or activating a crowbar circuit to clear a fuse to reduce the risk of shock. In devices that feature secondary switches or control over the power supply, these can also be operated to put the device into a safe state (i.e., open secondary switches; i.e., turn off or limit the power supply). With bidirectional switches that are comprised of 2 or more unidirectional switches in a back-to-back arrangement, if only 1 of the unidirectional switches is failed, the system may be able to continue operating in a degraded state depending on which unidirectional switch is failed (e.g., still blocks energy transfer from the AE-side to the DE-side during isolation intervals) and may perform actions such as warning a user, only operating for a limited amount of time or power, or performing a graceful shutdown of load equipment.

Detecting switch failures during or prior to start-up (i.e., before enabling high-power transfer) can be performed using many of the similar methods. Returning to the previously described switch test routine, instead of measuring the output voltage and the output current, the voltage across the switch itself can be measured to determine if a failed switch is present. When no failures are present and the DE-side of the circuit has been isolated from the AE-side of the circuit for a substantial amount of time, the output voltage will be approximately 0V, particularly in preferred embodiments wherein the output (i.e., the DE-side) is clamped. Alternatively, the AE-side voltage and DE-side voltage can be measured. This means that the voltage difference between the AE-side of the circuit (e.g., 400V from a power supply for a transmitter) and the DE-side of the circuit must be dropped across the switches in the AE/DE switching barrier. Nominally, the effective impedance of the switches (e.g., 705 and 711; e.g., 211 and 221) should be approximately equal, so the voltage drop on each switch should be approximately half. When a substantial departure of this balance is observed, this is indicative of a failed switch. Thus, the method measures a voltage drop across each switch, calculates a difference in voltage, compares the difference to a threshold, and registers a fault when the difference is above a positive threshold or below a negative threshold. The polarity of the difference and the polarity of the switch voltage sensors provide the insight to determine which switch has failed as can be determined with simple circuit analysis. Note that, in scenarios where both switches are failed, other detection mechanisms may be preferable to use to complement this method, such as detecting a high output current or high output voltage when all switches are nominally open (i.e., isolating the AE-side from the DE-side when no failed switch is present).

This method of a switch test routine using switch voltage sensors works for unidirectional and bidirectional switches; however, this is only fully true for bidirectional switches that are fully bidirectionally blocking (e.g., an electromechanical relay). For bidirectional switches comprising back-to-back unidirectional switches, additional measures are required in order to identify some of the failure cases since one unidirectional switch comprising a bidirectional switch will typically not have a substantial voltage drop across it due to the unidirectional nature and the orientation of the said unidirectional switch. In these cases, the methods and apparatus described for detection during an isolation interval can be adapted here, wherein the options include at least using a passive bias circuit or an active reverse bias circuit connected for a time interval during a switch test routine; wherein the previously described detection means (e.g., voltage exceeding a threshold) are still applicable using the same or a different threshold to account for different tolerances depending on the state of the system.

Setting an appropriate threshold for detecting a failed switch in a switch test routine during start-up using switch voltage sensors takes some consideration. While in an ideal case a failed switch is indicated by any switch voltage sensor imbalance that is not approximately 0V, other circuit effects can introduce complications. One such complication is presented when there is another leakage path between the AE-side of the circuit and the DE-side of the circuit, even if it is a high-impedance path. Such a leakage path can be introduced by the switch voltage sensors themselves if the switch voltage sensor for each switch is referenced to the same digital ground. When this leakage path exists, a first channel with a failed switch will show a switch voltage sensor imbalance, but so too will a second channel connected to the same AE-side without a failed switch. One way to solve this is to use a threshold of plus or minus half of the AE-side voltage. Switch voltage sensor imbalances that are above half of the AE-side voltage or below half of the negative of the AE-side voltage are indicative of a failed switch on that channel. Another solution is to increase the isolation between the AE-side and the DE-side, such as using isolated sensors to eliminate the high-impedance leakage path. An isolated sensor can utilize an isolated op-amp to provide isolation from the digital ground reference. Alternatively, an isolated sensor can comprise a sensor, an analog to digital converter (ADC), and an isolated communications interface connected to the ADC; all of which is on its own isolation plane such that it does not result in a leakage path between the AE-side and the DE-side.

Another complication arises when a plurality of transmitter channels connected to the same AE-side of the circuit are each connected to a distinct receiver front-end, wherein each receiver front-end is connected to the same receiver output control and conditioning circuit. Using a receiver that features unidirectional switches such as diodes in its AE/DE switching barrier, a coupling effect through the receiver circuitry exists when a switch is failed on one of the transmitter channels when the receiver is not already powered by another transmitter channel or is not storing a substantial amount of charge at a substantial voltage. In this case, the failed switch of a first transmitter channel establishes a voltage potential for that line of the receiver front-end connected to that first transmitter channel, and the resulting voltage dividers through the circuit result in a substantial switch voltage imbalance being observed on each of the other transmitter channels.

One way to resolve this is to use high-impedance input receivers, such as the hot-pluggable receiver disclosed in Lutz '603. Another solution is to use an actively switched receiver design such that bidirectional switches are used, thereby blocking or substantially limiting the path the enables this coupling effect. Yet another solution is for each transmitter channel to connect a current-limited circuit in parallel with a switch for each of its switches under test and to perform the methods previously described for detecting a switch failure during a switch test routine at start-up using switch voltage sensor imbalance. This dominates the coupling effect enough to allow a measurement to be taken after a delay to allow system capacitances to charge and discharge enough for the effect to be seen. It is not necessary to wait for the capacitances to fully charge or discharge since the switch voltage sensor imbalance for the transmitter with a failed switch will remain approximately constant when it connects its own current-limited circuits. The current limited circuit can be as simple as a current-limiting resistance that is in series with a switch so that it can be connected in parallel with a switch under test. A common embodiment of this current-limited circuit is the same as the one used by a transmitter to soft-start a receiver, such as soft-start switch 213 and soft-start resistance 212.

An additional benefit of this switch test routine is that it can also detect an imbalance of the soft-start circuit when the soft-start circuit is designed to be equivalent for each line (i.e., approximately the same resistance or same magnitude current-limiting effect). By connecting each soft-start circuit for a transmitter simultaneously, the switch voltage sensors can measure the voltage across each soft-start circuit, and a switch voltage sensor imbalance that is not approximately 0V is indicative of an internal failure and can register a fault. This can detect if the main switch in parallel with the soft-start circuit is failed as well as detect a mismatch in the current-limiting effect (e.g., the soft-start resistance) between each soft-start circuit for a transmitter, thereby also detecting what may be a reduction in the current-limiting efficacy. This is not necessarily true if multiple failures occur simultaneously, but the more probable failure modes of a single or imbalanced failure can be detected by this method. This same method can similarly be applied throughout soft-start, thereby detecting if the current-limiting design is compromised and registering a fault to avoid any potential shock risk if the safety of the design was predicated on the magnitude of the current-limiting effect.

A combination of methods can be used to comprise a multi-step switch test routine, and this can be effective at addressing the complication of a plurality of transmitters coupling through a common receiver via multiple receiver front-ends. In one embodiment, a first switch test routine is executed by measuring the voltage across each switch. If the voltage across a switch is low, the switch is considered not to be failed as described previously. If the voltage is high, it can be further examined. If the voltage is approximately equal to the difference between the AE-side voltage and DE-side voltage, the switch is likely failed. If the voltage is not quite equal to the difference between the AE-side voltage and the DE-side voltage (e.g., the voltage is 97% of the difference), this may be indicative of a false positive due to a failed switch on a distinct transmitter. In this case, a second switch test routine can be executed; such as the method of connecting a current-limited circuit in parallel with each switch under test and measuring the voltage across the switch, or the method of connecting the switch distinct from the suspected failed switch and measuring the output voltage and current as previously described, or a method of closing the suspected failed switch and monitoring if a significant change in the voltage across the switch is observed (e.g., the voltage equals approximately 100% of the difference in voltage between the AE-side and the DE-side). Other switch test routine combinations to comprise a multi-step switch test routine are possible.

While many of these embodiments of cross-port fault detection, switch failure detection, and similar methods are described primarily in the context of a DC system comprising a positive side and a negative side, they can similarly be applicable to other power formats and architectures. Consider a 3-phase AC system that not only has at least 3 live wires but also has each live conductor reach a positive voltage and a negative voltage with respect to each other live conductor at different times during the AC cycle. At any given time, the circuit can be viewed as one of these embodiments for each pair of lines and iteratively evaluated as such (e.g., between a first set of 2 lines, when available voltage is high enough, evaluate cross-port; then between a second set of 2 lines, when available voltage is high enough, evaluate cross-port; and so on for all combinations of lines as the set of lines). This may require apparatus to include components that reverse polarity, such as a reverse bias voltage supply that can be switched between a positive voltage and a negative voltage depending on the polarity of the lines being tested at the time.

With respect to the usage of switch voltage sensors, three primary types of faults have been described herein as ones that can be detected using switch voltage sensors: cross-port faults, line-to-earth faults, and failed switch faults. Many of these have overlapping detection methods or requirements, but in some cases, differentiation of exactly which type of fault occurred is desired. For example, notifying a user that a cross-port fault occurred will result in different troubleshooting and resolution steps than a failed switch fault. In addition to this, the type of fault can impact the design requirements, and a lack of distinction can make requirements overly restrictive. As described previously, unless the type of fault can be distinguished while detecting the fault, the worst-case threshold and response time requirements of each of the applicable types of faults must be used.

One distinguishing feature that can be leveraged for line-to-earth faults is that a line-to-earth voltage imbalance can also be measured on the AE-side of the circuit. This imbalance can be detected at the same time that the switch voltage sensor imbalance is measured, or the imbalance can be measured at a distinct time such as at an earlier time so that the information is available when the switch voltage sensor imbalance is detected so that an informed determination can be made. Similarly, after registering the fault for a channel and activating a fault response mechanism such as turning the channel off, a restoration of the line-to-earth balance on the AE-side of the circuit is observed when a line-to-earth fault was connected to that channel, which can help distinguish the type of fault after the fault is registered but before notifying the user.

A distinguishing feature of a cross-port fault is that, as described in other embodiments, a large initial voltage drop is often observed, at least with unidirectional switches. This feature can be used to complement the cross-port fault detection method of using the switch voltage sensor imbalance. In such an embodiment, a fault is registered upon the switch voltage sensor imbalance exceeding a threshold; but the presence of a large initial voltage drop is used as secondary information to classify the type of fault as likely being a cross-port fault. This information can be used in combination with the line-to-earth voltage balance on the AE-side of the circuit as described above to further establish the most probable type of fault. Another method to reasonably conclude that a fault is a cross-port fault is realized when a controller is provided with information from a plurality of transmitter outputs or receiver inputs on the same isolation plane. The controller can use this information to identify transmitter outputs or receiver inputs that detect opposing fault conditions. For example, the controller only observing a fault on a single transmitter output or a single receiver input may classify the fault as most probably a line-to-earth fault; but if a first transmitter output reports a fault due to a switch voltage sensor imbalance of one polarity at approximately the same time that a second transmitter output reports a fault due to a switch voltage sensor imbalance of the opposite polarity, the controller may classify the fault as most probably a cross-port fault.

Finally, failed switch faults are most easily distinguished by the switch voltage sensor imbalance continuing to exist after activating a fault response mechanism such as attempting to nominally isolate the AE-side from the DE-side. This is most effective when the DE-side is also clamped line-to-line. Once this is done, cross-port faults and line-to-earth faults will no longer exhibit any substantial switch voltage sensor imbalance; but when a failed switch is present, a substantial switch voltage sensor imbalance can be used to classify the fault as most probably a failed switch using the method described herein for a switch test routine.

Timing is a consideration in: all of these various embodiments that utilize detection of an imbalance; embodiments such as a switch voltage sensor imbalance for cross-port faults, line-to-earth fault, or failed FETs; a current sensor imbalance to detect cross-port faults or other miswiring faults as well as internal failures; or line-to-earth sensors to detect a line-to-earth fault or a cross-port fault. Due to capacitance, inductance, and time constants formed throughout the circuit, some effects take an appreciable amount of time to reach a fault threshold. As such, in many cases the preferred time to take measurements is as late as reasonably possible, such as near the end of an isolation interval. In some cases, such as with line-to-earth sensors for some faults, there may be an intermediate peak, such as one between the start of an isolation interval and the end of an isolation interval; but in most cases, the end of the isolation interval is still an acceptable time to take the measurements used to determine the presence or absence of a relevant fault. In some of these cases, the magnitude of the effect or the rate at which the magnitude of the effect presents can be increased through active means. One embodiment of this is connecting a crossline resistance (e.g., resistance 225 via switch 226) during an isolation interval when attempting to detect a cross-port fault via switch voltage sensor imbalance, as this can increase the rate at which the magnitude of the imbalance is reflected by the sensor measurements. This is ideally suited for usage in conjunction with the other methods that connect said crossline resistance, such as taking measurements with and without a known resistance to detect an unknown resistance as taught in Casey '067.

Summarizing the determination of the fault location for these various fault types, and describing the switches between a transmission line port and a non-transmission line port as comprising a high-side switch and a low-side switch corresponding to a high potential conductor and low potential conductor of the transmission line connected to the transmission line port, respectively, the logic is as follows.

When detecting a fault via a high-side leakage current (or reverse current) through the high-side switch from the transmission line port to the non-transmission line port or a low-side leakage current (or reverse current) through the low-side switch from the non-transmission line port to the transmission line port, the high-side leakage current exceeding a threshold indicative of a fault is indicative of the fault connected to the low potential conductor, and the low-side leakage current exceeding a threshold indicative of a fault is indicative of the fault connected to the high potential conductor.

When detecting a fault via a switch voltage imbalance, wherein the fault comprises a cross-port fault or a line-to-earth fault, upon a switch voltage imbalance exceeding a threshold indicative of the fault, a switch voltage imbalance indicative of a higher voltage across the high-side switch relative to a voltage across the low-side switch is indicative of the fault connected to the fault connected to the high potential conductor, and a switch voltage imbalance indicative of a higher voltage across the low-side switch relative to a voltage across the high-side switch is indicative of the fault connected to the low potential conductor.

Similarly, when detecting a failed switch via a switch voltage imbalance, upon a switch voltage imbalance exceeding a threshold indicative of the fault, a switch voltage imbalance indicative of a higher voltage across the high-side switch relative to a voltage across the low-side switch is indicative of the low-side switch failed short, and a switch voltage imbalance indicative of a higher voltage across the low side switch relative to a voltage across the high-side switch is indicative of the low-side switch failed short.

When detecting a line-to-earth fault via a line-to-earth voltage sensor, upon the line-to-earth voltage exceeding a positive threshold, this is indicative of the line-to-earth fault connected to a conductor distinct from the one measured. For example, when the line-to-earth voltage sensor measures from the high potential to earth, upon the line-to-earth voltage from the line-to-earth voltage sensor exceeding a positive threshold, this is indicative of the line-to-earth fault connected to the low potential conductor. Alternatively, upon a line-to-earth voltage being below a positive threshold while a line-to-line voltage is still sufficiently large, wherein the line-to-earth voltage is oriented as a positive voltage between the line and earth, this is indicative of the line-to-earth fault connected to the line that was measured by the line-to-earth voltage sensor.

As will be discussed elsewhere with respect to detecting a fault due to a current imbalance or a high residual current during a power transfer interval for at least cross-port faults or line-to-earth faults, the conductor to which the fault is connected can be identified as the conductor indicated as a higher current compared to the other conductor or conductors.

Continuing with the topic of other uses of switch voltage sensors, another useful application is for diagnostic purposes to detect sensor failures or sensor discrepancies. A prominent way to detect sensor discrepancies is by a cross-check to ensure a sensor output is approximately equal to another sensor output or a composite of other sensor outputs. In one embodiment, a first line-to-line voltage sensor can be duplicated as a second line-to-line voltage sensor measuring across the same voltage nodes, and a substantial mismatch between approximately simultaneous measurements by each of these sensors outside of tolerances is indicative of at least one of the sensors no longer being within an acceptable level of accuracy. In a second embodiment, wherein a first line-to-earth voltage sensor and a second line-to-earth voltage sensor each measure a distinct line that is measured by a line-to-line voltage sensor, the arithmetic combination of the first line-to-earth voltage sensor measurement and the second line-to-earth voltage sensor measurement is expected to be approximately equal to the line-to-line voltage sensor measurement when each measurement is taken approximately simultaneously or within an interval when no substantial voltage changes occur; and a substantial discrepancy outside of tolerances is indicative of at least one of the sensors no longer being within an acceptable level of accuracy.

With the switch voltage sensors, in combination with an AE-side line-to-line voltage sensor and a DE-side line-to-line voltage sensor, since these sensors in a 2-line system complete a loop, by Kirchoff's Voltage Law (KVL), it is expected that these voltages sum to 0V after accounting for the polarity of each sensor in accordance with applying the KVL (e.g., in FIG. 7, V_{F1,7}=V_{F1,1}+V_{F1,5}+V_{F1,2} from sensors 701, 703, 715, and 709, respectively). In an ideal embodiment, an analog op-amp circuit is used to sum the output of each sensor, with the output of the op amp compared against 0V plus or minus a tolerance. If the tolerance is exceeded, a fault is registered. Alternatively, each sensor can be sampled by an ADC and the sampled values can be summed and compared against 0V as well. In cases where a sensor may be used both for this analog op-amp circuit as well as be sampled by an ADC, the analog op-amp circuit should consider the effects of the sample-and-hold circuit of the ADC by using filtering, by including a buffer circuit before the ADC, or by examining the op-amp circuit output at a time distinct from the ADC sampling. While this is described primarily for 2-line systems, this same principle can be extended to 3-line systems such as 3-phase systems by using the same principle based upon a loop summing to approximately 0V according to the KVL.

Returning to the topic of imbalance, a significant difference between the positive and negative current sensors of a transmitter could be indicative of a cross-port fault. For example, with a 500Ω cross-port positive-to-negative fault in a 400V system, one transmitter port will see an additional 800 mA through its positive port compared to its negative port while another transmitter port will see an additional 800 mA through its negative port compared to its positive port. An advantage of this method is that this can be detected during the power transfer interval, allowing a faster response that does not require the fault current to persist until the next isolation interval. This current imbalance or residual current could be detected via separate positive and negative current sensors and compared in an analog or digital fashion; or the current imbalance could be detected by using an Ground Fault Circuit Interrupter (GFCI), a Residual Current Device (RCD), or a similar device that utilizes the electromagnetic field cancellation of the positive and negative rail currents such as a current transformer or fluxgate current sensor, yielding only the net difference in the magnitude of the current; where these devices can also be adapted for DC applications. Such a current imbalance measurement apparatus would be generalized to measure the net difference between all conductors of a given channel or port; for example, in a 3-conductor 3-phase AC system without a neutral, this current imbalance measurement apparatus would measure the net difference in current between all 3 conductors. With respect to cross-port faults, this current imbalance would be measured during at least partially concurrent power transfer intervals of at least the two transmission lines to which the cross-port fault is connected; otherwise, a current imbalance may not be measured since the current path for the cross-port fault may be impeded by the isolation of an isolation interval. While this method and apparatus have been introduced for cross-port faults, they will similarly detect line-to-earth faults.

These current imbalances due to cross-port faults could be confounded by current imbalances resulting from receivers that feature multiple PET front-ends, for example when one input conductor of one channel is disconnected, thereby causing extra current to return on other channels. In such a case, though, this is also an undesirable system state and detecting the fault is a preferred action. For higher resistance faults, the corresponding fault current is reduced, and this may present a challenge to distinguish the difference in current due to a fault from the difference in current due to other factors such as noise, offset error, and other sources of error in electrical measurement apparatus. This can be mitigated by using techniques known to one skilled in the art to counteract, account for, or eliminate such error factors. Alternatively or additionally, this current imbalance method can be used in combination with other cross-port fault methods. For example, this current imbalance method could be used for lower resistance and higher fault current scenarios that require faster detection while the higher resistance and lower fault current scenarios are handled by another method such as the disclosed initial voltage detection method.

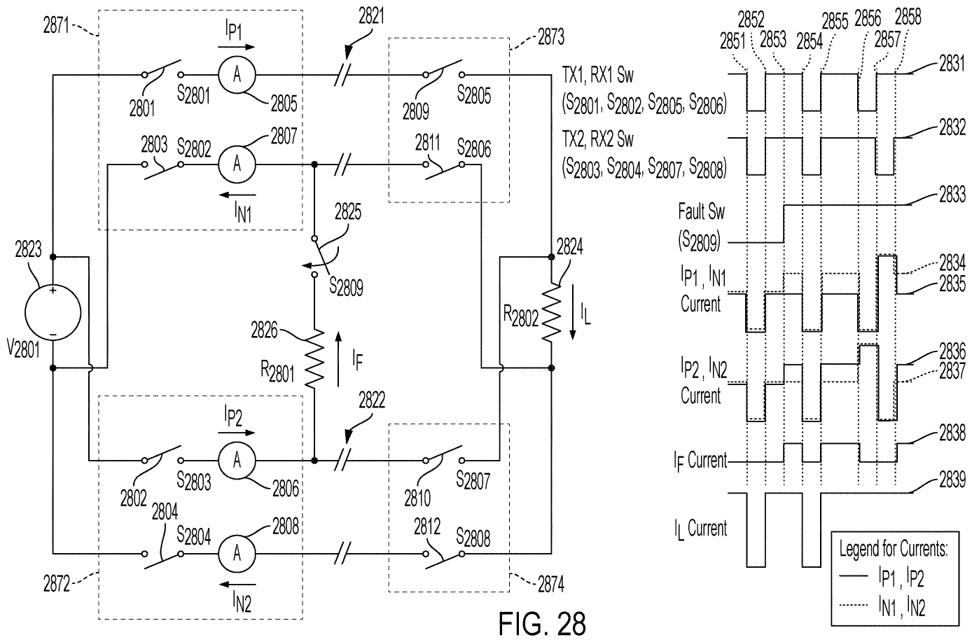

FIG. 28 shows a representative circuit along with timing diagrams and waveforms to exhibit cross-port fault detection via these current imbalance methods. The top half of the circuit corresponds to a first channel while the bottom half of the circuit corresponds to a second channel. The first channel comprises a first transmitter 2871, a first receiver 2873, and abbreviation mark 2821 to represent a variable cable length between the first transmitter and the first receiver. The first transmitter 2871 comprises switches 2801 and 2803 along with a first positive-side current sensor 2805 and a first negative-side current sensor 2807. The first receiver 2873 comprises switches 2809 and 2811. The second channel comprises elements 2802, 2804, 2806, 2808, 2810, 2812, 2822, 2872, and 2874 corresponding respectively to elements 2801, 2803, 2805, 2807, 2809, 2811, 2821, 2871, and 2873 of the first channel. Therefore, the second transmitter 2872 comprises switches 2802 and 2804 along with a second positive-side current sensor 2806 and a second negative-side current sensor 2808; and the second receiver 2874 comprises switches 2810 and 2812. The circuit further includes a source 2823 connected to the input of each transmitter and a load resistance 2824. Finally, a cross-port fault circuit is connected between the positive of the second transmitter output to the negative of the first transmitter output, wherein the cross-port fault circuit comprises fault switch 2825 and fault resistance 2826. Note that, while a variable cable length is indicated by abbreviation marks 2821 and 2822, the exemplary waveforms shown do not include effects from significant cable impedances for simplicity.

As shown in the waveforms, all switches for the first channel are switched together, and separately, all switches for the second channel are switched together. Waveform 2831 shows the control of the switches for the first channel while waveform 2832 shows the control of the switches for the second channel. Waveform 2833 is the control of the fault switch. For the positive and negative sensor current waveforms, the positive current sensors are shown with solid lines while the negative current sensors are shown with dashed lines. Hence, waveforms 2835 and 2834 are the current measurements for the first positive current sensor (I_{P1}) and the first negative current sensor (I_{N1}), respectively; and waveforms 2836 and 2837 are the current measurements for the second positive current sensor (I_{P2}) and the second negative current sensor (I_{N2}), respectively. The fault current is shown in waveform 2838 while the load current is shown in waveform 2839.

Prior to time 2851, both channels are in a first power transfer interval, and the load current is split evenly between the first and second channels, wherein each channel observes an equal current between its positive and negative current sensors. At time 2851, both the first and second channels initiate a first isolation interval by each opening all of its switches. Since there is no low impedance between the source 2823 and the load 2824 (and, in this circuit, no receiver link capacitance is included for simplicity), the load current drops to OA as does the measurement from each current sensor. At time 2852, all switches for the first and second channels are closed to begin a second power transfer interval, and the load current along with the current sensor measurements return to their nominal levels as defined prior to time 2851.

At time 2853, the cross-port fault switch 2825 is closed, resulting in a fault current through fault resistance 2826. This fault current does not flow evenly on each channel, but rather flows through part of one channel and returns through part of the other channel. Specifically, the second positive current sensor measurement and the first negative current sensor measurement increase produce a current measurement increased by the amount of the fault current since these current sensors are in the path of the cross-port fault current. This results in a current imbalance on each channel, with the first positive current sensor being smaller than the first negative current sensor and the second positive current sensor being larger than the second negative current sensor. The polarity of this current sensor imbalance on each channel provides further information to conclude the specific conductors to which the cross-port fault is connected.

At time 2854, both channels initiate a second isolation interval, and this results in all currents shown in waveforms 2834, 2835, 2836, 2837, and 2838 returning to approximately 0 A since all relevant current paths are in a high-impedance or isolated state. At time 2855, all switches for both channels are closed to initiate a third power transfer interval, which returns the current measurements to the state just prior to time 2854.

While the first and second isolation intervals show the behavior with concurrent isolation intervals between the first and second channels, slightly different behavior is observed with non-overlapping isolation intervals. At time 2856, the first channel opens all of its switches to initiate a third isolation interval, but the second channel remains in a power transfer interval. During this third isolation interval, the first channel current sensors return to OA, but the second channel is able to power the load, so the load current maintains its current level while the second channel doubles the current through its positive and negative current sensors to compensate for the lack of current from contributed by the first channel. Since the cross-port fault current path is broken by the first channel opening its switches, the fault current also returns to OA. This is repeated in a swapped fashion between times 2857 and 2858, wherein the first channel closes its switches to return to a power transfer interval and the second channel opens its switches to initiate a fourth isolation interval. During this fourth isolation interval, the first channel provides all current to the load while the second channel returns to OA and maintains the cross-port fault current at OA. Finally, at time 2858, the second channel returns to a power transfer interval and the state of the system and the current levels return to what they were between times 2853 and 2854.

Transmitters may perform their switching independently, where 2 transmitters are in their isolation intervals at the same time by coincidence rather than intentionally. One way of making the system behave in a more predictable and deterministic fashion is through synchronization of the transmitters, either by methods disclosed in Mlyniec '494 or by other means known to one skilled in the art. This synchronization can be factored into the design of the cross-port detection to provide guidance to the transmitter on when to look for a cross-port fault. For example, if transmitters synchronize the start of their isolation intervals, then each transmitter can reasonably expect the effects of a cross-port fault to be observable starting at the beginning of the isolation interval and can reasonably exclude the need to detect a cross-port fault at a variable time during the isolation interval. The transmitter may still utilize an algorithm to monitor during a variable time during the isolation interval since the fault itself may be introduced at that time, but depending on the severity of the fault, it may be acceptable to detect this fault during the next isolation interval. Deviations in synchronization that result in the cross-port fault effects occurring during a portion of the isolation interval that is subject to the anomaly detection methods of Mlyniec '494 may inherently be detected by said anomaly detection methods without further modification.

Wherein alternating actions may be performed in consecutive isolation intervals, such as a first isolation interval type taking a measurement without a known bias connected and a second isolation interval type taking a measurement with a known bias connected, these may require further synchronization in order to detect all faults correctly. In some cases, the introduction of a fault while a mismatch is present may result in an unacceptable alteration of the signal and hinder the observation of essential fault detection characteristics. One method to address this potential mismatch is to observe a change in signal characteristics, such as a decrease in the decay percentage during the first isolation interval type or an increase in the initial drop voltage during the first isolation interval type. When either of these is detected, the transmitter can repeat the same isolation interval type to correct the mismatch. When doing this, for faults that allow a plurality of failed checks prior to registering a fault, the number of failed checks can be preloaded with a value as if a failed check has occurred since it is indeterminate if a fault was present and unable to be evaluated properly during the isolation interval when the mismatch was detected.

While primary embodiments describe this method with a voltage source on the non-transmission-line side of the circuit, this is not the only way to elicit the desired fault indications. In an alternative embodiment, a large capacitance would also work in place of a regulated voltage source provided that the capacitance will not allow a substantial rise in its voltage due to the shunted fault energy similar to the behavior of a regulated voltage supply. Any other similar circuit that can shunt the fault energy that flows through the unidirectional switches when they are intended to be open in such a way that the transmitter algorithm can be adapted to account for this effect can work. For example, the transmitter may implement an algorithm that accounts for the shunt mechanism to determine a threshold to use for the settling voltage level across its output terminals that is indicative of a fault in all necessary fault scenarios that require detection.

Cross-port fault detection can be done by a device at any line end, but there must be consideration for which ends feature unidirectional switches and the voltages at those ends, particularly if a line-end with unidirectional switching other than the one performing the detection method may be at a higher voltage on the non-transmission-line side of the circuit. In a simple example that ignores diode voltage drops, where a transmitter has a source voltage of 300V and a receiver has a link voltage of 200V, the transmitter may consider output voltages below 150V (i.e., half of 300V) as a possible cross-port fault while the receiver may consider input voltages below 100V (i.e., half of 200V) as a possible cross-port fault. If only the transmitter features unidirectional switching, the receiver may not detect the fault when required since the fault may stop conducting current when the voltage has reached 150V. Many methods can be utilized to avoid this, such as performing the check by multiple devices, particularly a device that is at the highest voltage level; by using unidirectional switching in all locations; or by devices being able to consider voltage levels present in other parts of the system.

Adaptations may be required when a non-resistive fault is involved. When the fault is a human body model (HBM) configured according to IEC 60990 with a 500Ω body impedance in series with a parallel combination of a 1.5 kΩ and 220 nF skin impedance, up to ¾ of the voltage may be stored within the fault, albeit in an opposing polarity. This results in the excess voltage that can be discharged through unidirectional switches to be as low as ¼ of the supply voltage. In this case, the threshold for the voltage drop expected due to a cross-port fault can be adjusted for this sensitivity. When the fault is purely capacitive, this initial voltage drop method may be completely ineffective. In the case of a purely capacitive fault as well as of a HBM fault, other methods can be employed, such as current imbalance or earth ground imbalance sensing. In many cases, this HBM capacitance may discharge quickly enough such that the original cross-port fault methods disclosed herein work without alteration of the sensitivity. In some cases, a mismatch in the isolation interval type may mask or hinder the detection of fault characteristics; and for these cases, methods to align the isolation interval type can be implemented as described herein and known in the art.

A further consideration with the HBM is when a contact resistance is also included in series with the HBM circuit to represent realistic scenarios, such as a human being coming into partial contact with a line through insufficiently insulated clothing. This HBM with contact resistance may present additional alterations in the circuit behavior, but the methods disclosed herein are still applicable, albeit possibly different thresholds or further altered sensitivities used. In both the HBM case and the HBM with contact resistance case, many of these scenarios are mathematically intensive to analyze for a closed form circuit solution; therefore it is typically more feasible to use computer analysis, simulation, prototyping, and other such methods to determine appropriate limits to ensure HBM faults are detected with and without contact resistance.

When examining the characteristics of the waveform during the isolation interval to determine that the output voltage is still being altered by the presence of a cross-port fault through the fault's continued current conduction, many alternative methods can be utilized. A frequency-domain analysis may indicate the presence of this fault current conduction through a shift in the magnitude or phase over the spectrum relative to what is expected without a fault present, where this frequency analysis, including FFTs, could be used to detect other line disturbances such as ringing that may obfuscate reliable assessment. Unexpected responses by applying a known impedance or bias may also provide indications that an unexpected alteration due to a cross-port fault's conduction is present, including interactions between the ports involved in the fault, where some ports could see an increase in voltage during its isolation interval when the other port applies a known impedance due to the compromised isolation between these ports.

While a primary embodiment of cross-port detection with a snubber circuit will perform the cross-port fault evaluation based on measurements without the snubber circuit connected, this is not necessarily a requirement. Depending on the snubber circuit and system impedances, the voltage equalization that occurs with a cross-port fault may still be reached while the snubber circuit is connected provided that the time constants involved are sufficiently small relative to the time when the measurements are performed. Similarly, for the same reasons, it may also be possible to identify the waveform complexity and non-linearity that occurs while the voltage equalization is still in progress. With significantly slower time constants formed by the snubber circuit and the other system and fault impedances, it is unlikely that this will reach the required voltage in time, though it may have false positives if the snubber is still in the process of being used to negate oscillations.

When bidirectional switches are used, methods predicated on at least a temporary reverse current flow or energy transfer from a DE-side to an AE-side during an isolation interval are not directly applicable due to the nature of blocking current flow in both directions with said bidirectional switches. Because of this, adaptations of the method or entirely new alternative methods are required. It should also be noted that the method of single-side switching (i.e., only positive-side switches or only negative-side switches) is directly applicable with no changes required, and the method has similar trade-offs and detrimental effects incurred as the method when balanced switching is not employed in unidirectional switching schemes. Similarly, methods using a common link can be used to effectively determine a common mode voltage shift.

Many adaptations exist that allow the same reverse current flow or DE-to-AE energy transfer principle to be utilized. In a simplest example, a bidirectional switching system can temporarily be operated in a unidirectional fashion or by providing any other equivalent reverse leakage or DE-to-AE energy transfer path temporarily to utilize the reverse current flow or DE-to-AE energy transfer phenomenon for at least the time when this balancing would occur. This could be accomplished by switching in a parallel component such as a diode, or it could be accomplished by closing only FETs that normally block current flow in one direction but not closing FETs that normally block current flow in the other direction.

Proper timing of this operation may allow some of the benefits of bidirectional switching to still be utilized, such as waiting for a time delay after opening the bidirectional switches to stop high-power current flow before changing the switch positions to the unidirectional configuration at a later time in the same isolation interval so the cross-port fault can be checked after much of the ringing and inductive effects of the transmission line have subsided, thereby retaining much of the EMC and system stability and robustness. For example, switching in a bidirectional fashion may have significant EMC and other benefits near the moment of the switch state transition, but these effects may not be as significant when minimal current flow is occurring, such as a point in time after the start of an isolation interval. This less significant point in time may be ideal for temporarily converting to a unidirectional switching configuration to check for cross-port and other faults that may require such a switch configuration. When used with a snubber circuit, an opportune time may be when the snubber circuit is removed during an isolation interval or shortly after said snubber circuit disconnection, as minimal energy transfer may be occurring at that point in time.

This may look for the reverse current flow directly, or look for the large voltage drop, where this large voltage drop would occur at a time depending on the snubber usage as described within this disclosure. Similarly, this may include a series resistance to aid in the control of the discharge rate as well as controlling the current waveform, but this would likely need to be a very low impedance to minimize losses. The current sensor looking for a reverse current could be scaled to only require a small amount of current to be sensed, with currents above said small amount being unnecessary to distinguish since they are indicative of a fault. For example, a 10 A current may be expected in the forward direction, but any current above 7 mA in the reverse direction could be indicative of a fault, so the sensor only needs to distinguish current in a narrow range that includes this, such as 0-10 mA. Sensing the full range, however, may be useful for any algorithms that use the fault current to determine adaptive limits based on allowable exposure time that are a function of fault current. When the DE-to-AE energy transfer is not the same as a reverse current flow (e.g., a receiver's DE-to-AE energy transfer is the same direction as normal current flow during power transfer intervals), this principle can be adapted to use a narrow range current sensor when it is expected that negligible current would be flowing (e.g., during an isolation interval); or a fully range current sensor can also be used if the resolution is sufficient; or both can be used complementarily to cover the range of possible fault currents effectively.

Building off of this latter embodiment of a current sensor looking for a reverse current (or a current indicative of an DE-to-AE energy transfer that should nominally be negligible or negative), a diode can be used in parallel with said series combination of a resistance and a current sensor, where this is in series with the unidirectional switch and the diode is in an opposing direction of the unidirectional switch, such as a common cathode configuration. In some embodiments the resistance or current sensor may be omitted or placed in an effectively equivalent location, or may be combined in the case of a shunt current sensor. In this configuration, the resistance could be low or high impedance, but a likely embodiment would use a high value resistance to limit current flow through this branch in either direction, favoring the diode for the majority of the current flow until much higher currents are reached.

Continuing with this circuit configuration, a further enhancement could be made using a switch instead of an opposing diode, with the orientation of the switch the same as the diode it replaces. This allows the switch to bypass any effective diode drop that it may exhibit while still allowing the switch to be opened to look for reverse current through the resistor and current sensor in parallel with it. In an alternative or simultaneous enhancement, a diode can be included in series with the resistor and current sensor to only permit current flow in the reverse direction so that it does not contribute to the forward conduction path. This may facilitate a large range of resistance values to be considered without needing to consider impacts to compromises of the bidirectional switching benefits as diligently.

In yet another variation, the current sensor could take slightly different forms. While a current sensor with a comparator on its output would work to detect a reverse current at a specified level, alternative circuits that can make a similar assessment can be substituted. One such embodiment is an optocoupler. This can be oriented to trigger when the reverse current flows, and both the sense and drive sides of the optocoupler can be designed to respond in a predictable fashion at a desired current level. The inherent isolation and low current level may be particularly attractive for high-side or low-side current sense locations that need to detect currents where only small or negligible currents would be expected during normal operation without a fault present. This could be placed in parallel with the half of a bidirectional switch configuration where the diodes are in the same orientation (i.e., common anode), but there could be contention with respect to the current split. One way around this could be to place the optocoupler in a different location, such as in parallel with another series switch that has an opposing orientation.

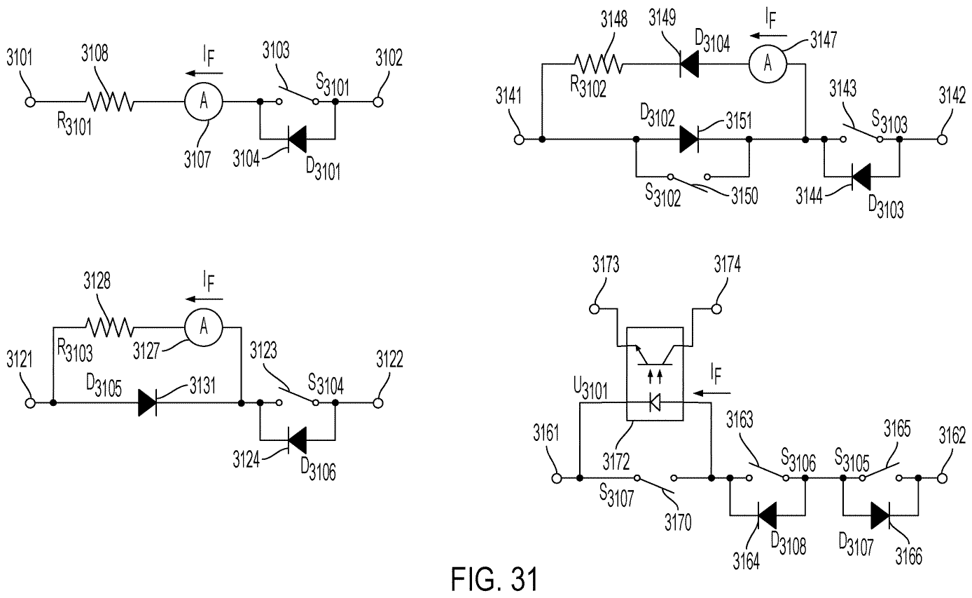

FIG. 31 shows many of these various embodiments of detecting a cross-port fault via reverse current conduction or DE-to-AE energy transfer. These circuits are shown in the context of the positive main switch of a transmitter (e.g., each circuit replaces switch 211 in FIG. 2), and most are shown with unidirectional switches with the understanding that they are applicable to bidirectional switch configurations when they are temporarily operated in a unidirectional fashion.

Starting with the less preferred embodiment of a first circuit in the top left of FIG. 31, between the AE-side terminal 3101 and DE-side terminal 3102 is the series combination of a current sensor 3107, a current-limiting resistance 3108, and a unidirectional main switch; wherein the unidirectional main switch comprises the parallel combination of switch 3103 and diode 3104. The current sensor 3107 can be the same as current sensor 222, but as disclosed herein, this may be less desirable if the current sensor scale, resolution, or accuracy have disparaging requirements between measuring forward current and reverse fault current.

A variation of this to avoid the losses of the series resistance 3108 is shown in a second circuit in the bottom left of FIG. 31. This second circuit is similar to the first circuit, with elements 3121, 3122, 3123, 3124, 3127, and 3128 corresponding respectively to elements 3101, 3102, 3103, 3104, 3107, and 3108. The second circuit further comprises diode 3131 that is in parallel with the series combination of current sensor 3127 and current-limiting resistance 3128 to allow forward current to primarily conduct through the diode 3131 instead of the resistance 3128 during power transfer intervals, enabling the design requirements of the reverse current path to be partially decoupled from the design requirements of the forward current.

A further variation of this second circuit to better control the circuit and possibly reduce losses is shown in a third circuit in the top right of FIG. 31. This third circuit is similar to the second circuit, with elements 3141, 3142, 3143, 3144, 3147, 3148, and 3151 corresponding respectively to 3121, 3122, 3123, 3124, 3127, 3128, and 3131. The third circuit further comprises a bypass switch 3150 in parallel with diode 3151 to allow the diode to be bypassed to reduce power dissipation depending on the component parameters and current level. This also indicates that the combination of switch 3150 and diode 3151 can be embodied as a MOSFET. The series combination of current sensor 3147 and current-limiting resistance 3148 further includes reverse-blocking diode 3149 to ensure only reverse currents flow through this branch of the circuit so that the forward current contribution through this branch of the circuit does not need to otherwise be considered in the design.

A different approach using an optocoupler as described herein is shown in a fourth circuit in the bottom right of FIG. 31. This again includes an AE-side terminal 3161 and DE-side terminal 3162. The main switches are now represented as a bidirectional switch configuration comprising unidirectional switches 3163 and 3165 with their associated respective diodes 3164 and 3165. The series path from DE-side terminal 3162 through said bidirectional switch configuration to the AE-side terminal 3161 is completed by optocoupler 3172 oriented to be activated when a reverse current flows, the isolated output of which is provided at terminals 3173 and 3174. A bypass switch 3170 is provided in parallel with optocoupler 3172 to allow forward current when the reverse current flow is not being tested by optocoupler 3172.

One related practical consideration when using bidirectional switches in the receiver is synchronization. Since active control of said switches is required in order for the receiver to operate fully, this synchronization becomes a necessity as compared to unidirectional switching implementations, where unidirectional switching implementations can gain efficiency by synchronously switching (i.e., synchronous rectification) but do not require this gain in order to operate fully since the non-blocked direction still provides the necessary power through the receiver and to the load. Synchronization can be attained in a multitude of ways, including out-of-band and in-band communications. Synchronization can also be attained through signal processing of the received signal at the receiver's input terminals. By identifying key characteristics of the isolation interval or power transfer interval, the receiver can determine when isolation intervals start and stop within an acceptable accuracy and open the bidirectional switches during this time and further closing said bidirectional switches outside of said time. For example, the large voltage or current change seen at the end of the isolation interval could be detected, and with a fixed power transfer interval duration, the receiver can predict the start of the isolation interval. These methods can be implemented in hardware, in firmware, or in a combination thereof. The receiver may utilize energy storage in order to make such measurements and determinations for synchronization. In particular, the initial start-up may have additional challenges and require some form of bootstrap circuitry or low-power provisioning, such as techniques described in Lutz '603. This synchronization can also be used to synchronously switch other elements, such as the load disconnect switches or load soft-start switches to prevent large link capacitance drainage and large current spikes when the receiver only operates with a single active front-end or with all front-ends in an isolation interval simultaneously so long as the load can tolerate such disruptions. Similarly, where system architectures feature series connected transmitters, since each transmitter input utilizes the same circuitry as a receiver front-end, these same principles would apply in addition to those described in Eaves '689.

Cross-port fault detection can also be applied to other circuit configurations. In particular, instead of the fault current path involving two transmitters or two receivers, the fault current path could instead involve a transmitter and a receiver. Such a configuration is encountered in a repeater device. A repeater device is a self-contained combination of a receiver and a transmitter, where the output of the receiver is connected to the input of a transmitter. Repeaters provide a number of benefits, including at least an increase in overall distance by reducing the distance that must be ensured to be safe by each transmitter; allowing new isolation planes to be generated; and providing an opportunity for power conversion to alter the transmission circuit, such as to boost the voltage back up to recover from inline power losses. When the repeater does not provide isolation between its receiver input and its transmitter output, there is the possibility for a fault current to exist if the fault connects between the first transmission line connected to the input of the repeater and the second transmission line connected to the output of the repeater.

In such a cross-port fault repeater, the cross-port fault detection algorithm continues to work without modification since the phenomenon is the same. With a positive-to-negative cross-port fault during simultaneous isolation intervals, the series combination of the capacitance connected to the repeater input and the capacitance connected to the repeater output still results in an excess of voltage compared to the voltage of the common bus link voltage between the input and output; and with a unidirectional switching mechanism such as diodes permitting that direction of current flow, this excess voltage will equalize to the link voltage plus the forward voltage drops of the diodes. This also shows that the device that charges the capacitance does not need to be the device that detects the fault, nor the one through which the fault current conducts. The input of the repeater will be connected to at least one transmitter, where this transmitter will charge the capacitance on its output and the repeater's input during at least the power transfer interval. When the isolation interval is entered and a positive-to-negative cross-port fault is connected from the repeater's input and the repeater's output, the fault current will not conduct through the transmitter connected to the repeater's input; but any devices connected to either transmission line may be able to detect the fault. The repeater is the most adept at detecting such a fault accurately since its link voltage is known; but that does not preclude other devices from getting such information nor from compensating for it with padding, factors of safety, or other means of estimation. This fault behavior and detection mechanism holds true even if multiple repeaters are chained together and the cross-port fault is present between an input port of a first repeater and the output port of a second repeater.

This behavior described for a repeater is expandable to more complex devices. A switch device, which may also be known as a router device in some cases, contains at least 3 ports, with 1 or more of those ports being receiver inputs at any given time and with 1 or more of those ports being transmitter outputs at any given time. A switch device may dynamically change roles of ports, such as the case of a matrix switch or where bidirectional power transfer is supported. Regardless of how many ports are present, provided there is no isolation stage, the cross-port fault phenomenon is reduced to the equivalent of any other 2 port cross-port fault configuration. Such a configuration could be 2 transmitters, it could be 2 receivers, it could be a transmitter and a receiver such as with a repeater, and so on. The other ports of the switch are either not affected or they do not contribute meaningfully to the behavior and detection of the cross-port fault.

Technically, when a fault current is conducting through a unidirectional switch, the switch is no longer isolating its two sides. To alleviate this confusion, the term “nominally isolates” is introduced to refer to a configuration that is normally successfully isolating when not in the presence of a fault, wherein this isolation may not be successful and allow current flow in at least one direction in the presence of a fault. An effort has been made to use this “nominally isolating” term throughout this disclosure, but wherein only the term “isolating” is used without the qualifier “nominally”, a determination can still be made as to whether such usage is in fact “nominally isolating” based on the context.

Regardless of whether or not a fault current is conducting, when opening a switch to isolate the two sides of the switch, these may not be completely isolated. For example, while the switch is open, an alternative impedance or energy source may provide a current path in parallel with the switch. In many cases, despite not being fully isolated, this effects the conditions required during an isolation interval for the methods disclosed herein to be implemented successfully. Therefore, the term “at least partially isolating” is used to refer to this possibility of not fully isolating between the two terminals of a switch when the switch is opened but still providing enough isolation for the methods herein to be implemented. Similarly, the term “at least partially disconnecting” is analogous to “at least partially isolating”. Wherein only the term “isolating” is used with the qualifier “at least partially”, a determination can be made as to whether such usage is in fact “at least partially isolating” based on the context. This can further be combined with the “nominally” term to form the complete term “at least partially nominally isolating”.

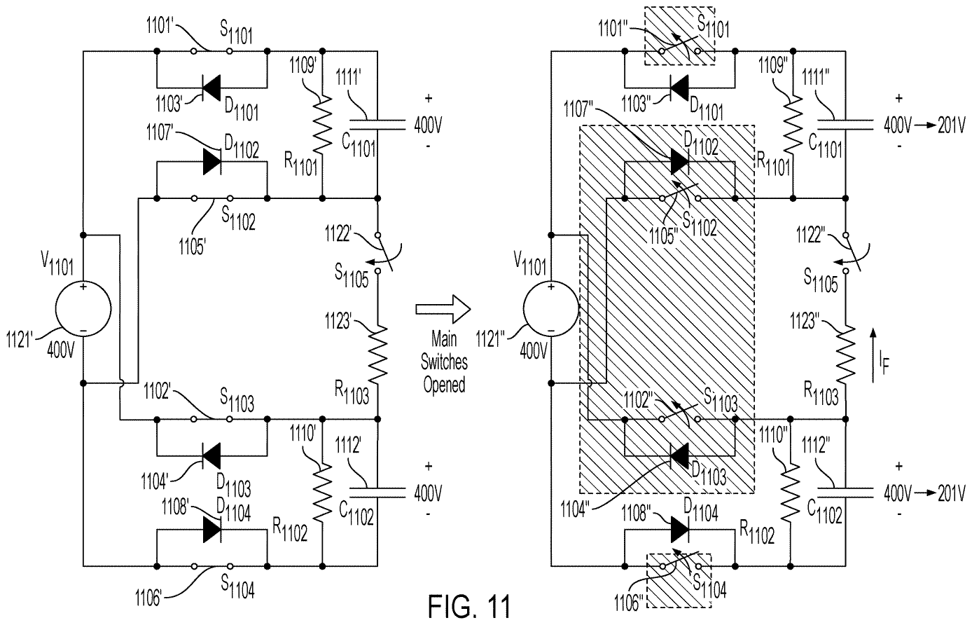

A cross-port fault and the detection disclosed herein can take many forms while remaining effective. In FIG. 11, a first transmitter nominally isolates a first transmission line from a voltage source during isolation intervals and a second transmitter nominally isolates a second transmission line from the same voltage source during isolation intervals. While the isolation intervals of both transmitters are at least partially overlapping, when a fault is connected from the negative-side of the first transmission line and the positive-side of the second transmission line, a fault current conducts through the positive-side unidirectional switching element of the first transmitter and returns through the negative-side unidirectional switching element of the second transmitter.

In FIG. 11, to show the behavior of a cross-port fault, the same circuit is presented in 2 different states: on the left half, the circuit is shown in a first state when the main switches are closed during a power transfer interval (callouts marked with prime symbol); and on the right half, the circuit is shown in a second state when the main switches are open during an isolation interval (callouts marked with double prime symbol). Furthermore, in the second state, components that do not contribute significantly to the main current path during the cross-port fault equalization process are enclosed within hatched boxes with a dashed outline so that the remaining components can emphasize the fault current path.

Defining the circuit components for a single state, the circuit shows a first channel in the top half and a second channel in the bottom half. The first channel is simplified to a transmitter that comprises switches 1101 and 1105 with respective diodes 1103 and 1107; and an effective crossline output impedance defined by resistance 1109 and capacitance 1111. These elements 1101, 1103, 1105, 1107, 1109, and 1111 correspond respectively to elements 1102, 1104, 1106, 1108, 1110, and 1112 to comprise the second channel, with 1102, 1104, 1106, and 1108 comprising the second transmitter. Completing the circuit is source 1121 connected to the input of each transmitter as well as the cross-port fault circuit comprising fault switch 1122 and fault resistance 1123.

As an example, each crossline capacitance 1111′ and 1112′ is shown to initially be charged to 400V, but after opening main switches 1101, 1105, 1102, and 1106, the voltage across each of these crossline capacitances 1111″ and 1112″ is ultimately reduced to 201V each. This 201V is derived from the voltage of source 1121 being 400V, the forward voltage drop of diodes 1103 and 1108 defined as 1V each (for simplicity instead of the typical 0.7V, though 1V may be typical for some power diodes), and the equal component sizing between the first and second channels while treating the crossline RC decay (e.g., with resistance 1109 and capacitance 1111) as negligible for simplicity.

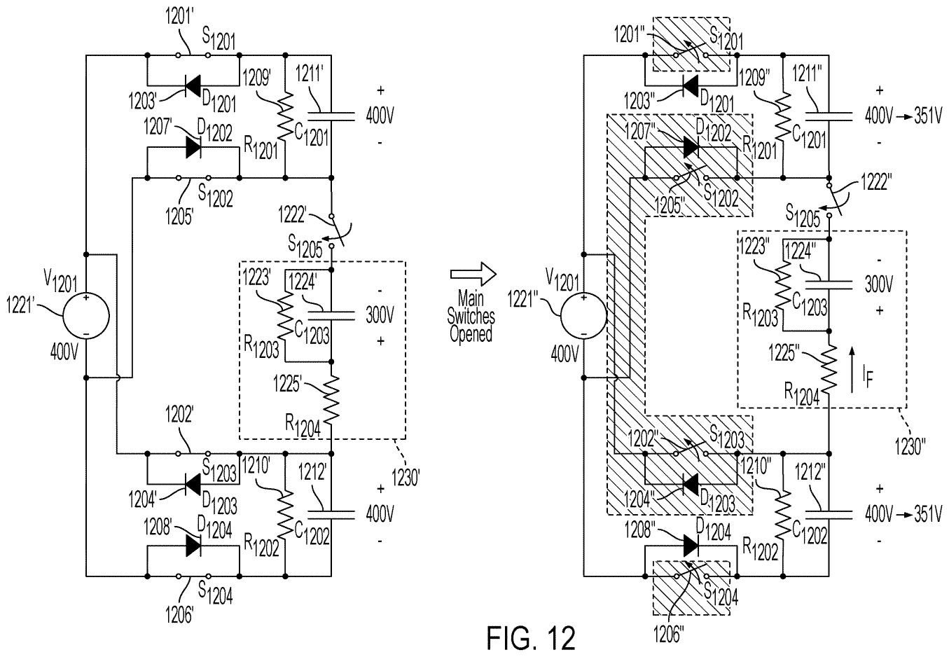

FIG. 12 is contrasted against FIG. 11, repeating the circuit and organization of FIG. 11, but replacing the fault resistance 1123 with a human body model (HBM) fault impedance 1230. The other elements 1201, 1202, 1203, 1204, 1205, 1206, 1207, 1208, 1209, 1210, 1211, 1212, 1221, and 1222 correspond respectively to elements 1101, 1102, 1103, 1104, 1105, 1106, 1107, 1108, 1109, 1110, 1111, 1112, 1121, and 1122. The fault impedance 1230 comprises the known HBM circuit as defined in publications such as IEC 60990, which includes the parallel combination of skin resistance 1223 and skin capacitance 1224 in series with core resistance 1225.

Adapting the example of FIG. 11 to FIG. 12, starting with each crossline capacitance 1211′ and 1212′ initially charged to 400V, it is observed that the capacitance 1224′ of the HBM fault impedance is initially charged to 300V but with an opposing polarity. This 300V is derived from the voltage divider formed with the skin resistance 1223 (typically 1.5 kΩ) and core resistance 1225 (typically 500Ω). After opening main switches 1201, 1205, 1202, and 1206, the voltage across each of these crossline capacitances 1211″ and 1212″ is reduced to 351V since the HBM skin capacitance 1224″ is shown in this example as retaining its 300V charge while a fault current path is provided by HBM skin resistance 1223″. This 351V is again derived from the voltage source 1221 being 400V, the forward voltage drop of diodes 1203 and 1208 defined as 1V each, the equal component sizing between the first and second channels, and the crossline RC decay as well as the RC decay within the HBM skin impedance (i.e., 1223 and 1224). In typical applications, lower voltages will be realized since the HBM skin capacitance will not remain at 300V, and each capacitance will experience RC decay in addition to the cross-port fault equalization effect.

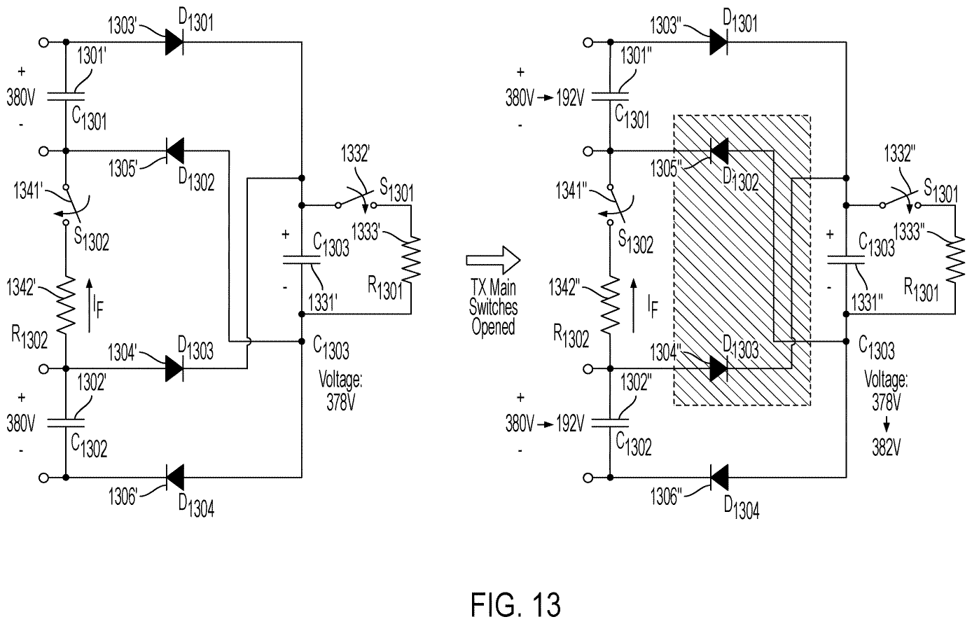

In FIG. 13, a first receiver front-end nominally isolates a first transmission line from a bulk capacitor during isolation intervals and a second receiver front-end nominally isolates a second transmission line from the same bulk capacitor during isolation intervals, which is a common configuration of a receiver that includes a plurality of receiver front-ends connected to the same output and conditioning circuit. While the isolation intervals of both receiver front-ends are at least partially overlapping, where this isolation interval may be driven by switching of the transmitters connected to those receiver front-ends, when a fault is connected from the negative-side of the first transmission line and the positive-side of the second transmission line, a fault current conducts through the positive-side unidirectional switching element of the first receiver front-end and returns through the negative-side unidirectional switching element of the second receiver front-end.

Thus, FIG. 13 shows the cross-port fault behavior when the effect is allowed to occur at the receiver-end. As with FIG. 11 and FIG. 12, the left half and right half show the circuit with the main switches closed during a power transfer interval and open during an isolation interval, respectively; and a first channel is shown in the top half while a second channel is shown in the bottom half. Hatched boxes with a dashed outline again show components that do not significantly contribute to the cross-port fault behavior during the isolation interval.

The first channel is simplified as an effective crossline capacitance 1301 and a first receiver comprising diodes 1303 and 1305. The second channel is defined by elements 1302, 1304, and 1306 that correspond respectively to elements 1301, 1303, and 1305; wherein diodes 1304 and 1306 comprise the second receiver. A common receiver link capacitance 1331 is connected to both receivers, and the common receiver link capacitance is further connected to output switch 1332 configured to be connected to a load represented as resistance 1333. Completing the circuit is the cross-port fault circuit comprising the fault switch 1341 and fault resistance 1342. Note that while the first and second receiver are described, this could alternatively be viewed as a single multi-input receiver, with diodes 1303 and 1305 comprising a first switching barrier, diodes 1304 and 1306 comprising a second switching barrier, and at least capacitance 1331 comprising the relevant portion of the output and conditioning circuit.

Providing an example, with each receiver connected to a respective transmitter (i.e., each transmitter output is connected across a respective crossline capacitance 1301 or 1302), the capacitances are initially charged during the power transfer interval, with crossline capacitances 1301′ and 1302′ charged to 380V (which can represent 20V of inline cable voltage drop from a 400V transmitter source) and the common receiver link capacitance 1331′ charged to 378V due to the 1V forward voltage drop of the diodes 1303, 1304, 1305, and 1306.

When an isolation interval is initiated by the transmitters, in the presence of the cross-port fault, the capacitance voltages are equalized. In this example, the crossline capacitances 1301″ and 1302″ are reduced to 192V and the common receiver link capacitance 1331″ is increased to 382V. This represents a capacitance sizing wherein the common receiver link capacitance is large enough to have negligible voltage reduction due to continuing to power load resistance 1333, but still results in an increased voltage due to the energy transfer from the crossline capacitances 1301 and 1302. These voltages are further accounted for based on the 1V forward voltage drop of diodes 1303 and 1306. Finally, as with other examples, this is representative of equal component sizing between the first and second channels.

Note that the exemplary voltages shown in FIG. 13 illustrate a couple of concepts. First, an input voltage of 380V across capacitances 1301′ and 1302′ during the power transfer interval is an example of a possible input voltage of a receiver when the transmitters (not shown) supply 400V but there is 20V of inline cable voltage drop. The link capacitance 1331′ having a power transfer interval voltage of 1331′ captures the simplified 1V diode drops from diodes 1303′, 1304′, 1305′, and 1306′. When concurrent isolation intervals occur, the crossline capacitances 1301″ and 1302″ settle at a voltage slightly higher than half of their respective initial voltages during the power transfer interval, and also a higher ratio than the example shown in FIG. 11 between capacitance states 1111′ and 1111″. This captures the effect that the AE-side voltage across the link capacitance 1331″ rises from 378V to 382V as some of the energy transfer from capacitances 1301 and 1302 are large enough to result in a 4V change in capacitance 1331. Since there is a load resistance 1333, the energy transfer in this example is larger than this since some energy is dissipated by the load resistance 1333, and the 4V is only the net energy gain on the AE-side of the circuit. This represents the case where the ratio of the capacitances 1301 and 1302 to capacitance 1303 is large enough for this raised voltage on capacitance 1331 to be significant and the various time constants in the circuit are such that this voltage rise is seen before it is fully dissipated by load resistance 1333 (among other time constant effects not depicted). Note that this is an exaggerated example, and in most cases, the design of the size of each of these caps will dictate that a smaller and likely negligible increase in voltage on the link capacitance 1331 will be observed. Also note that this behavior is not limited to receivers, as such an increase in AE-side voltage is possible on the AE-side of a transmitter, such as when the AE-side of a transmitter has a crossline capacitance and a two-quadrant power supply as a source.

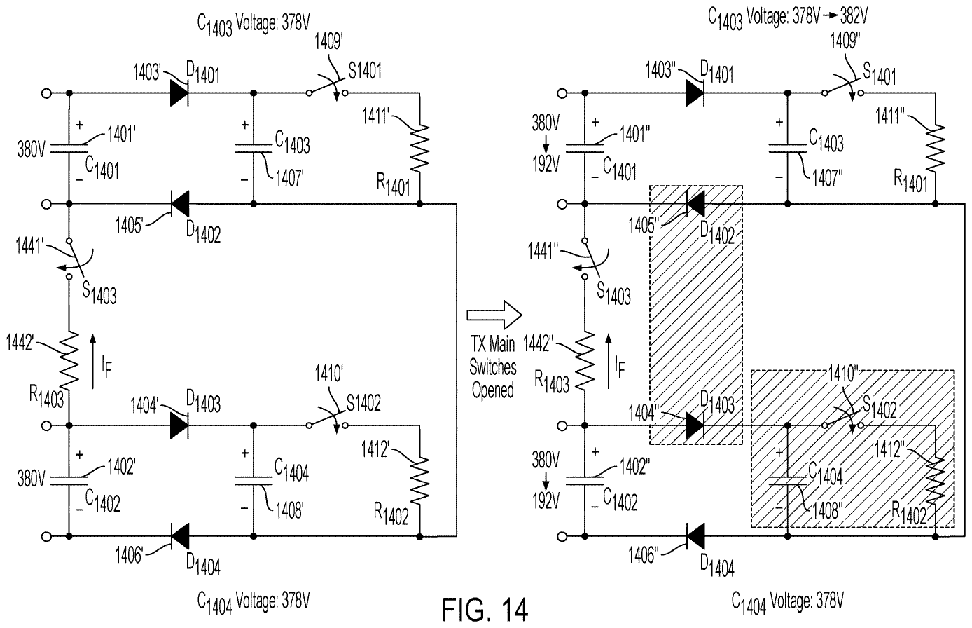

FIG. 14 is a slight variation of FIG. 13, where instead of a single output control and conditioning circuit, a plurality of output control and conditioning circuits exist, but the negative-side of these circuits is connected. In this figure, a first receiver front-end nominally isolates a first transmission line from a first bulk capacitor during isolation intervals and a second receiver front-end nominally isolates a second transmission line from a second bulk capacitor during isolation intervals, which is a common configuration where the first receiver front-end and the second receiver front-end are part of separate receivers. While the isolation intervals of both receiver front-ends are at least partially overlapping, where these isolation intervals may be driven by switching of the transmitters connected to those receiver front-ends, when a fault is connected from the negative-side of the first transmission line and the positive-side of the second transmission line, a fault current conducts through the positive-side unidirectional switching element of the first receiver and returns through the negative-side unidirectional switching element of the second receiver. In this case, while each receiver front-end isolates its respective transmission line from its respective bulk capacitor, it is only the first bulk capacitor that is part of the fault current loop; the second bulk capacitor does not conduct the fault current in this configuration.

Describing the elements of FIG. 14, wherein FIG. 14 is contrasted against FIG. 13, FIG. 14 more generally shows each receiver having a distinct output control and conditioning circuit and load, but a common reference ties the receiver outputs together such as the load negative leads being tied together. The first channel is simplified as an effective crossline capacitance 1401, a load resistance 1411, and a first receiver; wherein the first receiver now comprises diodes 1403 and 1405, link capacitance 1407, and output switch 1409. The second channel is then defined by elements 1402, 1404, 1406, 1408, 1410, and 1412 that correspond respectively to elements 1401, 1403, 1405, 1407, 1409, and 1411; wherein the second receiver comprises elements 1404, 1406, 1408, and 1410. The cross-port fault circuit comprises the fault switch 1441 and the fault resistance 1442. Finally, in this circuit, the load resistances 1411 and 1412 are tied together on one side (i.e., the negative side in this figure).

In an example using this circuit of FIG. 14, similar to FIG. 13, with each receiver connected to a respective transmitter, the capacitances are initially charged during the power transfer interval, with crossline capacitance 1401′ and 1402′ charged to 380V and link capacitances 1407′ and 1408′ charged to 378V due to the 1V forward voltage drop of the diodes 1403, 1404, 1405, and 1406.

When an isolation interval is initiated by the transmitters, in the presence of the cross-port fault, the capacitance voltages are equalized. In this example, the crossline capacitances 1401″ and 1402″ are reduced to 192V. The link capacitance 1407″ for the first receiver is increased to 382V since it is part of the cross-port fault equalization current path, but link capacitance 1408″ for the second receiver is not part of this path and therefore remains at 378V. This again represents a capacitance sizing wherein the link capacitances 1407 and 1408 are large enough to have negligible voltage reduction due to continuing to power their respective load resistances 1411 and 1412, but still result in an increased voltage for link capacitance 1407″ due to the energy transfer from the crossline capacitances 1401 and 1402. Again, this is representative of equal component sizing between the first and second channels.

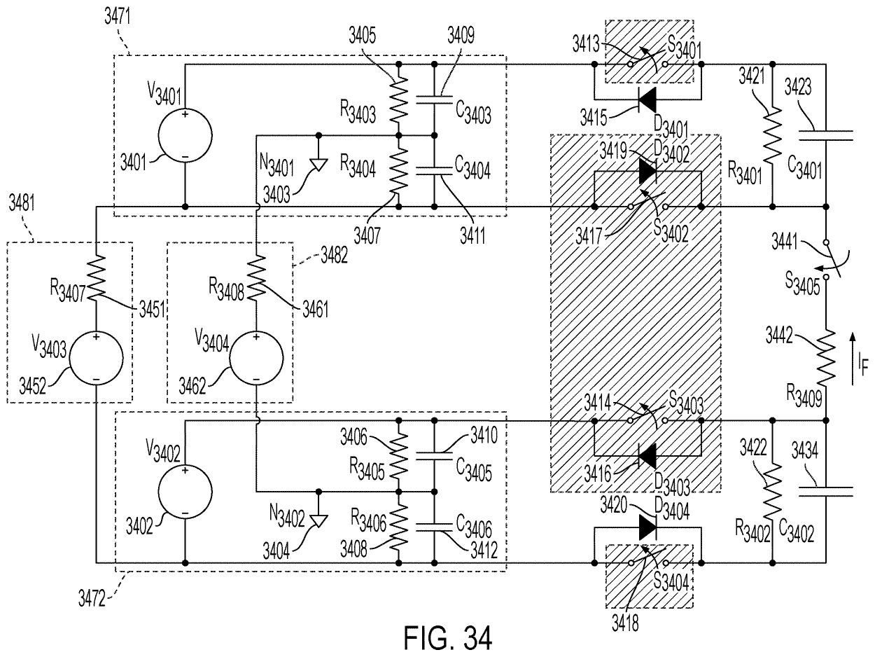

Similar to this concept, FIG. 34 shows the analogous configuration featuring 2 transmitters instead of 2 receivers. FIG. 34 further provides a depiction of a circuit that can be used to represent degrees of partial channel-to-channel isolation, particularly in the context of cross-port faults. At a high level, FIG. 34 shows a first channel in the top half of the figure and a second channel in the bottom half of the channel. The circuit is only shown in the state where all transmission lines are in an isolation interval.

A first power supply 3471 comprises source 3401, Y-capacitances 3409 and 3411 with resistances 3405 and 3407 in parallel with said Y-capacitors, respectively, with these Y-capacitors and resistors all center-tied to a first reference node 3403. This first power supply is connected to the input of a first transmitter switching barrier comprising switches 3413 and 3417 with associated respective diodes 3415 and 3419. The output of the first transmitter switching barrier is connected to a first transmission line represented by crossline capacitance 3423 and crossline resistance 3421. The first power supply 3471, the first transmitter switching barrier, and the first transmission line comprise the first channel.

The second channel comprises elements 3402, 3404, 3406, 3408, 3410, 3412, 3414, 3416, 3418, 3420, 3422, and 3424 correspond respectively to elements 3401, 3403, 3405, 3407, 3409, 3411, 3413, 3415, 3417, 3419, 3421, and 3423. The second power supply comprises 3402, 3406, 3408, 3410, 3412, and a second reference node 3404. The second transmitter switching barrier comprises 3414, 3416, 3418, and 3420 while the second transmission line comprises 3422 and 3424.

A cross-port fault circuit is configured to be connected between the positive of the second transmission line and the negative of the first transmission line, with the cross-port fault circuit comprising fault switch 3441 and fault resistance 3442. Finally, to represent the essential aspects of partial isolation between the first channel and the second channel, a line isolation barrier circuit 3481 is connected between the negative of the first channel and the negative of the second channel, wherein the line isolation barrier circuit comprises a voltage source 3452 and an isolation resistance 3451. This partial isolation is further represented by a reference isolation barrier circuit 3482 that is connected between the first reference node 3403 and the second reference node 3404, wherein the reference isolation barrier circuit comprises a voltage source 3462 and an isolation resistance 3461. Normally, for full isolation, these voltage sources 3452 and 3462 would be a negligible amount, the isolation resistance 3451 would be a high-impedance, and the isolation resistance 3461 would be a low impedance as these first and second references nodes would typically also be connected to a common earth ground reference for the system.

In this FIG. 34, a first transmitter switching barrier nominally isolates a first transmission line from the first voltage source 3401 during isolation intervals and a second transmitter switching barrier nominally isolates a second transmission line from the second voltage source 3402 during isolation intervals, which is a common configuration where the first voltage source and the second voltage source are at least partially isolated from each other. While the isolation intervals of both transmitter switching barriers are at least partially overlapping, and wherein the connection between the negative of the first voltage source and the negative of the second voltage source is a low impedance and low voltage offset connection, when a fault is connected from the negative-side of the first transmission line and the positive-side of the second transmission line, a fault current conducts through the positive-side unidirectional switching element of the first transmitter switching barrier and returns through the negative-side unidirectional switching element of the second transmitter switching barrier. In this case, while each transmitter switching barrier isolates its respective transmission line from its respective voltage source, it is only the first voltage source that is part of the fault current loop; the second voltage source does not conduct the fault current in this configuration.

As mentioned, FIG. 34 also introduces elements to represent the effective isolation between the first voltage source and the second voltage source. To be more precise, a voltage supply circuit is defined as one that contains a voltage source and a center-tie to a common ground through a parallel resistance and capacitance from each side of the voltage source to the common ground. This effective isolation is shown as a negative-side line isolation barrier circuit 3481 and a common-ground reference isolation barrier circuit 3482, where each of these is shown as a Thévenin resistance and a Thévenin voltage source to represent the impedance and voltage offset between their respective circuit connections between the first voltage supply circuit and the second voltage supply circuit. As described above, low impedance and low voltage offset between the negative-side of each voltage supply circuit permits the cross-port fault method to be effective without modification; and this is regardless of the impedance and voltage offset between the common ground of each voltage supply circuit. On the opposite end of the spectrum, a high impedance between the negative-side of each voltage supply circuit and a high impedance between the common ground of each voltage supply circuit results in an absence of the electrical characteristics of a cross-port fault as described herein, but such a configuration does not require cross-port fault detection since the fault current is already sufficiently limited at all times; and this is regardless of the voltage offset between the negative-side of each voltage supply circuit and the voltage offset between the common ground of each voltage supply circuit.

Continuing with the effects of the isolation between the first voltage supply circuit and the second voltage supply circuit, nuance is introduced in other cases. With a high voltage offset and low impedance between the negative-side of each voltage supply circuit, significant changes to the fault current magnitude and the electrical characteristics indicative of the cross-port fault are observed; and this is regardless of the impedance and voltage offset between the common ground of each voltage supply circuit. Similarly, with a high impedance between the negative-side of each voltage supply circuit and a low impedance between the common ground of each voltage supply circuit, smaller but still notable changes to the fault current magnitude and the electrical characteristics indicative of the cross-port fault are observed; and this is regardless of the offset voltage between the negative-side of each voltage supply and the offset voltage between the common ground of each voltage supply. These cases, while typically uncommon and may not need to be supported by the safety algorithm, do not necessarily completely preclude application of methods and apparatus disclosed herein. The voltage offsets and impedances can be factored in by adjusting limits to account for the voltage offset or adjusting the timing of the evaluation to account for the impedance; and the scenarios that must detect and respond to a fault can be adjusted to account for increased or decreased fault current magnitudes. These adjustments could be based on measurements of the voltage offsets or impedances, or they could be based on design specifications for the range of voltage offsets and impedances supported to effectively implement as factor of safety, or some combination thereof.

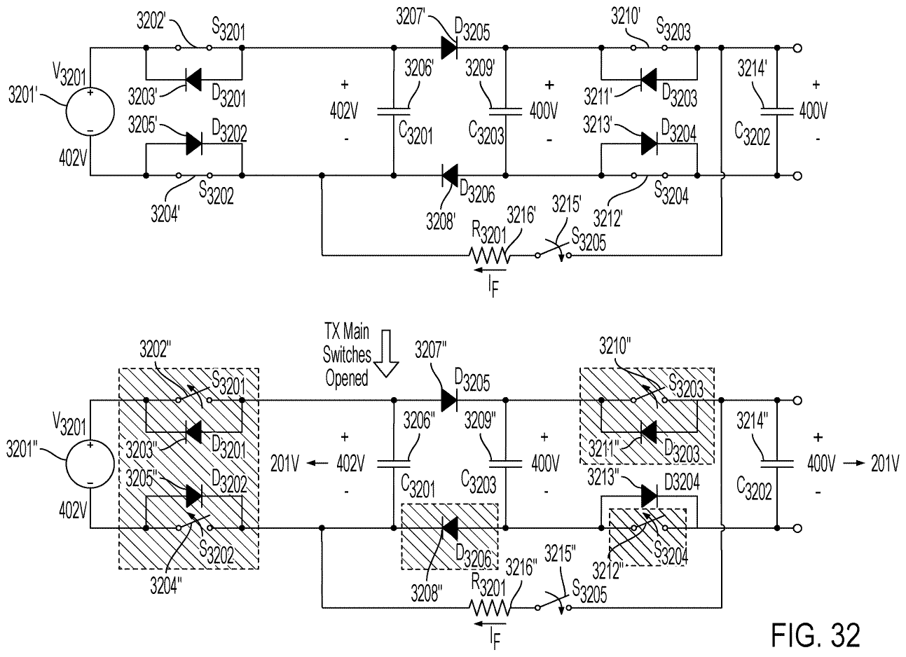

FIG. 32 shows an embodiment of a cross-port fault involving a transmitter and a receiver, which also shows the cross-port fault behavior when the fault is connected across an input and an output of a repeater. Similar to other figures such as FIG. 11, the circuit is shown in 2 different states: on the top half, the circuit is shown in a first state when the main switches are all closed during a power transfer interval for each transmission line (callouts marked with prime symbol); and on the bottom half, the circuit is shown in a second state when the main switches are all opened during an isolation interval for each transmission line (callouts marked with double prime symbol). Again, in the second state, components that do not contribute significantly to the main current path during the cross-port fault equalization process are enclosed within hatched boxes with a dashed outline so that the remaining components can emphasize the fault current path.

Starting with source 3201, this source is connected to the input of a first transmitter output (inclusive of a transmitter switching barrier) comprising switches 3202 and 3204 with associated respective diodes 3203 and 3205. The output of the first transmitter output is connected to a first transmission line represented by crossline capacitance 3206, which is also connected to the input of a receiver front-end. The receiver front-end (inclusive of a receiver switching barrier) comprises diodes 3207 and 3208; and is connected to a link or bulk capacitance 3209. The output of the receiver front-end is connected to the input of a second transmitter output, wherein the second transmitter output (inclusive of a transmitter switching barrier) comprises switches 3210 and 3212 with associated respective diodes 3211 and 3213. The output of the second transmitter output is connected to a second transmission line represented by crossline capacitance 3214. The combination of the receiver front-end, the link capacitance, and the second transmitter output embodies a repeater device. Finally, a cross-port fault circuit is connected between the positive of the second transmission line and the negative of the first transmission line, wherein the cross-port fault circuit comprises fault switch 3215 and fault resistance 3216.

When the switches for both transmitter outputs are opened to initiate an isolation interval on both transmission lines, with the cross-port fault switch closed, a fault current path is formed through the repeater as shown in the second state in the bottom half of FIG. 32. Therefore, the methods disclosed herein for cross-port fault detection can be used in this scenario without modification. The cross-port fault can be detected by the first transmitter, the receiver, or the second transmitter using said methods.

In this FIG. 32, generalizing the language, with each receiver front-end inclusive of a receiver switching barrier and each transmitter output inclusive of a transmitter switching barrier; a first receiver front-end nominally isolates a first transmission line connected to its input from a bulk capacitor during isolation intervals and a second transmitter output nominally isolates a second transmission line connected to its output from the same bulk capacitor during isolation intervals, which is representative of a repeater device (i.e., the combination of the receiver front-end, the bulk capacitor, and the second transmitter). While the isolation intervals of both the receiver front-end and the transmitter output are at least partially overlapping, where this isolation interval of the receiver front-end may be driven by switching of the first transmitter connected to said first receiver front-end through the first transmission line, when a fault is connected from the negative-side of the first transmission line and the positive-side of the second transmission line, a fault current conducts through the positive-side unidirectional switching element of the first receiver front-end and returns through the negative-side unidirectional switching element of the second transmitter output.

While FIG. 32 shows the configuration where fault current conducts from the first transmission line to the bulk capacitor through the positive-side of the receiver front-end and the fault current conducts from the bulk capacitor to the second transmission line through the negative-side of the second transmitter output, these transmitter and receiver roles are swapped when the opposite fault orientation is present. In other words, when the fault is connected from the negative-side of the second transmission line and the positive-side of the first transmission line, the fault current conducts from the second transmission line to the bulk capacitor through the positive-side of the second transmitter output and the fault current conducts from the bulk capacitor to the first transmission line through the negative-side of the receiver front-end, with the crossline capacitances of the first and second transmission line along with the fault resistance completing the circuit as it did in the first fault orientation as shown in FIG. 32. While the labels “first” and “second” for the transmission lines were kept the same for ease of showing the change, these labels can be swapped (i.e., the transmission line connected to the transmitter output is labeled the first transmission line and the transmission line connect to the receiver front-end input is labeled the second transmission line) without changing the functionality, which is helpful in describing and understanding the generic methodology and different combinations of elements.

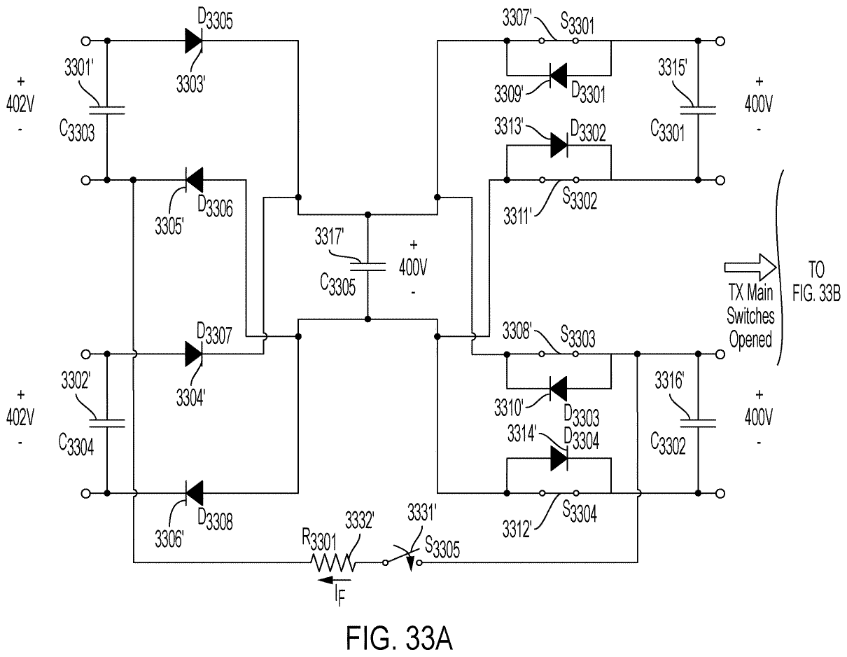

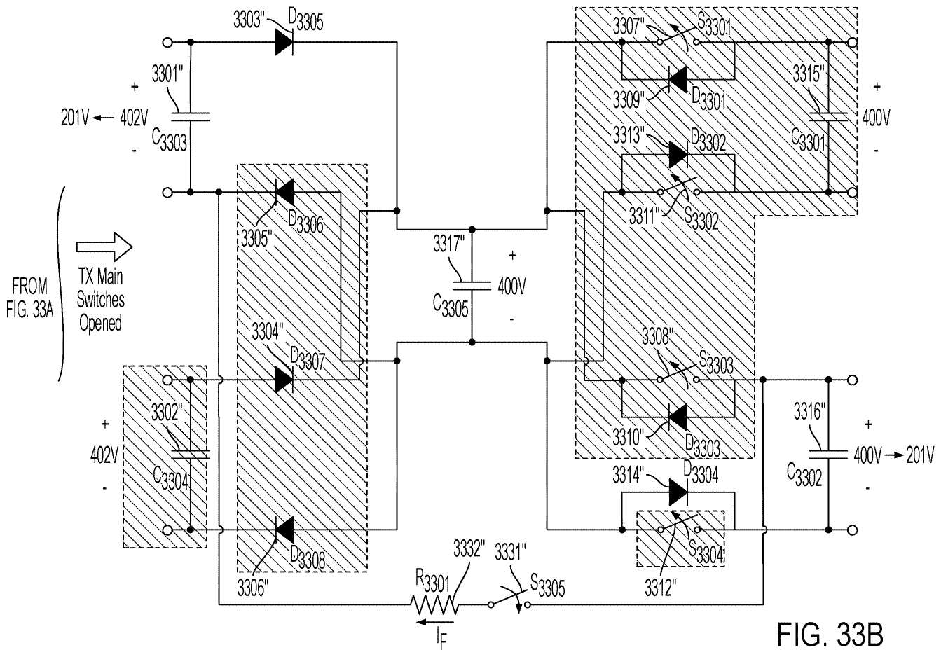

FIG. 33A and FIG. 33B show an expanded version of FIG. 32. With a plurality of receiver front-ends or transmitter outputs, this represents a possible state of a matrix switch that may feature such pluralities of channels; and this shows that the cross-port fault behavior and detection with a router is similarly applicable to a switch device such as a matrix switch or the 2×2 switch shown in FIG. 33A and FIG. 33B.

Again, the circuit is shown in 2 different states: in FIG. 33A, the circuit is shown in a first state when the main switches are all closed during a power transfer interval for each transmission line (callouts marked with prime symbol); and in FIG. 33B, the circuit is shown in a second state when the main switches are all opened during an isolation interval for each transmission line (callouts marked with double prime symbol). As before, components that do not contribute significantly to the main current path during the cross-port fault equalization process are enclosed within hatched boxes with a dashed outline so that the remaining components can emphasize the fault current path.

A first receiver front-end (inclusive of a receiver switching barrier) comprising diodes 3303 and 3305 is connected at its input to a first transmission line represented by crossline capacitance 3301. A second receiver front-end (inclusive of a receiver switching barrier) comprising diodes 3304 and 3306 is connected at its input to a second transmission line represented by crossline capacitance 3302. Not depicted is that each of the first and second transmission lines is connected to a distinct transmitter sourced by a 402V source. The outputs of the first and second receiver front-ends are connected to a common link or bulk capacitance 3317. A first transmitter output (inclusive of a transmitter switching barrier) comprising switches 3307 and 3311 with associated respective diodes 3309 and 3313 is connected at its input to the link capacitance 3317 and at its output to a third transmission line represented by crossline capacitance 3315. Similarly, a second transmitter output (inclusive of a transmitter switching barrier) comprising switches 3308 and 3312 with associated respective diodes 3310 and 3314 is connected at its input to the link capacitance 3317 and at its output to a fourth transmission line represented by crossline capacitance 3316. The combination of the first receiver front-end, the second receiver front-end, the first transmitter output, the second transmitter output, and the link capacitance comprises a 2×2 switch device. Finally, a cross-port fault circuit is connected between the positive of the fourth transmission line and the negative of the first transmission line, wherein the cross-port fault circuit comprises fault switch 3331 and fault resistance 3332.

When the switches for both the first and second transmitter outputs as well as the non-depicted transmitters connected to the first and second transmission lines are opened to initiate an isolation interval on all 4 transmission lines, with the cross-port fault switch closed, a fault current is conducted through the 2×2 switch device as shown in the second state in FIG. 33B. Therefore, again, the methods disclosed herein for cross-port fault detection can be used in this scenario without modification. In this scenario, the cross-port fault can be detected by the first receiver, the second transmitter, or the non-depicted devices connected to the first transmission line or the fourth transmission line.

The concept to understand in FIG. 33A and FIG. 33B is that the additional receiver front-ends and transmitter outputs that are not connected to the fault are superfluous-either these channels are also in an isolated state and do not factor in to the equivalent circuit as shown in FIG. 33B, or they are in a conductive state and therefore form a functionally equivalent circuit (e.g., capacitance 3315 adds in parallel with capacitance 3317 when switches 3307 and 3311 are closed, but this does not change the effective cross-port fault behavior).

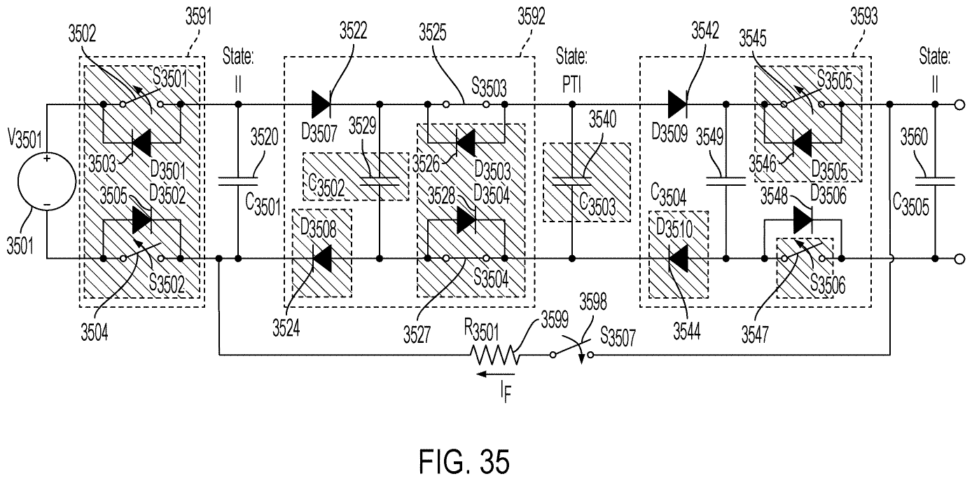

In a further expansion of embodiments involving a transmitter and a receiver, while FIG. 32 shows a cross-port fault between the input and output of a single repeater device, FIG. 32 can be expanded to include another repeater device as shown in FIG. 35; or more generally, a cross-port fault can also be detected across a plurality of chained repeater devices. A first example of this is shown in FIG. 35 with 2 repeater devices. Starting with source 3501 connected to the input of a transmitter output 3591, the transmitter output (inclusive of a transmitter switching barrier) comprises switches 3502 and 3504 with associated respective diodes 3503 and 3505. The output of the transmitter output is connected to a first transmission line shown in an isolation interval (II), wherein the first transmission line is represented by crossline capacitance 3520. This first transmission line is connected to the input of a first repeater 3592 comprising receiver input diodes 3522 and 3524, link or bulk capacitance 3529, and transmitter output switches 3525 and 3527 with associated respective diodes 3526 and 3528. The output of the first repeater is connected to a second transmission line in a power transfer interval (PTI), wherein the second transmission line is represented by crossline capacitance 3540. The second transmission line is also connected to the input of a second repeater 3593 comprising receiver input diodes 3542 and 3544, link or bulk capacitance 3549, and transmitter output switches 3545 and 3547 with associated respective diodes 3546 and 3548. The output of the second repeater is connected to a third transmission line in an isolation interval, wherein the third transmission line is represented by crossline capacitance 3560.

A cross-port fault circuit is configured to be connected between the positive of the third transmission line to the negative of the first transmission line. In the state as shown, with the cross-port fault switch closed, a fault current is conducted through the first and second repeater devices. Based on this, the methods disclosed herein for cross-port fault detection can be used in this scenario, wherein the cross-port fault can be detected by at least the transmitter, the first repeater (on the receiver input side), or the second repeater (on the transmitter output side).

In this FIG. 35, generalizing the language, with each receiver front-end inclusive of a receiver switching barrier and each transmitter output inclusive of a transmitter switching barrier; a first receiver front-end nominally isolates a first transmission line connected to its input from a first bulk capacitor during isolation intervals and a second transmitter output nominally isolates a second transmission line connected to its output from a second bulk capacitor during isolation intervals; wherein a chain of connections between the first bulk capacitor and the second bulk capacitor exists from the first bulk capacitor to a first intermediary transmitter output, then to a first intermediary transmission line, then to a first intermediary receiver front-end, then finally to the second bulk capacitor; and wherein the first receiver front-end, first bulk capacitor, and the first intermediary transmitter output are part of a first repeater device; and wherein the first intermediary receiver front-end, the second bulk capacitor, and the second transmitter output are part of a second repeater device. While the isolation intervals of both the first receiver front-end and the second transmitter output are at least partially overlapping with each other and this overlap is further at least partially overlapped with a power transfer interval of the first intermediary transmitter output and the first intermediary receiver front-end, when a fault is connected from the negative-side of the first transmission line and the positive-side of the second transmission line, a fault current conducts through the positive-side unidirectional switching element of the first receiver front-end and returns through the negative-side unidirectional switching element of the second transmitter output. In this case, while the first receiver front-end and the second transmitter output each isolates its respective transmission line from its respective bulk capacitor, it is only the second bulk capacitor that is part of the fault current loop; the first bulk capacitor does not conduct the fault current in this configuration. Given the advantage of potentially detecting additional fault scenarios such as this chaining of repeater devices, there is a motivation for a repeater device to avoid having completely concurrent isolation intervals between its receiver front-end and its transmitter output. This can further be applied to matrix devices, though the combinations of the timing of the isolation interval between each receiver front-end and each transmitter output may make such an avoidance of completely concurrent isolation interval more difficult, but not necessarily impossible in all scenarios.

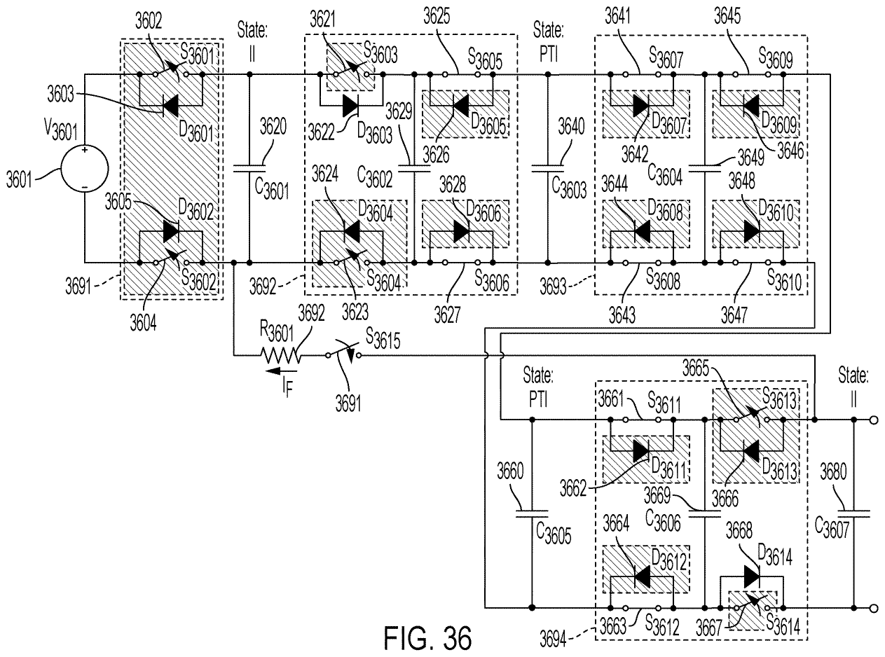

This repeater chaining embodiment can be expanded even further with additional repeaters and with synchronously switching receiver front-ends that use a switching element such as a MOSFET in place of the diode. This is shown in FIG. 36, where this switching element substitution has been made and a third repeater device has been added as compared to FIG. 35. In FIG. 36, source 3601 is connected to a transmitter output 3691 comprising elements 3602, 3603, 3604, and 3605 that correspond respectively to 3502, 3503, 3504, and 3505. The first transmission line is in an isolation interval (II) and represented by crossline capacitance 3620. This first transmission line is connected to the output of the transmitter output and the input of a first repeater device 3692. The first repeater comprises receiver input switches 3621 and 3623 with associated respective diodes 3622 and 3624, link or bulk capacitance 3629, and transmitter output switches 3625 and 3627 with associated respective diode 3626 and 3628. The output of the first repeater is connected to a second transmission line in a power transfer interval (PTI), wherein the second transmission line is represented by crossline capacitance 3640 and connected to the input of a second repeater device 3693. The second repeater device comprises elements 3641, 3642, 3643, 3644, 3645, 3646, 3647, 3648, and 3649 that correspond respectively to elements 3621, 3622, 3623, 3624, 3625, 3626, 3627, 3628, and 3629.

The output of the second repeater device is connected to a third transmission line in a power transfer interval (PTI), wherein the third transmission line is represented by crossline capacitance 3660 and connected to the input of a third repeater device 3694. The third repeater device comprises elements 3661, 3662, 3663, 3664, 3665, 3666, 3667, 3668, and 3669 that correspond respectively to elements 3621, 3622, 3623, 3624, 3625, 3626, 3627, 3628, and 3629. The output of the third repeater device is connected to a fourth transmission line in an isolation interval (II), wherein the fourth transmission line is represented by crossline capacitance 3680.

A cross-port fault is configured to be connected between the positive of the fourth transmission line and the negative of the first transmission line. In the state as shown, with the cross-port fault switch closed, a fault current is conducted through the first, second, and third repeater devices; and based on this, the methods disclosed herein for cross-port fault detection can be used in this scenario. In this scenario, the cross-port fault can be detected by at least the transmitter, the first repeater (on the receiver input side), or the third repeater (on the transmitter output side).

In this FIG. 36, generalizing the language, with each receiver front-end inclusive of a receiver switching barrier and each transmitter output inclusive of a transmitter switching barrier; a first receiver front-end nominally isolates a first transmission line connected to its input from a first bulk capacitor during isolation intervals and a second transmitter output nominally isolates a second transmission line connected to its output from a second bulk capacitor during isolation intervals; wherein a chain of connections between the first bulk capacitor and the second bulk capacitor exists from the first bulk capacitor to a first intermediary transmitter output, then to a first intermediary transmission line, then to a first intermediary receiver front-end, then to a first intermediary bulk capacitor, then to a second intermediary transmitter output, then to a second intermediary transmission line, then to a second intermediary receiver front-end, then to the second bulk capacitor; and wherein the first receiver front-end, first bulk capacitor, and the first intermediary transmitter output are part of a first repeater device; and wherein the second intermediary receiver front-end, the second bulk capacitor, and the second transmitter are part of a second repeater device; and wherein the first intermediary receiver front-end, the first intermediary bulk capacitor, and the second intermediary transmitter output are part of the first intermediary repeater device. While the isolation intervals of both the first receiver front-end and the second transmitter output are at least partially overlapping with each other and this overlap is further at least partially overlapped with a power transfer intervals of the first intermediary transmitter output, the first intermediary receiver front-end, the second intermediary transmitter output, and the second intermediary receiver front-end; when a fault is connected from the negative-side of the first transmission line and the positive-side of the second transmission line, a fault current conducts through the positive-side unidirectional switching element of the first receiver front-end and returns through the negative-side unidirectional switching element of the second transmitter output. In this case, the first bulk capacitor, the second bulk capacitor, the first intermediary bulk capacitor, and the capacitance of the first intermediary transmission line are all part of the fault current loop since these elements are all effectively connected in parallel in this configuration (i.e., assuming series resistance of the switches of the intermediary receiver front-ends and the intermediary transmitter outputs along with the transmission line are negligible).

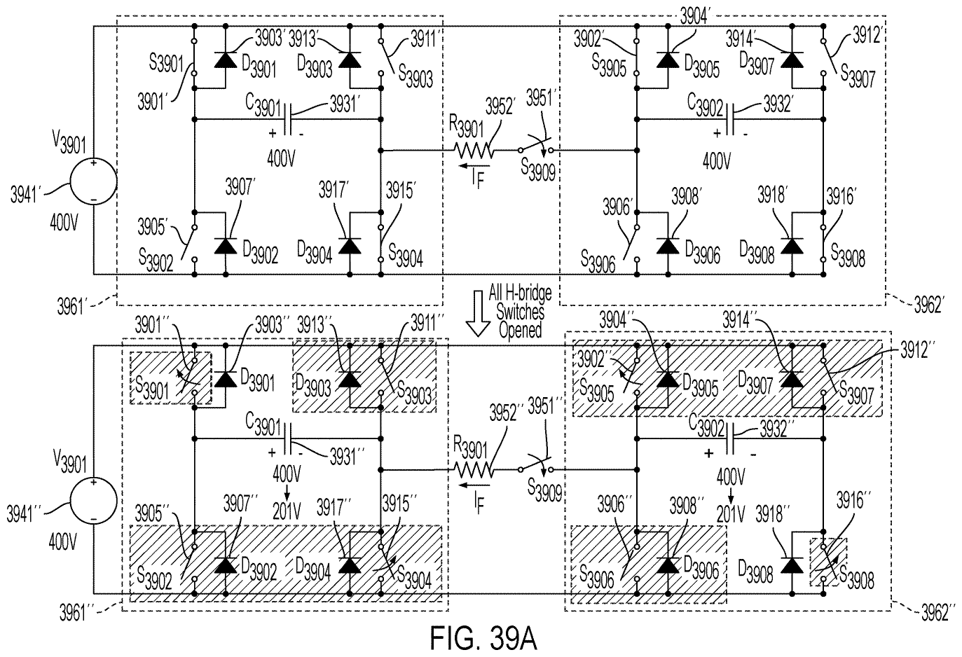

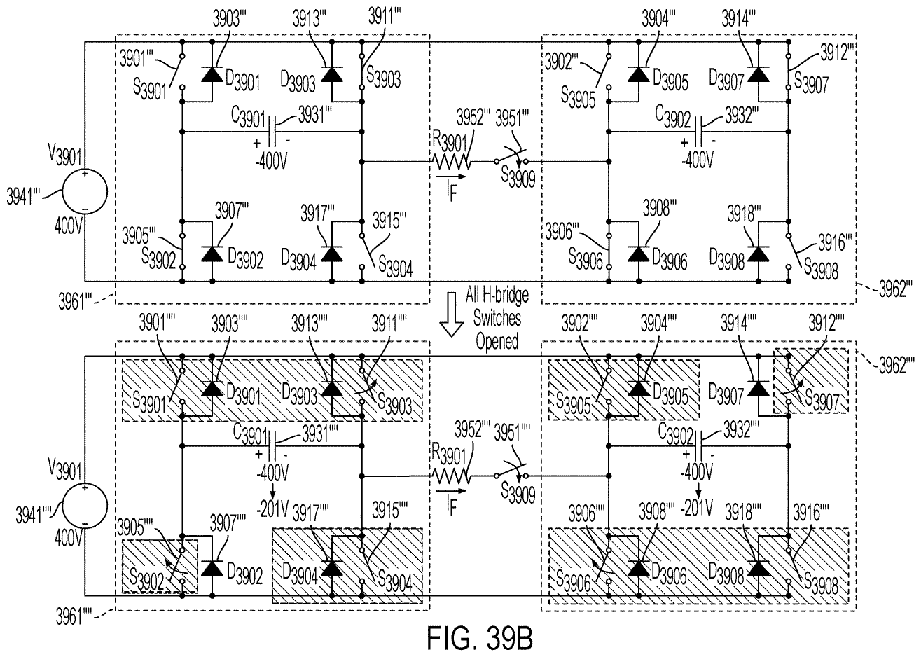

While the majority of embodiments are described for FMP systems based upon pulsed DC where transmission lines maintain one conductor as the positive conductor relative to the other conductor as the negative conductor, limited applicability exists for AC-based systems such as pulsed AC systems. This is shown in FIG. 39A and FIG. 39B, which includes a first H-bridge inverter circuit connected to a first transmission line represented by capacitance 3931 and a second H-bridge inverter circuit connected to a second transmission line represented by capacitance 3932. FIG. 39A and FIG. 39B show the cross-port fault behavior and applicability of the methods disclosed herein for cross-port fault behavior in an AC power embodiment utilizing an H-bridge switch configuration, wherein this is shown as a DC to AC inverter embodiment. FIG. 39A shows the relevant state during a first polarity of the AC cycle (e.g., the positive half cycle), with a first state wherein the relevant switches are closed analogous to a power transfer interval shown in the top half of the figure, and a second state wherein all switches are open analogous to an isolation interval shown in the bottom half of the figure. Elements in the first state in FIG. 39A are shown with callouts appended with a prime symbol while elements in the second state in FIG. 39A are shown with callouts appended with a double prime symbol. This is duplicated in FIG. 39B for a second polarity of the AC cycle (e.g., the negative half cycle), with elements in the first state in FIG. 39B shown using callouts appended with a triple prime symbol and elements in the second state in FIG. 39B shown using callouts appended with a quadruple prime symbol.

Describing the circuit arrangement, source 3641 is connected to a first H-bridge circuit 3961 and a second H-bridge circuit 3962. The first H-bridge circuit comprises switches 3901, 3905, 3911, and 3915 with respective diodes 3903, 3907, 3913, and 3917; along with output capacitance 3931. The elements 3901, 3903, 3905, 3907, 3911, 3913, 3915, 3917, and 3931 correspond respectively to elements 3902, 3904, 3906, 3908, 3912, 3914, 3916, 3918, and 3932 comprising the second H-bridge circuit. The cross-port fault circuit is configured to be connected from a first line of the output of the first H-bridge circuit to a second line of the output of the second H-bridge circuit, wherein the cross-port fault circuit comprises fault switch 3951 and fault resistance 3952. As shown, the first line and the second line are in phase, but the effect would be equivalent if they were 180° out of phase and the cross-port fault was connected to a different conductor (e.g., switch 3951 connected to the same conductor as switch 3912 instead of switch 3902); and the effect would be similar but a lesser magnitude with other phase alignments similar to checking the fault when the lines are in phase but at a different phase offset instead.

While this FIG. 39A and FIG. 39B each show a particular AC cycle polarity, it is understood that a control algorithm may, in fact, present a switch closure configuration of both FIG. 39A and FIG. 39B at distinct times for the same AC cycle polarity; and in this case, the cross-port algorithm is still applicable since the relevant circuit states are still presented to enable cross-port fault detection using these methods.

By arbitrary convention, the left terminal of each transmission line capacitance is line 1 of the respective H-bridge inverter circuit and the right terminal of each transmission line capacitance is line 2 of the respective H-bridge inverter circuit. In FIG. 39A, the fault connection is shown between line 2 of the first H-bridge inverter circuit and line 1 of the second H-bridge inverter circuit. When the fault is connected and all H-bridge inverter switches are open to nominally isolate during an effective isolation interval, and when the line 1 of each transmission line is a higher potential than the line 2 of the same transmission line, a fault current conducts through a first unidirectional switching element 3903″ and returns through a second unidirectional switching element 3918″ provided the summation of voltage across the transmission line and the voltage across the second transmission line is larger than the voltage source magnitude. Similarly, as shown in FIG. 39B, when the fault is connected and all H-bridge inverter switches are open to nominally isolate during an effective isolation interval, and when the line 1 of each transmission line is a lower potential than the line 2 of the same transmission line, a fault current conducts through a first unidirectional switching element 3914″″ and returns through a second unidirectional switching element 3907″″ provided the summation of voltage across the transmission line and the voltage across the second transmission line is larger than the voltage source magnitude.

Several limitations are observable in such a configuration. The fault current is only present during the isolation interval when the sum of the transmission line voltages exceeds the sum of the voltage supply magnitude and all diode forward-voltage drops. This means that portions of the AC phase where the line-to-line voltage is lower may not permit the fault current to flow during the isolation interval but may still by large enough during a power transfer interval that the fault would need to be detected to meet applicable safety standards within a specified amount of time, which may or may not be achievable depending on the voltages and fault resistance. The phase alignment between the transmission lines is also critical for the same reasons, which may or may not be at least partially controllable where the H-bridge inverter circuits for each respective transmission line are synchronized. At times when the fault current does conduct during the isolation interval, there is a further challenge that the magnitude of the electrical characteristics indicative of a fault may not be large enough to set an appropriate limit until a more substantial effect is reached, such as when larger line-to-line voltages across each transmission line are reached.

Regardless of the efficacy and challenges of implementation in a pulsed AC system, such an embodiment is useful in describing the general behavior of cross-port faults. A critical feature exhibited by this pulsed AC embodiment is that the cross-port fault method is not limited to transmission lines that maintain the same positive-negative orientation of its conductors nor a transmission line that maintains the same positive-negative orientation of one of its conductors relative to one of the conductors of another transmission line; what matters is the positive-negative orientation at the time of the fault and at the time of measurement.

With these embodiments described, a generic description of the physics and methodology can be described through abstraction to more generic terms. To this end, a “fault conducting device” is introduced to refer to a device that contains a unidirectional switching element or a capacitive coupling through which the cross-port fault current flows during an isolation interval (i.e., the fault current still flows through the capacitive coupling of a switching element; i.e., a displacement current). This can be a transmitter or a receiver, or a sub-portion thereof (e.g., receiver front-end). More generically, a fault conducting device can comprise a power distribution device.

A “fault monitoring device” is introduced to refer to a device that monitors for the electrical characteristics of the fault. This can be a transmitter or a receiver, or it can be another type of device, such as a management device that does not provide a high-power output port. The functionality of the fault monitoring device may be split between devices. In such an embodiment, a receiver may be the device that measures the electrical characteristics, but then these may be communicated to a management device that performs the calculations and analysis to determine if a fault is present, wherein a single management device may support such actions for a plurality of receiver devices, and wherein the management device does not need to be directly connected to the transmission line or switch (or related circuitry) for which the measurements are taken. It is understood that this effectively makes the combination of the receiver and the management device as a “fault monitoring device”.

A “voltage maintaining element” is introduced to refer to a device that opposes a change in voltage with respect to time. By definition, this can be a capacitor, but it also applies to a constant voltage source or any voltage-controlled circuit. This is the essential element that prevents a unidirectional switch from conducting when nominally isolating during an isolation interval in a digital electricity system, such as preventing a diode from conducting by keeping it reverse biased. In this regard, the magnitude of the voltage change opposition must be at least large enough to prevent the unidirectional switch from conducting while nominally isolating during an isolation interval, such as by ensuring a slower time constant on the side of the switch containing the voltage maintaining element as compared to the other side of the switch, or by regulating a higher voltage on the side of the switch containing the voltage maintaining element as compared to the other side of the switch. As such, this is not an essential element of the cross-port fault detection method but rather a normal element of a digital electricity system. In embodiments detecting switch voltage imbalance, the role of the voltage maintain element is less critical, but still serves to ensure that there is a voltage that is measurable across each switch in order to measure an imbalance, with the degree of voltage change opposition also being less critical so long as there is enough of a voltage to measure an imbalance.

With these generic terms defined, a formal definition of the methodology for cross-port fault detection can be constructed. In a fault managed power (FMP) transmission system including a first transmission line comprising a high potential conductor and a low potential conductor configured to be connected to a first fault conducting device and a second transmission line comprising a high potential conductor and a low potential conductor configured to be connected to a second fault conducting device; wherein the first fault conducting device connects a first voltage maintaining element to the first transmission line via a first switch during power transfer intervals and nominally isolates the first voltage maintaining element from the first transmission line during isolation intervals and the second fault conducting device connects a second voltage maintaining element to the second transmission line via a second switch during power transfer intervals and nominally isolates the second voltage maintaining element from the second transmission line during isolation intervals; and wherein a first fault monitoring device is connected to the first transmission line or the first switch, and a second fault monitoring device is connected to the second transmission line or the second switch; the method comprises: during a concurrent interval of when an isolation interval of the first fault conducting device and an isolation interval of the second fault conducting device are at least partially overlapping, monitoring by a first fault monitoring device or a second fault monitoring device for an electrical characteristic indicative of a first fault current through a first unidirectional switching element in the first fault conducting device in a direction flowing from the first transmission line to the first voltage maintaining element or an electrical characteristic indicative of a second fault current through a second unidirectional switching element in the second fault conducting device in a direction flowing from the second voltage maintaining element to the second transmission line indicative of a cross-port fault between the lower potential conductor of the first transmission line and the higher potential conductor of the second transmission line; and in response to detecting an electrical characteristic indicative of either a first fault current or a second fault current, limiting said detected first fault or said second fault current within a predefined amount of time.

With this method defined, some additional clarifications are now made. While the voltage maintaining elements are defined as 2 distinct elements in order to describe the general case, it is understood that these can be the same element in some embodiments, and this electric circuit equivalence is obvious to one skilled in the art. In other words, the first voltage maintaining element and second voltage maintaining element may not necessarily be implemented in a circuit as 2 distinct circuit elements, but may still be equivalently represented if that single circuit elements can be split in half, such as 2 capacitors in parallel or 2 voltage sources in parallel. Similarly, while the fault currents are described as a first fault current and a second fault current, these will typically be substantially the same fault current as one is the return path for the other; but in practice, some differences may be observed depending on other leakage paths and the balance of values between various circuit components.

A fault monitoring device may be the same as a fault conducting device or it may be different; what is essential is the transmission line or switch (or related circuitry) to which each device is connected. In other words, the first fault monitoring device and the first fault conducting device may be the same since they are connected to the same transmission line or the same switch, but the first fault monitoring device and the second fault conducting device cannot be the same device since they must be connected to distinct transmission lines or distinct switches. This does not preclude, however, that these first and second devices are enclosed within the same encapsulating device. For example, a receiver with 2 receiver front-ends and 1 output control and conditioning circuit may be viewed as a single “receiver” device, but functionally, each receiver front-end is a distinct fault conducting device and at least part of a distinct fault monitoring device since characteristics of each transmission line or fault conducting device must be monitored distinctly, where there may be a shared receiver controller that completes each fault monitoring device. In another example, a repeater device may encapsulate a receiver and a transmitter and therefore may encapsulate the first and second fault conducting device and first and second fault monitoring device when the cross-port fault is present from the repeater input to the repeater output, but the repeater device can be sub-divided based on functionality, wherein the receiver portion is the first fault conducting device and the first fault monitoring device while the transmitter portion is the second fault conducting device and the second fault monitoring device, making an allowance for some partially shared fault monitoring functionality if there is a single controller that processes the fault monitoring data for both fault monitoring devices as previously explained herein.

Through this repeater embodiment, it is evident that the first fault monitoring device and the second fault monitoring device can be the same, singular fault monitoring device in some cases. This is easiest to realize when the singular fault monitoring device has direct access to both the first transmission line and the second transmission line of the fault or the first switch and the second switch of the fault; but other variations are possible. When this direct access is not feasible, the singular fault monitoring device can be embodied in a distributed fashion, wherein a sensing and communication portion is present at each transmission line, and the resulting measurement data is communicated to a fault assessment portion of the singular fault monitoring device; wherein this communication can be inline communications as taught by Eaves '795 and other variations. This can be expanded to monitor many additional transmission lines by the singular fault monitoring device to implement this fault detection method or to implement supervisory fault detection methods described herein.

An alternative generalization of the methods and apparatus for cross-port fault detection and line-to-earth detection is realized when described in terms of transmission line side and non-transmission line side elements. With a device that can be embodied as a transmitter or a receiver, the device comprises a transmission line port, a switching barrier, and a non-transmission line port. The transmission line port is configured to be connected to a first transmission line comprising a high potential conductor and a low potential conductor, wherein the transmission line port comprises a high-side transmission line port terminal and a low-side transmission line port terminal, and wherein the high-side transmission line port terminal is configured to be connected to the high potential conductor and the low-side transmission line port terminal is configured to be connected to the low potential conductor. The non-transmission line port similarly comprises a high-side non-transmission line terminal and a low-side non-transmission line terminal. The switching barrier comprises a high-side switch and a low-side switch, wherein the high-side switch is connected between the high-side non-transmission line terminal and the high-side transmission line terminal, and the low-side switch is connected between the low-side non-transmission line terminal and the low-side transmission line terminal. The high-side switch and the low side switch are configured to be closed to electrically connect the transmission line port to the non-transmission line port during a power transfer interval and to at least partially isolate the transmission line port from the non-transmission line port during an isolation interval.

During the isolation interval, a control circuit, during the isolation interval, measures one or more of the transmission line voltage, the high-side leakage current, the low-side leakage current, the high-side switch voltage, or the low-side switch voltage; wherein the transmission line voltage is indicative of a voltage of the high-side transmission line terminal to the low-side transmission line terminal, the high-side leakage current is indicative of a current flowing through the high-side switch from the high-side transmission line terminal to the high-side non-transmission line terminal, the low-side leakage current is indicative of a current flowing through the low-side switch from the low-side non-transmission line terminal to the low-side transmission line terminal, the high-side switch voltage is indicative of a voltage across the high-side switch as the high-side non-transmission line terminal relative to the high-side transmission line terminal, and the low-side switch voltage is indicative of a voltage across the low-side switch as the low-side transmission line terminal relative to the low-side non-transmission line terminal.

When the transmission line voltage is below a first threshold, when the high-side leakage current is above a second threshold, when the low-side leakage current is above the second threshold, when the high-side switch voltage is above a third threshold, or when the low-side switch voltage is above the third threshold, a fault is determined to exist. Upon determining that the fault is present, a disconnect mechanism is activated. The fault comprises a line-to-earth fault, or a cross-port fault between a first fault conductor of the first transmission line and a second fault conductor of a second transmission line; wherein the first fault conductor comprises the high potential conductor of the low potential conductor; and wherein the first fault conductor is a distinct potential from the second fault conductor.

There are further less common embodiments that can implement the methods described herein, particularly where one of the switching elements does not switch to a nominally isolating state during an isolation interval either due to an internal failure or due to a deliberate operation. Here it is helpful to define the fault-side switch and the non-fault-side switch for the AE/DE switching barrier of each fault conducting device involved in a cross-port fault. In FIG. 11, these fault-side switches are 1102 and 1105 with associated respective diodes 1104 and 1107, and the non-fault-side switches are 1101 and 1106 with associated respective diodes 1103 and 1108.

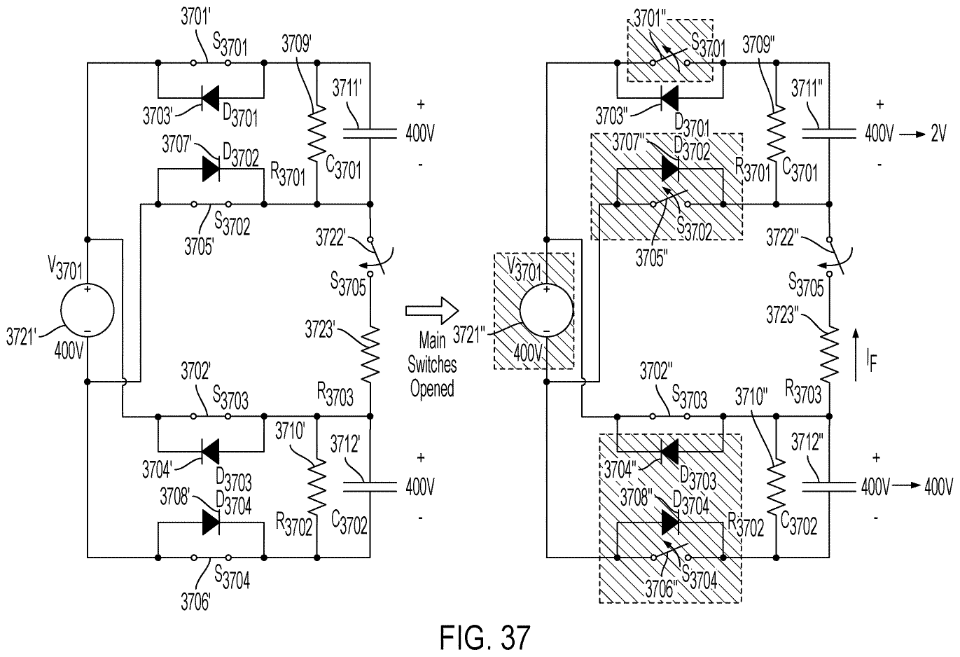

One such case is where one of the switches that comprises the AE/DE switching barrier remains in a closed position during an isolation interval, wherein said switch is a fault-side switch in the AE/DE switching barrier of one of the fault conducting devices. When said switch remains in a closed position during the isolation interval while in the presence of a cross-port fault, the electrical characteristics indicative of a cross-port fault are still present, but are only present on a single transmission line and therefore only a single fault monitoring device is required. This can be visualized using FIG. 37 while supposing that switch 3702 remains in a closed position during the isolation interval.

The circuit in 2 distinct states shown in FIG. 37 shows this variation of a cross-port fault effect when one of the switches remains closed during an isolation interval. Again, on the left half, the circuit is shown in a first state when the main switches are closed during a power transfer interval (callouts marked with prime symbol); and on the right half, the circuit is shown in a second state when the main switches except for one switch are open during an isolation interval (callouts marked with double prime symbol). In the second state, components that do not contribute significantly to the main current path during the cross-port fault equalization process are enclosed within hatched boxes with a dashed outline so that the remaining components can emphasize the fault current path.

The circuit shows a first channel in the top half and a second channel in the bottom half. The first channel comprises a first transmitter and an effective crossline output impedance, wherein the first transmitter comprises switches 3701 and 3705 with respective diodes 3703 and 3707, and wherein the effective crossline output impedance comprises a resistance 3709 and a capacitance 3711. These elements 3701, 3703, 3705, 3707, 3709, and 3711 correspond respectively to elements 3702, 3704, 3706, 3708, 3710, and 3712 to comprise the second channel, with 3702, 3704, 3706, and 3708 comprising a second transmitter. Completing the circuit is source 3721 connected to the input of each transmitter as well as the cross-port fault circuit comprising fault switch 3722 and fault resistance 3723.

In this example in FIG. 37, the first fault current still flows through the first unidirectional switching element (i.e., 3703; i.e., a non-fault-side switch) in the first fault conducting device, but it returns through the fault-side switch on the positive-side that remains in a closed position (i.e., 3702) in the second fault conducting device. When this occurs, some of the electrical characteristics indicative of the cross-port fault are only present on the first transmission line (i.e., the first transmission line and parallel components are represented as a simplified bulk model by capacitance 3711 and resistance 3709), including at least the initial voltage drop. In other words, 2 fault monitoring devices are only required for complete safety coverage if the fault-side switches in the AE/DE switching barrier for both fault conducting devices are open during the isolation interval. Note that if the fault-side switches in the AE/DE switching barrier for both fault conducting devices remain in a closed position during the isolation interval, neither the first nor second fault monitoring device will be able to detect some of the electrical characteristics indicative of a cross-port fault since said characteristics are not present, including at least the initial voltage drop. Regardless of whether one or both fault conducting devices keep their fault-side switches in a closed position, alternative methods for cross-port detection can still be implemented, such as those predicated on current measurements including leakage currents and current differentials, described herein.

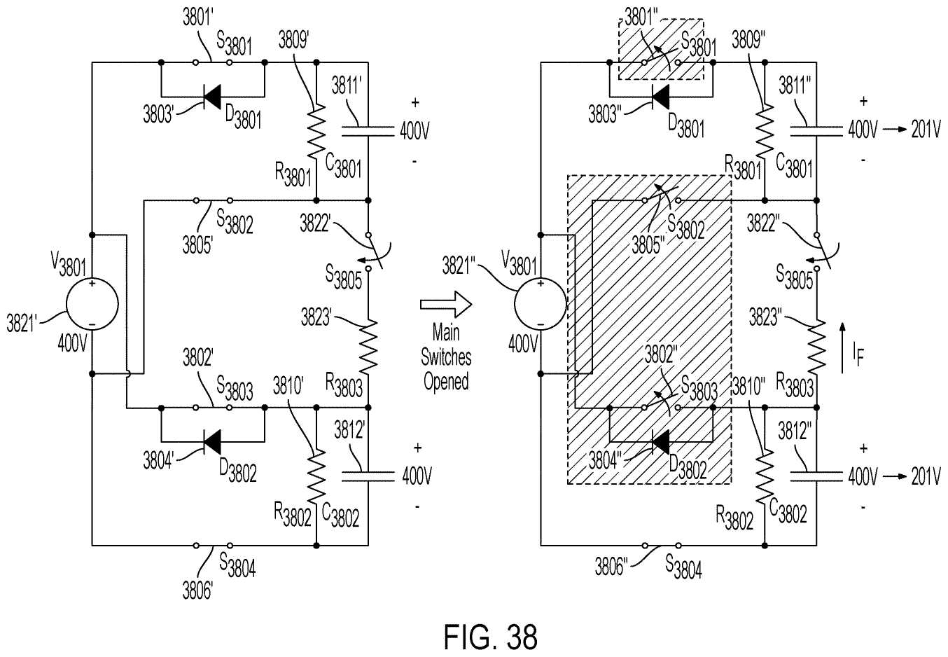

In another less common embodiment wherein a switching element does not switch to a nominally isolating state during an isolation interval, if one of the unidirectional switches that conducts the first or second fault current remains in a closed position and therefore continues to conduct current in either direction, the method still works as described, and it is understood that this is an equivalent embodiment. This is demonstrated more clearly where one of the unidirectional switches is comprised of the parallel combination of an electromechanical relay and a diode, which is impractical at any substantial switching frequency but is useful for clear distinction. In FIG. 11, if switch 1106 is implemented as this electromechanical relay while diode 1108 embodies a discrete diode, and if said electromechanical relay remains closed during the isolation interval, the cross-port fault method described herein still functions despite the second fault current conducting through the relay and not through the diode 1108. In this case, the “unidirectional switching element” is denoted as the parallel combination of the relay and the diode, so while the second fault current does not flow through the diode if the relay remains closed, it still holds true that the “unidirectional switching element” conducts the second fault current. Even if the diode is omitted to make the relay truly a bidirectional switch, this still behaves functionally equivalent to a unidirectional switch when the bidirectional switch is in a closed position, so it is understood that this is also an equivalent embodiment as shown in FIG. 38.

The organization of FIG. 37 is duplicated in FIG. 38 with most of the circuit matching up with respective components, with the difference being that a different switch remains in a closed state during an isolation interval, wherein 2 switches including the switch remaining in a closed state are purely bidirectionally blocking switches without unidirectional elements. As such, elements 3801, 3802, 3803, 3804, 3805, 3806, 3809, 3810, 3811, 3812, 3821, 3822, and 3823 correspond respectively to elements 3701, 3702, 3703, 3704, 3705, 3706, 3709, 3710, 3711, 3712, 3721, 3722, and 3723. The first transmitter comprises elements 3801, 3803, and 3805 while the second transmitter comprises elements 3802, 3804, and 3806. The first channel then comprises the first transmitter along with elements 3809 and 3811 while the second channel comprises the second transmitter along with elements 3810 and 3812.

Note that if switch 1105 or 3805 simultaneously remains in a closed position while switch 1106 or 3806 is also in a closed position during an isolation interval, this cross-port fault detection method does not apply since this effectively becomes a single-side switching embodiment that is electrically equivalent to a line-to-line fault across a single transmission line and is therefore detected using the methods taught in Eaves '637 and others, or is detected using current measurement methods described herein.

Many embodiments can be implemented in combination. One skilled in the art will be able to ascertain the compatibility of various methods.

Embodiments describe using a receiver, but these can be performed without a receiver where applicable, and this is shown non-exhaustively in many of the figures herein. For example, without a receiver connected, a transmission line connected to a transmitter will still exhibit reflections for which a transmitter can negate with a properly matched snubber circuit that is periodically disconnected to allow other essential functions to be performed properly. Some of these embodiments may not be as useful without a receiver, such as improving the inline voltage drop measurement; but that does not preclude their usage to allow a generalized implementation to simplify the system. For example, a transmitter that operates without a receiver connected can still use a snubber circuit to improve its inline voltage drop measurement, and while this will likely produce a measurement of an inline voltage drop of nearly 0 whether the snubber is used or not, the improvement in the accuracy of said measurement can be observable when a receiver is connected without any need to change the method being executed, and there are no significant false results produced when no receiver is connected. In embodiments of cross-port fault detection with unidirectional switching, no receiver is required to be connected provided that the transmitter features unidirectional switching. In a similar vein, embodiments may be applied and adapted to systems that include multiple receivers connected to a single transmitter; multiple transmitters connected in parallel to one or more receivers; multiple transmitters connected in series to one or more receivers; and systems that may connect a receiver's output to the input of one or more transmitters, which may be designed as separate devices or may be enclosed as a single device. In such a multidrop configuration with a plurality of receivers, many of the methods to determine the receiver input voltage will, in fact, overestimate the inline voltage drop, thereby erring on the side of safety. In some of these system architectures, synchronization methods or communication methods may be critical to implement to ensure proper implementation of the disclosed methods and apparatus. Depending on the system architecture, adjustments to limits to factor in multiple devices or the circuit layout of these architectures may be required.

While many embodiments are either explicitly or implicitly primarily DC systems in order to simplify explanations, this does not preclude adaptations for AC systems in said embodiments. This may entail consideration of different frequencies, using different impedances to achieve similar blocking effects, and other changes that are known to one skilled in the art. In embodiments relying upon unidirectional switching, similar effects may be possible through the adaptation of which direction is blocked and which direction is permitted based upon the phase of the AC signal. In other AC systems, rectification of some parts of the circuit may also simplify design or help realize practical implementation of these methods.

While many embodiments have been described in the context of line-to-line operation, these embodiments can also be adapted for line-to-earth and other applicable locations. The most common arrangement for line-to-earth implementation would utilize a balanced approach, where the same circuitry and methods are used positive-to-earth as well as earth-to-negative. In some cases, unbalanced operation may be a sufficient trade-off. In some cases, unbalanced operation may allow the implementation of different algorithms to detect different fault scenarios. Line-to-earth snubbers in particular may provide better common-mode voltage stabilization compared to the common mode voltage oscillations that may be seen by a receiver relative to a transmitter during transitions switching transients including transitions between the power transfer interval and the isolation interval. The periodic disconnect of the snubber would still permit unfettered execution of existing earth ground fault detection algorithms, whether such algorithms are active or rely upon high impedance networks to limit the fault current to a safe level, where the snubber circuit may otherwise defeat such fault current limiting when connected.

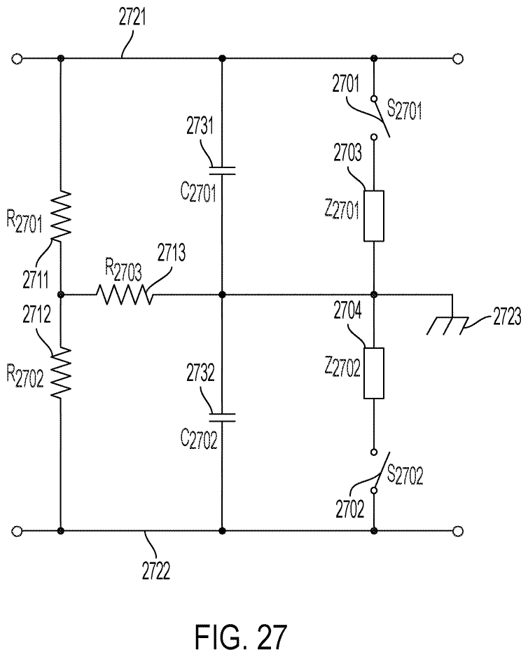

An embodiment of a line-to-earth snubber configuration is shown in FIG. 27. Between a first line 2721 and the earth ground node 2723, a first snubber circuit is connected; wherein the first snubber circuit comprises the series combination of switch 2701 and impedance 2703. Similarly, between a second line 2722 and the earth ground node 2723, a second snubber circuit is connected; wherein the second snubber circuit comprises the series combination of switch 2702 and impedance 2704. This is shown in conjunction with the current-limited center-tied earth ground circuit that may be implemented as well in accordance with other embodiments, wherein this circuit comprises resistance 2711 and 2712 connected between each line and a center point as well as a resistance 2713 connected between the center point and the earth ground node 2723. This also shows any effective Y-capacitance that may be present between each line and earth ground as capacitance 2731 and 2732.

It is understood that the disclosed methods can be used in combination with existing methods of fault detection. For example, while the snubber is disconnected during the isolation interval, methods of Eaves '637, Mlyniec '494, and others can be employed for series and parallel fault detection. Further enhancements can be made to these methods as described as follows. The methods of anomaly fault detection described by Mlyniec '494 can be used for arc fault detection, where the threshold for the fault must be set such that a reasonable amount of signal noise is permitted but alterations to the signal as a result of an arc fault will be determined to be a fault. Arc faults are a significant fault that can quickly lead to electrical fires and are a primary concern in electrical safety fault detection. The methods of Eaves '637 that look for a significant voltage drop or voltage slope to detect a crossline fault can be further enhanced for protection and robustness by considering the severity of the fault and the pulsed nature of the system.

Additional consideration may be required when the threshold of a pulse is reached, where the threshold that defines a pulse may be defined as 5% of its peak; or a let-go limit including 7.07 mA, 30 mA, 30V, 60V; or any other applicable limit as defined in academic literature and relevant industry safety standards. When multiple pulses of current pass through the heart in short succession, the onset of ventricular fibrillation requires less current for the same pulse duration until it approaches an asymptotic value. This can be factored into the methods of Eaves '637 and others by looking for this pulse threshold and registering a fault when falling below this pulse threshold. When this pulse threshold is not reached, the multiple pulse derating is not applicable, potentially allowing more time to detect the fault. This could allow the fault to persist for multiple power transfer intervals, allowing the fault detection to validate the measurements before turning off. When the multiple pulse derating is applicable, this validation over multiple power transfer intervals may still be an option if the fault current is sufficiently low as determined by measurements or worst-case analysis.

This validation over multiple power transfer intervals provides robustness and resiliency against so-called “nuisance trips” due to false positives of the fault detection execution. Similarly, while it is typically desirable to determine the presence of a fault during an isolation interval before turning back on for the next power transfer interval, it may also be acceptable for this determination to be made after the next power transfer interval has started to avoid increasing the isolation interval duration due to required computational time or to allow a subsequent check to confirm the fault which may be the same check method or a different check method, wherein this is feasible provided the required fault detection time will not be exceeded. A further robust embodiment that permits a plurality of failed checks before registering a fault tracks the number of failed checks over a time interval for each type of fault detection individually since each type of fault detection may have different response time requirements (e.g., a line-to-line fault versus a line-to-earth fault), hence effectively giving different types of fault detection the option to have different weighting factors. This embodiment can additionally consider a plurality of different types of fault detection failing a check or consider a failed check for a type of fault detection that may preclude a valid assessment of a different type of fault (e.g., a failed check for an anomaly fault detected by Mlyniec '494 may indicate that a line-to-line fault check per Eaves '637 does not have valid data to perform an accurate assessment). In these cases, the aggregation of the plurality of different types of fault detection failing a check can be also evaluated to register a fault prior to any individual type of fault detection would register a fault based on the number of failed checks; or when there is a shrouded type of fault detection that cannot be properly assessed due to the preclusion of a distinct type of fault detection that is failing a check, the shrouded type of fault detection can be assumed to have failed a check to err on the side of safety.

When the pulse threshold is reached, the multiple pulse derating can be factored in to turn off in a shortened amount of time. In a simple embodiment, whenever a threshold is reached that includes at least the threshold of a pulse that is distinct from transients or noise that are not applicable to the multiple pulse derating, the system can immediately turn off instead of permitting additional power transfer intervals to verify the fault. This determination can be incorporated into methods of auto-ranging limits and operation described by Casey '067.

While the most robust operation is attained by using bidirectional switches to connect and disconnect the snubber circuit, many systems may find unidirectional switching acceptable. By blocking current flow out of the snubber, crossline fault and inline fault detection methods by Eaves, et al. and cross-port fault and inline fault detection methods described herein function without hinderance. Some ancillary or other minor benefits may be appreciated by fully isolating the snubber circuit when it is disconnected, and certain algorithms may require bidirectional blocking, such as AC circuit embodiments.

In some instances in this specification where operation involving two transmitters is described, it is implied in these cases that this may comprise two separate transmitter units or a transmitter containing multiple copies of transmitter circuitry in one unit, otherwise referred to as transmitter channels.

Where rates are specified, these can be effectively replaced with mathematically similar representations. A rate can be calculated by 2 points over time. A rate can also be calculated from a multitude of points, such as a linear regression or any other linear or non-linear curve fitting technique. While a rate may most accurately be calculated based on the data within the time range over which the rate applies, the rate may also be estimated using data outside of said time range if the impact to accuracy is within an acceptable tolerance or is negligible. It is understood that a rate is the same as a slope and as a derivative such as dV/dt. In some contexts, the rate may also be expressed as a ratio of an initial and final value or vice versa.

Similarly, the disclosed methods typically describe steps to be performed to attain a reasonable best accuracy. Alternative steps can be performed using the same principles but with less accuracy if there is a reason to prefer the alternative steps using trade-offs that are obvious to one skilled in the art. For example, while the best accuracy for the inline voltage drop is attained by using the voltage before the snubber is disconnected, a less accurate evaluation can be performed with the voltage after the snubber is disconnected. This may reduce performance aspects such as the operational range when no fault is present, but it will provide a more conservative operation with respect to safety.

Applying limits on a rate can be done in any equivalent method. In a straight-forward case, a rate limit can be compared directly against a measured or calculated rate. In another equivalent method, a change in a value magnitude or a calculated relative or absolute value magnitude can be compared against a limit or used as a limit after a fixed time interval, where the fixed time interval is either a constant or is determined based on a previous measurement or other relevant data. Basing the time interval upon a previous measurement or other relevant data may be done to consider factors such as required detection time, measurement resolution, and speed of measurement among other factors. Similarly, the value magnitude and time could be swapped such that a change in time or a calculated relative or absolute time can be compared against a limit or used as a limit after a specified magnitude value is observed, where the specified magnitude value may be a change or a relative value or an absolute value, and where said magnitude value may be a fixed constant or may be determined based on a previous measurement or other relevant data.

“Droop”, such as “voltage droop”, may refer to a difference between 2 values or a difference in 2 values over time, the usage of which is clarified in context when essential.

Where “voltage” is used, an alternative method may be accomplished by using current instead. For example, measuring a voltage between 2 points may be equated to measuring a current through a sufficiently high resistance connected between said 2 points, where this current is an example of a value indicative of voltage. Similarly, where “current” is used, an alternative method may be accomplished by instead using voltage across a current shunt, a hall effect sensor, or any other relevant current sensing method. The applicability of this interchangeability is known to one skilled in the art. To this end, an effort has been made to capture this equivalence by referring to a “value indicative of” a desired property; but wherein such language has been omitted, it is understood that it can be equivalently applied by one skilled in art. It is also understood that, while many embodiments show the snubber being used to reduce ringing in voltage waveforms, the snubber can also be shown to produce similar reduced ringing in current waveforms.

In many contexts, the terms “source” and “transmitter” are interchangeable, such as when describing the end of a line or a generalized device. For the same reasons, “load” and “receiver” are interchangeable in similar contexts. Along the same lines, while “transfer period” and “sample period” may be descriptive terms in the context of a digital electricity system, these can also refer generically to a “on-time” and “off-time” of switches, respectively. “Power transfer interval”, “energy packet”, and “transfer period” are synonymous; as are “isolation interval” and “sample period”.

In circuits that feature mirrored circuitry between the positive and negative rails, it is understood that many algorithms that are implemented on one side or on one side relative to the other can also be implemented with the rails swapped. For example, detecting a leakage current on a positive rail could also be implemented as a leakage current detected on the negative rail. In another example, a positive rail current being high relative to a negative rail current could also feature detection of a negative rail current being high relative to a positive rail current.

Many figures depict a switch in parallel with a diode. In some embodiments, these may be separate components. In other embodiments, this may be a single component such as a MOSFET that features a body diode effect. Unless design requirements demand a specific implementation (e.g., specific diode characteristics are required that are not effectively achievable with a MOSFET's body diode), these embodiments are interchangeable. In general, where a switch is depicted or described, many known embodiments of a switch can be considered, including but not limited to a diode including an SCR or TRIAC; a transistor including a BJT, IGBT, MOSFET, or JFET; relay; or other semiconductor or electromechanical devices that can be controlled between a conducting and non-conducting state. The selection of an appropriate switch can be determined by one skilled in the art based upon the requirements of the methods and apparatus disclosed herein such as unidirectional blocking capability along with other typical considerations such as switching frequency, voltage and current requirements, and other similar design specifications. Note that many embodiments of a switch feature an intrinsic capacitive coupling across the switch terminals (e.g., output capacitance from drain-to-source for a MOSFET), and while this is not depicted in figures for simplicity, this capacitance may further comprise a switch for at least the embodiments herein that factor the effect of said capacitance into the methods and apparatus (e.g., a fault current path for a cross-port fault using bidirectional switches).

While many aspects and embodiments describe methods performed at a single end, such as by the transmitter, many of these methods could also be performed at a different end, such as by a receiver, in place of or in addition to. One skilled in the art can easily make this determination. For example, a snubber to cancel reflections can be placed at a multitude of locations, including at a transmitter, at a receiver, or both. In another example, a capacitive snubber circuit to improve inline voltage measurement can be placed at the receiver, but the capacitor may need to be larger and the time constant carefully selected, or a larger error must be considered acceptable as there is reduced margin between the voltage during the power transfer interval and the receiver link voltage. In this example, the receiver cannot directly measure the transmitter voltage during the power transfer interval, so alternative methods for the receiver to incorporate the transmitter or source voltage are required for the receiver to perform the inline power loss evaluation, or this method will need to be restricted to being implemented in a transmitter. Implementing in multiple locations may increase complexity but improve robustness through redundancy, while implementing in a single location may be more cost effect. In both cases, the impact to functional safety and various risk analysis are among the considerations that a designer may need to weigh. For example, implementing in multiple locations may increase the burden of functional safety analysis; but it may provide a necessary or desirable improvement over critical factors as compared to a single device implementation, such as the safe failure fraction.

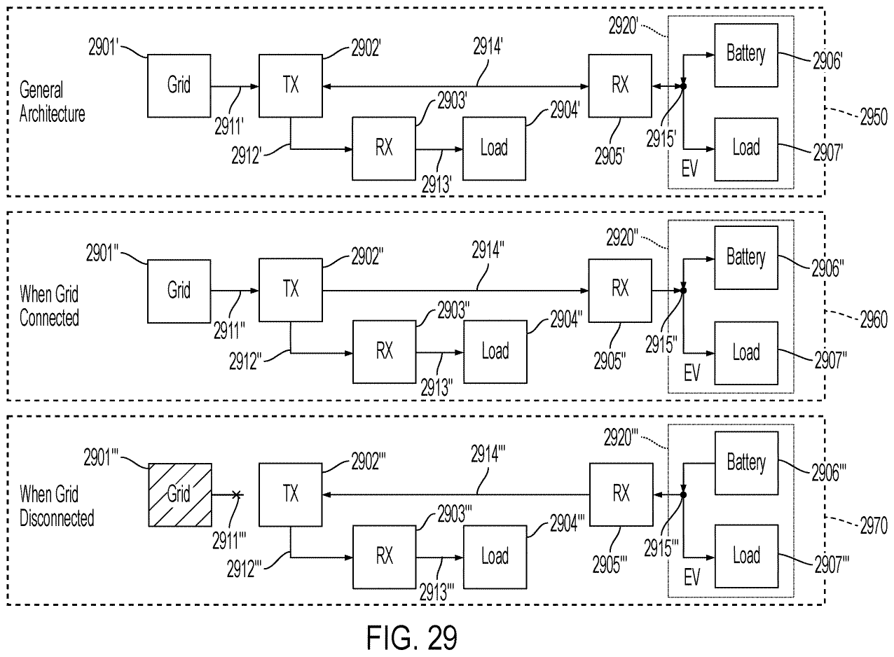

Devices that implement functionality of a transmitter and of a receiver are commonly defined as being located at the source end and the load end, respectively; but this can change on the fly, including on a per-pulse basis where bidirectional power transfer may be employed. An illustrative use case and benefit of bidirectional power transfer is depicted in FIG. 29. The exemplary system architecture is shown in 3 different states-a generalized state 2950, a grid connection state 2960, and a grid disconnection state 2970. The callout for each element in these diagrams is appended with a prime symbol, a double prime symbol, or a triple prime symbol depending on whether the element refers specifically to the state 2950, 2960, or 2970, respectively. All transmitters and receivers are configured for bidirectional power transfer on at least the DE-side of each device. Arrows on each transmission line end indicate the direction or possible direction of energy transfer.

Using the generalized state to introduce the elements, grid 2901′ is configured to be connected to transmitter 2902′ to provide power via transmission line 2911′, typically in a power format distinct from DE. Transmitter 2902′ receives the power from grid 2901′ and outputs said power to a first receiver 2903′ via transmission line 2912′ in a DE power format. This first receiver 2903′ then provides power to a first load 2904′ via transmission line 2913′, typically in a power format distinct from DE. Transmitter 2902′ also provides power to a second receiver 2905′ via transmission line 2914′ in a DE power format. This transmission line 2914′ is expected to support bidirectional power transfer. Transmitter 2902′ may provide distinct transmitter output channels for each receiver, or may support multi-drop by using a single transmitter output channel to connect to both receivers, which implies transmission lines 2912′ and 2914′ are electrically connected.

The second receiver 2905′ is connected to both a battery 2906′ and a second load 2907′. For at least illustrative purposes, this connection is shown as the second receiver 2905′ connecting to the battery and the second load via a transmission line 2915′ that includes an intermediate node that allows the power transfer directions to be indicated in this figure. As shown, the second receiver and the battery have a bidirectional power transfer capability to and from this intermediate node, while the second load can only draw power from this intermediate node. The battery 2906′ and the second load 2907′ may be encapsulated as an embodiment of an Electrical Vehicle (EV).

When the grid is connected as shown in state 2960, some of the transmission lines assume a specific power transfer direction. Specifically, transmission line 2914″ becomes a unidirectional power transfer from the transmitter 2902″ to the second receiver 2905″; and the output of second receiver 2905″ to the intermediate node of transmission line 2915″ becomes unidirectional to transfer power out of said receiver. The battery 2906″ maintains a bidirectional power transfer, as the battery may be either charging from the second receiver or discharging to power the second load. In rare circumstances, such as a grid brown out, the battery 2906″ may provide power to the second receiver 2905″ and the second receiver 2905″ may provide power to the transmitter 2902″, but this is not depicted.

When the grid is disconnected as shown in state 2970, some of the transmission lines assume a different specific power transfer direction. With transmission line 2911′″ effectively disconnected to isolate the grid 2901′″ from transmitter 2902′″, the battery 2906′″ becomes the only significant energy source available in the system. The battery 2906′″ transfers power unidirectionally to the second load 2907′″ and the second receiver 2905′″ via transmission line 2915′″. The second receiver 2905′″, in turn, transfers power to transmitter 2902′″ via transmission line 2914′″, which the transmitter 2902′″ can use to continue to provide power to the first receiver as it had when the grid was connected in state 2960.

The power transmission systems including digital electricity systems described herein can be used in a point-to-point, multi-drop, or multi-master architecture except where specific methods or embodiments prohibit certain architectures. In other words, the type of device and the number of each type of device do not necessarily prohibit the operation of said power transmission systems. Practical limits exist for the total number of devices regardless of type, largely due to signal resolution and the magnitude of desired effects.

It similarly follows that any number of network topologies can be applied, including point-to-point, daisy chaining as either linear or ring topology, star, and distributed bus. A mesh topology is possible where a transmitter contains multiple transmitter output channels and therefore has multiple transmission lines connected, or a receiver contains multiple receiver input channels and therefore has multiple transmission lines connected. A mesh topology with a single transmission line is possible, but is generally impractical from a power distribution perspective.

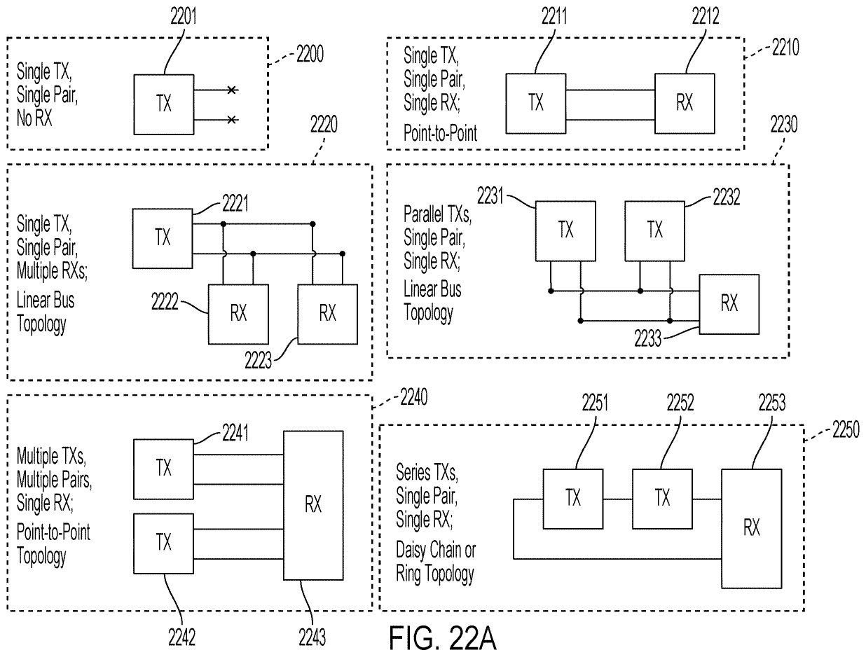

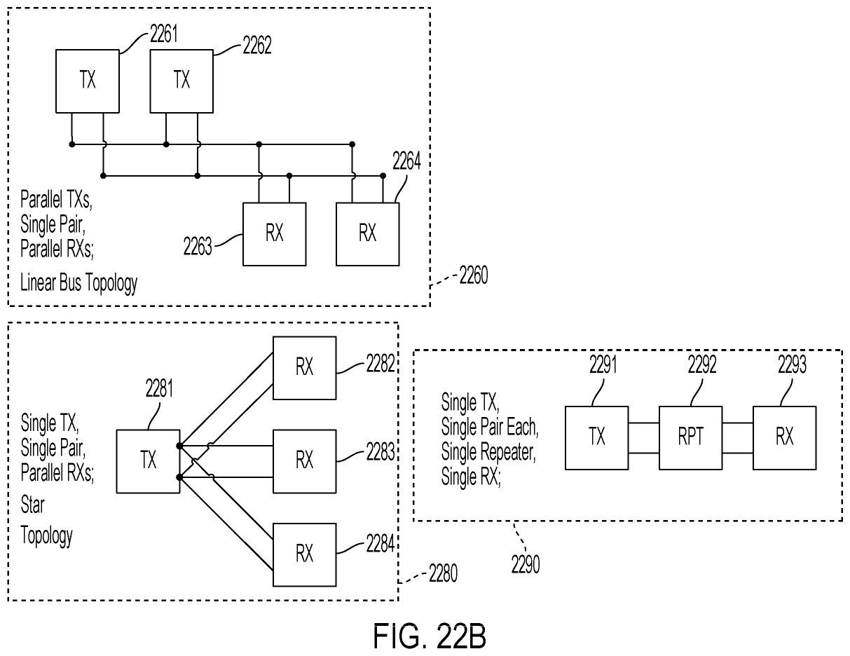

These possible topological and architectural arrangements of transmitters and receivers are shown in FIG. 22A and FIG. 22B. Starting in FIG. 22A with arrangement 2200, a single transmitter 2201 is configured to be connected to a single pair transmission line with no other devices connected. This is particularly useful in a system that supports hot plug receivers, as the transmitter can remain on and ready to speed up the startup process. Arrangement 2210 shows a single transmitter 2211 connected to a single receiver 2212 with a single pair transmission line. This point-to-point topology is among the most common used for power transmission in a DE system.

Expanding to include a plurality of a type of device, arrangement 2220 shows a single transmitter 2221 connected to a plurality of receivers 2222 and 2223 via a single pair transmission line, thereby demonstrating the applicability of a linear bus topology. Arrangement 2230 is also a linear bus topology, but this features a plurality of transmitters 2231 and 2232 connected to a single receiver 2233 via a single pair transmission line. Such a multiple transmitter arrangement can be realized in a digital electricity system using at least the methods of Weiss '479.

Continuing with multiple transmitter arrangements, arrangement 2240 also features a plurality of transmitters 2241 and 2242 connected to a single receiver 2243, but this time each transmitter is connected to a distinct single pair transmission line. This embodies a receiver that includes a plurality of DE-side receiver front-end circuits, and is still considered a point-to-point topology. Arrangement 2250 also shows a plurality of transmitters 2251 and 2252 connected to a single receiver 2253, but this returns to having a single pair transmission line; however, instead of a bus topology, a daisy chain or ring topology is utilized by stacking the transmitters in series. This is particularly useful to increase the total voltage delivered to the receiver, such as each transmitter accepting a solar panel input, a battery input, or any isolate supply input as a source and adding this input in series between the transmission line input and transmission line output. While shown with only 1 conductor path connected through each transmitter, a more common embodiment would include the other supply/return conductor to also pass through each transmitter, as this allows each transmitter to use this to at least sense the total voltage output for safety reasons.

Continuing in FIG. 22B with other arrangements featuring more devices, arrangement 2260 shows another linear bus topology, but this now includes a plurality of transmitters 2261 and 2262 as well as a plurality of receivers 2263 and 2264 connected via a single pair transmission line, effectively combining the implementation details of arrangements 2220 and 2230.

While arrangement 2200 shows a plurality of receivers connected in a linear bus topology, other topological arrangements are also possible. Arrangement 2280 shows this by arranging a single transmitter 2281 connected to a plurality of receivers 2282, 2283, and 2284 in a star topology, wherein the transmission line is branched at the transmitter output. Hybrid combinations of this are possible as well, such as the bus being partially a linear bus and conforming to a star topology at a certain branching point that may or may not be in the vicinity of a transmitter or receiver.

Introducing the repeater, arrangement 2290 shows a single transmitter 2291 connected via a first single pair transmission line to an input of a repeater 2292, wherein the output of the repeater 2292 is connected via a second single pair transmission line to a receiver 2293. This can be viewed as a daisy chain topology or as a plurality of point-to-point topology arrangements.

These arrangements are not an exhaustive list, nor are they mutually exclusive of each other. For example, while many arrangements are shown with single pair transmission lines, the multiple pair configuration of arrangement 2240 can be applied to many of the other arrangements. These combinations as well as applying other topologies known in power or communications networking are obvious to one skilled in the art.

It is understood that the terms “transmitter” and “receiver” do not necessarily restrict a method or apparatus at a particular end unless required, where this determination can be made by one skilled in the art. For example, a transmitter can open a switch to initiate an isolation interval, but a receiver could also open a switch to initiate an isolation interval in some embodiments. In this aspect, the transmitter and receiver can be interchangeable for this functionality. In another example, a transmitter utilizes an algorithm that measures voltage before and after a disconnect switch is opened to determine the voltage drop of the cable. In this embodiment, this measurement must be done by the device that is at a higher potential during the power transfer interval since the other device does not have the higher voltage information in this particular implementation. In other words, what matters is direction of current flow or energy transfer, not strictly the name of the device; and this can be determined in an obvious fashion using known principles by one skilled in the art. This does not preclude receiver-side determination of the cable voltage drop when the higher potential is at the transmitter end of the transmission line. The receiver can utilize a method where a transmitter's switches are closed and the receiver's switches are opened to obtain a voltage measurement of the transmitter end of the transmission line when there is negligible current and also measure the voltage and current when transmitter and receiver switches are closed in order to calculate the cable voltage drop, power loss, and series resistance. This can also be done more generically as a method where the receiver measures the voltage and current at 2 sufficiently distinct current levels in order to calculate the slope of the I-V curve, which is the series resistance of the cable by definition. The receiver could also attain further robustness by obtaining multiple datapoints, using linear regression and other statistical line fitting methods, using integration, and implementing other mathematical techniques to monitor the average power loss of the cable continuously and completely.

Where unidirectional switching is required, a multitude of equivalent embodiments exist. A diode can function as a unidirectional switch, where it allows current flow in one direction from anode to cathode but not significantly in the reverse direction. A diode can be used in combination with another switch, such as a MOSFET to allow current flow in both directions while the MOSFET is closed and to return to a unidirectional operation when the MOSFET is open. In other embodiments, the body diode effect of a MOSFET can be utilized in place of a separate discrete diode. Other means of providing current flow in one direction and significantly reduced current flow can also be used, whether these are by active or passive means. While unidirectional switching refers to an ideal embodiment where absolutely zero current flow is permitted in one direction, practical embodiments will likely have some small leakage current in this direction that is intended to have zero current flow, and this should be considered to ensure it is within tolerance. For example, a diode may exhibit a reverse leakage current from cathode to anode, but if this current is sufficiently small, this will not impair proper operation. Continuing with this example, a diode in a high-power path will likely have a reverse leakage current several orders of magnitude smaller than the normal permitted current flow from anode to cathode. The relative difference in current levels between the forward and reverse directions does not necessarily require a difference of several orders of magnitude.

It is understood that, while a switch can be an element that has an “open” and “close” state, it can in general be any element that significantly changes the impedance from a low impedance to a higher impedance state based on a signal. This difference in impedance level is at least an order of magnitude, and is more commonly several orders of magnitude.

Where a unidirectional switch is specified, the orientation of this unidirectional functionality is dependent on the system design intentions. For example, in a digital electricity system, during the isolation interval, one design goal is to isolate the transmission line from energy transfer between the transmission line and both the source and the load for at least a portion of time during the isolation interval. With DC transfer from the source to the load and a properly sized receiver link capacitance, a desired unidirectional switching orientation can be attained with diodes, including body diodes of MOSFETs, oriented such that positive-side diodes have their anodes connected to the transmission line and negative-side diodes have their cathodes connected to the transmission line. These must be aligned with the unidirectional switching orientation required by the disclosed methods in order to be compatible. For example, for cross-port fault detection in a DC digital electricity system, the desirable orientation of unidirectional switches is one that permits energy transfer out of the transmission line and blocks energy transfer into the transmission line from the non-transmission-line side of said switches.

While a comprehensive disclosure of devices such as a transmitter and receiver has been described, not every component is necessarily required, nor is each component necessarily required in the exact position described, nor do such descriptions preclude the addition of other components. For example, a transmitter may be made without a negative fuse and can instead be made with only a single fuse connected to the positive source, where said fuse 203 could be placed after resistance 204 in the current path from the source positive connected to terminal 239 to the secondary switch 207. This is a decision that could be made by one skilled in the art based on factors such as cost, probability of failure, failure modes and effects analysis, functional safety, and circuit analysis, among others. In another example, components could be added, such as bypass capacitors and other components that improve EMC, as is common by one skilled in the art. Common components may be refactored into a single location to avoid duplication. For example, in a system with a single source and multiple transmitters, the earth ground balance resistors 204, 205, and 208 could be moved to a position where only 1 set is required instead of including a set for each transmitter. When deciding on which components to include, the only components required are the ones that serve a critical function for the particular methods or apparatus that are being implemented.

In more precise terms, when discussing DE functionality, circuits can be described more accurately by identifying the portions of the circuit that are in a Digital Electricity (DE) format and the portions of the circuit that are in an Analog Electricity (AE) format, where said AE format covers forms of electrical power transfer distinct from DE, such as AC and DC forms. A transmitter comprises a transmitter AE-side circuit, an AE/DE switching barrier, and one or more transmitter DE-side circuits. Similarly, when discussing DE functionality, a receiver comprises a receiver AE-side circuit, an AE/DE switching barrier, and one or more receiver DE-side circuits. It is understood that within these functional components may exist further sub-circuits, such as a receiver AE-side circuit containing power conversion circuitry, one or more output ports, or other analog/digital input/output control ports. An effort has been made to standardize this nomenclature, but in instances where these functional component names have not been used, they can be discerned from context both within this disclosure and in prior art publications. For example, based on context, it can be determined if a “transmitter” refers to a single device containing a transmitter AE-side circuit, an AE/DE switching barrier (i.e., a transmitter switching barrier), and one or more transmitter DE-side circuits; or may instead refer to only the AE/DE switching barrier and a single transmitter DE-side circuit. This is similarly analogous for “receiver” references. A “transmitter output” may refer to a single transmitter DE-side circuit, but it may also include an AE/DE switching barrier in some contexts. Similarly, a “receiver front-end” may refer to a single receiver DE-side circuit, but it may also include an AE/DE switching barrier (i.e., a receiver switching barrier) in some contexts. These contexts are clear to one skilled in the art, as the embodiment may not be functional or may be overly restrictive if functional components are omitted.

Many similar terms are used to refer to these terms through this disclosure. An “AE/DE switching barrier” is sometimes abbreviated as a “switching barrier”. An “AE-side” of a transmitter may be referred to as an “input bus”, an “input side”, or a “non-transmission-line side”. A “DE-side” of a transmitter may be referred to as an “output bus”, an “output side”, or a “transmission-line side”. Similarly, for a receiver, an “AE-side” of a receiver may be referred to as an “output bus”, an “output side”, or a “non-transmission-line side”, wherein this receiver AE-side may further be characterized as an “output control and conditioning circuit” or a “receiver link circuit”. A “DE-side” of a receiver may be referred to as an “input bus”, an “input side”, or a “transmission-line side”, wherein this receiver DE-side may further be characterized as a “receiver front-end” or “receiver front-end circuit”. These terms are used selectively in certain contexts to add clarity to the function being served or to show generalizations that are possible (e.g., similarities between methods or apparatus relating to a transmitter and a receiver).

The interface on each side of an AE/DE switching barrier may further be referenced in some contexts. While the “DE-side” and “AE-side” terms (and related terms) are often used to refer to these interfaces, the interfaces themselves may be referred to as link interfaces. An “AE-side link interface” or “AE link interface” may be referred to as an “input link interface” for a transmitter or an “output link interface” for a receiver. Similarly, a “DE-side link interface” or “DE link interface” may be referred to as an “output link interface” for a transmitter or an “input link interface” for a receiver. This language can similarly be adapted to use the term “port” in place of “interface” to describe the same effective representation.

The individual nodes or terminals of each interface can further be referenced specifically. These include a “high-side AE link terminal” that can be a “high-side input link terminal” for a transmitter (i.e., 242) or a “high-side output link terminal” for a receiver (i.e., 325); a “low-side AE link terminal” that can be a “low-side input link terminal” for a transmitter (i.e., 243) or a “low-side output link terminal for a receiver (i.e., 326); a “high-side DE link terminal” that can be a “high-side output link terminal” for a transmitter (i.e., 244) or a “high-side input link terminal” for a receiver (i.e., 344); and a “low-side input link terminal” that can be a “low-side output link terminal” for a transmitter (i.e., 245) or a “low-side input link terminal” for a receiver (i.e., 345). This language can similarly be adapted to use the term “node” in place of “terminal” to describe the same effective electrical connection. While this is used to describe “high-side” and “low-side”, in accordance with the teachings within this disclosure, this does not necessitate a limitation to only 2 lines and can be applied to more than 2 lines as described in relevant embodiments (e.g., with 3 lines, “high-side” and “low-side” may refer to the effective potential difference between 2 lines connected to a cross-port fault).

In many contexts, the effective methods and apparatus are relevant with respect to these link interfaces, and one skilled in the art would be able to determine whether a DE-side reference effectively refers to a link interface when reduced to the essential aspects to implement an embodiment, for example.

While “DE-side” and “AE-side” imply applicability to Digital Electricity systems, this does not necessarily preclude the applicability to other forms of Fault Managed Power systems or other power or communication systems, as analogous methods or apparatus can be identified by one skilled in the art (e.g., identification of switches that can be used as an “AE/DE switching barrier” despite the application being a system distinct from Digital Electricity). These terms are used to be labels and do not necessitate limitations to a specific embodiment by the origins of the terms themselves.

Wherein conductors of a transmission line are described as comprising a low potential conductor and a high potential conductor (or a lower potential conductor and a higher potential conductor), it is understood that these potentials are not a specific potential and are, in fact, relativistic potentials in accordance with how voltage is defined (i.e., voltage must always be defined as relative between two points). It is understood that these high potential and low potential conductors as well as a first fault conductor at a distinct potential from a second fault conductor must be of a sufficient difference in potential to require fault detection in order for the methods disclosed herein to provide utility. For example, as shown in FIG. 26, with the conductors effectively connected to fault resistance 2624 when fault switch 2622 is closed and fault switch 2623 is open, these conductors are at approximately the same potential during concurrent power transfer intervals and may not reach a significant potential difference when an isolation interval overlaps with a power transfer interval of a distinct channel and therefore may not require detection. A sufficiently high potential to require fault detection is typically defined as one that exceeds a let-go limit when a current let-go limit is also exceeded.

In embodiments that perform at least some measurements or calculations for an assessment of safe operation, this can be expanded to cover more general applications as well as refined with some specific embodiments. The assessment of safe operation can be any method with an associate apparatus that is appropriate for implementation in the given state. In one embodiment, during a critical time interval that is a portion of an isolation interval wherein a snubber circuit is not connected, the assessment of safe operation can be any of the relevant methods of Eaves '637, Mlyniec '494, Weiss '930, Casey '067, Eaves '997, Eaves '220, or any other methods defined by other Fault Manager Power implementations or other safety methods distinct from Fault Managed Power. The chosen method for assessment of safe operation dictates the measurements, calculations, or operations required along with any additional apparatus needed. Using the method of Eaves '637, Mlyniec '494, or Casey '067, the measurements include at least a plurality of measurements indicative of a crossline transmission line voltage.

Expanding on a general application for assessment of safe operation, the assessment of safe operation may be performed by a device distinct from the device that operated a snubber circuit. For example, a receiver may operate a snubber circuit, but it may rely on a transmitter connected to the same transmission line to perform the assessment of safe operation. In such a case, the method is embodied by the transmitter obtaining data for an assessment of safe operation of the transmission system. From the perspective of the receiver for this case, the method is embodied as the receiver obtaining data for an assessment of safe operation of the transmission system by receiving or obtaining data from the transmitter indicative of an assessment of safe operation of the transmission line by the transmitter. Another way to view this is that the data obtained by the receiver is the assessment of safe operation of the transmission line by the transmitter. This received data could comprise measurements, results of calculations and other operations, descriptive information such as whether a safety check was passed or failed, or any other data the receiver can use to conclude whether or not the transmission system is in a safe condition. This data may be exchanged using a communication protocol, or it may be conveyed using simple signaling methods. For a receiver in particular, the transmitter continuing to supply power to the receiver can comprise such a signal that comprises the data. This similarly applies to a transmitter, wherein a transmitter obtaining data for an assessment of safe operation of the transmission system can comprise receiving or obtaining data from a receiver indicative of an assessment of safe operation of the transmission by the receiver. For example, the receiver may implement the safety methods taught in Eaves '637, and the measurements, results of calculations, or conclusion of whether the transmission system is in a safe condition may comprise the data that the transmitter obtains from the receiver as the assessment of safe operation of the transmission system.

It is further clarified in these cases wherein a first transmitter or a first receiver obtains data for an assessment of safe operation of the transmission system during an isolation interval, wherein the data is an assessment of safe operation of the transmission system during an isolation interval by a second transmitter or a second receiver, it is not necessarily essential that the data is obtained by the first transmitter or the first receiver during an isolation interval; what is essential is that the second transmitter or the second receiver perform the assessment of safe operation of the transmission system during an isolation interval. In other words, what matters is that an assessment of safe operation of the transmission system is performed during an isolation interval, but this data may be obtained at a distinct time. For example, the second transmitter or the second receiver may take measurements during an isolation interval, but these measurements may be communicated to and received by the first transmitter or the first receiver at a time that may or may not be during an isolation interval.

Detection limits for various embodiments disclosed herein can be defined in many ways. When specifying a threshold for a transmission line voltage during an isolation interval for cross-port fault detection, the threshold may be defined relative to a non-transmission line voltage, an initial transmission line voltage measured during a power transfer interval, or a maximum possible transmission line voltage; wherein the threshold is typically defined as no less than half of the chosen relative voltage; and wherein the maximum possible transmission line voltage may comprise the maximum rating a power source connected to a transmitter input port, the maximum rating of a transmitter or a receiver, or the maximum rating of a system.

When specifying a threshold for a reverse current or a leakage current through a switch during an isolation interval for cross-port fault detection, the threshold may be defined relative to a let-go threshold; wherein the let-go threshold comprises a DC let-go limit or an AC let-go limit. The threshold may be defined as no more than a positive let-go limit or no less than a negative let-go limit depending on the orientation of the current measurement apparatus and the switch (e.g., high-side or low-side). Alternatively, when the reverse current or the leakage current being outside of a predefined range is indicative of a cross-port fault, the predefined range may comprise a range from a negative let-go limit to a positive let-go limit.

In embodiments wherein a first value is compared to a threshold to determine if a fault is present and the threshold is defined relative to a second value, it is understood that this is inclusive of other equivalent mathematical representations. For example, comparing a first value to a first threshold wherein the first threshold is defined relative to a second value is equivalent to comparing an arithmetic combination of the first value and the second value to a second threshold, wherein the first threshold and the second threshold differ by an amount equal to the second value.

Where a system detects a fault and turns off, “faults out”, activates a disconnect mechanism, enters a degraded or offline state, registers a fault, mitigates a fault, limits the current through a fault, is disconnected, or any other similar action to handle a fault when detected, this could also be replaced by equivalent actions that result in a safe state with consideration of a possible fault being present. Instead of completely isolating for a time interval until it is permitted to retry, such as 3 seconds, a system could fallback to a lower voltage or lower power mode in order to limit fault current while still permitting some power transmission. This action taken when a fault is detected can be generalized as limiting the system to an electrical constriction limit. Depending on context, this limiting could be to no more than a positive electrical constriction limit, no less than a negative electrical constriction limit, or within a range from a negative to a positive of an electrical constriction limit. This electrical constriction limit can be one or more of a current limit, a voltage limit, a charge limit, a power limit, or an energy limit; or it can be any other chosen level of an alternative or composite characteristic to limit when a fault is detected, such as one prescribed by a standard or guideline. With respect to shock faults such as leakage faults, this constriction limit most commonly is a let-go limit; wherein the let-go limit is typically defined as 30 mA for DC based systems and 7 mA for AC based systems, with a curve typically defined for electrical power that may be a composite of AC and DC components; and wherein the let-go limit in terms of voltage is typically 60V for DC and 42.4V for AC under dry conditions, and 30V for DC and 21.2V for AC under wet conditions. With respect to a power limit comprising the electrical constriction limit, the power limit can be within any requirement of any relevant standard or guidelines, such as a maximum transmitter power of 100 W. Many of these requirements can be combined into limiting the energy transfer from an input port to an output port or from a non-transmission line port to a transmission line port, such as averaging the power over time to comprise an energy limit equivalent to a 100 W power limit over a given time interval; or the energy limit can comprise a value indicative of a let-go current limit. With respect to inline faults, the electrical constriction limit can be an inline power or inline power loss difference at a level that reduces the risk of an electrical fire, such as 15 W; or it can be an inline energy, such as one over a sliding time window. In this inline fault scenario, it may be possible to still transfer an appreciable amount of power between a source and load while limiting the system (e.g., limiting the current to the load or the voltage supplied), providing a benefit over alternative disconnect mechanisms such as opening a switch to cease all high power transfer. Note that not all disconnect mechanisms are applicable in all cases (e.g., a receiver cannot directly disconnect a power source connected to a transmitter input from the transmission line to which the receiver is connected), and the appropriate disconnect mechanisms can be determined by one skilled in the art.

Activating a disconnect mechanism, instead of or in addition to, may comprise signaling to another device or taking action to limit the available fault energy, available fault current, or available fault voltage. A communications protocol and apparatus, whether an inline communications protocol and apparatus or an external communications protocol and apparatus may be used to signal to another device, wherein the external communications apparatus may comprise optical fiber, conductors distinct from the conductors used for power transmission particularly those conductors upon which a fault was detected, or a wireless system such as Wi-Fi, Bluetooth, cellular radio, and others known in the art. Signaling another device may comprise a simpler signaling method and apparatus, such as intentionally connecting a crossline resistance across the transmission line that will be interpreted as a fault resistance by another device such as a transmitter connected to the same transmission line, wherein the fault resistance is within the detection range of the other device. Taking action to limit the available fault energy may further be accomplished through methods and apparatus such as connecting a clamp circuit across the transmission line to limit the available fault energy, available fault current, or available fault voltage. This can be effective even for a receiver where does not directly control whether a power source is connected to the transmission line. Taking such actions is best used in conjunction with other methods such as disconnecting a power source from the transmission line or signaling another device to do so.

Many methods described herein incorporate logical components. Such logical components could be implemented in software (i.e., embedded firmware), in hardware, or some combination thereof. Many considerations will advise on the optimal solution, including cost, complexity, resiliency, robustness, functional safety impact, size, and other typical design factors. In particular, this is applicable to controllers, including transmitter controllers and receiver controllers that may embed a microcontroller, microprocessor, or other equivalent compute device; but may also or instead include analog or digital circuitry to execute a particular method.

Where possible, circuits and components may be used for multiple purposes in order to reduce the need for additional components as is a typical design consideration. For example, instead of a cross-line snubber circuit and a positive-to-earth and earth-to-negative snubber circuits, some applications may be able to omit the dedicated cross-line snubber circuit in favor of the line-to-earth snubber circuits where said line-to-earth snubber circuits will sufficiently accomplish the goal for both line-to-earth and line-to-line.

The systems and methods of this disclosure can be implemented in a hardware circuit, in a computing system environment, or a combination thereof. Examples of well-known computing system environments and components thereof that may be suitable for use with the systems and methods include, but are not limited to, personal computers, server computers, hand-held or laptop devices, tablet devices, smart phones, multiprocessor systems, microprocessor-based systems, set top boxes, programmable consumer electronics, network PCs, minicomputers, mainframe computers, distributed computing environments that include any of the above systems or devices, and the like. Typical computing system environments and their operations and components are described in many existing patents (e.g., U.S. Pat. No. 7,191,467, owned by Microsoft Corp.).

The methods may be carried out via non-transitory computer-executable instructions, such as program modules. Generally, program modules include routines, programs, objects, components, data structures, and so forth, that perform particular tasks or implement particular types of data. The methods may also be practiced in distributed computing environments where tasks are performed by remote processing devices that are linked through a communications network. In a distributed computing environment, program modules may be located in both local and remote computer storage media including memory storage devices.

The processes and functions described herein can be non-transitorily stored in the form of software instructions in the computer. Components of the computer may include, but are not limited to, a computer processor, a computer storage medium serving as memory, and a system bus that couples various system components including the memory to the computer processor. The system bus can be of any of several types of bus structures including a memory bus or memory controller, a peripheral bus, and a local bus using any of a variety of bus architectures.

The computer typically includes one or more a variety of computer-readable media accessible by the processor and including both volatile and nonvolatile media and removable and non-removable media. By way of example, computer-readable media can comprise computer-storage media and communication media.

The computer storage media can store the software and data in a non-transitory state and includes both volatile and nonvolatile, removable and non-removable media implemented in any method or technology for storage of software and data, such as computer-readable instructions, data structures, program modules, or other data. Computer-storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium that can be used to store the desired information and that can be accessed and executed by the processor.

The memory includes computer-storage media in the form of volatile and/or nonvolatile memory such as read only memory (ROM) and random-access memory (RAM). A basic input/output system (BIOS), containing the basic routines that help to transfer information between elements within the computer, such as during start-up, is typically stored in the ROM. The RAM typically contains data and/or program modules that are immediately accessible to and/or presently being operated on by the processor.

The computer may also include other removable/non-removable, volatile/nonvolatile computer-storage media, such as (a) a hard disk drive that reads from or writes to non-removable, nonvolatile magnetic media; (b) a magnetic disk drive that reads from or writes to a removable, nonvolatile magnetic disk; and (c) an optical disk drive that reads from or writes to a removable, nonvolatile optical disk such as a CD ROM or other optical medium. The computer-storage medium can be coupled with the system bus by a communication interface, wherein the interface can include, e.g., electrically conductive wires and/or fiber-optic pathways for transmitting digital or optical signals between components. Other removable/non-removable, volatile/nonvolatile computer storage media that can be used in the exemplary operating environment include magnetic tape cassettes, flash memory cards, digital versatile disks, digital video tape, solid state RAM, solid state ROM, and the like.

The drives and their associated computer-storage media provide storage of computer-readable instructions, data structures, program modules, and other data for the computer. For example, a hard disk drive inside or external to the computer can store an operating system, application programs, and program data.

Thus, the scope of this disclosure should be determined by the appended claims and their legal equivalents, rather than the examples given. In describing embodiments in this disclosure, specific terminology is used for the sake of clarity. For the purpose of description, specific terms are intended to at least include technical and functional equivalents that operate in a similar manner to accomplish a similar result. Additionally, in some instances where a particular embodiment includes a plurality of system elements or method steps, those elements or steps may be replaced with a single element or step; likewise, a single element or step may be replaced with a plurality of elements or steps that serve the same purpose. Moreover, while this disclosure has been shown and described with references to particular embodiments thereof, those skilled in the art will understand that various substitutions and alterations in form and details may be made therein without departing from the scope of this disclosure. Further still, other aspects, functions and advantages are also within the scope of this disclosure; and all embodiments of this disclosure need not necessarily achieve all of the advantages or possess all of the characteristics described above. Additionally, steps, elements and features discussed herein in connection with one embodiment can likewise be used in conjunction with other embodiments. Still further, the components, steps and features identified in the Background section are integral to this disclosure and can be used in conjunction with or substituted for components and steps described elsewhere in the disclosure within the scope of the method and apparatus herein. In method claims, where stages are recited in a particular order—with or without sequenced prefacing characters added for ease of reference—the stages are not to be interpreted as being temporally limited to the order in which they are recited unless otherwise specified or implied by the terms and phrasing.

What is claimed is:

1. A method to detect cross-port faults in a fault managed power (FMP) transmission system, the method comprising:
providing a first transmission line having a high potential conductor and a low potential conductor;
connecting a first end of the first transmission line to an output port of a first transmitter, the first transmitter receiving power from a first power source;
connecting a second end of the first transmission line to an input port of a first receiver;
providing a second transmission line comprising a high potential conductor and a low potential conductor;
connecting a first end of the second transmission line to an output port of a second transmitter, the second transmitter receiving power from a second power source;
connecting a second end of the second transmission line to an input port of a second receiver;
connecting with the first transmitter the first power source to the first transmission line via a first switch and a second switch causing current to flow from the first power source to the first transmission line during FMP power transfer intervals and at least partially nominally isolating the first power source from the first transmission line during FMP isolation intervals;
connecting with the second transmitter the second power source to the second transmission line via a third switch and a fourth switch causing current to flow from the second power source to the second transmission line during FMP power transfer intervals and at least partially nominally isolating the second power source from the second transmission line during FMP isolation intervals;
during isolation intervals, monitoring for either:
an electrical characteristic indicative of a first fault current through a first unidirectional switching element in the first transmitter in a direction flowing from the output port of the first transmitter to the first source or for an electrical characteristic indicative of a second fault current through a second unidirectional switching element in the second transmitter in a direction flowing from the second source to the output port of the second transmitter indicating a cross-port fault between the lower potential conductor of the first transmission line and the higher potential conductor of the second transmission line; or
an electrical characteristic indicative of a third fault current through a third unidirectional switching element in the first receiver in a direction flowing from the input port of the first receiver to a first bulk capacitor in the first receiver or for an electrical characteristic indicative of a fourth fault current through a fourth unidirectional switching element in the second receiver in a direction flowing from a second bulk capacitor in the second receiver to the input port of the second receiver indicating a cross-port fault between the lower potential conductor of the first transmission line and the higher potential conductor of the second transmission line; and
in response to detecting an electrical characteristic indicative of one of the first fault current, the second fault current, the third fault current, or the fourth fault current limiting said detected first fault current, second fault current, third fault current, or fourth fault current within a predefined amount of time.

2. The method of claim 1, wherein the electrical characteristic indicative of the first fault current, the second fault current, the third fault current, or the fourth fault current includes, respectively, detecting a change in voltage drop across the first transmitter output port, the second transmitter output port, the first receiver input port, or the second receiver input port.

3. The method of claim 1, wherein the electrical characteristic indicative of the first fault current, the second fault current, the third fault current, or the fourth fault current includes detecting a faster time constant or increased non-linearity during a first time interval as compared to a time constant or non-linearity during a second time interval; wherein during the first time interval, the first unidirectional switch conducts the first fault current, or the second unidirectional switch conducts the second fault current, the third unidirectional switch conducts the third fault current, or the fourth unidirectional switch conducts the fourth fault current; and wherein during the second time interval, the first unidirectional switch does not conduct the first fault current, the second unidirectional switch does not conduct the second fault current, the third unidirectional switch does not conduct the third fault current, and the fourth unidirectional switch does not conduct the fourth fault current.

4. The method of claim 3, wherein said non-linearity is determined using numerical analysis to produce an approximation in the form of a polynomial function, where the estimated accuracy of said polynomial function is based on the magnitude of the variance of the individual measurements from the approximation.

5. The method of claim 4, wherein the non-linearity is determined by the estimated accuracy of said polynomial function not meeting a minimum accuracy requirement.

6. The method of claim 1, further including providing the first unidirectional switch, the second unidirectional switch, the third unidirectional switch, or the fourth unidirectional switch with a transistor.

7. The method of claim 1, further including providing the first unidirectional switch, the second unidirectional switch, the third unidirectional switch, or the fourth unidirectional switch with a diode.

8. The method of claim 1, wherein the electrical characteristic indicative of the first fault current, the second fault current, the third fault current, or the fourth fault current includes detecting a value indicative of the energy transfer through the first unidirectional switch while it conducts the first fault current, the energy transfer through the second unidirectional switch while it conducts the second fault current, the energy transfer through the third unidirectional switch while it conducts the third fault current, or the energy transfer through the fourth unidirectional switch while it conducts the fourth fault current.

9. The method of claim 1, further including one or both of providing the first transmitter or the first receiver with a first snubber circuit and periodically connecting the first snubber circuit across the first transmission line and periodically isolating the first snubber circuit from the first transmission line; and providing the second transmitter or the second receiver with a second snubber circuit and periodically connecting the second snubber circuit across the second transmission line and periodically isolating the second snubber circuit from the second transmission line.

10. The method of claim 9, wherein the electrical characteristic indicative of the first fault current or the electrical characteristic indicative of the second fault current is measured while the first snubber is disconnected from the first transmission line and the second snubber is disconnected from the second transmission line.

11. The method of claim 1, further including providing the first power source and the second power source as either a single power source or two different power sources.

12. The method of claim 1, further including providing one or more of the first transmitter, the second transmitter, the first receiver, or the second receiver with one or more current sensors to measure, during an FMP power transfer interval, an imbalance current indicative of a current difference between either the first high potential conductor and the first low potential conductor or the second high potential conductor and the second low potential conductor.

13. The method of claim 12, wherein the imbalance current being outside of a predefined range is indicative of a fault, wherein the fault is at least a line-to-line cross-port fault between the first transmission line and the second transmission line or a line-to-earth fault.

14. A system to detect cross-port faults between a first transmission line comprising a high potential conductor and a low potential conductor and a second transmission line comprising a high potential conductor and a low potential conductor, the system comprising:
a first transmitter including an output port connected to the first transmission line, the first transmitter receiving power from a first power source, wherein the first transmitter includes a first switch and a second switch configured to connect the first power source to the first transmission line causing current to flow from the first power source to the first transmission line during power transfer intervals and wherein the first switch and the second switch are configured to disconnect the first power source from the first transmission line to at least partially nominally isolate the first power source from the first transmission line during isolation intervals;
a first receiver including an input port connected to the first transmission line;
a second transmitter including an output port connected to the second transmission line, the second transmitter receiving power from a second power source, wherein the second transmitter includes a third switch and a fourth switch configured to connect the second power source to the second transmission line causing current to flow from the second power source to the second transmission line during power transfer intervals and wherein the third switch and the fourth switch are configured to disconnect the second power source from the second transmission line to at least partially nominally isolate the second power source from the second transmission line during isolation intervals;
a second receiver including an input port connected to the second transmission line; and
a control circuit configured to either:
monitor during isolation intervals for an electrical characteristic indicative of a first fault current through a first unidirectional switching element in the first transmitter in a direction flowing from the output port of the transmitter to the first source or for an electrical characteristic indicative of a second fault current through a second unidirectional switching element in the second transmitter in a direction flowing from the second source to the output port of the second transmitter indicating a cross-port fault between the lower potential conductor of the first transmission line and the higher potential conductor of the second transmission line, and in response to detecting an electrical characteristic indicative of either the first fault current or the second fault current, limiting said detected first fault current or said second fault current within a predefined amount of time; or
monitor during isolation intervals for an electrical characteristic indicative of a third fault current through a third unidirectional switching element in the first receiver in a direction flowing from the input port of the first receiver to a first bulk capacitor in the first receiver or for an electrical characteristic indicative of a fourth fault current through a fourth unidirectional switching element in the second receiver in a direction flowing from a second bulk capacitor in the second receiver to the input port of the second receiver indicating a cross-port fault between the lower potential conductor of the first transmission line and the higher potential conductor of the second transmission line, and limiting said third fault current or said fourth fault current within a predefined amount of time in response to detecting an electrical characteristic of either the third fault current or the fourth fault current.

15. The system of claim 14, wherein the control circuit is configured to detect a change in voltage drop across the first transmitter output port, the second transmitter output port, the first receiver input port, or the second receiver input port, as the electrical characteristic indicative of the first fault current, the second fault current, the third fault current, or the fourth fault current, respectively.

16. The system of claim 14, wherein, in connection with monitoring for the electrical characteristic indicative of the first fault current, the second fault current, the third fault current, or the fourth fault current, the control circuit is configured to detect a faster time constant or increased non-linearity during a first time interval as compared to a time constant or non-linearity during a second time interval; wherein during the first time interval, the first unidirectional switch conducts the first fault current, or the second unidirectional switch conducts the second fault current, or the third unidirectional switch conducts the third fault current, or the fourth unidirectional switch conducts the fourth fault current; and wherein during the second time interval, the first unidirectional switch does not conduct the first fault current, the second unidirectional switch does not conduct the second fault current, the third unidirectional switch does not conduct the third fault current, and the fourth unidirectional switch does not conduct the fourth fault current.

17. The system of claim 16, wherein the control circuit is configured to detect said non-linearity is using numerical analysis to produce an approximation in the form of a polynomial function, where the estimated accuracy of said polynomial function is based on the magnitude of the variance of the individual measurements from the approximation.

18. The system of claim 17, wherein the control circuit is configured to detect detection is determined by the estimated accuracy of the polynomial function not meeting a minimum accuracy requirement.

19. The system of claim 14, wherein the first unidirectional switch, the second unidirectional switch, the third unidirectional switch, or the fourth unidirectional switch comprises a transistor.

20. The system of claim 14, wherein the first unidirectional switch, the second unidirectional switch, the third unidirectional switch, or the fourth unidirectional switch comprises a diode.

21. The system of claim 14, wherein the electrical characteristic indicative of the first fault current, the second fault current, the third fault current, or the fourth fault current includes a value indicative of the energy transfer through the first unidirectional switch while it conducts the first fault current or the energy transfer through the second unidirectional switch while it conducts the second fault current.

22. The system of claim 14, wherein the first transmitter or the first receiver includes a snubber circuit and wherein the control circuit is configured to periodically connect the first snubber circuit across the first transmission line and wherein the control circuit is configured to periodically isolate the first snubber circuit from the first transmission line; or wherein the second transmitter or the second receiver includes a snubber circuit and wherein the control circuit is configured to periodically connect the second snubber circuit across the second transmission line and wherein the control circuit is configured to periodically isolate the second snubber circuit from the second transmission line.

23. The system of claim 22, wherein the electrical characteristic indicative of the first fault current or the electrical characteristic indicative of the second fault current is measured while the first snubber is disconnected from the first transmission line and the second snubber is disconnected from the second transmission line.

24. The system of claim 14, wherein the first power source and the second power source are either a single power source or two different power sources.

25. The system of claim 24, wherein the control circuit comprises a first control circuit implemented in the first transmitter, the first receiver, or in part in both the first transmitter and the first receiver and a second control circuit implemented in the second transmitter, the second receiver, or in part in both the second transmitter and the second receiver.

26. The system of claim 14, wherein the first transmitter, the second transmitter, the first receiver, or the second receiver further comprises one or more current sensors to measure, during an FMP power transfer interval, an imbalance current indicative of a current difference between either the first high potential conductor and the first low potential conductor or the second high potential conductor and the second low potential conductor.

27. The system of claim 26, wherein the imbalance current being outside of a predefined range is indicative of a fault, wherein the fault is at least a line-to-line cross-port fault between the first transmission line and the second transmission line or a line-to-earth fault.
